(19) United States
(12) Patent Application Publication
(10) Pub. No.: US 2025/0301707 A1
(43) Pub. Date: Sep. 25, 2025

(54) OXIDE SEMICONDUCTOR FILM AND SEMICONDUCTOR DEVICE

(71) Applicant: SEMICONDUCTOR ENERGY LABORATORY CO., LTD., Atsugi-shi (JP)

(72) Inventors: Shunpei YAMAZAKI, Tokyo (JP); Fumito ISAKA, Zama (JP); Toshikazu OHNO, Atsugi (JP); Yuji EGI, Atsugi (JP); Yuichi SATO, Isehara (JP); Seiji YASUMOTO, Tochigi (JP)

(21) Appl. No.: 19/079,699

(22) Filed: Mar. 14, 2025

(30) Foreign Application Priority Data
Mar. 21, 2024 (JP) 2024-045180
Mar. 21, 2024 (JP) 2024-045186
May 23, 2024 (JP) 2024-084366
Dec. 26, 2024 (JP) 2024-229970

(51) Int. Cl. H10D 30/67; H01L 21/385; H10D 62/40; H10D 62/60; H10D 86/40

(52) U.S. Cl. CPC H10D 30/6755; H01L 21/385; H10D 30/6706; H10D 30/6713; H10D 30/6728; H10D 30/6731; H10D 30/6734; H10D 30/6736; H10D 30/6757; H10D 62/40; H10D 62/60; H10D 86/423; H10D 86/425; H10D 86/471

(57) ABSTRACT

An oxide semiconductor film with high carrier mobility is provided. The oxide semiconductor film contains indium and oxygen. The oxide semiconductor film includes a crystal grain. The gallium concentration and the zinc concentration in the oxide semiconductor film are each lower than or equal to 0.1 atomic %. The extension length of a grain boundary in the oxide semiconductor film is greater than or equal to 0 nm and less than or equal to 10000 nm. The extension length of the grain boundary is calculated using a field of view of 90 nm square extracted from a TEM image of the oxide semiconductor film. The oxide semiconductor film has a property of transmitting oxygen in a range higher than or equal to 2×10²⁰ atoms/cm³ and lower than or equal to 1×10²¹ atoms/cm³ in heat treatment at a heating temperature of 400° C. for a treatment time of 8 hours.

### BACKGROUND OF THE INVENTION

### 1. Field of the Invention

One embodiment of the present invention relates to an oxide semiconductor film and a method for forming the oxide semiconductor film. One embodiment of the present invention also relates to a semiconductor device, a memory device, a display device, and an electronic device each including the oxide semiconductor film. One embodiment of the present invention also relates to a method for fabricating a semiconductor device including the oxide semiconductor film.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, semiconductor devices have been developed, and large-scale integrations (LSIs), central processing units (CPUs), memories (memory devices), and the like are mainly used in semiconductor devices. A CPU is an aggregation of semiconductor elements; the CPU includes an integrated circuit (including a transistor and a memory) formed into a chip by processing a semiconductor wafer, and is provided with an electrode that is a connection terminal.

An integrated circuit (IC) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely known, but oxide semiconductors have been attracting attention as alternative materials.

A transistor including an oxide semiconductor is known to have an extremely low leakage current in an off state. For example, Patent Document 1 discloses a low-power-consumption CPU utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

Examples of an oxide semiconductor that can be used for an active layer of a transistor include indium oxide and indium gallium zinc oxide. Non-Patent Document 2 discloses a thin film transistor in which hydrogenated polycrystal indium oxide formed by low-temperature solid phase crystallization is used for an active layer.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Documents

[Non-Patent Document 1] M. Oota, et al., “3D-Stacked CAAC—In—Ga—Zn Oxide FETs with Gate Length of 72 nm”, IEDM Tech. Dig., 2019, pp. 50-53
[Non-Patent Document 2] Y. Magari, et al., “High-mobility hydrogenated polycrystalline In₂O₃ (In₂O₃:H) thin-film transistors”, Nature Communications, 13, 1078 (2022)
[Non-Patent Document 3] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide an oxide semiconductor film with high carrier mobility. An object of one embodiment of the present invention is to provide a novel oxide semiconductor film. An object of one embodiment of the present invention is to provide a transistor, a semiconductor device, a memory device, or a display device that includes an oxide semiconductor film.

An object of one embodiment of the present invention is to provide a transistor with excellent electrical characteristics. An object of one embodiment of the present invention is to provide a transistor with a high on-state current. An object of one embodiment of the present invention is to provide a transistor with small parasitic capacitance. An object of one embodiment of the present invention is to provide a transistor, a semiconductor device, a memory device, or a display device that has high reliability. An object of one embodiment of the present invention is to provide a transistor, a semiconductor device, or a memory device that can be scaled down or highly integrated. An object of one embodiment of the present invention is to provide a semiconductor device, a memory device, or a display device that consumes low power. An object of one embodiment of the present invention is to provide a transistor, a semiconductor device, or a memory device that operates at high speed. An object of one embodiment of the present invention is to provide a display device with a high resolution or a high aperture ratio. An object of one embodiment of the present invention is to provide a method for fabricating the transistor, the semiconductor device, the memory device, or the display device.

Note that the description of these objects does not preclude the existence of other objects. One embodiment of the present invention does not necessarily achieve all of these objects. Other objects can be derived from the description of the specification, the drawings, and the claims.

One embodiment of the present invention is an oxide semiconductor film containing indium and oxygen. The oxide semiconductor film includes a crystal grain. A gallium concentration and a zinc concentration in the oxide semiconductor film are each lower than or equal to 0.1 atomic %. An extension length of a grain boundary in the oxide semiconductor film is greater than or equal to 0 nm and less than or equal to 10000 nm. The extension length of the grain boundary is calculated using a field of view of 90 nm square extracted from a transmission electron microscope (TEM) image of the oxide semiconductor film. The oxide semiconductor film has a property of transmitting oxygen in a range higher than or equal to 2×10²⁰ atoms/cm³ and lower than or equal to 1×10²¹ atoms/cm³ in heat treatment at a heating temperature of 400° C. for a treatment time of 8 hours.

One embodiment of the present invention is an oxide semiconductor film containing indium and oxygen. The oxide semiconductor film includes a crystal grain. A gallium concentration and a zinc concentration in the oxide semiconductor film are each lower than or equal to 0.1 atomic %. An extension length of a grain boundary in the oxide semiconductor film is greater than or equal to 0 nm and less than or equal to 10000 nm. The extension length of the grain boundary is calculated using a field of view of 90 nm square extracted from a TEM image of the oxide semiconductor film. Oxygen in a range higher than or equal to 2×10²⁰ atoms/cm³ and lower than or equal to 1×10²¹ atoms/cm³ diffuses in the crystal grain by heat treatment at a heating temperature of 400° C. for a treatment time of 8 hours.

One embodiment of the present invention is an oxide semiconductor film having a property of transmitting oxygen. The oxide semiconductor film contains indium and oxygen. The oxide semiconductor film includes a crystal grain. A gallium concentration and a zinc concentration in the oxide semiconductor film are each lower than or equal to 0.1 atomic %. An extension length of a grain boundary in the oxide semiconductor film is greater than or equal to 0 nm and less than or equal to 10000 nm. The extension length of the grain boundary is calculated using a field of view of 90 nm square extracted from a TEM image of the oxide semiconductor film. In the case where the oxide semiconductor film is provided between a first film and a second film, oxygen in a range higher than or equal to 2×10²⁰ atoms/cm³ contained in the first film diffuses into the second film through the oxide semiconductor film by heat treatment at a heating temperature of 400° C. for a treatment time of 8 hours. The first film includes a region where an oxygen concentration measured by secondary ion mass spectrometry (SIMS) is higher than or equal to 1×10²² atoms/cm³. The second film before the heat treatment includes a region where an oxygen concentration measured by SIMS is lower than 1×10²⁰ atoms/cm³.

One embodiment of the present invention is an oxide semiconductor film containing indium and oxygen. The oxide semiconductor film includes a crystal grain. A gallium concentration and a zinc concentration in the oxide semiconductor film are each lower than or equal to 0.1 atomic %. An extension length of a grain boundary in the oxide semiconductor film is greater than or equal to 0 nm and less than or equal to 10000 nm. The extension length of the grain boundary is calculated using a field of view of 90 nm square extracted from a TEM image of the oxide semiconductor film. The oxide semiconductor film has a property such that an integral value of a diffusion amount of deuterium is greater than or equal to 5×10¹² atoms/cm² and less than or equal to 1×10¹⁴ atoms/cm² in heat treatment at a heating temperature of 200° C. for a treatment time of 8 hours.

The extension length of the grain boundary in the oxide semiconductor film is preferably greater than or equal to 0 nm and less than or equal to 1000 nm.

A carbon concentration and an aluminum concentration in the oxide semiconductor film are each preferably lower than 100 ppm.

One embodiment of the present invention is a semiconductor device that includes an oxide semiconductor layer including the oxide semiconductor film, a conductive layer, and an insulating layer including a portion positioned between the oxide semiconductor layer and the conductive layer.

It is preferable that the semiconductor device include an oxide layer overlapping with the insulating layer with the oxide semiconductor layer therebetween, and the oxide layer include a cubic crystal grain.

In the semiconductor device, a lattice mismatch degree of the crystal grain in the oxide semiconductor film with respect to the crystal grain in the oxide layer is preferably higher than or equal to −10% and lower than or equal to 10%.

In the semiconductor device, the oxide layer preferably contains yttrium, zirconium, and oxygen.

It is preferable that the semiconductor device include an oxide layer overlapping with the insulating layer with the oxide semiconductor layer therebetween, and the oxide layer include a hexagonal crystal grain or a trigonal crystal grain.

In the semiconductor device, it is preferable that a c-axis of the crystal grain in the oxide layer be perpendicular or substantially perpendicular to a surface or a formation surface of the oxide layer.

In the semiconductor device, the oxide layer preferably contains indium, gallium, zinc, and oxygen.

It is preferable that the semiconductor device include a layer between the oxide layer and the oxide semiconductor layer, and the layer contain aluminum and oxygen.

In the semiconductor device, it is preferable that the oxide semiconductor layer include an In—Ga—Zn oxide film over the oxide semiconductor film, and the oxide semiconductor film have a higher property of transmitting one or both of an oxygen atom and a hydrogen atom than the In—Ga—Zn oxide film.

One embodiment of the present invention is a method for fabricating a semiconductor device. The method includes a step of forming a first insulating layer including silicon oxide over a first conductive layer; a step of adding nitrogen dioxide and oxygen to the first insulating layer by plasma treatment using a nitrogen-containing gas; a step of forming a second conductive layer over the first insulating layer; a step of forming an opening portion reaching the first conductive layer by processing the second conductive layer and the first insulating layer; a step of forming an oxide layer to cover the opening portion; a step of forming an oxide semiconductor layer over the oxide layer; a step of forming a second insulating layer over the oxide semiconductor layer and the first insulating layer to have a portion in contact with the oxide semiconductor layer and a portion in contact with the first insulating layer; and a step of supplying oxygen added to the first insulating layer to the oxide semiconductor layer through the second insulating layer by heat treatment.

In the method for fabricating the semiconductor device, the oxide semiconductor layer preferably has a higher property of transmitting an oxygen atom than the oxide layer.

In the method for fabricating the semiconductor device, it is preferable that the oxide semiconductor layer include an indium oxide film and the indium oxide film include a crystal grain.

In the method for fabricating the semiconductor device, the oxide layer preferably contains indium, gallium, zinc, and oxygen.

In the method for fabricating the semiconductor device, it is preferable that the oxide layer include a hexagonal crystal grain or a trigonal crystal grain, and a c-axis of the crystal grain in the oxide layer be perpendicular or substantially perpendicular to a surface or a formation surface of the oxide layer.

In the method for fabricating the semiconductor device, the oxide layer preferably contains yttrium, zirconium, and oxygen.

One embodiment of the present invention is a method for fabricating a semiconductor device. The method includes a step of forming a first insulating layer including silicon oxide over a first conductive layer; a step of adding nitrogen dioxide and oxygen to the first insulating layer by plasma treatment using a nitrogen-containing gas; a step of forming a second conductive layer over the first insulating layer; a step of forming an opening portion reaching the first conductive layer by processing the second conductive layer and the first insulating layer; a step of forming an oxide layer to cover the opening portion; a step of forming an oxide semiconductor layer over the oxide layer; a step of forming a second insulating layer over the oxide semiconductor layer and the first insulating layer to have a portion in contact with the oxide semiconductor layer and a portion in contact with the first insulating layer; and a step of supplying oxygen added to the first insulating layer to the oxide semiconductor layer through the oxide layer and the second insulating layer by heat treatment.

In the method for fabricating the semiconductor device, it is preferable that the oxide semiconductor layer include an indium oxide film and the indium oxide film include a crystal grain.

In the method for fabricating the semiconductor device, a nitrogen gas or a dinitrogen monoxide gas is preferably used as the nitrogen-containing gas.

In the method for fabricating the semiconductor device, a difference between a spin density corresponding to an absorption peak at a g-factor greater than or equal to 1.94 and less than or equal to 2.05, which is obtained by electron spin resonance measurement on the first insulating layer before the heat treatment, and a spin density corresponding to an absorption peak at a g-factor greater than or equal to 1.94 and less than or equal to 2.05, which is obtained by electron spin resonance measurement on the first insulating layer after the heat treatment, is preferably less than or equal to 10%.

According to one embodiment of the present invention, an oxide semiconductor film with high carrier mobility can be provided. According to one embodiment of the present invention, a novel oxide semiconductor film can be provided. According to one embodiment of the present invention, a transistor, a semiconductor device, a memory device, or a display device that includes an oxide semiconductor film can be provided.

According to one embodiment of the present invention, a transistor with excellent electrical characteristics can be provided. According to one embodiment of the present invention, a transistor with a high on-state current can be provided. According to one embodiment of the present invention, a transistor with small parasitic capacitance can be provided. According to one embodiment of the present invention, a transistor, a semiconductor device, a memory device, or a display device that has high reliability can be provided. According to one embodiment of the present invention, a transistor, a semiconductor device, or a memory device that can be scaled down or highly integrated can be provided. According to one embodiment of the present invention, a semiconductor device, a memory device, or a display device that consumes low power can be provided. According to one embodiment of the present invention, a transistor, a semiconductor device, or a memory device that operates at high speed can be provided. According to one embodiment of the present invention, a display device with a high resolution or a high aperture ratio can be provided. According to one embodiment of the present invention, a method for fabricating the transistor, the semiconductor device, the memory device, or the display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A to 1G are cross-sectional views illustrating examples of a semiconductor device, and FIGS. 1H and 1I are perspective views illustrating examples of the semiconductor device;

FIGS. 2A1, 2A2, 2B1, 2B2, 2C1, 2C2, 2D1, and 2D2 illustrate crystal structures of a metal oxide and silicon;

FIGS. 3A and 3B are schematic perspective views illustrating an example of a semiconductor device;

FIG. 4A is a plan view illustrating an example of a semiconductor device, and FIGS. 4B to 4D are cross-sectional views illustrating an example of the semiconductor device;

FIGS. 5A and 5B are cross-sectional views illustrating an example of a semiconductor device;

FIGS. 6A and 6B are cross-sectional views illustrating an example of a semiconductor device;

FIGS. 7A and 7B are cross-sectional views illustrating examples of a semiconductor device;

FIGS. 8A to 8D are cross-sectional views illustrating examples of a semiconductor device;

FIGS. 9A and 9B are cross-sectional views illustrating examples of a semiconductor device;

FIGS. 10A and 10B are cross-sectional views illustrating examples of a semiconductor device;

FIGS. 11A and 11B are cross-sectional views illustrating examples of a semiconductor device;

FIG. 12A is a plan view illustrating an example of a semiconductor device, and FIGS. 12B and 12C are cross-sectional views illustrating an example of the semiconductor device;

FIGS. 13A and 13B are cross-sectional views illustrating examples of a semiconductor device;

FIG. 14A is a plan view illustrating an example of a semiconductor device, and FIGS. 14B to 14D are cross-sectional views illustrating an example of the semiconductor device;

FIGS. 15A and 15B are cross-sectional views illustrating an example of a semiconductor device;

FIGS. 16A and 16B are cross-sectional views illustrating examples of a semiconductor device;

FIG. 17 is a cross-sectional view illustrating an example of a semiconductor device;

FIGS. 18A and 18B are cross-sectional views illustrating examples of a semiconductor device;

FIGS. 19A and 19B are cross-sectional views illustrating examples of a semiconductor device;

FIG. 20A is a plan view illustrating an example of a semiconductor device, and FIGS. 20B to 20D are cross-sectional views illustrating an example of the semiconductor device;

FIGS. 21A and 21B are cross-sectional views illustrating examples of a semiconductor device;

FIG. 22A is a plan view illustrating an example of a semiconductor device, and FIGS. 22B to 22D are cross-sectional views illustrating an example of the semiconductor device;

FIG. 23A is a plan view illustrating an example of a semiconductor device, and FIGS. 23B and 23C are cross-sectional views illustrating an example of the semiconductor device;

FIGS. 24A to 24C are schematic perspective views illustrating an example of a semiconductor device;

FIG. 25A is a plan view illustrating an example of a semiconductor device, and FIGS. 25B to 25D are cross-sectional views illustrating an example of the semiconductor device;

FIG. 26A is a plan view illustrating an example of a semiconductor device, and FIGS. 26B and 26C are cross-sectional views illustrating an example of the semiconductor device;

FIG. 27A is a plan view illustrating an example of a semiconductor device, and FIGS. 27B and 27C are cross-sectional views illustrating an example of the semiconductor device;

FIG. 28A is a plan view illustrating an example of a semiconductor device, and FIGS. 28B to 28D are cross-sectional views illustrating an example of the semiconductor device;

FIGS. 29A and 29B are cross-sectional views illustrating examples of a semiconductor device;

FIGS. 30A to 30C are cross-sectional views illustrating examples of a semiconductor device;

FIG. 31A is a plan view illustrating an example of a semiconductor device, and FIGS. 31B to 31D are cross-sectional views illustrating an example of the semiconductor device;

FIG. 32A is a plan view illustrating an example of a semiconductor device, and FIGS. 32B to 32D are cross-sectional views illustrating an example of the semiconductor device;

FIGS. 33A to 33C are cross-sectional views illustrating examples of a semiconductor device;

FIG. 34A is a plan view illustrating an example of a semiconductor device, and FIGS. 34B to 34D are cross-sectional views illustrating an example of the semiconductor device;

FIG. 35 is a cross-sectional view illustrating an example of a semiconductor device;

FIGS. 36A and 36B show the dependence of Hall mobility on a carrier concentration, and FIG. 36C is a cross-sectional view of an indium oxide film;

FIG. 37A is a plan view illustrating an example of a memory device, and FIGS. 37B and 37C are cross-sectional views illustrating an example of the memory device;

FIG. 38A is a plan view illustrating an example of a memory device, and FIGS. 38B and 38C are cross-sectional views illustrating an example of the memory device;

FIGS. 39A to 39C are cross-sectional views illustrating examples of a memory device;

FIGS. 40A and 40B are cross-sectional views illustrating an example of a memory device;

FIGS. 41A and 41B are a plan view and a cross-sectional view illustrating an example of a memory device;

FIG. 42 is a cross-sectional view illustrating an example of a memory device;

FIG. 43 is a cross-sectional view illustrating an example of a memory device;

FIG. 44 is a block diagram illustrating a structure example of a semiconductor device;

FIGS. 45A to 45G illustrate circuit configuration examples of memory cells;

FIGS. 46A and 46B are perspective views illustrating structure examples of a semiconductor device;

FIG. 47 is a block diagram illustrating a CPU;

FIGS. 48A and 48B are perspective views of a semiconductor device;

FIGS. 49A and 49B are perspective views of semiconductor devices;

FIGS. 50A and 50B are perspective views illustrating an example of a display device;

FIG. 51 is a cross-sectional view illustrating an example of a display device;

FIG. 52 is a cross-sectional view illustrating an example of a display device;

FIGS. 53A and 53B illustrate examples of electronic components;

FIGS. 54A to 54C illustrate an example of a large computer, FIG. 54D illustrates an example of space equipment, and FIG. 54E illustrates an example of a storage system that can be used in a data center;

FIGS. 55A to 55F illustrate examples of electronic devices;

FIGS. 56A to 56G illustrate examples of electronic devices;

FIGS. 57A to 57F illustrate examples of electronic devices;

FIGS. 58A to 58E show SIMS analysis results of samples in Example;

FIGS. 59A to 59E show SIMS analysis results of samples in Example;

FIGS. 60A to 60E show SIMS analysis results of samples in Example;

FIGS. 61A to 61E show SIMS analysis results of samples in Example;

FIGS. 62A1, 62A2, 62B1, 62B2, 62C1, and 62C2 show TEM images of samples in Example;

FIGS. 63A1, 63A2, 63B1, and 63B2 show TEM images of samples in Example;

FIGS. 64A and 64B each illustrate a stacked-layer structure of stacked films;

FIGS. 65A to 65C show SIMS analysis results of fabricated samples;

FIGS. 66A and 66B show SIMS analysis results of fabricated samples;

FIGS. 67A and 67B each show a relationship between the extension length of a grain boundary and an oxygen concentration;

FIGS. 68A to 68C show SIMS analysis results of fabricated samples;

FIGS. 69A and 69B show SIMS analysis results of fabricated samples;

FIG. 70 is a conceptual diagram showing a method for calculating an integral value;

FIG. 71 shows a relationship between the extension length of a grain boundary and an integral value of the diffusion amount of deuterium;

FIG. 72 is a cross-sectional view illustrating a structure and a fabrication method of samples in Example;

FIGS. 73A to 73F show TDS analysis results in Example;

FIGS. 74A to 74C show TDS analysis results in Example;

FIGS. 75A to 75C show TDS analysis results in Example; and

FIG. 76 is a schematic view illustrating release of oxygen.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of current or voltage, switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an oxide semiconductor (OS) transistor. A transistor containing silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region. In this specification and the like, a channel formation region refers to a region through which current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as Vo) in an oxide semiconductor, for example.

In this specification and the like, an oxynitride refers to a material in which an oxygen content is higher than a nitrogen content. A nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The content of an element such as hydrogen, oxygen, carbon, or nitrogen in a film can be analyzed by secondary ion mass spectrometry (SIMS) or X-ray photoelectron spectroscopy (XPS or electron spectroscopy for chemical analysis (ESCA)), for example. XPS is suitable when the content of a target element is high (e.g., 0.5 atomic % or more, or 1 atomic % or more). By contrast, SIMS is suitable when the content of a target element is low (e.g., 0.5 atomic % or less, or 1 atomic % or less). To compare the contents of elements, analysis with a combination of SIMS and XPS is preferably used.

In this specification and the like, a content percentage refers to a proportion of a component contained in a film. In the case where an oxide semiconductor layer contains a metal element X, a metal element Y, and a metal element Z whose atomic numbers are respectively represented by A_{X}, A_{Y}, and A_{Z}, for example, the content percentage of the metal element X can be represented by A_{X}/(A_{X}+A_{Y}+A_{Z}). Moreover, in the case where the atomic ratio between the metal element X, the metal element Y, and the metal element Z contained in the oxide semiconductor layer is represented by B_{X}:B_{Y}:B_{Z}, the content percentage of the metal element X can be represented by B_{X}/(B_{X}+B_{Y}+B_{Z}).

Note that the terms “film” and “layer” can be used interchangeably depending on the case or the circumstances. For example, the term “conductive layer” can be replaced with the term “conductive film”. For another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. The term “substantially perpendicular” indicates that the angle formed between two straight lines is greater than or equal to 70° and less than or equal to 110°.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

Unless otherwise specified, an off-state current in this specification and the like refers to leakage current between a source and a drain generated when a transistor is in an off state (also referred to as a non-conducting state or a cutoff state). Unless otherwise specified, the off state of an n-channel transistor means that gate-source voltage V_{gs} is lower than threshold voltage Vₜₕ, and the off state of a p-channel transistor means that V_{gs} is higher than Vₜₕ.

In this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is positioned over B” is used, at least part of A is positioned over B. In other words, A includes a region positioned over B, for example. Similarly, when the expression “A is in contact with B” or “A overlaps with B” is used, at least part of A is in contact with or overlaps with B. In other words, A includes a region in contact with B or A includes a region overlapping with B. Similarly, in this specification and the like, when the expression “A covers B” is used, at least part of A covers B. In other words, A includes a region covering B, for example.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers of light-emitting elements (also referred to as light-emitting devices) having different emission wavelengths are separately formed may be referred to as a side-by-side (SBS) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the carrier-injection layer, the carrier-transport layer, and the carrier-blocking layer cannot be clearly distinguished from each other. One layer may have two or three functions of the carrier-injection layer, the carrier-transport layer, and the carrier-blocking layer.

In this specification and the like, a light-emitting element includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, disconnection refers to a phenomenon in which a layer, a film, or an electrode is divided because of the shape of the formation surface (e.g., a level difference).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

In this specification and the like, a crystal structure of a cubic crystal system is sometimes referred to as a cubic crystal, a cubic crystal structure, or the like. The same applies to the other crystal systems (e.g., a hexagonal crystal system, a trigonal crystal system, a tetragonal crystal system, an orthorhombic crystal system, a monoclinic crystal system, and a triclinic crystal system).

### Embodiment 1

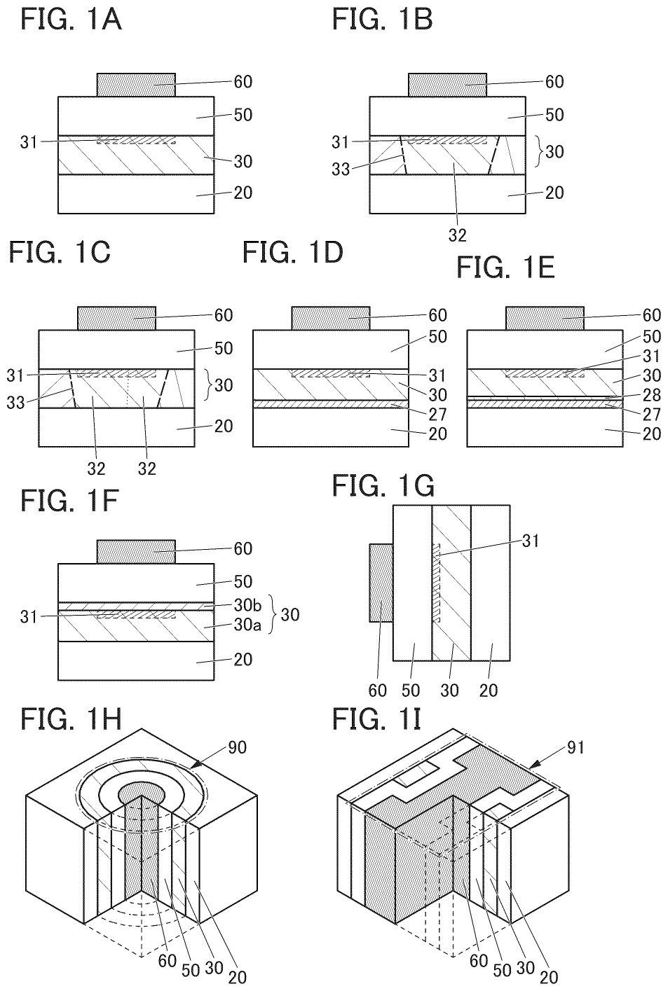

In this embodiment, a semiconductor device of one embodiment of the present invention will be described with reference to FIGS. 1A to 1I. The semiconductor device of one embodiment of the present invention can include an oxide semiconductor film of one embodiment of the present invention.

### [Structure Example of Semiconductor Device]

FIG. 1A is a schematic cross-sectional view of the semiconductor device of one embodiment of the present invention. The semiconductor device illustrated in FIG. 1A includes, over an insulating layer 20, an oxide semiconductor layer 30, an insulating layer 50, and a conductive layer 60. A transistor included in the semiconductor device of one embodiment of the present invention includes the oxide semiconductor layer 30, the insulating layer 50, and the conductive layer 60. The insulating layer 50 includes a portion positioned between the oxide semiconductor layer 30 and the conductive layer 60.

In the transistor of one embodiment of the present invention, the conductive layer 60 functions as a gate electrode and the insulating layer 50 functions as a gate insulating layer. The oxide semiconductor layer 30 includes a channel formation region 31. The oxide semiconductor layer 30 includes a region overlapping with the conductive layer 60 with the insulating layer 50 therebetween. At least part of the region functions as the channel formation region 31. Note that a source and a drain of the transistor are omitted in FIG. 1A.

The transistor of one embodiment of the present invention includes a metal oxide functioning as a semiconductor (also referred to as an oxide semiconductor) in the oxide semiconductor layer 30 including the channel formation region. That is, the transistor can be regarded as an OS transistor.

Oxygen vacancies and impurities in the channel formation region in the oxide semiconductor may easily vary the electrical characteristics of the OS transistor and may worsen the reliability thereof. In some cases, a defect that is an oxygen vacancy into which hydrogen enters (hereinafter, sometimes referred to as V_{O}H) is formed and an electron serving as a carrier is generated. Thus, when the channel formation region in the oxide semiconductor includes oxygen vacancies, the OS transistor is likely to be normally on. Accordingly, the oxygen vacancies and the impurities are preferably reduced as much as possible in the channel formation region in the oxide semiconductor. In other words, the oxide semiconductor preferably includes an i-type (intrinsic) or substantially i-type channel formation region with a low carrier concentration.

When an excessive amount of oxygen is supplied to the oxide semiconductor layer 30, an electron trap due to the oxygen is formed in the insulating layer 50. Thus, the OS transistor is likely to suffer from positive drift degradation in a gate bias temperature (+GBT) stress test. In other words, the amount of positive drift degradation in the +GBT stress test increases.

In view of this, the hydrogen concentration in the oxide semiconductor layer 30 is preferably low in the semiconductor device of one embodiment of the present invention. An appropriate amount of oxygen is preferably supplied to the oxide semiconductor layer 30. An excessive amount of oxygen in the oxide semiconductor layer 30 is preferably reduced.

Indium oxide is preferably used as the metal oxide used for the oxide semiconductor layer 30. For example, the oxide semiconductor layer 30 preferably includes an indium oxide film. The indium oxide film preferably includes the channel formation region 31. As the proportion of the number of indium atoms in the total number of atoms of all the metal elements included in the metal oxide is higher, the field-effect mobility of the transistor can be higher. Thus, the use of indium oxide for the oxide semiconductor layer 30 enables the transistor to have a high on-state current and high frequency characteristics.

The indium oxide film preferably has crystallinity. For example, the indium oxide film preferably includes a crystal grain in the channel formation region 31. Specifically, the indium oxide film is preferably a single crystal film or a polycrystal film. Impurities easily diffuse at a crystal grain boundary; thus, the indium oxide film is further preferably a single crystal film. Note that the indium oxide film may be an amorphous film including a crystal grain.

A crystal grain of a film having crystallinity can be observed in a high-resolution transmission electron microscope (TEM) image, for example. In addition, a crystal grain boundary of a film having crystallinity can sometimes be observed in a high-resolution TEM image, for example. That is, a crystal grain and a crystal grain boundary of a film having crystallinity can sometimes be observed in a high-resolution TEM image. The total magnification at the time of obtaining a TEM image is preferably greater than or equal to 2000000 times, further preferably greater than or equal to 4000000 times.

FIG. 1A illustrates a structure example in which the oxide semiconductor layer 30 includes a single crystal indium oxide film. In the case where the indium oxide film is a single crystal film, the indium oxide film includes one crystal grain, and a crystal grain boundary is not observed throughout the oxide semiconductor layer 30. That is, a crystal grain boundary is not observed in the channel formation region. Such a structure can inhibit carrier scattering or the like at the crystal grain boundary, achieving a transistor with high field-effect mobility and a transistor with high reliability.

FIG. 1B illustrates a structure example in which the oxide semiconductor layer 30 includes a polycrystal indium oxide film. In FIG. 1B, the indium oxide film includes a plurality of crystal grains 32, and a crystal grain boundary 33 is observed between the crystal grains 32. The crystal grain boundary is denoted by a dashed line in FIG. 1B.

In the case where the indium oxide film is a polycrystal film, it is preferable that one of the crystal grains 32 include a portion positioned in the channel formation region 31 and the crystal grain boundary not be observed in the channel formation region 31. Such a structure can produce an effect similar to that of the structure in which the indium oxide film is a single crystal film.

In the case where the channel formation region 31 is included in one crystal grain 32, the indium oxide film in the channel formation region 31 can be regarded as a single crystal.

FIG. 1C illustrates another example of the structure in which the oxide semiconductor layer 30 includes a polycrystal indium oxide film. In FIG. 1C, the indium oxide film includes the plurality of crystal grains 32, and two crystal grains 32 (a first crystal grain and a second crystal grain) are positioned in the channel formation region 31.

Here, it is preferable that the crystal orientation of the first crystal grain be aligned or substantially aligned with the crystal orientation of the second crystal grain. In the case where the crystal orientation of the first crystal grain is aligned or substantially aligned with the crystal orientation of the second crystal grain, a crystal grain boundary is sometimes not observed at the boundary (denoted by a dotted line in FIG. 1C) between the first crystal grain and the second crystal grain. When the crystal orientation of the first crystal grain is aligned or substantially aligned with the crystal orientation of the second crystal grain, the formation of the crystal grain boundary between the first crystal grain and the second crystal grain can be inhibited. Thus, such a structure can also produce an effect similar to that of the structure in which the indium oxide film is a single crystal film. Note that a state where the crystal orientation of the first crystal grain is aligned or substantially aligned with the crystal orientation of the second crystal grain can sometimes be observed in a high-resolution TEM image, for example. Specifically, this state can be observed in a high-resolution TEM image showing continuous connection between the lattice fringes of the first crystal grain and the lattice fringes of the second crystal grain at the boundary between the first crystal grain and the second crystal grain.

In this specification and the like, a crystal grain boundary refers to a boundary between adjacent crystal grains with different crystal orientations, for example. Thus, in this specification and the like, a crystal grain boundary does not include a boundary between adjacent crystal grains with the same crystal orientation. For example, in the case where a boundary is observed between two crystal grains in a high-resolution TEM image but the crystal orientations of the two crystal grains are aligned or substantially aligned with each other, the boundary is not called a crystal grain boundary in some cases.

The degree of the polycrystallinity of an indium oxide film can be evaluated from a crystal grain size. The crystal grain size can be calculated, for example, as the diameter of a perfect circle assumed to have an area equivalent to the calculated area of the crystal grain. The diameter here is sometimes referred to as an equivalent circular area diameter or the like.

The degree of the polycrystallinity of an indium oxide film can also be evaluated from the extension length of a grain boundary. The extension length of a grain boundary can be calculated as, for example, the total length of crystal grain boundaries observed in a field of view of a specific area extracted from a TEM image of a film obtained at a total magnification at which the crystal grain boundaries can be observed. The details will be described in Example. An indium oxide film in which the extension length of a grain boundary is 0 nm can be regarded as a single crystal film. As the extension length of a grain boundary is longer, the number of grain boundary components is larger.

The extension length of a grain boundary in an indium oxide film is preferably longer than or equal to 0 nm and shorter than or equal to 15000 nm, further preferably longer than or equal to 0 nm and shorter than or equal to 10000 nm, still further preferably longer than or equal to 0 nm and shorter than or equal to 8000 nm. In addition, the extension length of a grain boundary in an indium oxide film is preferably longer than or equal to 0 nm and shorter than or equal to 1500 nm, further preferably longer than or equal to 0 nm and shorter than or equal to 1000 nm, still further preferably longer than or equal to 0 nm and shorter than or equal to 800 nm. When the oxide semiconductor layer 30 includes an indium oxide film in which the extension length of a grain boundary falls within the above range, any of the structures illustrated in FIGS. 1A to 1C can be achieved. In this specification and the like, the area of a field of view used to calculate the extension length of a grain boundary is 90 nm square, unless otherwise specified.

The thickness of the oxide semiconductor layer 30 is preferably greater than or equal to 2 nm and less than or equal to 50 nm, further preferably greater than or equal to 2.5 nm and less than or equal to 30 nm, still further preferably greater than or equal to 2.5 nm and less than or equal to 20 nm, yet further preferably greater than or equal to 5 nm and less than or equal to 20 nm, yet still further preferably greater than or equal to 5 nm and less than or equal to 10 nm. Note that the oxide semiconductor layer 30 at least partly includes a region with the above thickness. For example, the channel formation region in the oxide semiconductor layer 30 includes a region with the above thickness.

When the thickness of the oxide semiconductor layer 30 falls within the above range, the crystallinity of the oxide semiconductor layer 30 can be increased. Increasing the crystallinity of the oxide semiconductor layer 30 allows the oxide semiconductor layer 30 to include a crystal grain.

In the case where a metal oxide contains indium and zinc, the metal oxide sometimes has high crystallinity, e.g., a c-axis aligned crystalline (CAAC) structure. The CAAC structure has fewer crystal grain boundaries in the a-b plane than a polycrystalline structure. Examples of the metal oxide containing indium and zinc include indium zinc oxide (also referred to as In—Zn oxide or IZO (registered trademark)) and indium gallium zinc oxide (also referred to as In—Ga—Zn oxide or IGZO).

In an oxide semiconductor layer having high crystallinity, one or both of hydrogen and oxygen move more easily in an indium oxide film than in an IGZO film, for example. Thus, it can be said that one or both of hydrogen and oxygen are more likely to be supplied to and released from an indium oxide film than to/from an IGZO film, for example. Note that an indium oxide film can be regarded as having a higher property of transmitting one or both of hydrogen and oxygen than an IGZO film, for example. In other words, an indium oxide film can be regarded as having a lower barrier property against one or both of hydrogen and oxygen than an IGZO film, for example.

The indium oxide film in this embodiment has a property of transmitting oxygen in a range higher than or equal to 1×10²⁰ atoms/cm³ and lower than or equal to 2×10²¹ atoms/cm³, preferably higher than or equal to 2×10²⁰ atoms/cm³ and lower than or equal to 1×10²¹ atoms/cm³, for example, in heat treatment at a heating temperature of 400° C. for a treatment time of 8 hours. The details will be described in Example.

The indium oxide film in this embodiment has a property of diffusing oxygen in a range higher than or equal to 1×10²⁰ atoms/cm³ and lower than or equal to 2×10²¹ atoms/cm³, preferably higher than or equal to 2×10²⁰ atoms/cm³ and lower than or equal to 1×10²¹ atoms/cm³, for example, through the crystal grain by heat treatment at a heating temperature of 400° C. for a treatment time of 8 hours.

When oxygen in the indium oxide film diffuses through the crystal grain and the crystal grain boundary, V_{O} and V_{O}H in the crystal grain or the crystal grain boundary can be reduced. This can inhibit the transistor from becoming normally on. In other words, the negative shift of the threshold voltage of the transistor can be eliminated in principle.

The indium oxide film in this embodiment has a property such that the integral value of the diffusion amount of deuterium (D (²H)) is greater than or equal to 5×10¹² atoms/cm² and less than or equal to 1×10¹⁴ atoms/cm² or greater than or equal to 1×10¹³ atoms/cm² and less than or equal to 8×10¹³ atoms/cm², for example, in heat treatment at a heating temperature of 200° C. for a treatment time of 8 hours. The details will be described in Example.

The indium oxide film in this embodiment has a property of diffusing deuterium through the crystal grain by heat treatment at a heating temperature of 200° C. for a treatment time of 8 hours such that the integral value of the diffusion amount of deuterium is greater than or equal to 5×10¹² atoms/cm² and less than or equal to 1×10¹⁴ atoms/cm² or greater than or equal to 1×10¹³ atoms/cm² and less than or equal to 8×10¹³ atoms/cm², for example.

When hydrogen in the indium oxide film diffuses through the crystal grain and the crystal grain boundary, hydrogen in the crystal grain or the crystal grain boundary can be reduced, for example, by heat treatment or the like. This can inhibit the transistor from becoming normally on. In other words, the negative shift of the threshold voltage of the transistor can be eliminated in principle.

The properties of transmitting oxygen and hydrogen in the film can be evaluated by calculation using a nudged elastic band (NEB) method, for example. Specifically, the properties can be evaluated using migration barriers against an oxygen atom and a hydrogen atom obtained by the calculation using the NEB method. As the value of the migration barrier is smaller, the corresponding atom moves (is transmitted) more easily.

Table 1 shows examples of calculation results. In Table 1, In₂O₃ is a crystal model of indium oxide and IGZO is a crystal model of In—Ga—Zn oxide. The term “excess oxygen” in Table 1 refers to oxygen whose amount is in excess of the stoichiometric composition.

TABLE 1

| | In₂O₃ | IGZO |
|---|---|---|
| Migration barrier against oxygen | 0.85 eV | 1.88 eV |
| Migration barrier against hydrogen | 0.34 eV | 1.39 eV |
| Migration barrier against excess oxygen | 1.25 eV | 1.43 eV |

According to Table 1, the migration barriers against oxygen, hydrogen, and excess oxygen in the crystal model of indium oxide are lower than those in the crystal model of In—Ga—Zn oxide. This indicates that oxygen and hydrogen move (are transmitted) more easily in the indium oxide film than in the In—Ga—Zn oxide film. It is also indicated that the indium oxide film has higher properties of transmitting an oxygen atom and a hydrogen atom than the In—Ga—Zn oxide film. It is thus presumed that hydrogen and oxygen are easily supplied to and released from the indium oxide film. Furthermore, an effect of filling Vo generated in the +GBT test with oxygen will be produced, probably achieving a highly reliable transistor.

The crystallinity of the oxide semiconductor layer 30 can be analyzed by X-ray diffractometry (XRD), transmission electron microscopy (TEM), or electron diffraction (ED), for example. Alternatively, these methods may be combined to be employed for analysis.

The content of a first element in the oxide semiconductor layer 30 is preferably low. In addition, the concentration of the first element in the oxide semiconductor layer 30 is preferably low. In particular, the concentration of the first element in the channel formation region is preferably low. Here, the first element is at least one of boron, carbon, aluminum, zinc, and gallium. That is, in the oxide semiconductor layer 30, the concentration of any one of boron, carbon, aluminum, zinc, and gallium is preferably low, the concentrations of two elements selected from boron, carbon, aluminum, zinc, and gallium are further preferably low, and the concentrations of all of boron, carbon, aluminum, zinc, and gallium are still further preferably low. The concentration of the first element in the oxide semiconductor layer 30 is preferably lower than or equal to 1 atomic %, further preferably lower than or equal to 0.1 atomic %, still further preferably lower than or equal to 0.01 atomic % (100 ppm), for example. Note that the preferable concentration of the first element in the oxide semiconductor layer 30 can be rephrased as a preferable concentration of the first element in the channel formation region.

When the concentrations of boron, carbon, and aluminum in the oxide semiconductor layer 30 are reduced, the crystallinity of the oxide semiconductor layer 30 can be improved.

In the case where the oxide semiconductor layer 30 contains a gallium atom, the gallium atom is bonded to an excess oxygen atom to form a Ga—O structure. The Ga—O structure functions as an acceptor that traps electrons. Thus, in the transistor including the oxide semiconductor layer 30 containing a gallium atom and an excess oxygen atom, the amount of threshold voltage change in a positive bias temperature stress (PBTS) test is large. Reducing the concentration of gallium in the oxide semiconductor layer 30 can reduce the amount of threshold voltage change in the PBTS test. Accordingly, the transistor can be highly reliable against positive bias application. A phenomenon similar to that in the case where the oxide semiconductor layer 30 contains a gallium atom occurs also in the case where the oxide semiconductor layer 30 contains a zinc atom.

The concentration of the first element can be evaluated by, for example, inductively coupled plasma-mass spectrometry (ICP-MS), XPS, SIMS, time-of-flight secondary ion mass spectrometry (ToF-SIMS), auger electron spectroscopy (AES), energy dispersive X-ray spectroscopy (EDX), inductively coupled plasma-atomic emission spectroscopy (ICP-AES), or the like.

The band gap of indium oxide is greater than or equal to 2.5 eV and less than or equal to 3.7 eV. The use of indium oxide having a wide band gap for the oxide semiconductor layer 30 leads to a low off-state current of the transistor, so that the power consumption of the semiconductor device can be sufficiently reduced.

An OS transistor is an accumulation transistor in which electrons are majority carriers. That is, carriers in an OS transistor are electrons. Assuming that the relaxation time of carriers is constant, the electron (carrier) mobility is higher as the effective mass of electrons (carriers) is smaller. That is, a transistor in which a metal oxide film with a small effective mass of electrons is used for a semiconductor layer can have a high on-state current or high field-effect mobility.

Table 2 shows the effective masses of electrons (me), the effective masses of holes (m*h), and the band gaps (Eg) in semiconductor materials. The semiconductor materials in Table 2 are indium oxide (here, In₂O₃), In—Ga—Zn oxide (IGZO), and silicon (Si). In Table 2, m*ₑ and m*ₕ are calculated by first-principles electronic state calculation and Eg is calculated by actual measurement. Note that Eg of silicon in Table 2 represents a typical measured value.

TABLE 2

| | In₂O₃ | IGZO | Si |
|---|---|---|---|
| m*ₑ | 0.17 | 0.21 | 0.26 |
| m*ₕ | 3.56 | 4.89 | 0.17 |
| Eg | 2.94 eV | 3.14 eV | 1.1 eV |

As shown in Table 2, the effective mass of electrons in indium oxide is small. Thus, the use of indium oxide with a small effective mass of electrons for the oxide semiconductor layer 30 enables a transistor to have a high on-state current, high field-effect mobility, or high frequency characteristics (also referred to as f characteristics). The effective mass of electrons in indium oxide is smaller than that in silicon, for example. Hence, in terms of the effective mass of electrons, the f characteristics of a transistor containing indium oxide in its channel formation region are higher than those of a Si transistor.

As shown in Table 2, the effective mass of holes in indium oxide is large. Thus, the use of indium oxide with a large effective mass of holes for the oxide semiconductor layer 30 enables a transistor to have an extremely low off-state current. The effective mass of holes in indium oxide is larger than that in silicon, for example. Hence, in terms of the effective mass of holes, the off-state current of a transistor containing indium oxide in its channel formation region is sufficiently lower than that of a Si transistor.

The off-state current per micrometer of channel width of the transistor in which indium oxide is used for the oxide semiconductor layer 30 at room temperature can be lower than or equal to 1×10⁻¹⁷ A/μm, preferably lower than or equal to 1×10⁻¹⁸ A/μm, further preferably lower than or equal to 1×10⁻¹⁹ A/μm. The off-state current per micrometer of channel width at 85° C. can be lower than or equal to 1×10⁻¹⁶ A/μm, preferably lower than or equal to 1×10⁻¹⁷ A/μm, further preferably lower than or equal to 1×10⁻¹⁸ A/μm.

Scaling down of an OS transistor can improve the high-frequency characteristics of the transistor. For example, the cutoff frequency of the transistor can be improved. Specifically, the cutoff frequency of the transistor can be higher than or equal to 50 GHZ, preferably higher than or equal to 100 GHz, further preferably higher than or equal to 150 GHz at room temperature.

A carrier is likely to flow through a region ranging from the surface of the oxide semiconductor layer 30 on the insulating layer 50 side to a depth of 1 nm. Thus, the channel formation region 31 is a region of the oxide semiconductor layer 30 that overlaps with the conductive layer 60 and ranges from the surface on the insulating layer 50 side to a depth of 1 nm or less. Alternatively, the channel formation region 31 is a region of the oxide semiconductor layer 30 that overlaps with the conductive layer 60 and ranges from the interface with the insulating layer 50 to a depth of 1 nm or less.

The interface between the oxide semiconductor layer 30 and the insulating layer 50 can be observed, for example, in a cross-sectional TEM image, a cross-sectional scanning transmission electron microscope (STEM) image, or the like. The interface between the oxide semiconductor layer 30 and the insulating layer 50 can sometimes be observed by performing SIMS or composition line analysis by EDX on the interface and its vicinity.

For example, EDX line analysis is performed on the interface and its vicinity with the direction perpendicular to the formation surface of the oxide semiconductor layer 30 regarded as the depth direction. Next, in the profiles of the quantitative values of elements in the depth direction obtained by the analysis, the depth at which the quantitative value of a metal (e.g., aluminum) that is the main component of the insulating layer 50 and is not the main component of the oxide semiconductor layer 30 becomes half can be defined as the interface. Alternatively, in the profiles of the quantitative values of the elements in the depth direction obtained by the analysis, the depth at which the quantitative value of a metal (e.g., indium) that is the main component of the oxide semiconductor layer 30 and is not the main component of the insulating layer 50 becomes half may be defined as the interface.

The indium oxide film can contain one or more kinds of metal elements with large period numbers in the periodic table as long as it has crystallinity. The larger the overlap between orbits of metal elements is, the more likely it is that the carrier conductivity will be increased. Thus, when a metal element with a large period number in the periodic table is contained, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, and light rare earth elements (lanthanum, cerium, prascodymium, neodymium, promethium, samarium, and curopium).

For example, the indium oxide film preferably contains antimony. The concentration of antimony in the indium oxide film is, for example, preferably higher than or equal to 1×10¹⁷ atoms/cm³ and lower than or equal to 8×10²¹ atoms/cm³, further preferably higher than or equal to 1×10¹⁷ atoms/cm³ and lower than or equal to 3×10²⁰ atoms/cm³, still further preferably higher than or equal to 1×10¹⁷ atoms/cm³ and lower than or equal to 1×10¹⁹ atoms/cm³. Alternatively, the concentration of antimony in the indium oxide film is preferably higher than or equal to 0.0002 atomic % and lower than or equal to 10 atomic %, further preferably higher than or equal to 0.0002 atomic % and lower than or equal to 0.5 atomic %, still further preferably higher than or equal to 0.0002 atomic % and lower than or equal to 0.013 atomic %. Note that the above preferable ranges also hold in the case where the indium oxide film contains any of the metal elements other than antimony.

Here, one of the insulating layer 20 and the insulating layer 50 is referred to as a first insulating layer, and the other of the insulating layer 20 and the insulating layer 50 is referred to as a second insulating layer.

The first insulating layer preferably has a function of supplying oxygen to the oxide semiconductor layer 30. The first insulating layer preferably includes a region containing oxygen that is released by heating (hereinafter, sometimes referred to as excess oxygen), for example. When the insulating layer including the region containing excess oxygen is in contact with the oxide semiconductor layer 30, oxygen can be supplied to the oxide semiconductor layer 30. Oxygen supplied to the oxide semiconductor layer 30 fills oxygen vacancies, so that the amount of oxygen vacancies in the oxide semiconductor layer 30 can be reduced. Examples of an insulating material that easily forms the region containing excess oxygen include silicon oxide, silicon oxynitride, and porous silicon oxide.

The second insulating layer preferably has a function of capturing or fixing (also referred to as gettering) oxygen. As described above, oxygen easily moves in the indium oxide film. Thus, when the second insulating layer has a function of capturing or fixing oxygen, an excessive amount of oxygen in the oxide semiconductor layer 30 can diffuse into the second insulating layer and the oxygen can be captured or fixed. Accordingly, the positive drift degradation of the OS transistor in the +GBT stress test due to the oxygen can be inhibited. Examples of an insulating material having a function of capturing or fixing oxygen include aluminum oxide, hafnium oxide, hafnium zirconium oxide, and an oxide containing hafnium and silicon (hafnium silicate).

An aluminum oxide film, a hafnium oxide film, a hafnium zirconium oxide film, and a hafnium silicate film each have a function of capturing or fixing hydrogen. As described above, hydrogen easily moves in the indium oxide film. Thus, when the second insulating layer has a function of capturing or fixing hydrogen, hydrogen in the oxide semiconductor layer 30 can diffuse into the second insulating layer and the hydrogen can be captured or fixed. Hence, the hydrogen concentration in the oxide semiconductor layer 30 (in particular, the hydrogen concentration in the channel formation region 31) can be reduced. Accordingly, V_{O}H in the channel formation region can be reduced, so that the channel formation region can be an i-type or substantially i-type region.

The conductive layer 60 is preferably formed using a material having high conductivity such as tungsten. In addition, a conductive material that is not easily oxidized, a conductive material having a function of inhibiting diffusion of oxygen, or the like is preferably used for the conductive layer 60. Examples of the conductive material include a conductive material containing nitrogen (e.g., titanium nitride and tantalum nitride) and a conductive material containing oxygen (e.g., ruthenium oxide). Thus, a decrease in conductivity of the conductive layer 60 can be inhibited.

It is preferable to use, for the conductive layer 60, a conductive material containing oxygen and a metal element contained in the metal oxide where a channel is formed. Alternatively, a conductive material containing nitrogen (e.g., titanium nitride or tantalum nitride) may be used. One or more of indium tin oxide (also referred to as In—Sn oxide or ITO), indium oxide containing tungsten oxide, indium zinc oxide containing tungsten oxide, indium oxide containing titanium oxide, indium tin oxide containing titanium oxide, In—Zn oxide, and indium tin oxide containing silicon oxide (also referred to as ITSO) may be used. Indium gallium zinc oxide containing nitrogen may also be used. With the use of such a material, hydrogen contained in the metal oxide where a channel is formed can be captured in some cases. Alternatively, hydrogen entering from a surrounding insulating layer or the like can be captured in some cases.

As illustrated in FIG. 1D, an oxide layer 27 can be provided between the insulating layer 20 and the oxide semiconductor layer 30. The oxide layer 27 includes a region overlapping with the insulating layer 50 with the oxide semiconductor layer 30 therebetween. The oxide semiconductor layer 30 is provided over the oxide layer 27 and includes a region in contact with the oxide layer 27. The oxide layer 27 is a layer that grows the crystal grain included in the oxide semiconductor layer 30 from below the oxide semiconductor layer 30 or a layer that does not inhibit growth of the crystal grain included in the oxide semiconductor layer 30 from above the oxide layer 27. In the case where the oxide layer 27 has a function of growing the crystal grain included in the oxide semiconductor layer 30 from below the oxide semiconductor layer 30, the oxide layer 27 can be referred to as a seed layer.

Indium oxide has a cubic crystal structure (bixbyite structure). The lattice constant of the crystal structure is 1.0117 nm (see Inorganic Crystal Structure Database (ICSD) coll. code. 14387).

In the case where indium oxide is used for the oxide semiconductor layer 30, an oxide having a cubic crystal structure is preferably used for the oxide layer 27. When the oxide layer 27 and the oxide semiconductor layer 30 have the same crystal structure, the oxide semiconductor layer 30 can epitaxially grow with the oxide layer 27 as a nucleus, so that the crystallinity of the oxide semiconductor layer 30 can be increased. Zirconium oxide or yttria-stabilized zirconia (YSZ) can be used for the oxide layer 27, for example. Zirconium oxide and YSZ each have a cubic crystal structure. In the case where the oxide semiconductor layer 30 and the oxide layer 27 have the same crystal structure, the crystal orientation of the surface of the oxide layer 27 is not particularly limited. For example, the crystal orientation may be [100], [110], or [111].

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, crystal planes, crystal orientations, and space groups are sometimes expressed by placing a minus sign (−) in front of a number instead of placing a bar over the number. Furthermore, an individual direction that shows an orientation in crystal is denoted by “[ ]”, a set direction that shows all of the equivalent orientations is denoted by “< >”, an individual plane that shows a crystal plane is denoted by “( )”, and a set plane having equivalent symmetry is denoted by “{ }”.

Note that YSZ in this specification and the like includes an oxide containing yttrium and zirconium. Thus, YSZ in this specification and the like can be rephrased as zirconium oxide containing yttrium, yttrium zirconium oxide, or the like.

A difference in a lattice constant or a unit lattice vector between a crystal included in the oxide layer 27 and a crystal included in the oxide semiconductor layer 30 (also referred to as a lattice mismatch) is preferably small. The use of an oxide that makes a lattice mismatch small for the oxide layer 27 can increase the crystallinity of the oxide semiconductor layer 30.

One of methods for evaluating the degree of a lattice mismatch is a method using a value of a lattice mismatch degree described below. A lattice mismatch degree Δa [%] of a crystal included in a film to be formed (here, the indium oxide film) with respect to a crystal included in a seed layer is calculated by Formula (1) below. Hereinafter, the lattice mismatch degree Δa of the crystal included in the film to be formed with respect to the crystal included in the seed layer may be simply referred to as the lattice mismatch degree Δa of the film to be formed with respect to the seed layer.

$$\begin{matrix}[ Formula 1 ] & \\ Δ a = ( \frac{{L}_{1}}{{L}_{2}} - 1 ) \times 100 & ( 1 )\end{matrix}$$

In Formula (1), L₁ is the lattice constant or the length of the unit lattice vector of the crystal included in the film to be formed, and L₂ is the lattice constant or the length of the unit lattice vector of the crystal included in the seed layer.

The lattice mismatch degree Δa of the crystal grain included in the oxide semiconductor layer 30 with respect to the crystal grain included in the oxide layer 27 is preferably higher than or equal to −10% and lower than or equal to 10%, further preferably higher than or equal to −5% and lower than or equal to 5%, still further preferably higher than or equal to −3% and lower than or equal to 3%. When a material that makes the lattice mismatch degree with respect to the oxide semiconductor layer 30 low is used for the oxide layer 27, the crystallinity of the oxide semiconductor layer 30 can be increased.

The lattice constant of a Zr_{0.9}Y_{0.1}O_{1.95} crystal (fluorite crystal) is 0.51481 nm (see ICSD coll. code. 248790), for example. Thus, the lattice mismatch degree of an indium oxide crystal with respect to an YSZ crystal is −1.74%. This means that, in the case where indium oxide is used for the oxide semiconductor layer 30, YSZ can be suitably used for the oxide layer 27. Note that YSZ contains yttrium, zirconium, and oxygen. The content of yttrium in YSZ is higher than or equal to 2 atomic % and lower than or equal to 15 atomic %, preferably higher than or equal to 5 atomic % and lower than or equal to 10 atomic %.

In the case where YSZ is used for the oxide layer 27 and indium oxide is used for the oxide semiconductor layer 30, a buffer layer containing indium and zirconium is sometimes formed at the interface between the oxide layer 27 and the oxide semiconductor layer 30. Since the ion radius of indium and the ion radius of zirconium are different from each other, the lattice constant or the unit lattice vector of a crystal included in the buffer layer is presumably a value between the lattice constant or the unit lattice vector of the YSZ crystal and the lattice constant or the unit lattice vector of the indium oxide crystal. Thus, the formation of the buffer layer can relieve the lattice mismatch between the oxide layer 27 and the oxide semiconductor layer 30, thereby increasing the crystallinity of the oxide semiconductor layer 30.

The crystal orientation may be different between the crystal included in the oxide layer 27 and the crystal included in the oxide semiconductor layer 30. For example, the oxide layer 27 including a crystal having a layered structure may be provided below indium oxide including a cubic crystal. Specifically, in the case where a film including a hexagonal or trigonal crystal is used as the oxide layer 27, a certain crystal orientation relationship can be satisfied when the crystal orientation of the surface of the oxide layer 27 is and the crystal orientation of the bottom surface of the oxide semiconductor layer 30 is [111]. In the case where the crystal orientation of the surface of the oxide layer 27 is [001], the c-axis of the crystal included in the oxide layer 27 is perpendicular or substantially perpendicular to the surface or the formation surface of the oxide layer 27. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. Note that the above structure can be regarded as a structure in which an oxide semiconductor layer including a cubic crystal is formed over an oxide layer including a crystal having a layered structure. That is, the above structure can be considered as a stacked-layer structure formed using a heteroepitaxial growth technique or a technique like heteroepitaxial growth.

Specifically, it is possible to use, for the oxide layer 27, zinc oxide, indium gallium oxide (also referred to as In—Ga oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), In—Ga—Zn oxide, indium tin zinc oxide (also referred to as In—Sn—Zn oxide), or the like. In the case where In—Ga—Zn oxide is used for the oxide layer 27, the oxide layer 27 contains indium, gallium, and zinc.

As described above, the transistor including the oxide semiconductor layer 30 containing a gallium atom might have poor reliability. Thus, in the case where an oxide containing gallium, such as In—Ga—Zn oxide, is used for the oxide layer 27, a layer 28 is preferably provided between the oxide layer 27 and the oxide semiconductor layer 30 (see FIG. 1E).

The layer 28 preferably contains a metal that has a higher bonding strength with oxygen than indium has. For example, aluminum oxide is preferably used for the layer 28. In that case, the layer 28 contains aluminum and oxygen. As described above, aluminum oxide is an insulating material having a function of capturing or fixing oxygen. Providing the layer 28 containing aluminum oxide can inhibit diffusion of gallium contained in the oxide layer 27 into the oxide semiconductor layer 30. In addition, an excessive amount of oxygen in the oxide semiconductor layer 30 can diffuse into and be captured or fixed by the layer 28.

The thickness of the layer 28 is preferably small. For example, the layer 28 includes a region where, when the thickness is converted into atomic layers, the number of atomic layers is preferably larger than or equal to 1 and smaller than or equal to 5, further preferably larger than or equal to 1 and smaller than or equal to 3. A small thickness of the layer 28 enables formation of the oxide semiconductor layer 30 including the crystal grain reflecting the crystal structure of the oxide layer 27.

In the case where the layer 28 is provided, an extremely small thickness of the layer 28 sometimes makes it difficult to clearly detect the boundary between the oxide layer 27 and the layer 28 and the boundary between the layer 28 and the oxide semiconductor layer 30. Whether the boundaries between the layers are present can be checked with a cross-sectional TEM, a cross-sectional STEM, or the like, for example.

A material used for the oxide layer 27 is not limited to an oxide as long as the lattice mismatch with the oxide semiconductor layer 30 is small. For example, a silicon-based semiconductor, e.g., single crystal silicon, may be used for the oxide layer 27. The lattice mismatch degree of an indium oxide crystal with respect to single crystal silicon is 3.3%. Thus, in the case where indium oxide is used for the oxide semiconductor layer 30, silicon may be used for the oxide layer 27.

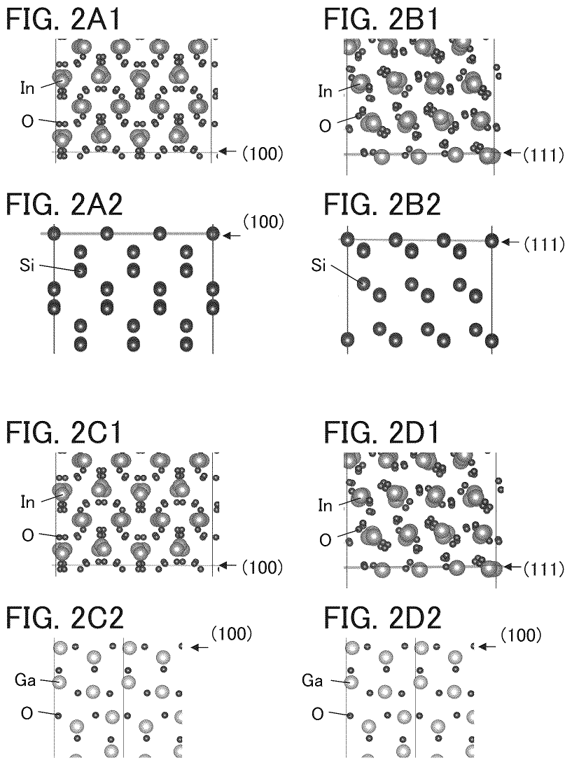

FIG. 2A1 illustrates an In₂O₃ crystal (bixbyite structure) seen from the direction parallel to the (100) plane, FIG. 2A2 illustrates single crystal silicon seen from the direction parallel to the (100) plane, FIG. 2B1 illustrates the In₂O₃ crystal seen from the direction parallel to the (111) plane, and FIG. 2B2 illustrates the single crystal silicon seen from the direction parallel to the (111) plane.

FIG. 2C1 illustrates the In₂O₃ crystal (bixbyite structure) seen from the direction parallel to the (100) plane, FIG. 2C2 illustrates a beta-type Ga₂O₃ crystal (monoclinic crystal system) seen from the direction parallel to the (100) plane, FIG. 2D1 illustrates the In₂O₃ crystal seen from the direction parallel to the (111) plane, and FIG. 2D2 illustrates the beta-type Ga₂O₃ crystal seen from the direction parallel to the (100) plane. The lattice mismatch degree of the (100) plane of the indium oxide crystal with respect to the beta-type Ga₂O₃ crystal is −4.9% in a′ and 4.7% in b′. The lattice mismatch degree of the (111) plane of the indium oxide crystal with respect to the beta-type Ga₂O₃ crystal is 1.9% in a′ and −1.3% in b′. Thus, in the case where indium oxide is used for the oxide semiconductor layer 30, gallium oxide may be used for the oxide layer 27. Note that a′ and b′ represent the lattice constants of the superlattice of the beta-type Ga₂O₃ crystal at the interface (superlattice) between the indium oxide crystal and the beta-type Ga₂O₃ crystal.

Note that a material that can be used for the oxide layer 27 is not particularly limited. Either an insulating material or a semiconductor material may be used for the oxide layer 27. In the case where an insulating material is used for the oxide layer 27, the oxide layer 27 may be regarded as part of the insulating layer 20. In the case where a semiconductor material is used for the oxide layer 27, the oxide layer 27 may be regarded as part of the oxide semiconductor layer 30.

The thickness of the oxide layer 27 is preferably small. For example, the thickness of the oxide layer 27 is preferably smaller than that of the oxide semiconductor layer 30. In the case where the oxide semiconductor layer 30 is in contact with a source electrode or a drain electrode through the oxide layer 27, a small thickness of the oxide layer 27 can inhibit an increase in contact resistance between the oxide semiconductor layer 30 and the source electrode or the drain electrode. Specifically, the oxide layer 27 preferably includes a region with a thickness greater than or equal to 0.1 nm and less than 2 nm, further preferably includes a region with a thickness greater than or equal to 0.5 nm and less than 2 nm.

In the example illustrated in FIG. 1A, the oxide semiconductor layer 30 has a single-layer structure. Note that the oxide semiconductor layer 30 can have a stacked-layer structure of two or more layers. FIG. 1F illustrates a structure example in which the oxide semiconductor layer 30 has a two-layer structure of an oxide semiconductor layer 30a and an oxide semiconductor layer 30b over the oxide semiconductor layer 30a. The oxide semiconductor layer 30a is in contact with the insulating layer 20, and the oxide semiconductor layer 30b is in contact with the insulating layer 50.

In the case where the oxide semiconductor layer 30 has the stacked-layer structure illustrated in FIG. 1F, it is preferable that the metal oxide that can be used for the oxide semiconductor layer 30 (typically, indium oxide) be used for the oxide semiconductor layer 30a and an oxide semiconductor whose conduction band minimum is positioned closer to the vacuum level than the conduction band minimum of the oxide semiconductor layer 30a is be used for the oxide semiconductor layer 30b. In that case, the oxide semiconductor layer 30a can function mainly as a current path (channel). That is, the oxide semiconductor layer 30a includes the channel formation region 31 on its surface on the oxide semiconductor layer 30b side and the vicinity thereof.

The above structure can reduce the number of carriers trapped at the interface between the oxide semiconductor layer 30a and the oxide semiconductor layer 30b and its vicinity. Moreover, the channel can be distanced from the surface of the insulating layer 50, so that the influence of surface scattering can be reduced. Thus, the field-effect mobility of the transistor can be increased.

In the case where the oxide layer 27 is formed using a semiconductor material, the oxide semiconductor layer 30a is sandwiched between the oxide layer 27 and the oxide semiconductor layer 30b each having a wide band gap and functions mainly as a current path (channel). When the oxide semiconductor layer 30a is sandwiched between the oxide layer 27 and the oxide semiconductor layer 30b, the numbers of trap states at the interface between the oxide semiconductor layer 30a and the oxide semiconductor layer 30b and its vicinity and at the interface between the oxide semiconductor layer 30a and the oxide layer 27 and its vicinity can be reduced. Accordingly, a buried-channel transistor where a channel is distanced from the interface with an insulating layer can be achieved, whereby the field-effect mobility can be increased. Furthermore, the influence of interface states that might be formed on the back channel side is reduced, so that light deterioration (e.g., light negative bias deterioration) of the transistor can be inhibited and the reliability of the transistor can be increased.

The oxide semiconductor layer 30b is preferably formed using a material having a high oxygen-transmitting property. This achieves the effect of releasing an excessive amount of oxygen in the oxide semiconductor layer 30a to the insulating layer 50. The oxide semiconductor layer 30b having a small thickness has a high oxygen-transmitting property. Thus, the above effect can be obtained also in the case where the oxide semiconductor layer 30b has a small thickness. The thickness of the oxide semiconductor layer 30b is, for example, greater than or equal to 0.1 nm and less than or equal to 3 nm, preferably greater than or equal to 0.1 nm and less than or equal to 2 nm, further preferably greater than or equal to 0.1 nm and less than or equal to 1 nm, still further preferably greater than or equal to 0.1 nm and less than or equal to 0.5 nm.

As the metal oxide that can be used for the oxide semiconductor layer 30b, for example, In—Ga oxide, In—Zn oxide, ITO, indium titanium oxide (In—Ti oxide), In—Al—Zn oxide, In—Ga—Zn oxide, In—Sn—Zn oxide, indium titanium zinc oxide (In—Ti—Zn oxide), ITSO, or the like can be used. Alternatively, zinc oxide, aluminum zinc oxide (also referred to as Al—Zn oxide or AZO), aluminum tin oxide (Al—Sn oxide), or the like can be used.

Specifically, the In—Zn oxide used for the oxide semiconductor layer 30b can have an atomic ratio of In:Zn=1:1 or the neighborhood thereof, In:Zn=2:1 or the neighborhood thereof, or In:Zn=4:1 or the neighborhood thereof. Furthermore, specifically, IGZO used for the oxide semiconductor layer 30b can have an atomic ratio of In:Ga:Zn=1:1:1 or the neighborhood thereof, In:Ga:Zn=1:3:2 or the neighborhood thereof, or In:Ga:Zn=1:3:4 or the neighborhood thereof. Note that the neighborhood of the atomic ratio includes ±30% of an intended atomic ratio.

There is no particular limitation on the crystallinity of the metal oxide included in the oxide semiconductor layer 30b. The oxide semiconductor layer 30b sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions).

In the example illustrated in FIG. 1A, the insulating layer 20 has a single-layer structure. Note that the insulating layer 20 can have a stacked-layer structure of two or more layers. In the case where the insulating layer 20 has the stacked-layer structure of two or more layers, the layer in contact with the oxide semiconductor layer 30 among the two or more layers included in the insulating layer 20 is preferably formed using the insulating material that can be used for the insulating layer 20 (typically, silicon oxide). With such a structure, oxygen can be supplied to the oxide semiconductor layer 30.

In the case where the layer not in contact with the oxide semiconductor layer 30 among the two or more layers included in the insulating layer 20 is formed using the insulating material that can be used for the insulating layer 20 (typically, silicon oxide), the layer in contact with the oxide semiconductor layer 30 preferably has a high oxygen-transmitting property. In other words, the layer in contact with the oxide semiconductor layer 30 preferably has a low oxygen barrier property. With such a structure, oxygen contained in the layer not in contact with the oxide semiconductor layer 30 can be supplied to the oxide semiconductor layer 30.

When having a small thickness, the layer in contact with the oxide semiconductor layer 30 has a high oxygen-transmitting property. Thus, the effect of supplying oxygen contained in the layer not in contact with the oxide semiconductor layer 30 to the oxide semiconductor layer 30 can be obtained also in the case where the layer in contact with the oxide semiconductor layer 30 has a small thickness. The thickness of the layer in contact with the oxide semiconductor layer 30 is, for example, greater than or equal to 0.1 nm and less than or equal to 3 nm, preferably greater than or equal to 0.1 nm and less than or equal to 2 nm, further preferably greater than or equal to 0.1 nm and less than or equal to 1 nm, still further preferably greater than or equal to 0.1 nm and less than or equal to 0.5 nm. In that case, the layer in contact with the oxide semiconductor layer 30 can be formed using an insulating material described later in [Insulating layer]. For example, gallium oxide or the like can be used.

In the example illustrated in FIG. 1A, the insulating layer 50 has a single-layer structure. Note that the insulating layer 50 can have a stacked-layer structure of two or more layers. In the case where the insulating layer 50 has the stacked-layer structure of two or more layers, the layer in contact with the oxide semiconductor layer 30 among the two or more layers included in the insulating layer 50 is preferably formed using the insulating material that can be used for the insulating layer 50 (typically, aluminum oxide). With such a structure, an excessive amount of oxygen in the oxide semiconductor layer 30 can be released to the insulating layer 50. In addition, hydrogen in the oxide semiconductor layer 30 can be captured or fixed.

In this manner, oxygen can be pushed into the oxide semiconductor layer 30 from the insulating layer 20 side, the amount of oxygen vacancies in the oxide semiconductor layer 30 can be reduced, an excessive amount of oxygen in the oxide semiconductor layer 30 can be pulled from the insulating layer 50 side, and the excessive amount of oxygen in the oxide semiconductor layer 30 can be reduced. Accordingly, a highly reliable semiconductor device can be provided.

FIG. 1A illustrates a structure in which the insulating layer 20, the oxide semiconductor layer 30, the insulating layer 50, and the conductive layer 60 are stacked in the direction perpendicular or substantially perpendicular to the substrate surface (not illustrated). Note that the present invention is not limited thereto. For example, as illustrated in FIG. 1G, the insulating layer 20, the oxide semiconductor layer 30, the insulating layer 50, and the conductive layer 60 can be stacked in the direction parallel or substantially parallel to the substrate surface (not illustrated).

For another example, as illustrated in FIG. 1H, a structure can be employed in which an opening portion 90 is provided in the insulating layer 20 and the oxide semiconductor layer 30, the insulating layer 50, and the conductive layer 60 are provided concentrically in the opening portion 90. FIG. 1H is a perspective view obtained by cutting part of the semiconductor device of one embodiment of the present invention.

For another example, as illustrated in FIG. 1I, a structure can be employed in which a groove portion 91 is provided in the insulating layer 20 and the oxide semiconductor layer 30, the insulating layer 50, and the conductive layer 60 are provided in the groove portion 91. FIG. 1I is a perspective view obtained by cutting part of the semiconductor device of one embodiment of the present invention.

### [Example of Method for Fabricating Semiconductor Device]

The insulating layer 20, the oxide semiconductor layer 30, the insulating layer 50, and the conductive layer 60 can be formed by a sputtering method, a chemical vapor deposition (CVD) method, a vacuum evaporation method, a molecular beam epitaxy (MBE) method, a pulsed laser deposition (PLD) method, an atomic layer deposition (ALD) method, or the like. It is particularly preferable to form the insulating layer 20, the oxide semiconductor layer 30, and the insulating layer 50 by an ALD method.

Unlike in a film formation method in which particles ejected from a target or the like are deposited, a film is formed by reaction at a surface of an object to be processed in an ALD method. Thus, an ALD method can provide good step coverage, almost regardless of the shape of an object to be processed. In particular, an ALD method allows excellent step coverage and excellent thickness uniformity and thus can be suitably used to cover a surface of an opening portion or a groove portion with a high aspect ratio, for example.

Some precursors used in an ALD method contain an element such as carbon or chlorine. Thus, a film formed by an ALD method sometimes contains an element such as carbon or chlorine in a larger quantity than a film formed by another film formation method. Note that these elements can be quantified by XPS or SIMS. An ALD method employing one or both of a film formation condition with a high substrate temperature and impurity removal treatment can sometimes form a film with smaller amounts of carbon and chlorine than an ALD method without the film formation condition with a high substrate temperature or the impurity removal treatment.

Examples of an ALD method include a thermal ALD method, in which a precursor and a reactant react with each other only by thermal energy, and a plasma-enhanced ALD (PEALD) method, in which a reactant excited by plasma is used.

A film formation apparatus employing an ALD method performs film formation in the following manner: a first source gas (sometimes referred to as a precursor or a metal precursor) and a second source gas (sometimes referred to as a reactant, an oxidizer, or a non-metal precursor) are alternately introduced into a chamber for reaction, and the introduction of these source gases is repeated. Note that the source gases to be introduced can be switched by switching the respective switching valves (sometimes referred to as high-speed valves), for example. When the source gases are introduced, an inert gas such as nitrogen (N₂), argon (Ar), or helium (He) may be introduced as a carrier gas together with the source gases into the chamber. With the use of a carrier gas, the source gases can be inhibited from being adsorbed onto an inner side of a pipe and an inner side of a valve and can be introduced into the chamber, even in the case where the volatility of the source gases is low or the vapor pressure is low. The use of a carrier gas is preferable also because the uniformity of the formed film is improved.

An ALD method in which a plurality of kinds of precursors are introduced at the same time enables formation of a film with a desired composition. In the case where a plurality of kinds of precursors are introduced, the number of cycles for each precursor is controlled, whereby a film with a desired composition can be formed.

First, the insulating layer 20 is formed over a structure body (not illustrated). That is, the structure body includes the formation surface of the insulating layer 20. The formation surface may have a flat shape, or may include a projection, a convex surface, a concave surface, a depression, an opening portion, or the like. In the case where the formation surface has a flat shape, for example, the semiconductor device illustrated in FIG. 1A can be formed.

The insulating layer 20 is preferably formed by an ALD method. The insulating layer 20 can be formed using a first precursor and a first oxidizer. The first precursor preferably contains silicon. In that case, a silicon oxide film is formed as the insulating layer 20. That is, an oxide film containing a single element besides oxygen is formed. In the case where the first precursor contains silicon, a PEALD method can be used as an ALD method.

As a precursor containing silicon, trisilylamine, bis(diethylamino) silane, tris(dimethylamino) silane, bis(tert-butylamino) silane, bis(ethylmethylamino) silane, or the like can be used.

As the first oxidizer, ozone (O₃), oxygen (O₂), water (H₂O), or the like can be used. When the first oxidizer not containing hydrogen but containing ozone, oxygen, or the like is used, the amount of hydrogen entering the insulating layer 20 can be reduced.

In this specification and the like, ozone, oxygen, and water that can be used as an oxidizer include not only those in gas or molecular states but also those in plasma, radical, and ion states, unless otherwise specified.

The insulating layer 20 can be formed in an oxygen-containing atmosphere by a sputtering method. By using a sputtering method that does not need to use a molecule containing hydrogen in a film formation gas, the hydrogen concentration in the insulating layer 20 can be reduced. When the insulating layer 20 is formed in an oxygen-containing atmosphere by a sputtering method, oxygen can be added to the insulating layer 20. When heat or the like is applied after the formation of the oxide semiconductor layer 30, oxygen can be supplied from the insulating layer 20 to the channel formation region in the oxide semiconductor layer 30 to reduce oxygen vacancies and V_{O}H.

Before the formation of the oxide semiconductor layer 30, heat treatment is preferably performed. The heat treatment is performed, for example, at higher than or equal to 250° C. and lower than or equal to 650° C., preferably higher than or equal to 300° C. and lower than or equal to 500° C., further preferably higher than or equal to 320° C. and lower than or equal to 450° C.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in a nitrogen gas atmosphere or an inert gas atmosphere, and then another heat treatment may be performed in an atmosphere containing an oxidizing gas at 10 ppm or more, 1% or more, or 10% or more in order to compensate for released oxygen. By the above-described heat treatment, impurities such as hydrogen and water contained in the insulating layer 20 or the like can be reduced before the formation of the oxide semiconductor layer 30.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment performed using a highly purified gas can prevent entry of moisture or the like into the insulating layer 20 or the like as much as possible.

Before the formation of the oxide semiconductor layer 30, treatment for supplying oxygen is preferably performed. In that case, oxygen can be supplied to the insulating layer 20, and the oxygen can be supplied from the insulating layer 20 to the oxide semiconductor layer 30 by heat or the like applied after the formation of the oxide semiconductor layer 30.

Examples of the treatment for supplying oxygen include heat treatment in an oxygen-containing atmosphere and plasma treatment (including microwave plasma treatment) in an oxygen-containing atmosphere. Alternatively, an oxide film (preferably a metal oxide film) may be formed in an oxygen-containing atmosphere by a sputtering method, thereby supplying oxygen to the insulating layer 20. The formed oxide film may be removed immediately or left as it is. In the case where the formed oxide film is left as it is, the oxide film can be used as part of the oxide semiconductor layer 30. Note that the oxygen-containing atmosphere includes an atmosphere containing not only an oxygen gas (O₂) but also a gas of a compound containing oxygen, such as ozone (O₃) or dinitrogen monoxide (N₂O). The substrate temperature in the plasma treatment is higher than or equal to room temperature (25° C.) and lower than or equal to 450° C.

Before the formation of the oxide semiconductor layer 30, the opening portion 90 may be formed in the insulating layer 20. In the case where the opening portion 90 is formed, the semiconductor device illustrated in FIG. 1H can be formed. Alternatively, before the formation of the oxide semiconductor layer 30, the groove portion 91 may be formed in the insulating layer 20. In the case where the groove portion 91 is formed, the semiconductor device illustrated in FIG. 1I can be formed.

Then, the oxide semiconductor layer 30 is formed over the insulating layer 20. The oxide semiconductor layer 30 is preferably formed by an ALD method. The oxide semiconductor layer 30 can be formed using a second precursor and a second oxidizer. The second precursor preferably contains indium. In that case, an indium oxide film is formed as the oxide semiconductor layer 30. That is, an oxide film containing a single element besides oxygen is formed. In the case where the second precursor contains indium, a thermal ALD method can be used as an ALD method.

In the formation method of the oxide semiconductor layer 30, a material with a low impurity concentration is preferably used. In other words, a high-purity material is preferably used in the formation method of the oxide semiconductor layer 30. For example, the purity of the second precursor is preferably higher than or equal to 3N (99.9%), further preferably higher than or equal to 4N (99.99%), still further preferably higher than or equal to 5N (99.999%), yet still further preferably higher than or equal to 6N (99.9999%). With the use of a high-purity material, the amount of impurities in the oxide semiconductor layer 30 can be reduced.

The content of gallium in the second precursor is preferably lower than or equal to 1000 ppm, further preferably lower than or equal to 500 ppm, still further preferably lower than or equal to 100 ppm, yet further preferably lower than or equal to 50 ppm, yet still further preferably lower than or equal to 10 ppm, yet still further preferably lower than or equal to 1 ppm. With the use of a precursor having a low content of gallium, the oxide semiconductor layer 30 having a low gallium concentration can be formed.

The content of aluminum in the second precursor is preferably lower than or equal to 1000 ppm, further preferably lower than or equal to 500 ppm, still further preferably lower than or equal to 100 ppm, yet further preferably lower than or equal to 50 ppm, yet still further preferably lower than or equal to 10 ppm, yet still further preferably lower than or equal to 1 ppm. With the use of a precursor having a low content of aluminum, the aluminum concentration in the oxide semiconductor layer 30 can be reduced and the crystallinity of the oxide semiconductor layer 30 can be increased.

As the precursor containing indium, it is possible to use trimethylindium, triethylindium, ethyldimethylindium, tris(1-methylethyl)indium, tris(2,2,6,6-tetramethyl-3,5-heptanedionato)indium, cyclopentadienylindium, indium(III) acetylacetonate, (3-(dimethylamino)propyl)dimethylindium, (diethylphosphino)dimethylindium, chlorodimethylindium, bromodimethylindium, dimethyl(2-propanolato)indium, or the like.

As the precursor containing indium, an inorganic precursor not containing hydrocarbon may be used. As the inorganic precursor containing indium, it is possible to use a halogen-based indium compound such as trifluoroindium (indium(III) fluoride), indium trichloride (indium(III) chloride), indium tribromide (indium(III) bromide), or indium triiodide (indium(III) iodide). The decomposition temperature of indium trichloride is approximately higher than or equal to 500° C. and lower than or equal to 700° C. Thus, with the use of indium trichloride, film formation can be performed by an ALD method while a substrate is being heated at approximately higher than or equal to 400° C. and lower than or equal to 600° C., e.g., at 500° C.

The second oxidizer preferably contains ozone. Any of the materials that can be used as the first oxidizer can be used as the second oxidizer. When the second oxidizer not containing hydrogen but containing ozone, oxygen, or the like is used, the amount of hydrogen entering the oxide semiconductor layer 30 can be reduced.

Here, the temperature of substrate heating at the time of introducing the second precursor into a reaction chamber is referred to as a first temperature, and the temperature of substrate heating at the time of introducing the second oxidizer into a reaction chamber is referred to as a second temperature.

The first temperature is preferably a temperature corresponding to the decomposition temperature of the second precursor. In the case where triethylindium is used as the precursor containing indium and a thermal ALD method is employed, for example, the first temperature is higher than or equal to 100° C. and lower than or equal to 350° C., preferably higher than or equal to 150° C. and lower than or equal to 300° C. Providing the oxide layer 27 enables the formation of the oxide semiconductor layer 30 having crystallinity even when the first temperature is lower than the above-described temperature. In the case where the oxide layer 27 is provided, the first temperature can be higher than or equal to room temperature (25° C.) and lower than or equal to 300° C., preferably higher than or equal to room temperature and lower than or equal to 200° C., further preferably higher than or equal to room temperature and lower than or equal to 150° C.

The second temperature is preferably higher than the first temperature. In the case where the second oxidizer contains ozone, for example, the second temperature is preferably higher than 200° C. and lower than 450° C., further preferably higher than or equal to 250° C. and lower than or equal to 400° C., still further preferably higher than or equal to 300° C. and lower than or equal to 350° C. This can reduce the hydrogen concentration in the oxide semiconductor layer. When the first temperature is lower than the second temperature, generation of particles due to the decomposition of the second precursor can be inhibited. Note that the second temperature may be the same as the first temperature. In that case, the temperature of substrate heating at the time of forming the oxide semiconductor layer 30 can be constant, thereby improving the productivity.

The reaction chamber into which the second precursor is introduced is preferably the same as the reaction chamber into which the second oxidizer is introduced. With such a structure, a film can be formed without carrying of a substrate into and out of the chamber, so that the productivity can be improved. Note that the reaction chamber into which the second precursor is introduced can be different from the reaction chamber into which the second oxidizer is introduced. When a first reaction chamber at the first temperature and a second reaction chamber at the second temperature are prepared, the first temperature and the second temperature can be separately retained. This facilitates temperature control, improving the work efficiency and the safety.

In the case where the indium oxide film included in the oxide semiconductor layer 30 is formed by an ALD method, the end portion of the indium oxide film is terminated with oxygen and thus is probably inactivated. Since being inactivated, the end portion of the indium oxide film presumably has few defects. This indicates that the transistor can have high reliability.

The oxide semiconductor layer 30 can be formed in an oxygen-containing atmosphere by a sputtering method. By using a sputtering method that does not need to use a molecule containing hydrogen in a film formation gas, the hydrogen concentration in the oxide semiconductor layer 30 can be reduced. For example, oxygen or a mixed gas of oxygen and a noble gas is preferably used as a sputtering gas.

The oxide semiconductor layer 30 can be formed by a sputtering method and an ALD method, for example. In the case where the oxide semiconductor layer 30 has the two-layer structure of the oxide semiconductor layer 30a and the oxide semiconductor layer 30b (see FIG. 1F), for example, the oxide semiconductor layer 30a can be formed by an ALD method and the oxide semiconductor layer 30b can be formed by a sputtering method. An ALD method provides better coverage than a sputtering method; thus, formation of the oxide semiconductor layer 30a by an ALD method can improve coverage with the oxide semiconductor layer 30. Accordingly, the oxide semiconductor layer can suitably cover a step, an opening portion, or the like with a high aspect ratio. An ALD method causes less damage to the formation surface; hence, in the case where the oxide layer 27 is provided, formation of the oxide semiconductor layer 30a by an ALD method can promote the epitaxial growth of the oxide semiconductor layer 30a. When the oxide semiconductor layer 30b is formed by a sputtering method, the productivity can be increased. In addition, the oxide semiconductor layer 30 with high crystallinity or high film density can be formed.

Alternatively, the oxide semiconductor layer 30a may be formed by a sputtering method and the oxide semiconductor layer 30b may be formed by an ALD method. An oxide semiconductor layer formed by a sputtering method is likely to have crystallinity. Thus, when an oxide semiconductor layer having crystallinity is provided as the oxide semiconductor layer 30a, the crystallinity of the oxide semiconductor layer 30b can be increased. Even when a pinhole, disconnection, or the like is generated in the oxide semiconductor layer 30a formed by a sputtering method, such a defect can be filled with the oxide semiconductor layer 30b formed by an ALD method that provides excellent coverage.

A sputtering method causes relatively great damage to the formation surface; thus, in the case where the oxide semiconductor layer 30a is formed by a sputtering method, a mixed layer with low crystallinity is sometimes formed between the insulating layer 20 and the oxide semiconductor layer 30a or in the oxide semiconductor layer 30a in the vicinity of the insulating layer 20. In the present invention, however, only the crystallinity of the channel formation region 31 positioned in the upper portion (on the insulating layer 50 side) of the oxide semiconductor layer 30a needs to be high; thus, a structure in which the mixed layer is not formed in the channel formation region 31 can be obtained by increasing the thickness of the oxide semiconductor layer 30 within the above range. This can increase the crystallinity of the channel formation region 31.

Note that the oxide layer 27 may be formed over the insulating layer 20 before the formation of the oxide semiconductor layer 30. The oxide layer 27 can be formed by a sputtering method, a CVD method, a vacuum evaporation method, an MBE method, a PLD method, an ALD method, or the like.

The oxide layer 27 is preferably formed by an ALD method. The oxide layer 27 formed by an ALD method can have excellent coverage. In the case where the oxide layer 27 and the oxide semiconductor layer 30 are formed by the same film formation method, the oxide layer 27 and the oxide semiconductor layer 30 are preferably formed successively without exposure to the air. Forming the two kinds of films successively without exposure to the air can increase the productivity. Furthermore, impurities (typically, moisture or the like) taken into the interface between the two kinds of films and the vicinity thereof can be reduced.

The oxide layer 27 can also be formed by a sputtering method. When the oxide layer 27 is formed by a sputtering method, the crystallinity of the oxide semiconductor layer 30 can be increased. When the oxide layer 27 is formed in an oxygen-containing atmosphere by a sputtering method, oxygen can be added to the insulating layer 20.

In the case where the oxide layer 27 is provided and the oxide semiconductor layer 30 has the two-layer structure of the oxide semiconductor layer 30a and the oxide semiconductor layer 30b, it is preferable that the oxide layer 27 be formed by a sputtering method, the oxide semiconductor layer 30a be formed by an ALD method, and the oxide semiconductor layer 30b be formed by a sputtering method. With such a structure, the oxide semiconductor layer 30a can epitaxially grow from the oxide layer 27, so that the crystallinity of the oxide semiconductor layer 30a can be increased. For example, the oxide layer 27 can be formed using an YSZ film by a sputtering method, the oxide semiconductor layer 30a can be formed using an indium oxide film by an ALD method, and the oxide semiconductor layer 30b can be formed using an IGZO film by a sputtering method. In that case, for example, it is preferable that the oxide layer 27 include a region with a thickness greater than or equal to 1 nm and less than or equal to 5 nm, the oxide semiconductor layer 30a include a region with a thickness greater than or equal to 5 nm and less than or equal to 7 nm, and the oxide semiconductor layer 30b include a region with a thickness greater than or equal to 3 nm and less than or equal to 5 nm.

After the formation of the oxide semiconductor layer 30, treatment for supplying oxygen to the oxide semiconductor layer 30 may be performed. Accordingly, oxygen can be supplied to the oxide semiconductor layer 30 by heat or the like applied after the treatment. Note that the above description can be referred to for the details of the treatment for supplying oxygen.

Next, heat treatment is preferably performed. By the heat treatment, impurities such as hydrogen and water contained in the oxide semiconductor layer 30 can be reduced. The temperature of the heat treatment is preferably higher than or equal to 100° C. and lower than or equal to 650° C., further preferably higher than or equal to 250° C. and lower than or equal to 600° C., still further preferably higher than or equal to 300° C. and lower than or equal to 500° C. or higher than or equal to 350° C. and lower than or equal to 550° C. The above description can be referred to for the details of the heat treatment.

The gas used in the above heat treatment is preferably highly purified. The heat treatment performed using a highly purified gas can prevent entry of moisture or the like into the oxide semiconductor layer 30 as much as possible.

By the heat treatment, impurities such as carbon, hydrogen, and water in the oxide semiconductor layer 30 can be reduced. Impurities in the film are reduced in the above manner, whereby the crystallinity of the oxide semiconductor layer 30 can be improved and a highly dense structure can be obtained. Accordingly, the crystal region in the oxide semiconductor layer 30 can be increased, and an in-plane variation in the crystal region in the oxide semiconductor layer 30 can be reduced. Thus, an in-plane variation in the electrical characteristics of the transistor can be reduced.

In the case where the insulating layer 20 contains oxygen, oxygen is preferably supplied from the insulating layer containing oxygen to the channel formation region in the oxide semiconductor layer 30 by the heat treatment. Accordingly, oxygen vacancies and V_{O}H can be reduced.

After the formation of the oxide semiconductor layer 30, microwave plasma treatment may be performed. The microwave plasma treatment can reduce the concentration of impurities such as hydrogen and water contained in the oxide semiconductor layer 30. In addition, the crystal region of the oxide semiconductor layer 30 grows in some cases.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

By performing microwave plasma treatment in an oxygen-containing atmosphere, the impurity concentration in the oxide semiconductor layer 30 can be reduced. Specific examples of impurities include hydrogen and carbon. Although the microwave plasma treatment in an oxygen-containing atmosphere is performed on the oxide semiconductor layer 30 in the above example, one embodiment of the present invention is not limited thereto. For example, microwave plasma treatment in an oxygen-containing atmosphere may be performed on an insulating film, specifically a silicon oxide film, which is provided in the vicinity of the oxide semiconductor layer 30. Furthermore, the crystallinity of the oxide semiconductor layer 30 is sometimes increased by heat in the microwave plasma treatment.

The microwave plasma treatment is preferably performed under a reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating may be performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. For example, the substrate heating temperature is preferably higher than or equal to room temperature and lower than or equal to 500° C., further preferably higher than or equal to 100° C. and lower than or equal to 450° C., still further preferably higher than or equal to 200° C. and lower than or equal to 450° C., yet further preferably higher than or equal to 300° C. and lower than or equal to 450° C., yet still further preferably higher than or equal to 400° C. and lower than or equal to 450° C.

The microwave plasma treatment can be performed using an oxygen gas and an argon gas, for example. In the microwave plasma treatment using an oxygen gas and an argon gas, oxygen radicals can be mainly in three states: triplet oxygen (O(³Pj)), singlet oxygen (O(¹D₂)), and an oxygen ion (O₂⁺). Note that the oxygen ion effectively acts for reducing the hydrogen concentration in an oxide film by the microwave plasma treatment. The amount of oxygen radicals in each state changes depending on the oxygen flow rate ratio or a pressure in the microwave plasma treatment. For example, the amount of oxygen ions tends to increase under a condition with a low oxygen flow rate ratio and a low pressure. Meanwhile, an extremely low oxygen flow rate ratio or pressure might destabilize the control of the oxygen flow rate, thereby making stable discharging difficult or causing etching of an oxide film, for example. Thus, for example, the oxygen flow rate ratio (O₂/(O₂+Ar)) in the microwave plasma treatment is preferably higher than 0% and lower than or equal to 45%, further preferably higher than 0% and lower than or equal to 30%, still further preferably higher than 0% and lower than or equal to 10%, yet further preferably higher than or equal to 0.5% and lower than or equal to 5%, yet still further preferably higher than or equal to 0.5% and lower than or equal to 3%, and is typically preferably 1%.

As the microwave plasma treatment time is shorter, the productivity is higher. In view of this, the microwave plasma treatment time is preferably longer than or equal to 1 minute and shorter than or equal to 60 minutes, further preferably longer than or equal to 1 minute and shorter than or equal to 30 minutes, still further preferably longer than or equal to 1 minute and shorter than or equal to 10 minutes, for example.

The microwave plasma treatment in an oxygen-containing atmosphere can convert an oxygen gas into plasma by using a high-frequency wave such as a microwave or an RF, and apply, to the oxide semiconductor layer, oxygen radicals that are generated by conversion of the oxygen gas into plasma. By the effects of plasma, a microwave, oxygen radicals, and the like, V_{O}H in the oxide semiconductor layer can be divided into an oxygen vacancy and hydrogen, and hydrogen which is an impurity can be removed from the oxide semiconductor layer. In this manner, V_{O}H contained in the oxide semiconductor layer can be reduced. At this time, carbon bonded to oxygen, hydrogen, or the like can also be removed in some cases. Performing the microwave plasma treatment in such a manner can reduce impurities such as carbon and hydrogen. Supplying the oxygen radicals to oxygen vacancies formed in the oxide semiconductor layer can further reduce oxygen vacancies in the oxide semiconductor layer.

When part of oxygen that has been present in the oxide semiconductor before the microwave plasma treatment reacts with hydrogen in the oxide semiconductor, i.e., a reaction “2H+O→H₂O↑” occurs, the hydrogen can be removed as H₂O (i.e., dehydration or dehydrogenation can be achieved). H₂O is a limiting factor in improving crystallinity and thus is preferably removed from the oxide semiconductor. Hydrogen in the oxide semiconductor is removed as H₂O to reduce the hydrogen concentration in the oxide semiconductor, whereby an improvement in crystallinity can be promoted. When the temperature of the microwave plasma treatment is increased, the hydrogen concentration in the oxide semiconductor can be further reduced.

Note that the microwave plasma treatment may be followed successively by heat treatment without exposure to the air. The temperature of the heat treatment is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

Note that the crystallinity can also be improved by performing plasma treatment using an oxygen gas, instead of the microwave plasma treatment.

Oxygen supplied to the oxide semiconductor layer is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Oxygen injected into the oxide semiconductor layer preferably has one or more of the above forms. An oxygen radical is particularly preferable.

In the above manner, impurities in the oxide semiconductor layer 30 can be reduced. Furthermore, the crystallinity of the oxide semiconductor layer 30 can be improved.

Then, the insulating layer 50 is formed over the oxide semiconductor layer 30. The insulating layer 50 is preferably formed by an ALD method. The insulating layer 50 can be formed using a third precursor and a third oxidizer. The third precursor preferably contains one of aluminum and hafnium. In that case, an aluminum oxide film or a hafnium oxide film is formed as the insulating layer 50. That is, an oxide film containing a single element besides oxygen is formed. In the case where the third precursor contains one of aluminum and hafnium, a thermal ALD method can be used as an ALD method.

As the precursor containing aluminum, aluminum chloride, trimethylaluminum, or the like can be used, for example. As the precursor containing hafnium, hafnium tetrachloride, tetrakis(ethylmethylamide) hafnium (TEMAHf), or the like can be used, for example.

Any of the materials that can be used as the first oxidizer can be used as the third oxidizer.

In an ALD process, a step in which a precursor is introduced into a chamber and adsorbed onto a substrate surface is performed. Here, the precursor is adsorbed onto the substrate surface, whereby a self-limiting mechanism of surface chemical reaction works and no more precursor is adsorbed onto a layer of the precursor over the substrate. Note that the proper range of substrate temperatures at which the self-limiting mechanism of surface chemical reaction works is also referred to as an ALD window. The ALD window depends on the temperature characteristics, vapor pressure, decomposition temperature, and the like of a precursor. That is, the ALD window differs between precursors. Thus, in the case where an oxide film containing a plurality of kinds of elements besides oxygen is formed, the film formation conditions need to be adjusted in consideration of the ALD windows of precursors. Meanwhile, in the case where an oxide film containing a single element besides oxygen, such as an indium oxide film or an aluminum oxide film, is formed, the film formation conditions can be adjusted in consideration of the ALD window of only one kind of precursor, which facilitates the adjustment of the film formation conditions and enables a high-quality oxide film to be formed.

The same oxidizer may be used as all of the first oxidizer, the second oxidizer, and the third oxidizer, or at least one of the first oxidizer, the second oxidizer, and the third oxidizer may be a different oxidizer from the two others.

In the case where the insulating layer 20 and the oxide semiconductor layer 30 are formed by the same film formation method, the insulating layer 20 and the oxide semiconductor layer 30 are preferably formed successively without exposure to the air. In the case where the oxide semiconductor layer 30 and the insulating layer 50 are formed by the same film formation method, the oxide semiconductor layer 30 and the insulating layer 50 are preferably formed successively without exposure to the air. In the case where the insulating layer 20, the oxide semiconductor layer 30, and the insulating layer 50 are formed by the same film formation method, the insulating layer 20, the oxide semiconductor layer 30, and the insulating layer 50 are preferably formed successively without exposure to the air. Forming the two or more kinds of films successively without exposure to the air can increase the productivity. Furthermore, impurities (typically, moisture or the like) taken into the interface between the two kinds of films and the vicinity thereof can be reduced.

For example, after the oxide semiconductor layer 30 is formed by a thermal ALD method, the insulating layer 50 is preferably formed by a thermal ALD method successively without exposure to the air. Here, the same oxidizer is used as the second oxidizer and the third oxidizer and a reaction chamber into which the second precursor and the third precursor can be introduced is used, in which case the oxide semiconductor layer 30 and the insulating layer 50 can be formed without carrying of the substrate into and out of the chamber and thus the productivity can be improved.

After the formation of the insulating layer 50, microwave plasma treatment is preferably performed. The microwave plasma treatment can reduce the concentration of impurities such as hydrogen and water contained in the oxide semiconductor layer 30. The above description can be referred to for the details of the microwave plasma treatment.

Then, the conductive layer 60 is formed over the insulating layer 50.

Through the above steps, the semiconductor device of one embodiment of the present invention can be fabricated.

This embodiment can be combined with any of the other embodiments and examples as appropriate. In this specification, in the case where a plurality of structure examples are shown in one embodiment, the structure examples can be combined as appropriate.

### Embodiment 2

In this embodiment, semiconductor devices having any of the structures described in Embodiment 1 will be described.

### Structure Example 1 of Semiconductor Device

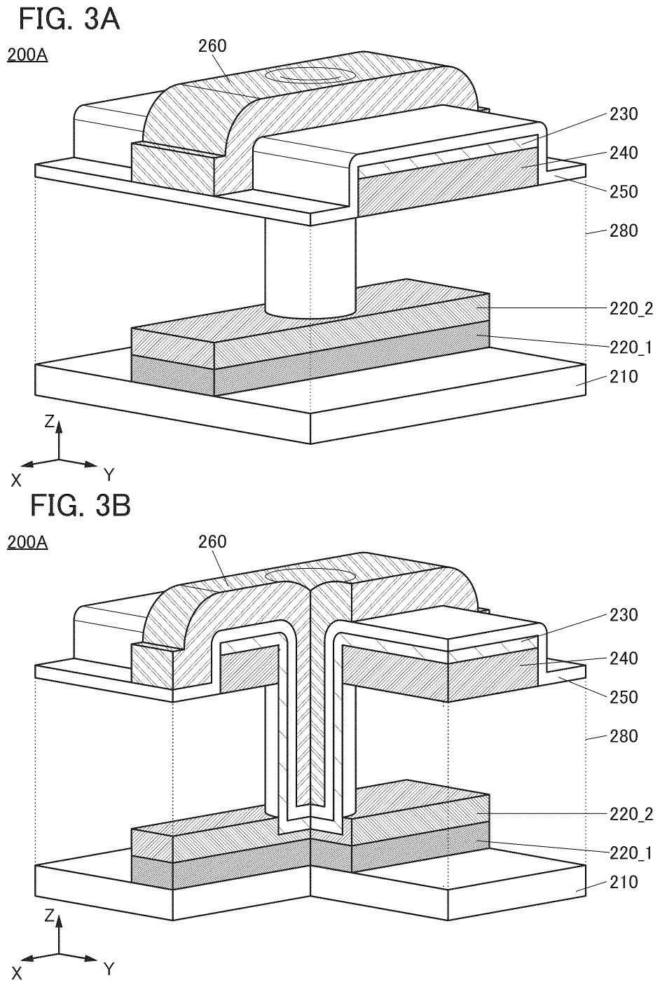

Structure examples of semiconductor devices of one embodiment of the present invention will be described with reference to FIGS. 3A and 3B to FIGS. 27A to 27C. FIGS. 3A and 3B are schematic perspective views of a semiconductor device including a transistor 200A. FIG. 3B is a perspective view obtained by cutting part of FIG. 3A. For some components (e.g., interlayer insulating layers), FIGS. 3A and 3B show only outlines indicated by dashed lines.

In FIGS. 3A and 3B, the X direction, the Y direction, and the Z direction are indicated by arrows. The directions denoted by X, Y, and Z are consistent in FIGS. 3A and 3B but may be inconsistent among the drawings.

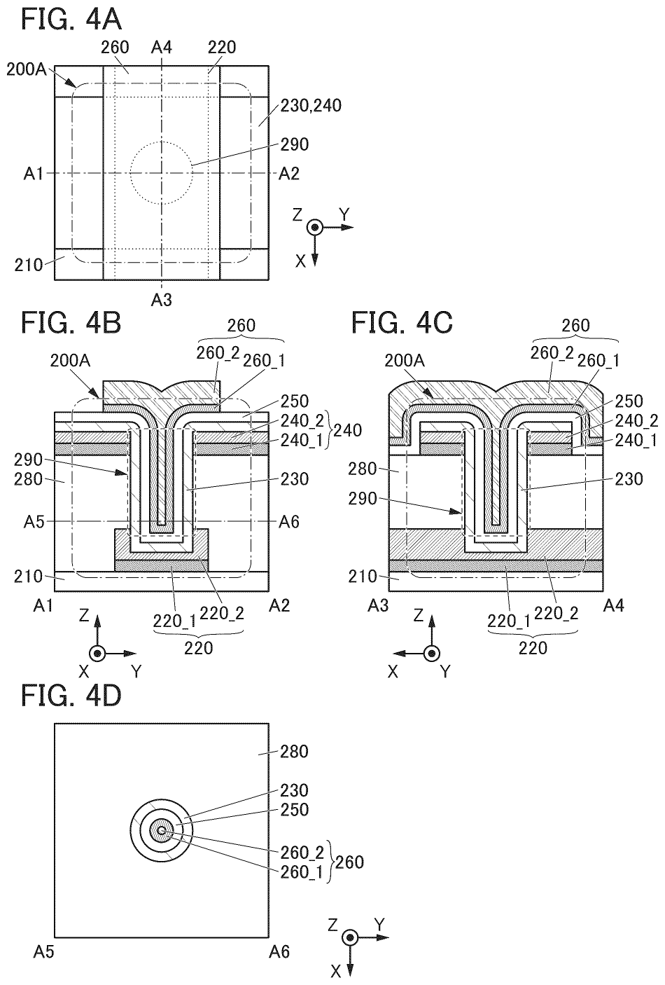

FIG. 4A is a plan view of the semiconductor device including the transistor 200A. FIG. 4B is a cross-sectional view taken along the dashed-dotted line A1-A2 in FIG. 4A. FIG. 4C is a cross-sectional view taken along the dashed-dotted line A3-A4 in FIG. 4A. FIG. 4D is a cross-sectional view taken along the dashed-dotted line A5-A6 in FIG. 4B. For simplification of the drawing, some components are not illustrated in the plan view of FIG. 4A. Some components may be omitted also in the following plan views.

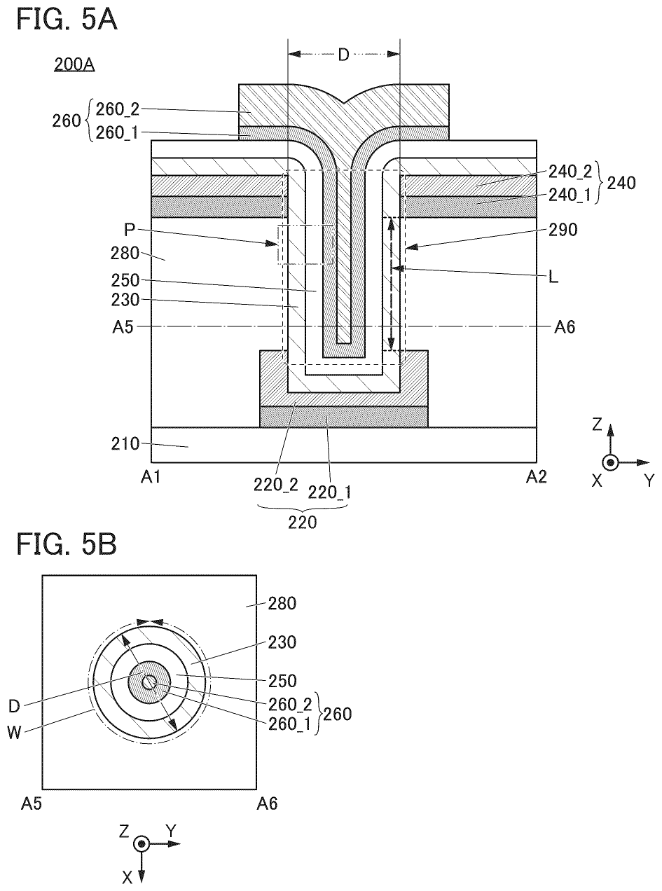

FIG. 5A is a cross-sectional view taken along the dashed-dotted line A1-A2 in FIG. 4A. FIG. 5B is a cross-sectional view taken along the dashed-dotted line A5-A6 in FIG. 4B. FIGS. 5A and 5B correspond to examples of enlarged views of FIGS. 4B and 4D, respectively.

The semiconductor device illustrated in FIGS. 4A to 4D includes an insulating layer 210 over a substrate (not illustrated), the transistor 200A over the insulating layer 210, and an insulating layer 280 over the insulating layer 210.

### [Transistor 200A]

The transistor 200A includes a conductive layer 220, a conductive layer 240 over the insulating layer 280, an oxide semiconductor layer 230, an insulating layer 250 over the oxide semiconductor layer 230, and a conductive layer 260 over the insulating layer 250. The insulating layer 280 is positioned over the conductive layer 220.

FIGS. 4B and 4C illustrate an example in which the conductive layer 220 has a two-layer structure of a conductive layer 220_1 and a conductive layer 220_2 over the conductive layer 220_1, the conductive layer 240 has a two-layer structure of a conductive layer 240_1 and a conductive layer 240_2 over the conductive layer 240_1, and the conductive layer 260 has a two-layer structure of a conductive layer 260_1 and a conductive layer 260_2 over the conductive layer 260_1.

In the transistor 200A, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode. The conductive layer 260 includes a region functioning as a gate wiring.

The oxide semiconductor layer 230, the insulating layer 280, the insulating layer 250, and the conductive layer 260 included in the transistor 200A respectively correspond to the oxide semiconductor layer 30, the insulating layer 20, the insulating layer 50, and the conductive layer 60 described in Embodiment 1. Thus, for the structures, materials, and the like of the oxide semiconductor layer 230, the insulating layer 280, the insulating layer 250, and the conductive layer 260, the structures, materials, and the like of the oxide semiconductor layer 30, the insulating layer 20, the insulating layer 50, and the conductive layer 60 described in Embodiment 1 can be referred to.

As illustrated in FIGS. 4B and 4C, an opening portion 290 reaching the conductive layer 220 is provided in the insulating layer 280 and the conductive layer 240.

The opening portion 290 includes an opening portion of the insulating layer 280 and an opening portion of the conductive layer 240. The shape and the size of the opening portion 290 in the plan view may differ from layer to layer. When the opening portion 290 has a circular top-view shape, the opening portions of the layers may be, but not necessarily, concentrically arranged. The opening portion of the insulating layer 280 corresponds to the opening portion 90 described in Embodiment 1.

The oxide semiconductor layer 230, the insulating layer 250, and the conductive layer 260 are placed in the opening portion 290 at least partly. Portions of the oxide semiconductor layer 230, the insulating layer 250, and the conductive layer 260 which are placed in the opening portion 290 reflect the shape of the opening portion 290.

The oxide semiconductor layer 230 is provided to cover the bottom portion and the sidewall of the opening portion 290. The oxide semiconductor layer 230 has a depression reflecting the shape of the opening portion 290. The oxide semiconductor layer 230 includes a portion in contact with the top surface of the conductive layer 240 and a portion in contact with the top surface of the conductive layer 220 in the opening portion 290.

The insulating layer 250 is provided to cover the oxide semiconductor layer 230. The insulating layer 250 is provided over the insulating layer 280 to cover the top and side surfaces of the oxide semiconductor layer 230 and the side surface of the conductive layer 240. The insulating layer 250 has a depression reflecting the shape of the depression of the oxide semiconductor layer 230.

The conductive layer 260 is provided to fill at least part of the depression of the insulating layer 250. In the opening portion 290, the conductive layer 260 includes a region overlapping with the oxide semiconductor layer 230 with the insulating layer 250 therebetween.

The oxide semiconductor layer 230 includes a region overlapping with the conductive layer 260 with the insulating layer 250 therebetween. At least part of the region functions as a channel formation region of the transistor 200A. One of a region of the oxide semiconductor layer 230 which is in the vicinity of the conductive layer 220 and a region of the oxide semiconductor layer 230 which is in the vicinity of the conductive layer 240 functions as a source region, and the other functions as a drain region. That is, the channel formation region is sandwiched between the source region and the drain region.

The oxide semiconductor layer 230 is provided in the opening portion 290. The transistor 200A has a structure in which current flows in the vertical direction since one of the source electrode and the drain electrode (here, the conductive layer 220) is positioned on the lower side and the other of the source electrode and the drain electrode (here, the conductive layer 240) is positioned on the upper side. That is, a channel is formed along the side surface of the opening portion 290. Thus, the area occupied by the transistor 200A can be smaller than the area occupied by a planar transistor in which a channel formation region, a source region, and a drain region are provided separately on the XY plane. Accordingly, the semiconductor device can be highly integrated. In the case where the semiconductor device of one embodiment of the present invention is used for a memory device, the memory capacity per unit area can be increased. The channel length direction of the transistor 200A includes a height (vertical) component; thus, the transistor 200A can be referred to as a vertical field-effect transistor (VFET), a vertical transistor, a vertical-channel transistor, or the like.

The transistor 200A includes a metal oxide functioning as a semiconductor in the oxide semiconductor layer 230 including the channel formation region. That is, the transistor 200A can be regarded as an OS transistor.

As illustrated in FIG. 5A, the conductive layer 220 has a depression overlapping with the opening portion 290. Specifically, the depression is provided in the conductive layer 220_2 in a position overlapping with the opening portion 290. When the conductive layer 220_2 has the depression in a position overlapping with the opening portion 290, unlike in the case where the depression is not provided, the levels of the bottom surfaces of the insulating layer 250 and the conductive layer 260 in the opening portion 290 can be lower than the level of the top surface of the conductive layer 220_2 which is in contact with the insulating layer 280, with the top surface of the insulating layer 210 used as a reference. The levels of the surfaces can be determined using the formation surface of the transistor as a reference. Here, the top surface of the insulating layer 210 is used as the reference. The surface used as the reference is not limited to the formation surface of the transistor. For example, the top surface of the substrate where the transistor or the semiconductor device is provided may be used as the reference.

The oxide semiconductor layer 230 is in contact with the bottom and side surfaces of the depression of the conductive layer 220_2. When the conductive layer 220_2 has the depression, the contact area between the oxide semiconductor layer 230 and the conductive layer 220_2 can be increased. Thus, the contact resistance between the oxide semiconductor layer 230 and the conductive layer 220_2 can be reduced.

FIG. 4C illustrates a structure in which the side end portion of the conductive layer 240 and the side end portion of the oxide semiconductor layer 230 are aligned or substantially aligned with each other outside the opening portion 290. The conductive layer 240 and the oxide semiconductor layer 230 can be formed by being processed using the same mask. This is preferable because the number of masks required for fabricating the semiconductor device can be reduced. Note that the present invention is not limited thereto. For example, in the X direction or the Y direction, any one of the end portion of the oxide semiconductor layer 230, the end portion of the conductive layer 240_1, and the end portion of the conductive layer 240_2 may be positioned inward or outward from the others.

It is preferable that, in the opening portion 290, the side end portion of the conductive layer 240 and the side end portion of the insulating layer 280 be aligned or substantially aligned with each other. With such a structure, the opening portion 290 can be formed in the conductive layer 240 and the insulating layer 280 at a time. Moreover, the thickness distribution of the oxide semiconductor layer 230 and the like provided in the opening portion 290 can be uniform. In addition, the oxide semiconductor layer 230 and the like can be inhibited from being divided by a step or the like between the conductive layer 240 and the insulating layer 280.

As illustrated in FIG. 4A, the transistor 200A is provided at an intersection of the conductive layer 260 extending in the X direction and the conductive layer 240 extending in the Y direction. As illustrated in FIG. 4A, the diameter of the opening portion 290 can be smaller than the width of the short side of the conductive layer 240 and the width of the short side of the conductive layer 260. Thus, it can be said that the transistor 200A can be highly integrated and scaled down.

As illustrated in FIG. 5B, when the opening portion 290 is formed to be circular in the plan view, the oxide semiconductor layer 230, the insulating layer 250, and the conductive layer 260 are formed concentrically. Thus, the side surface of the conductive layer 260 provided at the center of the opening portion 290 faces the side surface of the oxide semiconductor layer 230 with the insulating layer 250 therebetween. That is, in the plan view, the entire perimeter of the oxide semiconductor layer 230 serves as the channel formation region. In that case, for example, the channel width of the transistor 200A is determined by the length of the perimeter of the oxide semiconductor layer 230. That is, the channel width of the transistor 200A is determined by the width of the opening portion 290 (the diameter in the case where the opening portion 290 is circular in the plan view). FIGS. 5A and 5B illustrate a width D of the opening portion 290, and FIG. 5B illustrates a channel width W of the transistor 200A.

When the oxide semiconductor layer 230, the insulating layer 250, and the conductive layer 260 are formed concentrically, the distance between the conductive layer 260 and the oxide semiconductor layer 230 is substantially uniform; thus, a gate electric field can be substantially uniformly applied to the oxide semiconductor layer 230.

By increasing the width D of the opening portion 290, the channel width per unit area can be increased and the on-state current can be increased. Meanwhile, the area occupied by the transistor 200A, e.g., the area of the transistor 200A in the plan view, is roughly determined by the width of the opening portion 290. By reducing the width D of the opening portion 290, the area occupied by the transistor 200A can be reduced and the semiconductor device can be highly integrated.

The width D of the opening portion 290 sometimes varies in the depth direction. Here, the shortest distance between two side surfaces of the conductive layer 240 on the opening portion side in a cross-sectional view is particularly used as the width D. In other words, the minimum width of the opening portion in the conductive layer 240 is used as the width D of the opening portion 290. The width of the opening portion at the highest position, the width of the opening portion at the lowest position, or the width of the opening portion at the midpoint therebetween in the conductive layer 240, or the average value of these three widths may be used as the width D. Although an example in which the width D of the opening portion 290 is determined by the width of the opening portion of the conductive layer 240 is described here, there is no particular limitation on the method for determining the width D. For example, the shortest distance between two side surfaces of the insulating layer 280 on the opening portion side can be used as the width D. The width of the opening portion at the highest position, the width of the opening portion at the lowest position, or the width of the opening portion at the midpoint therebetween in the insulating layer 280, or the average value of these three widths may be used as the width D of the opening portion 290.

The width D of the opening portion 290 is determined by the thicknesses of the oxide semiconductor layer 230, the insulating layer 250, and the conductive layer 260 provided in the opening portion 290. The width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the width D of the opening portion 290 corresponds to the diameter of the opening portion 290, and the channel width W can be calculated to be “D×π”.

This embodiment describes the example in which the opening portion 290 is circular in the plan view. When the opening portion is circular, the processing accuracy in forming the opening portion can be increased; thus, the opening portion can be formed to have a minute size. Note that the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the circular shape is not necessarily a perfect circular shape. The polygonal shape may be a concave polygonal shape (a polygonal shape at least one of the interior angles of which is greater than) 180° or a convex polygonal shape (a polygonal shape all the interior angles of which are less than or equal to 180°).

The channel length of the transistor 200A is a distance between the source region and the drain region. That is, the channel length of the transistor 200A is determined by the thickness of the insulating layer 280 over the conductive layer 220. Thus, the channel length of the transistor 200A does not affect the area occupied by the transistor 200A, e.g., the area of the transistor 200A in the plan view. In FIG. 5A, a channel length L of the transistor 200A is indicated by a dashed double-headed arrow. The channel length L can be regarded as a distance between the end portion of a region where the oxide semiconductor layer 230 and the conductive layer 220 are in contact with each other and the end portion of a region where the oxide semiconductor layer 230 and the conductive layer 240 are in contact with each other in the cross-sectional view. In that case, the channel length L corresponds to the length of the side surface of the insulating layer 280 on the opening portion 290 side in the cross-sectional view.

The channel length of the transistor 200A can be determined by the thickness of the insulating layer 280. Thus, the channel length of the transistor 200A can be, for example, less than or equal to 500 nm, less than or equal to 300 nm, less than or equal to 100 nm, less than or equal to 60 nm, less than or equal to 50 nm, less than or equal to 40 nm, less than or equal to 30 nm, less than or equal to 20 nm, or less than or equal to 10 nm and greater than or equal to 0.1 nm, greater than or equal to 1 nm, or greater than or equal to 5 nm. The channel length of the transistor 200A can be typically greater than or equal to 1 nm and less than or equal to 300 nm, preferably greater than or equal to 5 nm and less than or equal to 100 nm. In that case, the productivity, yield, and the like can be improved in formation of the insulating layer 280 and formation of the opening portion 290 in the insulating layer 280, for example. In addition, the transistor 200A can have a higher on-state current and higher frequency characteristics.

The channel length L of the transistor 200A is preferably smaller than at least the channel width W of the transistor 200A. The channel length L of the transistor 200A is preferably greater than or equal to 0.1 times and less than or equal to 0.99 times, further preferably greater than or equal to 0.5 times and less than or equal to 0.8 times the channel width W of the transistor 200A. This structure enables the transistor to have excellent electrical characteristics and high reliability.

The insulating layer 210 functions as an interlayer film and thus is preferably formed using a material with a low dielectric constant. In the case where a material with a low dielectric constant is used for an interlayer film, the parasitic capacitance generated between wirings can be reduced.

The insulating layer 210 preferably has a barrier property against hydrogen. When the insulating layer 210 provided below the oxide semiconductor layer 230 has a barrier property against hydrogen, diffusion of hydrogen into the oxide semiconductor layer 230 from below the transistor 200A can be inhibited.

The insulating layer 210 preferably has a function of capturing or fixing hydrogen. When the insulating layer 210 has a function of capturing or fixing hydrogen, hydrogen in the oxide semiconductor layer 230 can diffuse into the insulating layer 210 through the conductive layer 220 and the hydrogen can be captured or fixed. Thus, the hydrogen concentration in the oxide semiconductor layer 230 can be reduced.

The concentration of impurities such as water and hydrogen in the insulating layer 210 is preferably reduced. This can inhibit entry of impurities such as water and hydrogen into the channel formation region in the oxide semiconductor layer 230.

In the example illustrated in FIG. 5A, the insulating layer 210 has a single-layer structure. Note that the insulating layer 210 can have a stacked-layer structure of two or more layers. For example, the insulating layer 210 can have a two-layer structure of a first insulating layer and a second insulating layer over the first insulating layer. In that case, it is preferable that the first insulating layer have a barrier property against hydrogen and the second insulating layer have a function of capturing or fixing hydrogen, for example. Specifically, it is preferable that silicon nitride be used for the first insulating layer and aluminum oxide, hafnium oxide, hafnium zirconium oxide, or hafnium silicate be used for the second insulating layer.

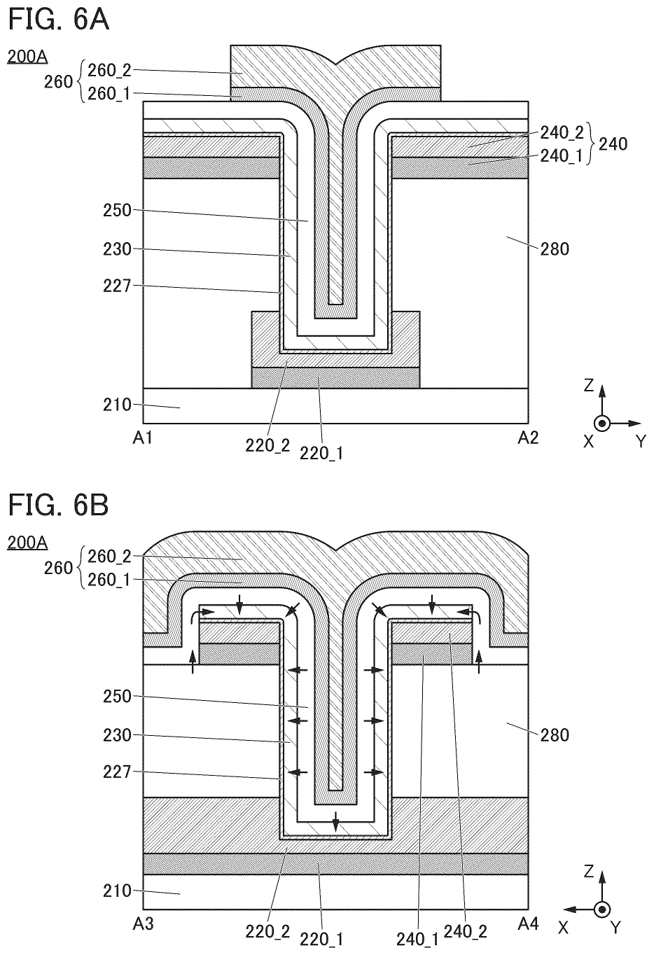

As illustrated in FIG. 6A, an oxide layer 227 can be provided below the oxide semiconductor layer 230. The oxide layer 227 corresponds to the oxide layer 27 described in Embodiment 1. Thus, for the structure, material, and the like of the oxide layer 227, the structure, material, and the like of the oxide layer 27 described in Embodiment 1 can be referred to.

The insulating layer 280 functions as an interlayer film and thus is preferably formed using a material with a low dielectric constant. In the case where a material with a low dielectric constant is used for an interlayer film, the parasitic capacitance generated between wirings can be reduced. Silicon oxide or silicon oxynitride can be used for the insulating layer 280, for example.

The concentration of impurities such as water and hydrogen in the insulating layer 280 is preferably reduced. This can inhibit entry of impurities such as water and hydrogen into the channel formation region in the oxide semiconductor layer 230.

The insulating layer 280 preferably contains nitrogen dioxide (NO₂). In the case where the insulating layer 280 contains silicon oxide or silicon oxynitride, for example, NO₂ in the insulating layer 280 is presumed to exist in a state close to an isolated molecule.

When a potential is supplied to the conductive layer 260 functioning as the gate electrode at the time of turning on an OS transistor, electrons are not only injected into the oxide semiconductor layer 230 but also trapped by NO₂. The charge of the NO₂ that traps the electrons becomes −1; thus, the NO₂ becomes negative fixed charge. When NO₂ in the insulating layer 280 becomes negative fixed charge in this manner, a higher potential needs to be supplied to the conductive layer 260 in order to turn on the OS transistor. That is, when NO₂ in the insulating layer 280 becomes negative fixed charge, the threshold voltage of the OS transistor can be shifted in the positive direction.

As described in Embodiment 1, the OS transistor in which the channel formation region in the oxide semiconductor layer includes V_{O} and V_{O}H is likely to have normally-on characteristics. However, with the above structure in which NO₂ in the insulating layer 280 becomes negative fixed charge, the negative shift of the electrical characteristics of the OS transistor can be inhibited and the OS transistor can have normally-off characteristics. Accordingly, the semiconductor device having excellent electrical characteristics can be provided.

The amount of NO₂ in the insulating layer 280 can be evaluated by electron spin resonance (ESR), thermal desorption spectroscopy (TDS), or the like.

In the case where silicon oxide containing NO₂ is used for the insulating layer 280, for example, the evaluation can be performed by ESR measurement. Neutral NO₂ in silicon oxide has an isolated electron; thus, the ESR measurement can be performed. An absorption peak attributed to NO₂ and obtained by the ESR measurement appears at a g-factor greater than or equal to 1.94 and less than or equal to 2.05. Thus, the spin density corresponding to the absorption peak at a g-factor greater than or equal to 1.94 and less than or equal to 2.05 which is measured by ESR from the insulating layer 280 is higher than or equal to 4.8×10⁻³ spins/nm³ and lower than or equal to 1.0×10⁻² spins/nm³, preferably higher than or equal to 7.38×10⁻³ spins/nm³ and lower than or equal to 1.0×10⁻² spins/nm³. When the absorption peak measured by ESR from the insulating layer 280 containing NO₂ is the above value, the threshold voltage of the OS transistor can be 0 V or around 0 V or higher. In addition, efficient treatment for adding NO₂ can improve the productivity of the semiconductor device.

Note that the insulating layer 280 having the above spin density is not limited to being provided in the vicinity of the oxide semiconductor layer 230. The insulating layer 280 having the above spin density is preferably provided in a periphery of a region where the OS transistor is provided, e.g., in a region where a marker is formed or a region where an electrode pad is formed.

Plasma treatment using a nitrogen-containing gas is preferably performed to add NO₂ to the insulating layer 280. As the nitrogen-containing gas, a nitrogen gas or a dinitrogen monoxide (N₂O) gas can be used. When the insulating layer 280 containing silicon oxide is subjected to treatment using N₂ or N₂O which is made to be plasma, NO₂ can be added to the insulating layer 280. At this time, oxygen can also be added to the insulating layer 280.

The plasma treatment can be performed using a sputtering apparatus, a CVD apparatus, a dry etching apparatus, a CVD apparatus including a high-density plasma source, a dry etching apparatus including a high-density plasma source, or the like.

The semiconductor device illustrated in FIG. 6A can be fabricated in the following manner: the conductive layer 220 is formed over the insulating layer 210; the insulating layer 280 is formed over the conductive layer 220; the conductive layer 240 is formed over the insulating layer 280; the opening portion 290 reaching the conductive layer 220 is formed by processing the conductive layer 240 and the insulating layer 280; the oxide layer 227 is formed to cover the opening portion 290; the oxide semiconductor layer 230 is formed over the oxide layer 227; the insulating layer 250 is formed over the oxide semiconductor layer 230 and the insulating layer 280 to include a portion in contact with the oxide semiconductor layer 230 and a portion in contact with the insulating layer 280; and the conductive layer 260 is formed over the insulating layer 250. The plasma treatment can be performed after the formation of the insulating layer 280.

During the plasma treatment, substrate heating is preferably performed. Heat treatment may be performed before or after the plasma treatment. The temperature of the substrate heating or the heat treatment can be, for example, higher than or equal to 200° C. and lower than or equal to 450° C., preferably higher than or equal to 350° C. and lower than or equal to 400° C. By performing the substrate heating or the heat treatment in this manner, the amount of excess oxygen contained in the insulating layer 280 can be reduced, the OS transistor can have normally-off characteristics, and the electrical characteristics of the OS transistor can be improved. In addition, the reliability of the OS transistor can be increased. When the substrate temperature is lower than or equal to 450° C., preferably lower than or equal to 400° C., release of NO₂ by the heat treatment can be inhibited.

FIG. 6B is a cross-sectional view of the semiconductor device illustrated in FIG. 6A seen from the Y direction. Arrows in FIG. 6B indicate oxygen diffusion paths.

Even in the case where the oxide layer 227 has a function of inhibiting diffusion of oxygen, oxygen can be supplied from the insulating layer 280 to the oxide semiconductor layer 230 through the insulating layer 250 by the heat treatment to reduce oxygen vacancies in the oxide semiconductor layer 230, as illustrated in FIG. 6B. With the use of an indium oxide film having a high oxygen-transmitting property for the oxide semiconductor layer 230, an excessive amount of oxygen in the oxide semiconductor layer 230 can be released to the insulating layer 250, so that the excessive amount of oxygen in the oxide semiconductor layer 230 can be reduced. Thus, the electrical characteristics and reliability of the transistor 200A can be improved.

In the case where the oxide layer 227 has a function of transmitting oxygen, oxygen can be supplied from the insulating layer 280 to the oxide semiconductor layer 230 through the oxide layer 227 or the insulating layer 250 by the heat treatment to reduce oxygen vacancies in the oxide semiconductor layer 230. With the use of an indium oxide film having a high oxygen-transmitting property for the oxide semiconductor layer 230, an excessive amount of oxygen in the oxide semiconductor layer 230 can be released to the insulating layer 250, so that the excessive amount of oxygen in the oxide semiconductor layer 230 can be reduced. Thus, the electrical characteristics and reliability of the transistor 200A can be improved.

Since oxygen in the insulating layer 280 is supplied to the oxide semiconductor layer 230 through the insulating layer 250, the heat treatment is preferably performed after the formation of the insulating layer 250.

Note that NO₂ added to the insulating layer 280 remains in the insulating layer 280 even after the heat treatment. Thus, the amount of NO₂ in the insulating layer 280 hardly changes before and after the heat treatment. For example, a difference between the spin density measured by ESR from the insulating layer 280 before the heat treatment and the spin density measured by ESR from the insulating layer 280 after the heat treatment is less than or equal to 10%, preferably less than or equal to 7%, further preferably less than or equal to 5%, still further preferably less than or equal to 3%. Note that the spin densities each correspond to an absorption peak at a g-factor greater than or equal to 1.94 and less than or equal to 2.05.

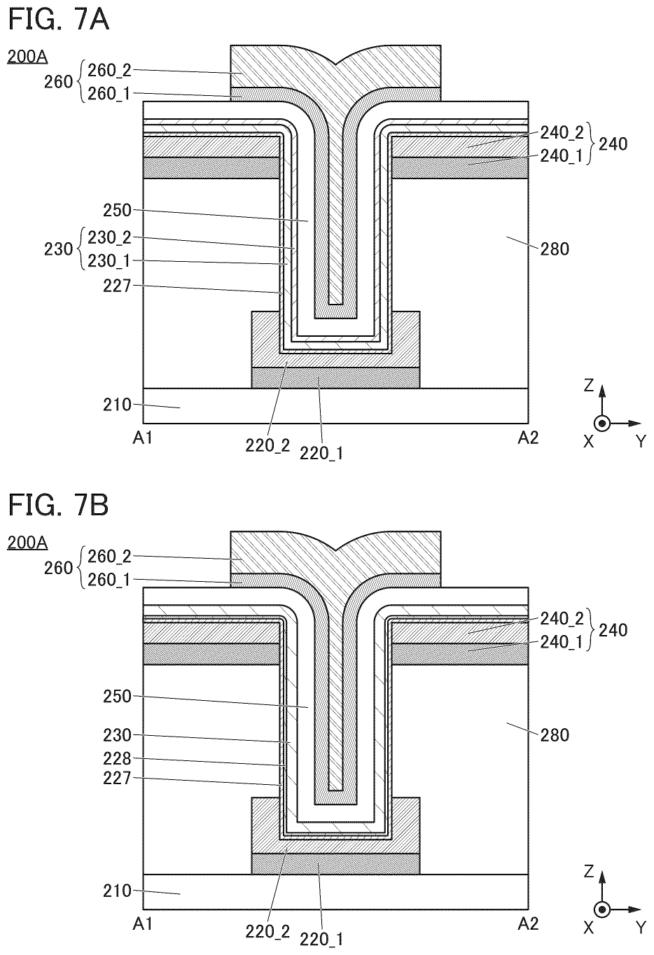

In the example illustrated in FIG. 5A, the oxide semiconductor layer 230 has a single-layer structure. Note that the oxide semiconductor layer 230 can have a stacked-layer structure of two or more layers. As illustrated in FIG. 7A, the oxide semiconductor layer 230 can have a two-layer structure of an oxide semiconductor layer 230_1 and an oxide semiconductor layer 230_2 over the oxide semiconductor layer 230_1. The oxide semiconductor layer 230_1 and the oxide semiconductor layer 230_2 respectively correspond to the oxide semiconductor layer 30a and the oxide semiconductor layer 30b described in Embodiment 1. Thus, for the structures, materials, and the like of the oxide semiconductor layer 230_1 and the oxide semiconductor layer 230_2, the structures, materials, and the like of the oxide semiconductor layer 30a and the oxide semiconductor layer 30b described in Embodiment 1 can be referred to.

As illustrated in FIG. 7B, a layer 228 can be provided between the oxide layer 227 and the oxide semiconductor layer 230. The layer 228 corresponds to the layer 28 described in Embodiment 1. Thus, for the structure, material, and the like of the layer 228, the structure, material, and the like of the layer 28 described in Embodiment 1 can be referred to.

In the example illustrated in FIG. 5A, the insulating layer 250 has a single-layer structure. Note that the insulating layer 250 can have a stacked-layer structure of two or more layers. In that case, the insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting an excessive amount of oxygen from the oxide semiconductor layer 230, a function of extracting hydrogen from the oxide semiconductor layer 230, and a function of inhibiting diffusion of hydrogen into the oxide semiconductor layer 230.

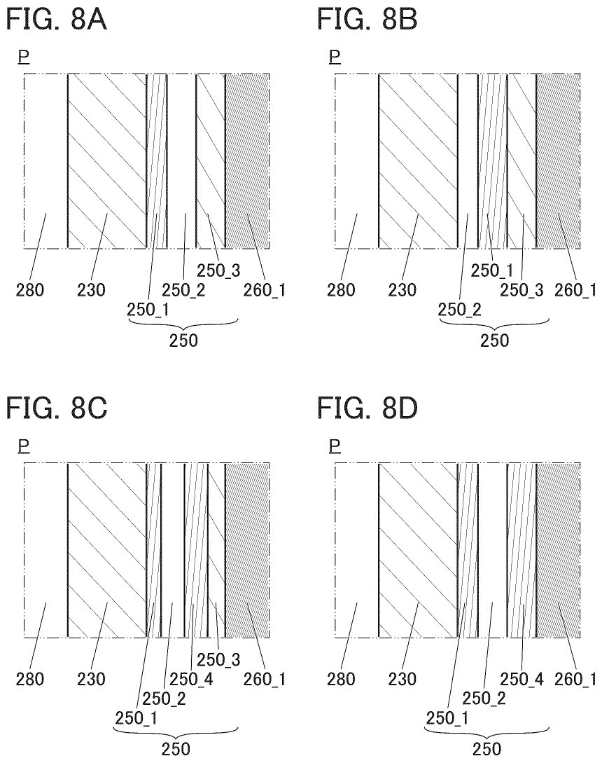

FIGS. 8A to 8D are enlarged views of the insulating layer 250 and its vicinity. FIGS. 8A to 8D are also enlarged views of a region P surrounded by a dashed-dotted line in FIG. 5A.

FIG. 8A illustrates an example in which the insulating layer 250 has a three-layer structure of an insulating layer 250_1, an insulating layer 250_2 over the insulating layer 250_1, and an insulating layer 250_3 over the insulating layer 250_2. In that case, the insulating layer 250_1 is in contact with the oxide semiconductor layer 230.

The insulating layer 250_1 can be formed using any of the materials that can be used for the second insulating layer described in Embodiment 1. For example, the insulating layer 250_1 preferably has a function of capturing or fixing oxygen. Such a structure can reduce an excessive amount of oxygen in the oxide semiconductor layer 230. The insulating layer having a function of capturing or fixing oxygen sometimes has a function of capturing or fixing hydrogen; thus, the hydrogen concentration in the oxide semiconductor layer 230 can sometimes be reduced. Accordingly, the transistor can have high reliability.

The insulating layer 250_1 is preferably formed using a material with a high dielectric constant (a high-k material). An example of the high-k material is an oxide containing one or both of aluminum and hafnium. With the use of the high-k material for the insulating layer 250_1, a gate potential applied during the operation of the transistor can be reduced while the physical thickness of a gate insulator is maintained. Furthermore, the equivalent oxide thickness (EOT) of the insulator functioning as the gate insulator can be reduced.

As described above, for the insulating layer 250_1, it is preferable to use an oxide containing one or both of aluminum and hafnium and it is further preferable to use an oxide containing one or both of aluminum and hafnium and having an amorphous structure. Since aluminum oxide can be formed as an amorphous film relatively easily by an ALD method, the use of aluminum oxide having an amorphous structure is further preferable. In this embodiment, aluminum oxide is used for the insulating layer 250_1. Aluminum oxide has a function of capturing or fixing oxygen and hydrogen, and thus is suitably used for the insulating layer 250_1.

The insulating layer 250_2 is preferably formed using a material with a low dielectric constant, for example. The insulating layer 250_2 preferably includes a silicon oxide film or a silicon oxynitride film, for example.

Silicon oxide or silicon nitride is an insulating material having a high withstand voltage. Thus, leakage current of the transistor can be reduced. A silicon oxide film or a silicon oxynitride film has a high hydrogen-transmitting property. Hence, as illustrated in FIG. 8B, the insulating layer 250 may have a three-layer structure of the insulating layer 250_2, the insulating layer 250_1 over the insulating layer 250_2, and the insulating layer 250_3 over the insulating layer 250_1. With such a structure, hydrogen in the oxide semiconductor layer 230 can diffuse into the insulating layer 250_1 through the insulating layer 250_2, and the hydrogen can be captured or fixed. Accordingly, the hydrogen concentration in the oxide semiconductor layer 230 can be reduced.

The insulating layer 250_3 preferably has a barrier property against hydrogen. Such a structure can inhibit diffusion of hydrogen into the oxide semiconductor layer 230. The insulating layer 250_3 preferably also has a barrier property against oxygen. The insulating layer 250_3 is provided between the channel formation region in the oxide semiconductor layer 230 and the conductive layer 260. Such a structure can inhibit oxygen contained in the channel formation region in the oxide semiconductor layer 230 from diffusing into the conductive layer 260 and thus can inhibit formation of oxygen vacancies in the channel formation region in the oxide semiconductor layer 230. Oxygen contained in the oxide semiconductor layer 230 can be inhibited from diffusing into the conductive layer 260 and oxidizing the conductive layer 260. The insulating layer 250_3 preferably has a lower oxygen-transmitting property than at least the insulating layer 250_2. The insulating layer 250_3 preferably has a function of inhibiting diffusion of hydrogen. This can prevent diffusion of impurities such as hydrogen contained in the conductive layer 260 into the oxide semiconductor layer 230. Silicon nitride is preferably used for the insulating layer 250_3, for example.

As illustrated in FIG. 8C, an insulating layer 250_4 may be provided over the insulating layer 250_2. The insulating layer 250_4 can be formed using any of the insulating materials that can be used for the insulating layer 250_1. The insulating layer 250_4 preferably has a function of capturing or fixing hydrogen, for example. When the insulating layer 250_4 is provided between the insulating layer 250_3 and the insulating layer 250_2, hydrogen contained in the insulating layer 250_2 and the like can be captured or fixed more effectively.

Specifically, the insulating layer 250 preferably has a four-layer structure in which an aluminum oxide film, a silicon oxide film, a hafnium oxide film, and a silicon nitride film are stacked in this order from the oxide semiconductor layer 230 side. With such a structure, hydrogen in the oxide semiconductor layer 230 can diffuse into the insulating layer 250_1 or the insulating layer 250_4, and the hydrogen can be captured or fixed. Accordingly, the hydrogen concentration in the oxide semiconductor layer 230 can be reduced.

The insulating layer 250 is preferably thin. For example, when the thickness of the insulating layer 250 is greater than or equal to 1 nm and less than or equal to 20 nm, preferably greater than or equal to 3 nm and less than or equal to 10 nm, the subthreshold swing value (also referred to as S value) can be reduced. Note that the S value means the amount of change in gate voltage in a subthreshold region when drain voltage is constant and drain current is changed by one order of magnitude.

The thickness of each layer included in the insulating layer 250 is preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet further preferably greater than or equal to 1 nm and less than 5 nm, yet still further preferably greater than or equal to 1 nm and less than or equal to 3 nm. Note that each layer included in the insulating layer 250 at least partly includes a region with the above thickness.

Typically, the thicknesses of the insulating layer 250_1, the insulating layer 250_2, the insulating layer 250_4, and the insulating layer 250_3 are 1 nm, 2 nm, 2 nm, and 1 nm, respectively. Such a structure enables the transistor to have excellent electrical characteristics even when the transistor is scaled down or highly integrated.

The insulating layer 250_3 in the insulating layer 250 having the four-layer structure is not necessarily provided (see FIG. 8D). For example, an insulating layer having a function of capturing or fixing oxygen can be used as the insulating layer 250_1, an insulating layer containing a material with a low dielectric constant can be used as the insulating layer 250_2, and an insulating layer having a function of capturing or fixing hydrogen can be used as the insulating layer 250_4. Specifically, the insulating layer 250 can have a three-layer structure in which an aluminum oxide film, a silicon oxide film, and a hafnium oxide film are stacked in this order from the oxide semiconductor layer 230 side.

In order that the insulating layers 250_1 to 250_4 have small thicknesses as described above, an ALD method is preferably employed. In order that the insulating layers 250_1 to 250_4 with good coverage are formed in the opening portion 290, an ALD method is preferably employed.

Note that in formation of the insulating layer 250 having a stacked-layer structure of a plurality of insulating films, an ALD process is preferably performed twice or more. For example, two or more kinds of the insulating films in the insulating layer 250 are preferably formed through an ALD process. When at least two kinds of insulating films are formed through an ALD process, the coverage with the insulating layer 250 and the thickness uniformity of the insulating layer 250 can be improved. When two or more kinds of insulating films are successively formed through an ALD process, for example, the productivity can be increased.

Although the insulating layer 250 has the three-layer structure of the insulating layers 250_1 to 250_3 or the four-layer structure of the insulating layers 250_1 to 250_4 in the above description, the present invention is not limited thereto. The insulating layer 250 can have a structure including at least one of the insulating layers 250_1 to 250_4. When the insulating layer 250 is formed of one, two, or three of the insulating layers 250_1 to 250_4, the fabrication process of the semiconductor device can be simplified and the productivity can be improved.

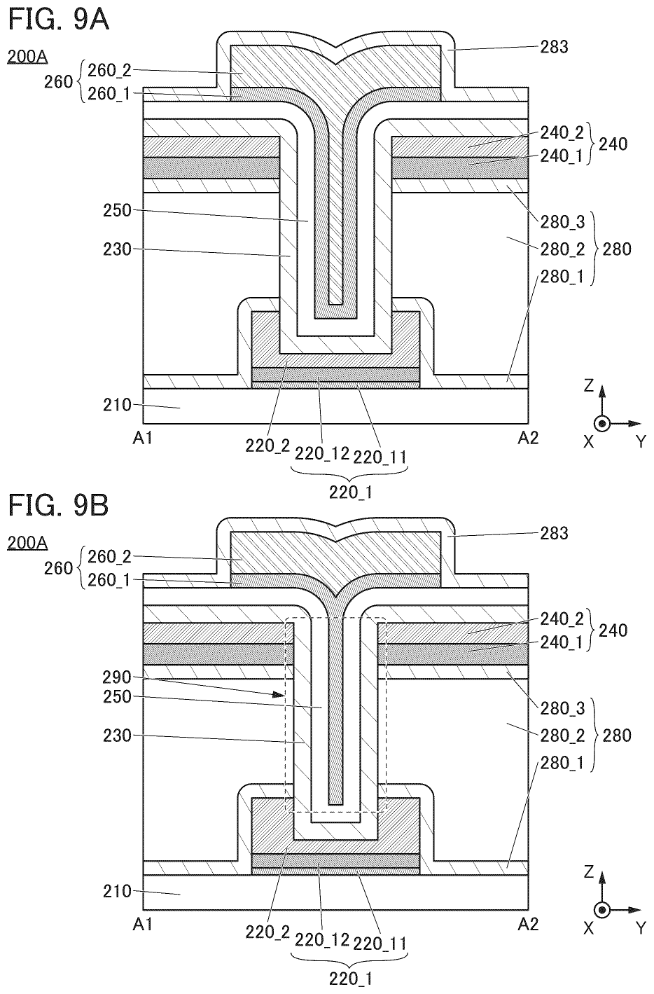

In the example illustrated in FIG. 5A, the insulating layer 280 has a single-layer structure. Note that the insulating layer 280 can have a stacked-layer structure of two or more layers. For example, as illustrated in FIG. 9A, the insulating layer 280 can have a three-layer structure of an insulating layer 280_1, an insulating layer 280_2 over the insulating layer 280_1, and an insulating layer 280_3 over the insulating layer 280_2. In that case, it is preferable that the material with a low dielectric constant be used for the insulating layer 280_2 and a barrier insulating layer against oxygen be used as each of the insulating layers 280_1 and 280_3. Thus, the conductive layer 220 and the conductive layer 240 can be inhibited from being oxidized and having an increased resistance. In the structure illustrated in FIG. 9A, the insulating layer 280_2 corresponds to the insulating layer 20 described in Embodiment 1.

It is preferable that silicon nitride or aluminum oxide be used for each of the insulating layers 280_1 and 280_3 and silicon oxide be used for the insulating layer 280_2, for example. Note that each of the insulating layers 280_1 and 280_3 may have a stacked-layer structure of two or more layers.

Each of the conductive layers 220 and 240 is in contact with the oxide semiconductor layer 230, and thus is preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of each of the conductive layers 220 and 240 can be inhibited.

When a conductive material containing oxygen is used for the conductive layer 220, the conductive layer 220 can maintain its conductivity even after absorbing oxygen. Similarly, when a conductive material containing oxygen is used for the conductive layer 240, the conductive layer 240 can maintain its conductivity even after absorbing oxygen. The use of a conductive material containing oxygen for the conductive layer 220 is preferable because the conductive layer 220 can maintain its conductivity even when an insulator containing oxygen, such as hafnium oxide, is used for the insulating layer 210. For each of the conductive layers 220 and 240, ITO, ITSO, In—Zn oxide, or the like is preferably used, for example.

In the case where the conductive layers 220 and 240 each have a stacked-layer structure, a conductive material containing oxygen is preferably used for a layer having the largest contact area with the oxide semiconductor layer 230 in the stacked-layer structure, in which case the contact resistance between the conductive layer 220 and the oxide semiconductor layer 230 and the contact resistance between the conductive layer 240 and the oxide semiconductor layer 230 can be reduced.

FIG. 9A illustrates an example in which the conductive layer 220_1 has a two-layer structure of a conductive layer 220_11 and a conductive layer 220_12 over the conductive layer 220_11. In other words, the conductive layer 220 illustrated in FIG. 9A has a three-layer structure of the conductive layer 220_11, the conductive layer 220_12 over the conductive layer 220_11, and the conductive layer 220_2 over the conductive layer 220_12. In that case, for example, it is preferable that a conductive material that is not easily oxidized or a conductive material that has a function of inhibiting diffusion of oxygen be used for the conductive layer 220_11, a material that has high conductivity be used for the conductive layer 220_12, and a conductive material that contains oxygen (further preferably an oxide conductor) be used for the conductive layer 220_2. Specifically, it is preferable that titanium nitride be used for the conductive layer 220_11, tungsten be used for the conductive layer 220_12, and an oxide conductor (e.g., ITO, ITSO, or In—Zn oxide) be used for the conductive layer 220_2. In that case, a titanium nitride film is in contact with the insulating layer 210, and an oxide conductive film is in contact with the oxide semiconductor layer 230. In addition, an oxide conductor is used for a layer closest to the channel formation region in the oxide semiconductor layer 230. Since the oxide conductor has a lower contact resistance with the oxide semiconductor layer 230 than tungsten, the current path between the source and the drain can be shortened and the on-state current of the transistor 200A can be increased. Such a structure enables the conductive layer 220 to maintain its conductivity even when the conductive layer 220 is in contact with the oxide semiconductor layer 230. In the case of using an oxide insulating layer as the insulating layer 210, such a structure can inhibit the conductive layer 220 from being excessively oxidized by the insulating layer 210. When a metal material (here, tungsten) having higher conductivity than the oxide conductor and titanium nitride is used for the conductive layer 220_12, the conductivity of the conductive layer 220 can be increased.

The conductive layer 240 illustrated in FIG. 5A has the two-layer structure of the conductive layer 240_1 and the conductive layer 240_2 over the conductive layer 240_1. In that case, for example, it is preferable that a conductive material containing oxygen be used for the conductive layer 240_2, and a material having higher conductivity than the material for the conductive layer 240_2 be used for the conductive layer 240_1. Specifically, it is preferable that an oxide conductor (e.g., ITO, ITSO, or In—Zn oxide) be used for the conductive layer 240_2 and tungsten be used for the conductive layer 240_1. For the conductive layer 240_1, ruthenium, titanium nitride, tantalum nitride, or the like may be used. When an oxide conductor is used for the conductive layer 240_2 mainly in contact with the oxide semiconductor layer 230, the contact resistance with the oxide semiconductor layer 230 can be reduced. When a material having higher conductivity than an oxide conductor is used for a layer included in the conductive layer 240, the conductivity of the conductive layer 240 can be increased.

Note that a conductive material containing oxygen can be used for the conductive layer 240_1, and a material having higher conductivity than the material for the conductive layer 240_1 can be used for the conductive layer 240_2. In that case, an oxide conductor is used for the layer of the conductive layer 240 which is closest to the channel formation region in the oxide semiconductor layer 230. Thus, the current path between the source and the drain can be shortened and the on-state current of the transistor 200A can be increased.

The conductive layer 260 illustrated in FIG. 5A has the two-layer structure of the conductive layer 260_1 and the conductive layer 260_2 over the conductive layer 260_1. In that case, for example, it is preferable that titanium nitride be used for the conductive layer 260_1, and tungsten be used for the conductive layer 260_2. Alternatively, it is preferable that tantalum nitride be used for the conductive layer 260_1, and copper be used for the conductive layer 260_2. Such a structure can increase the conductivity of the conductive layer 260.

Alternatively, the conductive layer 260 may have a stacked-layer structure of three or more layers. For example, the conductive layer 260 may have a three-layer structure of a tantalum nitride film, a titanium nitride film over the tantalum nitride film, and a tungsten film over the titanium nitride film.

As illustrated in FIG. 9A, the semiconductor device of one embodiment of the present invention may include an insulating layer 283 over the transistor 200A. Specifically, the insulating layer 283 may be provided over the conductive layer 260 and the insulating layer 250.

As the insulating layer 283, a barrier insulating layer against hydrogen is preferably used. Such a structure can inhibit diffusion of hydrogen from above the transistor 200A into the oxide semiconductor layer 230.

In the transistor 200A illustrated in FIG. 5A, both the conductive layer 260_1 and the conductive layer 260_2 are positioned in the opening portion 290. Depending on the width of the opening portion 290, the thicknesses of the oxide semiconductor layer 230, the insulating layer 250, and the conductive layer 260_1, and the like, the conductive layer 260_1 is provided in the opening portion 290 and the conductive layer 260_2 is provided in a position overlapping with the opening portion 290 in some cases (see FIG. 9B).

Although FIG. 9A illustrates a structure in which the side end portion of the conductive layer 240 and the side end portion of the insulating layer 280 are aligned or substantially aligned with each other in the opening portion 290, the present invention is not limited thereto. For example, the side surface of the conductive layer 240 and the side surface of the insulating layer 280 may be discontinuous in the opening portion 290. The inclination of the side surface of the conductive layer 240 and the inclination of the side surface of the insulating layer 280 may be different from each other in the opening portion 290. At this time, part of the sidewall of the opening portion 290 has a tapered shape.

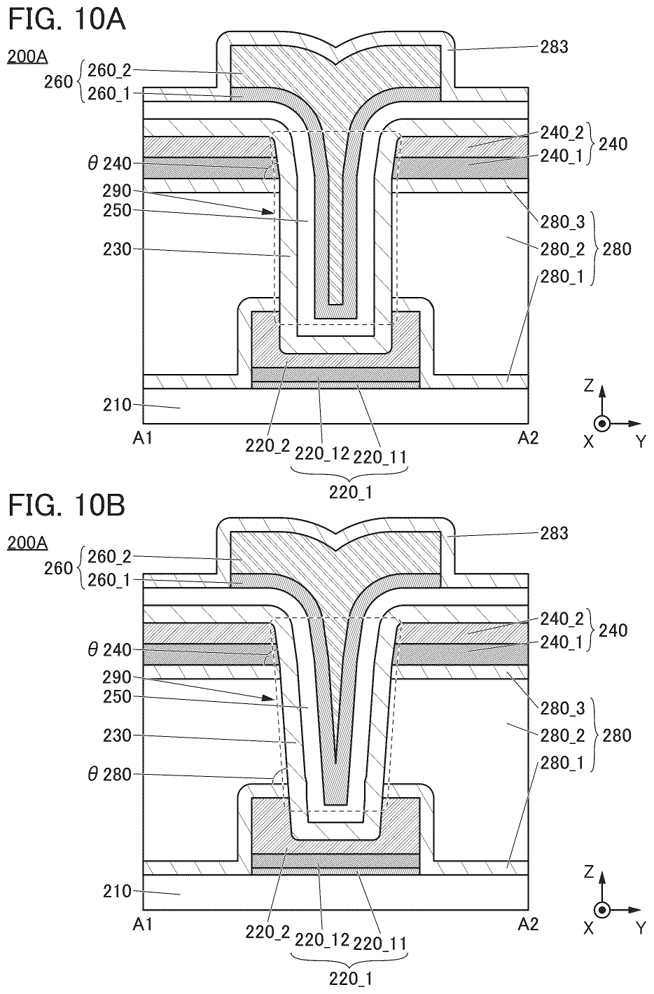

FIGS. 10A and 10B each illustrate an example in which at least part of the sidewall of the opening portion 290 has a tapered shape. FIG. 10A illustrates an example in which the side surface of the conductive layer 240 in the opening portion 290 has a tapered shape, and FIG. 10B illustrates an example in which the side surfaces of the conductive layer 240 and the insulating layer 280 in the opening portion 290 each have a tapered shape.

When the sidewall of the opening portion 290 has a tapered shape, the coverage with the oxide semiconductor layer 230, the insulating layer 250, and the like can be improved, so that defects such as voids can be reduced. In the case where the sidewall of the opening portion 290 has a tapered shape, for example, a taper angle (an angle θ240) of the side surface of the conductive layer 240 in the opening portion 290 and a taper angle (an angle θ280) of the side surface of the insulating layer 280 in the opening portion 290 are each preferably greater than or equal to 45° and less than 90°. Specifically, the taper angles are each preferably greater than or equal to 80° and less than 90°, in which case the semiconductor device can be scaled down or highly integrated as described above. Moreover, the taper angles are each preferably greater than or equal to 45° or greater than or equal to 50° and less than 80°, less than or equal to 75°, less than or equal to 70°, less than or equal to 65°, or less than or equal to 60°, in which case the coverage with a film to be formed in the opening portion 290 is improved.

For example, the angle θ240 is preferably smaller than the angle θ280. With such a structure, the coverage of the side surface of the conductive layer 240 in the opening portion 290 with the oxide semiconductor layer 230 or the like is improved, so that defects such as voids can be reduced. In the case where the insulating layer 280 has a stacked-layer structure, the inclinations of the side surfaces of the layers in the opening portion 290 may be different from each other. Similarly, in the case where the conductive layer 240 has a stacked-layer structure, the inclinations of the side surfaces of the layers in the opening portion 290 may be different from each other.

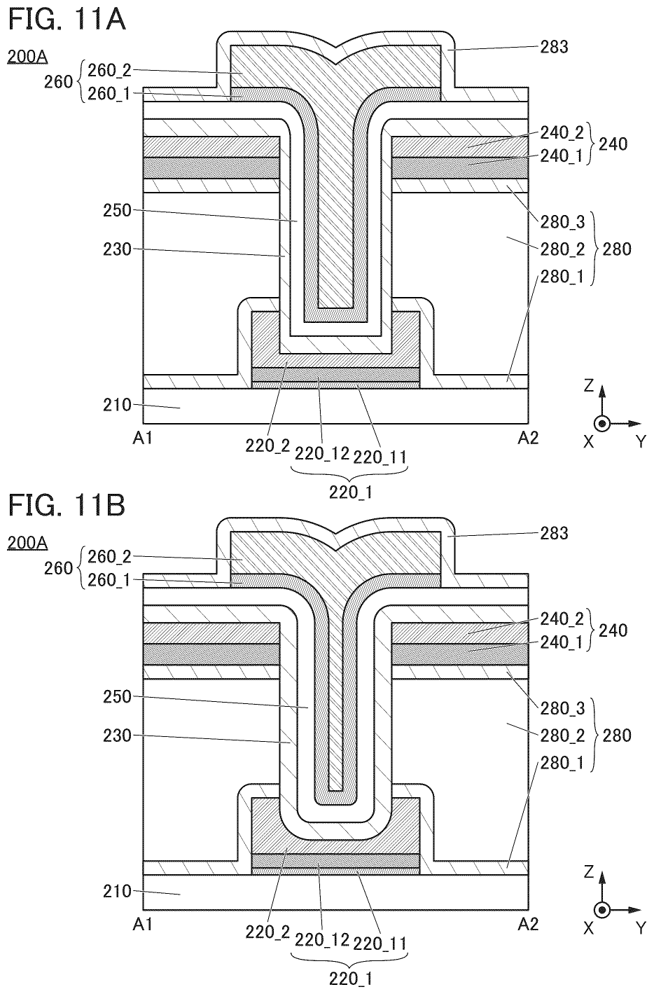

As illustrated in FIG. 11A, a ratio between the thickness of a portion of the oxide semiconductor layer 230 that is formed over the top surface of the conductive layer 240 or the conductive layer 220 (hereinafter, the thickness is referred to as a first thickness) and the thickness of a portion of the oxide semiconductor layer 230 that is formed over the sidewall of the opening portion 290 (hereinafter, the thickness is referred to as a second thickness) sometimes varies. In the case where part of the oxide semiconductor layer 230 is formed by a sputtering method, for example, the ratio between the first thickness and the second thickness of the oxide semiconductor layer 230 sometimes varies. For example, as illustrated in FIG. 11A, the ratio of the second thickness to the first thickness is lower than 1, lower than 0.8, or lower than 0.5 in some cases. In particular, as the angle θ280 is closer to 90°, the ratio of the second thickness to the first thickness of the oxide semiconductor layer 230 tends to be lower.

As illustrated in FIG. 11B, the depression of the conductive layer 220_2 preferably has a curved portion. When the depression has the curved portion, portions of the oxide semiconductor layer 230, the insulating layer 250, and the like that are provided over the depression and in the vicinity of the depression each have a curved portion in some cases. In other words, the portions each have a curved surface or a concave surface in the cross-sectional view in some cases. The portions each do not have an angle portion (a right angle or an acute angle) in the cross-sectional view in some cases. Thus, electric field concentration on the insulating layer 250 in the vicinity of the depression is relieved, so that the withstand voltage of the transistor 200A can be increased and the electrostatic breakdown of the transistor 200A can be inhibited. Accordingly, the reliability of the semiconductor device can be improved.

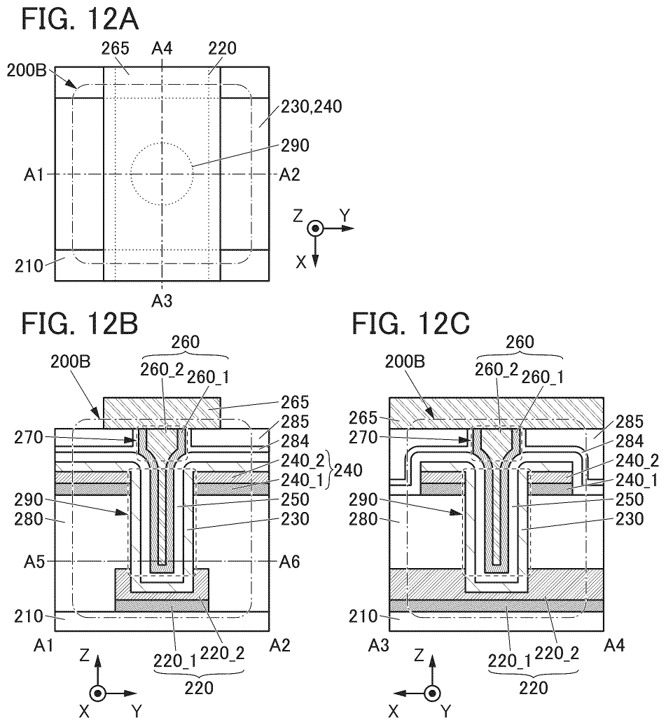

Structure examples of transistors whose structures are partly different from that of the transistor 200A will be described below with reference to FIGS. 12A to 12C to FIGS. 27A to 27C. Note that description of the portions already described is omitted and only different portions are described in detail. Even when positions or shapes of components are different from those in the above example, the same reference numerals are used as long as the components have the same functions as those in the above example, and description thereof is omitted in some cases.

### [Transistor 200B]

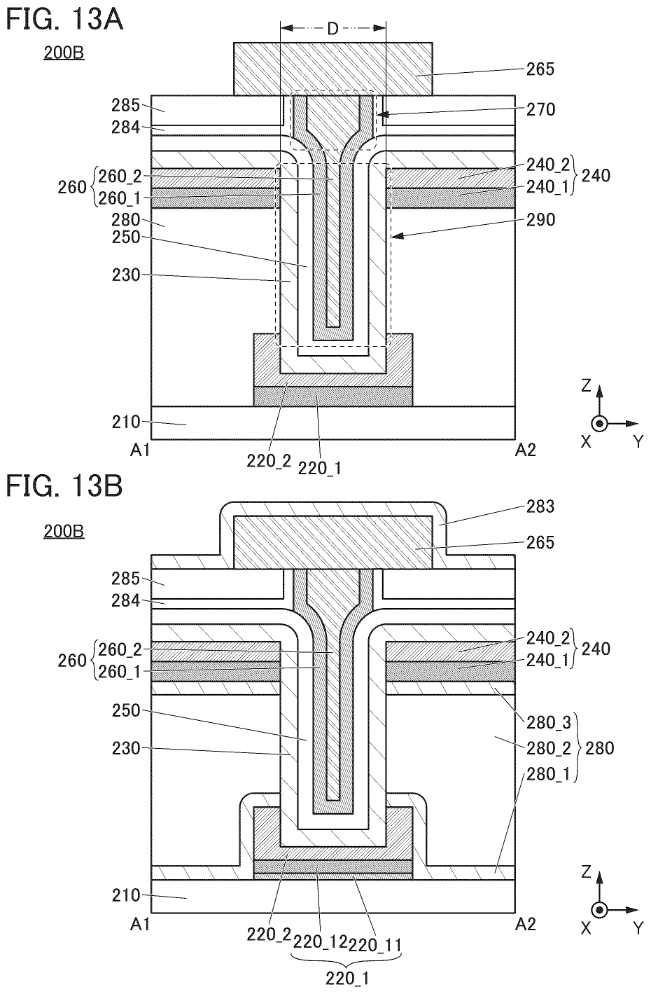

FIG. 12A is a plan view of a semiconductor device including a transistor 200B. FIG. 12B is a cross-sectional view taken along the dashed-dotted line A1-A2 in FIG. 12A. FIG. 12C is a cross-sectional view taken along the dashed-dotted line A3-A4 in FIG. 12A. FIG. 4D can be referred to for a cross-sectional view along the dashed-dotted line A5-A6 in FIG. 12B. FIG. 13A is an enlarged view of FIG. 12B.

The semiconductor device illustrated in FIGS. 12A to 12C includes the insulating layer 210 over a substrate (not illustrated), the transistor 200B over the insulating layer 210, the insulating layer 280 and an insulating layer 284 over the insulating layer 210, an insulating layer 285 over the insulating layer 284, and a conductive layer 265 over the transistor 200B, the insulating layer 284, and the insulating layer 285.

The semiconductor device illustrated in FIGS. 12A to 12C is different from the semiconductor device illustrated in FIGS. 4A to 4D in including the conductive layer 265, the insulating layer 284, and the insulating layer 285.

The conductive layer 265 functions as a gate wiring. For the conductive layer 265, any of the materials that can be used for the conductive layer 260 can be used. For example, a high-melting-point material that has both heat resistance and conductivity, such as tungsten or molybdenum, can be used for the conductive layer 265. Alternatively, a low-resistance conductive material such as aluminum or copper can be used. The use of a low-resistance conductive material can reduce wiring resistance.

The transistor 200B includes the conductive layer 220, the conductive layer 240, the oxide semiconductor layer 230, the insulating layer 250, and the conductive layer 260. Since the stacked-layer structure from the conductive layer 220 to the insulating layer 250 in the transistor 200B is similar to that in the transistor 200A, the details thereof are not described.

As illustrated in FIGS. 12B and 12C, the insulating layer 284 is positioned over the insulating layer 250. The insulating layer 284 is provided with an opening portion 270 reaching the insulating layer 250 at a position overlapping with the opening portion 290.

The conductive layer 260 is provided to fill the opening portion 290 and the opening portion 270. The conductive layer 260 is provided over the insulating layer 250 and is in contact with the insulating layer 250 in the opening portion 270. The conductive layer 260 includes a portion facing the oxide semiconductor layer 230 with the insulating layer 250 therebetween in the opening portion 290 and a portion positioned in the opening portion 270.

FIGS. 12B and 12C illustrate an example in which both the conductive layer 260_1 and the conductive layer 260_2 are provided in the opening portion 290. In the case where the widths of the opening portions 290 and 270 are small, only the conductive layer 260_1 is provided in the opening portion 290 and the conductive layers 260_1 and 260_2 are provided in the opening portion 270 in some cases. Alternatively, only the conductive layer 260_1 is provided in the opening portion 270 in some cases.

A portion of the conductive layer 265 that does not overlap with the opening portion 290 is mainly positioned over the insulating layer 285. Thus, the conductive layer 265 mainly overlaps with the conductive layer 240 with the insulating layers 284 and 285 therebetween. This can increase the physical distance between the conductive layers 265 and 240, and reduce the parasitic capacitance generated therebetween. Note that the conductive layers 240 and 265 may include a portion where they overlap with each other without the insulating layer 285 therebetween.

FIG. 13A illustrates an example in which the width of the opening portion 270 is smaller than the width D of the opening portion 290. The width of the opening portion 270 is preferably as small as possible, in which case the physical distance between the conductive layer 240 and the conductive layer 260 can be increased and thus the parasitic capacitance generated therebetween can be reduced. For example, the width of the opening portion 270 is preferably smaller than or equal to that of the opening portion 290.

The conductive layer 265 is provided over the conductive layer 260 and is in contact with the top surface of the conductive layer 260. It can be said that the conductive layer 260 and the conductive layer 265 are connected to each other. The conductive layer 265 may be regarded as a component of the transistor 200B. The top surface of the conductive layer 260 and the top surface of the insulating layer 285 are level or substantially level with each other.

The transistor 200B has a structure in which the parasitic capacitance generated between the other of the source and drain electrodes and the gate wiring is reduced. Accordingly, the frequency characteristics of a circuit including the transistor can be improved.

Although this embodiment describes the example in which the opening portion 270 has a circular shape in the plan view, the present invention is not limited thereto. Any of the above-described shapes that can be employed for the opening portion 290 can be employed as the shape of the opening portion 270.

The width of the opening portion 270 varies in the depth direction in some cases. Here, the maximum width of the opening portion 270 provided in the insulating layer 284 in the cross-sectional view is specifically used as the width of the opening portion 270.

The insulating layer 284 preferably has a function of capturing or fixing hydrogen. With such a structure, diffusion of hydrogen from above the insulating layer 284 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 284, aluminum oxide, hafnium oxide, hafnium zirconium oxide, hafnium silicate, or the like can be used.

The insulating layer 284 can be a barrier insulating layer against hydrogen. In that case, diffusion of hydrogen from above the insulating layer 284 into the oxide semiconductor layer 230 can be inhibited. Silicon nitride and silicon nitride oxide can be suitably used for the insulating layer 284 because they are less likely to transmit oxygen and hydrogen.

In the case where the insulating layer 284 includes a silicon nitride film, the silicon nitride film is preferably formed by a sputtering method. A film formation gas in a sputtering method need not include molecules containing hydrogen; thus, the hydrogen concentration in the insulating layer 284 can be reduced. When the insulating layer 284 is formed by a sputtering method, a high-density silicon nitride film can be obtained.

The insulating layer 284 may have a stacked-layer structure of an insulating layer having a function of capturing or fixing hydrogen and a barrier insulating layer against hydrogen. For example, the insulating layer 284 may include a stack of an aluminum oxide film and a silicon nitride film over the aluminum oxide film.

The insulating layer 285 functions as an interlayer film and thus is preferably formed using any of the above-described materials with a low dielectric constant. For example, the insulating layer 285 preferably includes a silicon oxide film.

Note that the transistor 200B can have a structure similar to that of the transistor 200A. FIG. 13B illustrates an example in which the structure illustrated in FIG. 9A is employed for the semiconductor device illustrated in FIG. 13A. In FIG. 13B, the insulating layer 283 is provided over the insulating layer 285 and the conductive layer 265.

### [Transistor 200C]

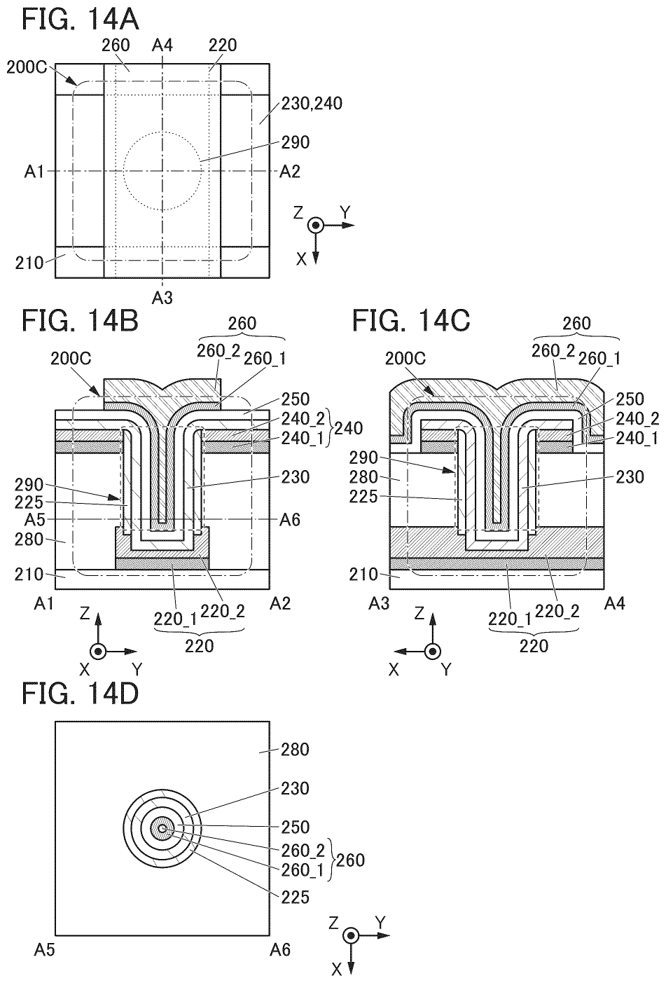

FIG. 14A is a plan view of a semiconductor device including a transistor 200C. FIG. 14B is a cross-sectional view taken along the dashed-dotted line A1-A2 in FIG. 14A. FIG. 14C is a cross-sectional view taken along the dashed-dotted line A3-A4 in FIG. 14A. FIG. 14D is a cross-sectional view taken along the dashed-dotted line A5-A6 in FIG. 14B.

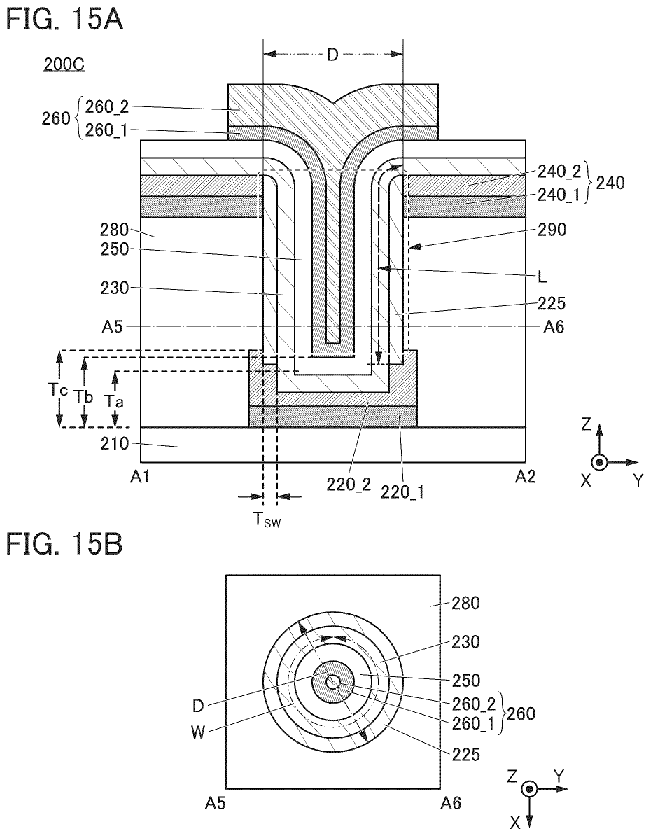

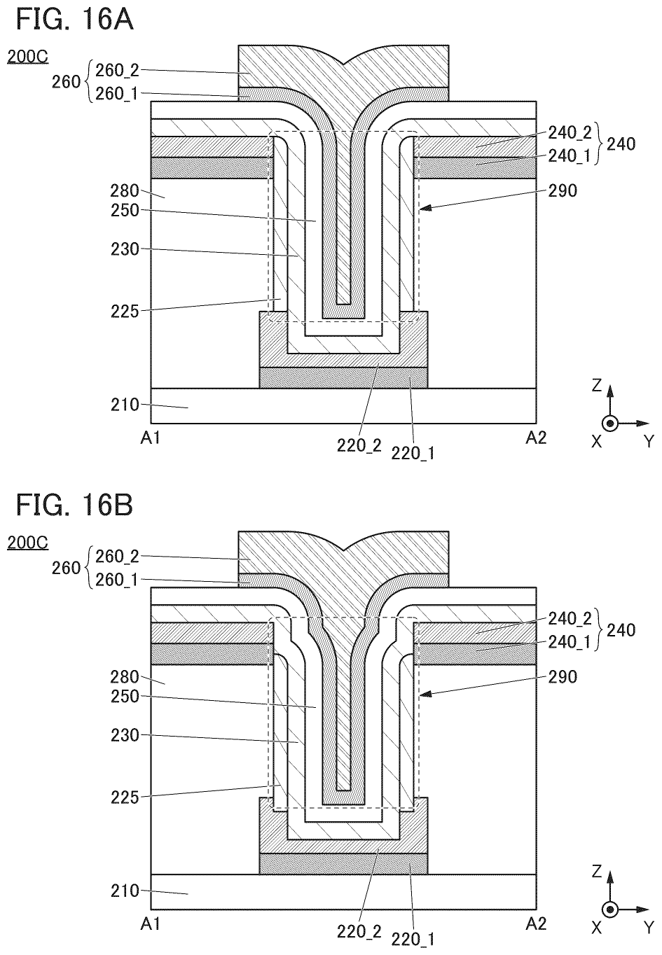

FIG. 15A is an enlarged view of FIG. 14B, and FIG. 15B is an enlarged view of FIG. 14D. FIGS. 16A and 16B are each a cross-sectional view taken along the dashed-dotted line A1-A2 in FIG. 14A. FIGS. 16A and 16B each correspond to an example of the enlarged view of FIG. 14B, and illustrate structure examples of the layers more specifically.

The semiconductor device illustrated in FIGS. 14A to 14D includes the insulating layer 210 over a substrate (not illustrated), the transistor 200C over the insulating layer 210, and the insulating layer 280 over the insulating layer 210.

The transistor 200C includes the conductive layer 220, the conductive layer 240, an insulating layer 225, the oxide semiconductor layer 230, the insulating layer 250, and the conductive layer 260.

The transistor 200C illustrated in FIGS. 14A to 14D is different from the transistor 200A illustrated in FIGS. 4A to 4D in including the insulating layer 225.

The oxide semiconductor layer 230, the insulating layer 225, the insulating layer 250, and the conductive layer 260 included in the transistor 200C respectively correspond to the oxide semiconductor layer 30, the insulating layer 20, the insulating layer 50, and the conductive layer 60 described in Embodiment 1. Thus, for the structures, materials, and the like of the oxide semiconductor layer 230, the insulating layer 225, the insulating layer 250, and the conductive layer 260, the structures, materials, and the like of the oxide semiconductor layer 30, the insulating layer 20, the insulating layer 50, and the conductive layer 60 described in Embodiment 1 can be referred to.

As illustrated in FIG. 14D, the transistor 200C has a structure in which the insulating layer 225 is provided between the insulating layer 280 and the oxide semiconductor layer 230 in the plan view.

The insulating layer 225 is provided in the opening portion 290, and thus is preferably formed by a CVD method or an ALD method, further preferably formed by an ALD method. In such a case, the insulating layer 225 can be provided with good coverage.

As illustrated in FIG. 14B and the like, the conductive layer 220_2 has a first depression and a second depression positioned outward from the first depression. The depth of the first depression is greater than that of the second depression. In other words, the bottom surface of the first depression is positioned below the bottom surface of the second depression (on the insulating layer 210 side). The second depression is provided in the conductive layer 220_2 at the time of forming the opening portion 290, and then the first depression is provided in the conductive layer 220_2 at the time of processing the insulating layer 225. Thus, in FIG. 14B and the like, the side end portion of the second depression is aligned or substantially aligned with the side end portion of the insulating layer 280 in the opening portion 290, and the side end portion of the first depression is aligned or substantially aligned with the end portion of the insulating layer 225 on the oxide semiconductor layer 230 side. Hereinafter, the first depression and the second depression are collectively referred to as a depression in some cases.

In FIG. 14B and the like, the insulating layer 225 is in contact with the bottom and side surfaces of the second depression of the conductive layer 220, and is in contact with the side surfaces of the insulating layer 280 and the conductive layer 240 in the opening portion 290. The oxide semiconductor layer 230 is in contact with the bottom and side surfaces of the first depression of the conductive layer 220, the insulating layer 225, and the top surface of the conductive layer 240_2. The insulating layer 250 is positioned inward from the oxide semiconductor layer 230 in the opening portion 290, and the conductive layer 260 is positioned inward from the insulating layer 250 in the opening portion 290.

As illustrated in FIG. 15A, the shortest distance Tc from the top surface of the insulating layer 210 to the top surface of the conductive layer 220_2 which is in contact with the insulating layer 280 is preferably longer than the shortest distance Ta from the top surface of the insulating layer 210 to the bottom surface of the insulating layer 250. Accordingly, the contact area between the side surface of the conductive layer 220_2 and the oxide semiconductor layer 230 can be increased, so that the contact resistance between the conductive layer 220_2 and the oxide semiconductor layer 230 can be reduced. This can inhibit a decrease in on-state current of the transistor 200C due to the contact resistance between the conductive layer 220_2 and the oxide semiconductor layer 230. Note that the shortest distance Ta can be determined on the basis of the bottom surface of the insulating layer 250 in the opening portion 290.

As illustrated in FIG. 15A, the shortest distance Tc is preferably longer than or equal to the shortest distance Tb from the top surface of the insulating layer 210 to the bottom surface of the conductive layer 260, further preferably longer than the shortest distance Tb. Accordingly, a gate electric field is easily applied to the channel formation region in the oxide semiconductor layer 230, so that the electrical characteristics of the transistor 200C can be improved. Furthermore, a gate electric field is easily applied to a region of the oxide semiconductor layer 230 that is in contact with the conductive layer 220_2, so that the on-state current of the transistor 200C can be increased. The electrical characteristics of the transistor 200C can be improved when either the conductive layer 220 or the conductive layer 240 is used as the drain electrode. Note that the shortest distance Tb can be determined on the basis of the bottom surface of the conductive layer 260 in the opening portion 290.

Here, the width (thickness) of the insulating layer 225 is referred to as a width T_{SW} as illustrated in FIG. 15A. The width T_{SW} is preferably small. The small width T_{SW} can inhibit a reduction in the channel width of the transistor 200C, thereby inhibiting a reduction in the on-state current of the transistor 200C. By contrast, the large width T_{SW} can enhance the function of the insulating layer 225. Accordingly, the width T_{SW} is preferably larger than or equal to 1 nm and smaller than or equal to 20 nm, further preferably larger than or equal to 2 nm and smaller than or equal to 15 nm, still further preferably larger than or equal to 3 nm and smaller than or equal to 10 nm, for example.

FIG. 15B illustrates the channel width W of the transistor 200C. In the case where the opening portion 290 is circular in the plan view, the width D of the opening portion 290 corresponds to the diameter of the opening portion 290, and the channel width W can be calculated to be “(D−2×T_{SW})×π”.

The channel length of the transistor 200C can be regarded as a distance between a source region and a drain region. That is, the channel length of the transistor 200C is determined by the height of the insulating layer 225. The channel length of the transistor 200C is determined also by the depth of the depression (specifically, the second depression) of the conductive layer 220, the thickness of the insulating layer 280 over the conductive layer 220, and the thickness of the conductive layer 240. In the case where the channel length of the transistor 200C is regarded as the distance between the source region and the drain region, the channel length of the transistor 200C can be a length L illustrated in FIG. 15A.

In the example illustrated in FIG. 15A, the conductive layer 220_2 has the first depression and the second depression; however, the present invention is not limited thereto. For example, as illustrated in FIG. 16A, the transistor 200C may have a structure in which only the first depression is provided in the conductive layer 220_2.

In the conductive layer 220_2, the depression can be formed in one or both of a step of forming the opening portion 290 and a step of forming the insulating layer 225. In the example of the transistor 200C illustrated in FIG. 15A, the depression is formed in the conductive layer 220_2 in both of the steps, whereas in the example of the transistor 200C illustrated in FIG. 16A, the depression is formed in the conductive layer 220_2 not in the step of forming the opening portion 290 but in the step of forming the insulating layer 225.

In the transistor 200C illustrated in FIG. 16A, the insulating layer 225 is in contact with the side surface of the insulating layer 280, the side surface of the conductive layer 240, and the top surface of the conductive layer 220_2 in the opening portion 290. The oxide semiconductor layer 230 is in contact with the bottom and side surfaces of the depression of the conductive layer 220_2.

When the depression is formed in the conductive layer 220_2 in at least one of the step of forming the opening portion 290 and the step of forming the insulating layer 225, the level of the bottom surface of the conductive layer 260 in the opening portion 290 can be made low; accordingly, a gate electric field can be easily applied to the channel formation region in the oxide semiconductor layer 230 and the electrical characteristics of the transistor 200C can be improved.

The depression is preferably formed in the conductive layer 220_2 in the step of forming the insulating layer 225, in which case the oxide semiconductor layer 230 can be in contact with the bottom and side surfaces of the depression of the conductive layer 220_2, so that the contact area between the oxide semiconductor layer 230 and the conductive layer 220_2 can be increased and accordingly the contact resistance between the oxide semiconductor layer 230 and the conductive layer 220 can be reduced.

As illustrated in FIG. 16B, for example, the transistor 200C may have a structure in which the insulating layer 225 does not cover the side surface of the conductive layer 240_2.

The insulating layer 225 illustrated in FIG. 16B is in contact with the bottom and side surfaces of the depression of the conductive layer 220, and is in contact with the side surface of the insulating layer 280 in the opening portion 290. The insulating layer 225 is in contact with part of the side surface of the conductive layer 240_1 and not in contact with the side surface of the conductive layer 240_2. The insulating layer 225 may be in contact with one or more of the side surfaces of the insulating layer 280, the conductive layer 240_1, and the conductive layer 240_2 in the opening portion 290, or may cover part or the whole of each side surface.

In the case where at least part of the side surface of the conductive layer 240_2 is not covered with the insulating layer 225, the uncovered part is in contact with the oxide semiconductor layer 230. Thus, the contact area between the oxide semiconductor layer 230 and the conductive layer 240 can be increased and the contact resistance therebetween can be reduced. Similarly, in the case where the insulating layer 225 does not cover the side surface of the conductive layer 240_2 and at least part of the side surface of the conductive layer 240_1, the uncovered parts are in contact with the oxide semiconductor layer 230. Hence, the contact area between the oxide semiconductor layer 230 and the conductive layer 240 can be increased and the contact resistance therebetween can be reduced.

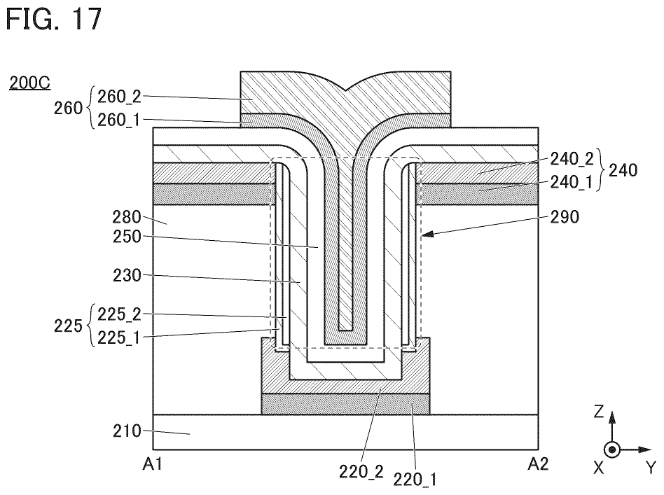

In the example illustrated in FIG. 15A, the insulating layer 225 has a single-layer structure. Note that the insulating layer 225 can have a stacked-layer structure of two or more layers. For example, as illustrated in FIG. 17, the insulating layer 225 can have a two-layer structure of an insulating layer 225_1 and an insulating layer 225_2.

FIG. 17 illustrates an example in which the insulating layer 225 includes two layers of the insulating layer 225_1 and the insulating layer 225_2; the insulating layer 225_1 is in contact with the insulating layer 280; and the insulating layer 225_2 is positioned between the insulating layer 225_1 and the oxide semiconductor layer 230. The insulating layer 225 illustrated in FIG. 17 has a two-layer structure of the insulating layer 225_1 and the insulating layer 225_2 over the insulating layer 225_1.

A barrier insulating layer against hydrogen can be used as the insulating layer 225_1 provided in contact with the side surface of the insulating layer 280 in the opening portion 290, and an insulating layer including a region containing excess oxygen can be used as the insulating layer 225_2 provided in contact with the oxide semiconductor layer 230. Such a structure can reduce one or both of oxygen vacancies and hydrogen in the oxide semiconductor layer 230. Thus, the electrical characteristics and reliability of the transistor can be improved. For example, it is preferable that silicon nitride be used for the insulating layer 225_1 and silicon oxide or silicon oxynitride be used for the insulating layer 225_2. The thicknesses of the insulating layers 225_1 and 225_2 are each 2 nm.

As described above, the barrier insulating layer against hydrogen encloses the periphery of the oxide semiconductor layer 230 in a ring shape, and the insulating layer including a region containing excess oxygen is provided in the vicinity of the oxide semiconductor layer 230, in which case one or both of oxygen vacancies and impurities in the oxide semiconductor layer 230 can be reduced. Accordingly, the electrical characteristics and reliability of the transistor can be improved.

Note that the insulating layer 225_1 can be formed using any of insulating materials described later in [Insulating layer], and the insulating layer 225_2 can be formed using any of the materials that can be used for the insulating layer 20 described in Embodiment 1.

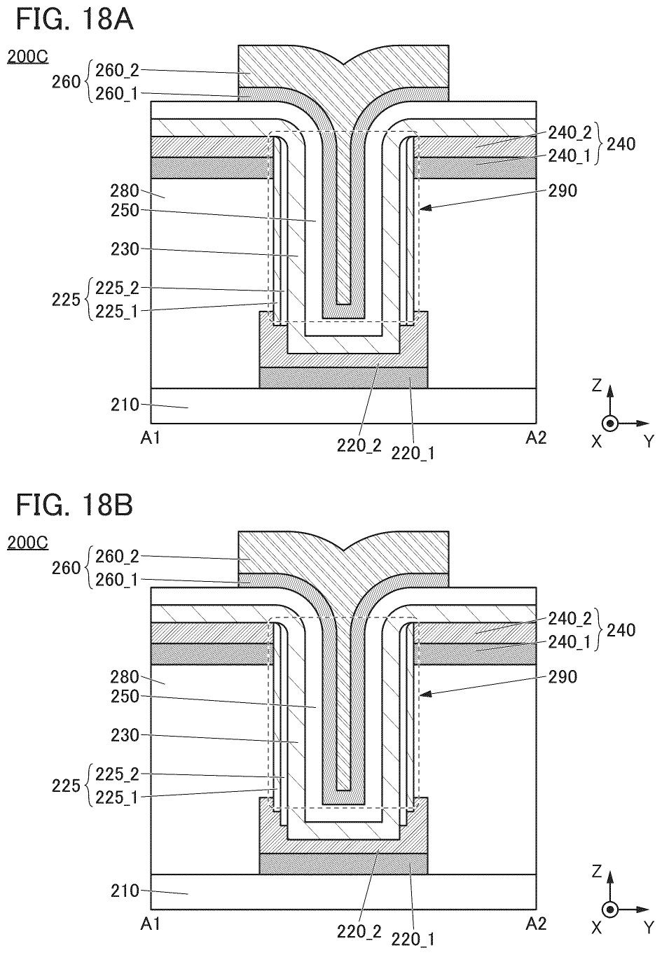

Here, another structure example of the insulating layer 225 illustrated in FIG. 17 is illustrated in FIGS. 18A and 18B.

In the transistor 200C illustrated in FIG. 18A, the insulating layer 225_1 is provided in contact with the side surface and part of the bottom surface of the depression of the conductive layer 220_2, and the insulating layer 225_2 is positioned inward from the insulating layer 225_1 in the opening portion 290 and is provided in contact with another part of the bottom portion of the depression of the conductive layer 220_2, for example.

In the transistor 200C illustrated in FIG. 18B, the conductive layer 220_2 has the first depression, the second depression positioned outward from the first depression, and a third depression positioned outward from the second depression. The depth of the first depression is greater than that of the second depression, and the depth of the second depression is greater than that of the third depression. The third depression is provided in the conductive layer 220_2 at the time of forming the opening portion 290, the second depression is provided in the conductive layer 220_2 at the time of processing the insulating layer 225_1, and then the first depression is provided in the conductive layer 220_2 at the time of processing the insulating layer 225_2. Thus, in FIG. 18B, the side end portion of the third depression is aligned or substantially aligned with the side end portion of the insulating layer 280 in the opening portion 290, the side end portion of the second depression is aligned or substantially aligned with the end portion of the insulating layer 225_1 on the insulating layer 225_2 side, and the side end portion of the first depression is aligned or substantially aligned with the end portion of the insulating layer 225_2 on the oxide semiconductor layer 230 side.

In the transistor 200C illustrated in FIG. 18B, the insulating layer 225_1 is provided in contact with the bottom and side surfaces of the third depression of the conductive layer 220_2, and the insulating layer 225_2 is provided in contact with the bottom and side surfaces of the second depression of the conductive layer 220_2.

For example, the insulating layer 225_1 is provided on the sidewall of the opening portion 290 and then an insulating film to be the insulating layer 225_2 is formed and processed, so that the insulating layer 225 having the structure illustrated in FIG. 18A or 18B can be formed. The contact area between the insulating layer 225_1 and the oxide semiconductor layer 230 can be smaller than that in the transistor 200C illustrated in FIG. 17, and thus the insulating layer 225_2 can be in contact with the oxide semiconductor layer 230.

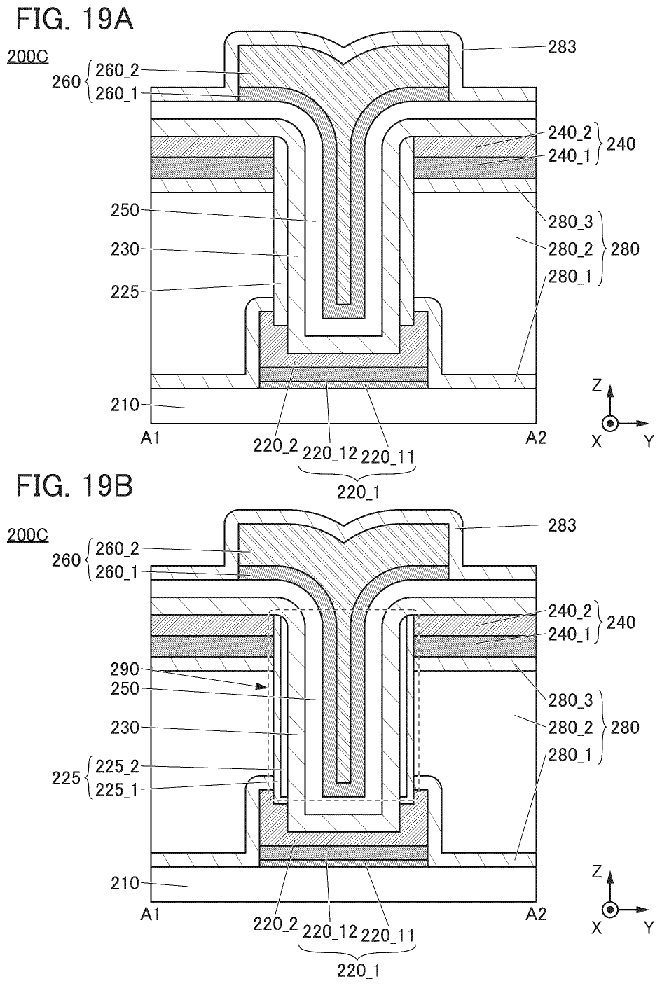

Note that the transistor 200C can have a structure similar to that of at least one of the transistor 200A and the transistor 200B. FIG. 19A illustrates an example in which the structure illustrated in FIG. 9A is employed for the semiconductor device illustrated in FIG. 15A. FIG. 19B illustrates an example in which the structure illustrated in FIG. 9A is employed for the semiconductor device illustrated in FIG. 17.

### [Transistor 200D]

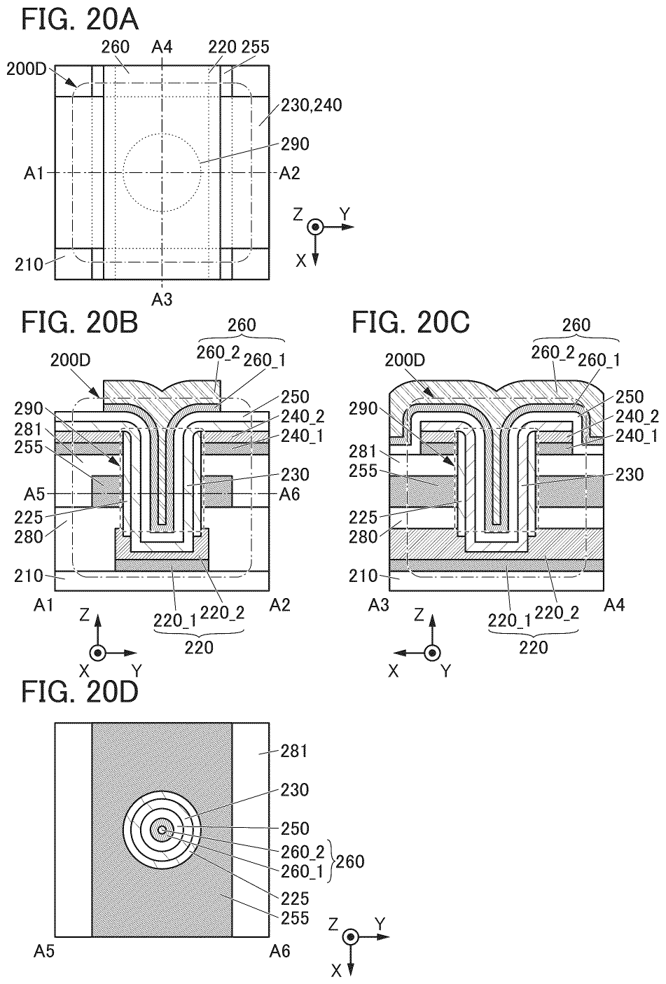

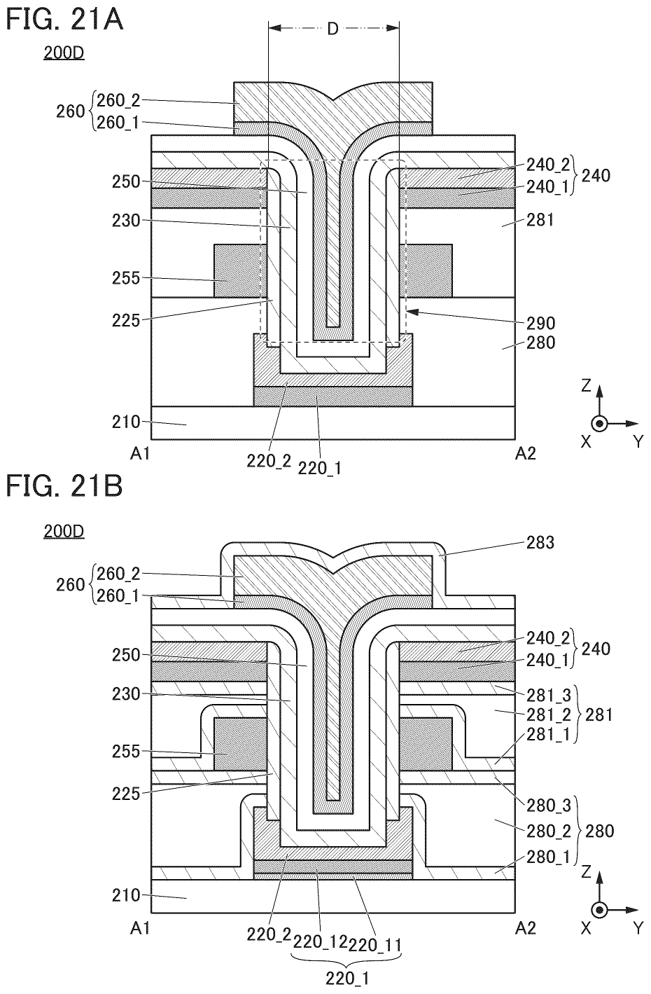

FIG. 20A is a plan view of a semiconductor device including a transistor 200D. FIG. 20B is a cross-sectional view taken along the dashed-dotted line A1-A2 in FIG. 20A. FIG. 20C is a cross-sectional view taken along the dashed-dotted line A3-A4 in FIG. 20A. FIG. 20D is a cross-sectional view taken along the dashed-dotted line A5-A6 in FIG. 20B. FIG. 21A is an enlarged view of FIG. 20B.

The semiconductor device illustrated in FIGS. 20A to 20D includes the insulating layer 210 over a substrate (not illustrated), the transistor 200D over the insulating layer 210, the insulating layer 280 over the insulating layer 210, and an insulating layer 281 over the insulating layer 280.

The transistor 200D includes the conductive layer 220, a conductive layer 255, the conductive layer 240, the insulating layer 225, the oxide semiconductor layer 230, the insulating layer 250, and the conductive layer 260.

The semiconductor device illustrated in FIGS. 20A to 20D is different from the semiconductor device illustrated in FIGS. 4A to 4D mainly in including the insulating layer 225, the conductive layer 255, and the insulating layer 281. The transistor 200D illustrated in FIGS. 20A to 20D is different from the transistor 200C illustrated in FIGS. 14A to 14D mainly in including the conductive layer 255 and the insulating layer 281.

The conductive layer 255 is positioned over the insulating layer 280, and the insulating layer 281 is positioned over the conductive layer 255 and the insulating layer 280. The conductive layer 240_1 is positioned over the insulating layer 281.

As illustrated in FIG. 21A, the opening portion 290 reaching the conductive layer 220 is provided in the insulating layer 280, the conductive layer 255, the insulating layer 281, and the conductive layer 240.

In the transistor 200D, the oxide semiconductor layer 230 functions as a semiconductor layer, the conductive layer 260 functions as a first gate electrode, the insulating layer 250 functions as a first gate insulating layer, the conductive layer 220 functions as one of a source electrode and a drain electrode, the conductive layer 240 functions as the other of the source electrode and the drain electrode, the conductive layer 255 functions as a second gate electrode, and the insulating layer 225 functions as a second gate insulating layer.

The oxide semiconductor layer 230, the insulating layer 225, the insulating layer 250, and the conductive layer 260 included in the transistor 200D respectively correspond to the oxide semiconductor layer 30, the insulating layer 20, the insulating layer 50, and the conductive layer 60 described in Embodiment 1. Thus, for the structures, materials, and the like of the oxide semiconductor layer 230, the insulating layer 225, the insulating layer 250, and the conductive layer 260, the structures, materials, and the like of the oxide semiconductor layer 30, the insulating layer 20, the insulating layer 50, and the conductive layer 60 described in Embodiment 1 can be referred to.

Alternatively, the oxide semiconductor layer 230, the insulating layer 250, the insulating layer 225, and the conductive layer 255 included in the transistor 200D may respectively correspond to the oxide semiconductor layer 30, the insulating layer 20, the insulating layer 50, and the conductive layer 60 described in Embodiment 1. In that case, for the structures, materials, and the like of the oxide semiconductor layer 230, the insulating layer 250, the insulating layer 225, and the conductive layer 255, the structures, materials, and the like of the oxide semiconductor layer 30, the insulating layer 20, the insulating layer 50, and the conductive layer 60 described in Embodiment 1 can be referred to.

The oxide semiconductor layer 230 includes a region overlapping with the conductive layer 255 with the insulating layer 225 therebetween and overlapping with the conductive layer 260 with the insulating layer 250 therebetween. At least part of the region functions as the channel formation region of the transistor 200D.

Since the transistor 200D includes the conductive layer functioning as the back gate electrode, the threshold voltage of the transistor 200D can be controlled by a potential supplied to the conductive layer. Thus, by controlling the threshold voltage, a normally-off transistor is easily achieved.

In the transistor 200D, one of the conductive layers 255 and 260 can be used as a gate electrode and the other can be used as a back gate electrode. In the transistor 200D, it is particularly suitable to use the conductive layer 260 as the gate electrode and to use the conductive layer 255 as the back gate electrode in some cases. When the conductive layer 260 whose region facing the oxide semiconductor layer 230 is larger than that of the conductive layer 255 is used as the gate electrode, a gate electric field is applied to the oxide semiconductor layer 230 more efficiently; thus, the electrical characteristics of the transistor can be improved in some cases. In the case where the conductive layer 260 functions as the gate electrode and the conductive layer 255 functions as the back gate electrode, the insulating layer 250 functions as a gate insulating layer and the insulating layer 225 functions as a back gate insulating layer.

For the conductive layer 255, any of the conductive materials that can be used for the conductive layer 260 can be used.

The insulating layer 281 functions as an interlayer film. The insulating layer 281 can be formed using any of the insulating materials that can be used for the insulating layer 280.

Note that the transistor 200D can have a structure similar to that of at least one of the transistors 200A to 200C. FIG. 21B illustrates an example in which the structure illustrated in FIG. 9A is employed for the semiconductor device illustrated in FIG. 21A.

In the example illustrated in FIG. 21A, the insulating layer 281 has a single-layer structure. Note that the insulating layer 281 can have a stacked-layer structure of two or more layers. For example, as illustrated in FIG. 21B, the insulating layer 281 can have a three-layer structure of an insulating layer 281_1, an insulating layer 281_2 over the insulating layer 281_1, and an insulating layer 281_3 over the insulating layer 281_2. In that case, it is preferable that any of the above-described materials with a low dielectric constant be used for the insulating layer 281_2 and a barrier insulating layer against oxygen be used as each of the insulating layers 281_1 and 281_3. Thus, the conductive layers 255 and 240 can be inhibited from being oxidized and having an increased resistance.

In the illustrated examples, at least some of the components of the transistors 200A to 200D are provided in the opening portion 290 that is circular in the plan view; however, the present invention is not limited thereto. At least some of the components of the transistors can be provided in a groove portion that is formed to extend.

In this specification and the like, a groove can be rephrased as a slit or a trench. A groove portion can be rephrased as a slit portion or a trench portion. A groove portion may be rephrased as a slit or a trench.

### [Transistor 200E]

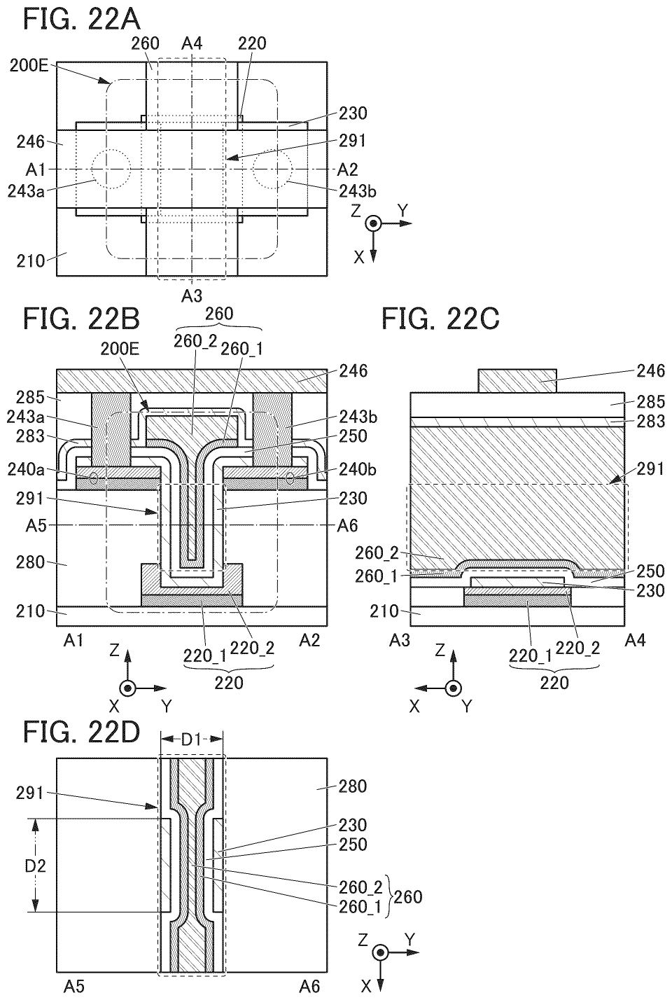

FIG. 22A is a plan view of a semiconductor device including a transistor 200E. FIG. 22B is a cross-sectional view taken along the dashed-dotted line A1-A2 in FIG. 22A. FIG. 22C is a cross-sectional view taken along the dashed-dotted line A3-A4 in FIG. 22A. FIG. 22D is a cross-sectional view taken along the dashed-dotted line A5-A6 in FIG. 22B.

The semiconductor device illustrated in FIGS. 22A to 22D includes the insulating layer 210 over a substrate (not illustrated), the transistor 200E over the insulating layer 210, and the insulating layer 280 over the insulating layer 210. The semiconductor device also includes a conductive layer 243a, a conductive layer 243b, and a conductive layer 246. The semiconductor device also includes the insulating layer 283 over the transistor 200E like the semiconductor device illustrated in FIG. 9A. The semiconductor device also includes the insulating layer 285 like the semiconductor device illustrated in FIGS. 12A to 12C. The insulating layer 285 is provided over the insulating layer 283.

The transistor 200E includes the conductive layer 220, a conductive layer 240a and a conductive layer 240b over the insulating layer 280, the oxide semiconductor layer 230, the insulating layer 250, and the conductive layer 260.

In the transistor 200E, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layers 240a and 240b function as the other of the source electrode and the drain electrode.

As illustrated in FIGS. 22A to 22D, a groove portion 291 reaching the conductive layer 220 is provided in the insulating layer 280. The groove portion 291 extends in the X direction. The groove portion 291 of the insulating layer 280 corresponds to the groove portion 91 described in Embodiment 1.

The transistor 200E illustrated in FIGS. 22A to 22D is different from the transistor 200A illustrated in FIGS. 4A to 4D in that some of the components of the transistor are provided in the groove portion 291 instead of the opening portion 290. The transistor 200E is different from the transistor 200A illustrated in FIGS. 4A to 4D also in that the conductive layer 240 is divided into the conductive layer 240a and the conductive layer 240b by the groove portion 291.

The oxide semiconductor layer 230, the insulating layer 250, and the conductive layer 260 are placed in the groove portion 291 at least partly.

The oxide semiconductor layer 230 is provided to have an island shape. The oxide semiconductor layer 230 is provided along part of the bottom portion and part of the sidewall of the groove portion 291. The oxide semiconductor layer 230 includes a portion in contact with the top surface of the conductive layer 240, a portion in contact with the side surface of the conductive layer 240 on the groove portion 291 side, and a portion in contact with the bottom and side surfaces of the depression of the conductive layer 220 in the groove portion 291.

The insulating layer 250 is provided to cover the oxide semiconductor layer 230. The insulating layer 250 is provided over the insulating layer 280 to cover the top and side surfaces of the oxide semiconductor layer 230 and the side surface of the conductive layer 240.

The conductive layer 260 is provided to fill at least part of the groove portion 291. Thus, the conductive layer 260 is provided to extend in the extending direction of the groove portion 291. Also in the transistor 200E, a channel is formed along the sidewall of the groove portion 291.

An opening reaching the conductive layer 240a is provided in the insulating layer 285, the insulating layer 283, the insulating layer 250, and the oxide semiconductor layer 230, and the conductive layer 243a is provided in the opening. An opening reaching the conductive layer 240b is provided in the insulating layer 285, the insulating layer 283, the insulating layer 250, and the oxide semiconductor layer 230, and the conductive layer 243b is provided in the opening. The conductive layer 243a is in contact with the conductive layer 240a, and the conductive layer 243b is in contact with the conductive layer 240b.

The conductive layer 246 is provided over the insulating layer 285. The conductive layer 246 is connected to the conductive layer 240a and the conductive layer 240b respectively through the conductive layer 243a and the conductive layer 243b. The conductive layer 246 functions as a wiring. The conductive layer 246 extends in the Y direction. That is, the extending direction of the conductive layer 246 intersects with the extending direction of the groove portion 291.

In each of the transistors 200A to 200D, the width of the conductive layer 240 in the X direction (the width of the short side of the conductive layer 240) needs to be larger than the width D of the opening portion 290 in order that the conductive layer 240 can be provided to extend. Meanwhile, in the transistor 200E, the conductive layers 240a and 240b functioning as the other of the source electrode and the drain electrode are connected to each other through the conductive layer 246; thus, the widths of the conductive layers 240a and 240b in the X direction can be small; for example, the widths can each be smaller than a width D1 of the groove portion 291 (see FIG. 22D). Accordingly, the semiconductor device can be scaled down.

In the plan view, the side surface of the conductive layer 260 provided in the groove portion 291 has a portion facing the side surface of the oxide semiconductor layer 230 with the insulating layer 250 therebetween. Thus, the channel width of the transistor 200E is determined by a width D2 of the oxide semiconductor layer 230 (see FIG. 22D). The channel width of the transistor 200E can be calculated to be “2×D2”.

In each of the transistors 200A to 200D, the oxide semiconductor layer 230 in the opening portion 290 does not need to be processed, which facilitates the processing of the oxide semiconductor layer 230 and can improve the productivity of the semiconductor device.

In the plan view of the transistor 200E, a portion of the oxide semiconductor layer 230 that is positioned in the groove portion 291 does not have a curved surface. Thus, distortion is unlikely to be generated in a region of the oxide semiconductor layer 230 that is in the vicinity of the insulating layer 250, so that a decrease in the crystallinity of the region can be inhibited. Note that the region includes a channel formation region.

In the plan view of each of the transistors 200A to 200D, a portion of the oxide semiconductor layer 230 that is positioned in the opening portion 290 has a curved surface. However, the curvature of the curved surface can be reduced (the radius of curvature of the curved surface can be increased) by increasing the width of the opening portion 290 or reducing the thickness of the oxide semiconductor layer 230, for example. Thus, generation of the distortion in the region of the oxide semiconductor layer 230 that is in the vicinity of the insulating layer 250 can be inhibited, so that a decrease in the crystallinity of the region can be inhibited.

The transistor 200E illustrated in FIGS. 22A to 22D has a structure in which the level of the top surface of the conductive layer 260 is higher than that of the top surface of the insulating layer 250. Note that the present invention is not limited thereto. The level of the top surface of the conductive layer 260 may be equal to, substantially equal to, or lower than that of the top surface of the insulating layer 250.

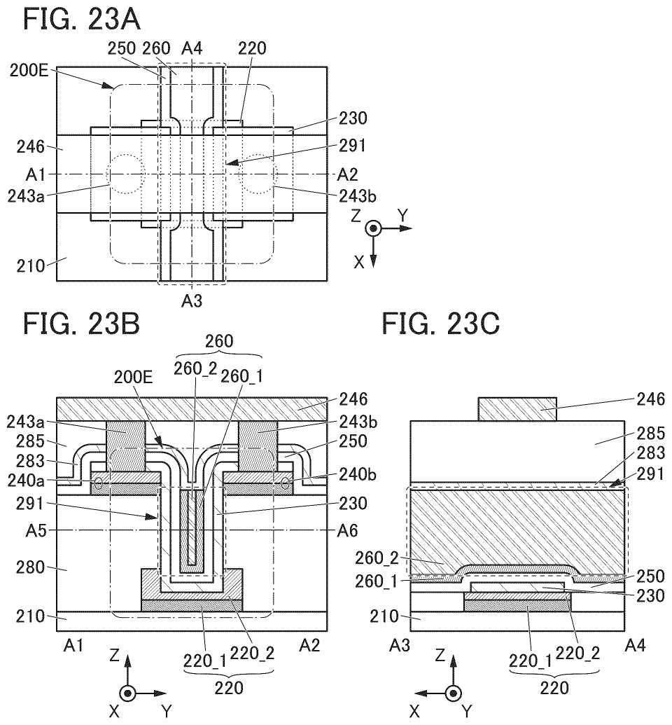

FIGS. 23A to 23C illustrate a modification example of the transistor 200E described with reference to FIGS. 22A to 22D. FIG. 23A is a plan view of the semiconductor device including the transistor 200E. FIG. 23B is a cross-sectional view taken along the dashed-dotted line A1-A2 in FIG. 23A. FIG. 23C is a cross-sectional view taken along the dashed-dotted line A3-A4 in FIG. 23A. Note that FIG. 22D can be referred to for a cross-sectional view taken along the dashed-dotted line A5-A6 in FIG. 23B.

The transistor 200E illustrated in FIGS. 23A to 23C is different from the transistor 200E illustrated in FIGS. 22A to 22D in that the level of the top surface of the conductive layer 260 is lower than that of the top surface of the insulating layer 250.

The structure in which the level of the top surface of the conductive layer 260 is lower than that of the top surface of the insulating layer 250 can reduce the area where the conductive layer 260 faces the conductive layer 240a or the conductive layer 240b, thereby reducing the parasitic capacitance generated between the conductive layer 260 and the conductive layer 240a or the conductive layer 240b. The above structure can increase the physical distance between the conductive layer 260 and the conductive layer 246, and can reduce the parasitic capacitance generated therebetween. Accordingly, the frequency characteristics of a circuit including the transistor can be improved.

In the transistor 200E illustrated in FIGS. 22A to 22D, the cross-sectional area of the conductive layer 260 functioning as a gate wiring can be increased and the wiring resistance can be reduced. Thus, the power consumption of the semiconductor device can be reduced.

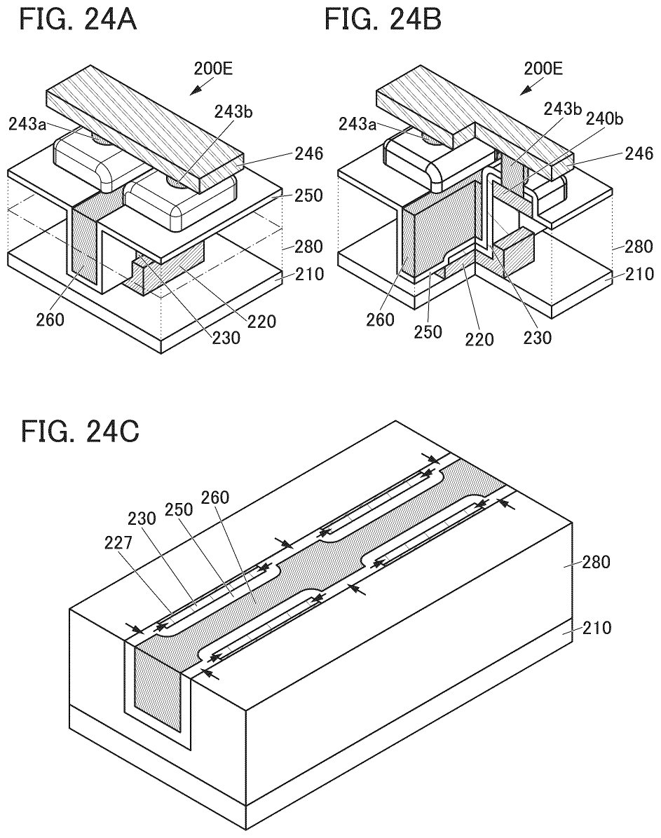

FIGS. 24A and 24B are schematic perspective views of the semiconductor device including the transistor 200E illustrated in FIGS. 23A to 23C. FIG. 24B is the perspective view obtained by cutting part of FIG. 24A. In FIGS. 24A and 24B, some components (e.g., interlayer insulating layers) are illustrated only by their outlines with dashed lines.

FIG. 24C is a perspective view taken along a plane indicated by a dashed-dotted line in FIG. 24A. In FIG. 24C, the oxide layer 227 is provided between the oxide semiconductor layer 230 and the insulating layer 280. Arrows in FIG. 24C indicate oxygen diffusion paths.

Even in the case where the oxide layer 227 has a function of inhibiting diffusion of oxygen, oxygen can be supplied from the insulating layer 280 to the oxide semiconductor layer 230 through the insulating layer 250 by heat treatment to reduce oxygen vacancies in the oxide semiconductor layer 230, as illustrated in FIG. 24C. With the use of an indium oxide film having a high oxygen-transmitting property for the oxide semiconductor layer 230, an excessive amount of oxygen in the oxide semiconductor layer 230 can be released to the insulating layer 250, so that the excessive amount of oxygen in the oxide semiconductor layer 230 can be reduced. Thus, the electrical characteristics and reliability of the transistor 200E can be improved.

In the case where the oxide layer 227 has a function of transmitting oxygen, oxygen can be supplied from the insulating layer 280 to the oxide semiconductor layer 230 through the oxide layer 227 or the insulating layer 250 by heat treatment to reduce oxygen vacancies in the oxide semiconductor layer 230. With the use of an indium oxide film having a high oxygen-transmitting property for the oxide semiconductor layer 230, an excessive amount of oxygen in the oxide semiconductor layer 230 can be released to the insulating layer 250, so that the excessive amount of oxygen in the oxide semiconductor layer 230 can be reduced. Thus, the electrical characteristics and reliability of the transistor 200E can be improved.

In the example illustrated in FIGS. 22A to 22D, the extending direction of the groove portion 291 is the same as the extending direction of the conductive layer 260 functioning as the gate wiring; however, the present invention is not limited thereto. For example, the extending direction of the groove portion 291 may intersect with the extending direction of the gate wiring.

### [Transistor 200F]

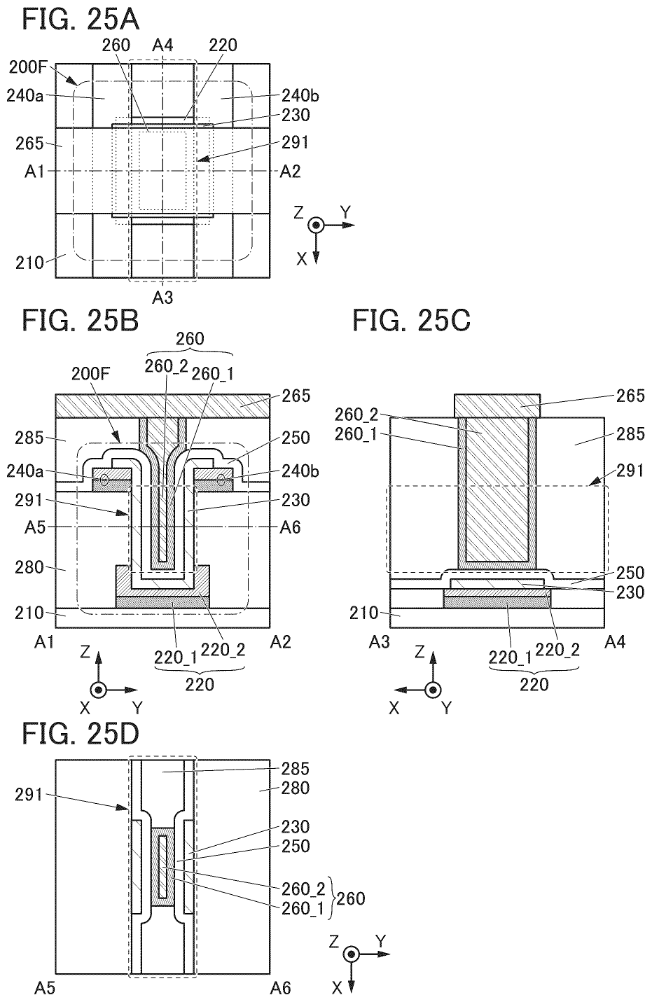

FIG. 25A is a plan view of a semiconductor device including a transistor 200F. FIG. 25B is a cross-sectional view taken along the dashed-dotted line A1-A2 in FIG. 25A. FIG. 25C is a cross-sectional view taken along the dashed-dotted line A3-A4 in FIG. 25A. FIG. 25D is a cross-sectional view taken along the dashed-dotted line A5-A6 in FIG. 25B.

The semiconductor device illustrated in FIGS. 25A to 25D includes the insulating layer 210 over a substrate (not illustrated), the transistor 200F over the insulating layer 210, and the insulating layer 280 over the insulating layer 210. The semiconductor device also includes the insulating layer 285 and the conductive layer 265 over the insulating layer 285 like the transistor 200B illustrated in FIGS. 12A to 12C. The insulating layer 285 is provided over the insulating layer 250.

The transistor 200F includes the conductive layer 220, the conductive layer 240a, the conductive layer 240b, the oxide semiconductor layer 230, the insulating layer 250, and the conductive layer 260.

In the transistor 200F, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layers 240a and 240b function as the other of the source electrode and the drain electrode.

The semiconductor device illustrated in FIGS. 25A to 25D is different from the semiconductor device illustrated in FIGS. 22A to 22D mainly in that the conductive layer 265 is provided and the insulating layer 283, the conductive layer 243a, the conductive layer 243b, and the conductive layer 246 are not provided. The semiconductor device illustrated in FIGS. 25A to 25D is different from the semiconductor device illustrated in FIGS. 22A to 22D also mainly in that the conductive layer 260 is provided to have an island shape and the conductive layers 240a and 240b are provided to extend.

The conductive layer 265 is provided to extend in the Y direction, and the conductive layers 240a and 240b are provided to extend in the X direction.

The conductive layer 260 is provided to have an island shape. In the plan view, the periphery of the conductive layer 260 is positioned inward from the periphery of the oxide semiconductor layer 230. Note that in the plan view, the periphery of the conductive layer 260 may overlap with part of the periphery of the oxide semiconductor layer 230 or may be positioned outward from part of the periphery of the oxide semiconductor layer 230.

The conductive layer 265 is in contact with the conductive layer 260.

In the YZ plane including the oxide semiconductor layer 230, the end portion of the oxide semiconductor layer 230 outside the groove portion 291 is positioned inward from the end portion of the conductive layer 240 outside the groove portion 291 (see FIG. 25B). Note that in the YZ plane including the oxide semiconductor layer 230, the end portion of the oxide semiconductor layer 230 outside the groove portion 291 may be aligned or substantially aligned with the end portion of the conductive layer 240 outside the groove portion 291, or may be positioned outward from the end portion of the conductive layer 240 outside the groove portion 291.

The insulating layer 285 is provided over the insulating layer 250. The insulating layer 285 is provided to fill a portion of the groove portion 291 where the conductive layer 260 is not positioned.

The structure illustrated in FIGS. 25A to 25D can increase the physical distance between the conductive layer 260 and the conductive layer 240a or the conductive layer 240b, thereby reducing the parasitic capacitance generated therebetween. The above structure can increase the physical distance between the conductive layer 265 and the conductive layer 240a or the conductive layer 240b and can reduce the parasitic capacitance generated therebetween. Accordingly, the frequency characteristics of a circuit including the transistor can be improved.

In the example illustrated in FIGS. 25A to 25D, the conductive layer 260 includes a region facing the side surface of the conductive layer 240a with the oxide semiconductor layer 230 therebetween and a region facing the side surface of the conductive layer 240b with the oxide semiconductor layer 230 therebetween; however, the present invention is not limited thereto. For example, a first conductive layer facing the side surface of the conductive layer 240a with the oxide semiconductor layer 230 therebetween and a second conductive layer facing the side surface of the conductive layer 240b with the oxide semiconductor layer 230 therebetween may be provided.

[Transistor 200Ga and transistor 200Gb]

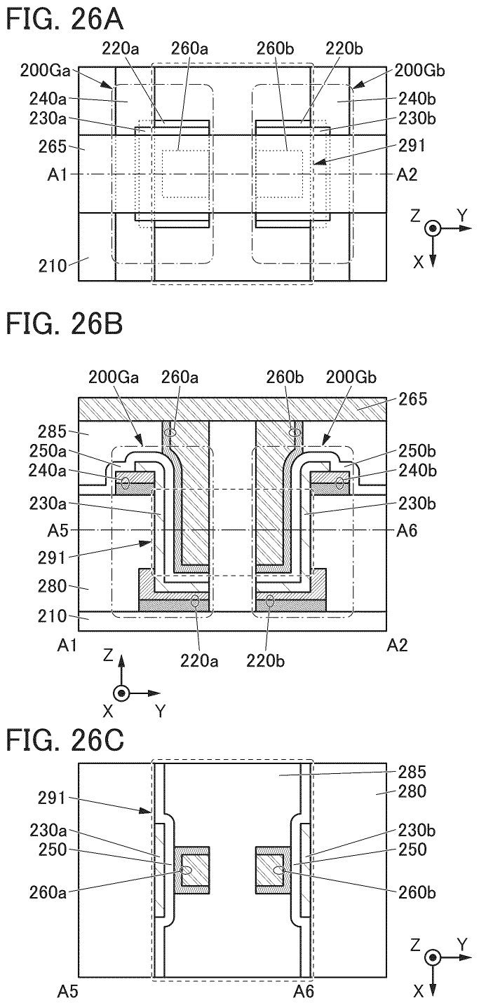

FIG. 26A is a plan view of a semiconductor device including two transistors. FIG. 26B is a cross-sectional view taken along the dashed-dotted line A1-A2 in FIG. 26A. FIG. 26C is a cross-sectional view taken along the dashed-dotted line A5-A6 in FIG. 26B.

The semiconductor device illustrated in FIGS. 26A to 26C includes the insulating layer 210 over a substrate (not illustrated), a transistor 200Ga and a transistor 200Gb over the insulating layer 210, and the insulating layer 280 over the insulating layer 210.

The transistor 200Ga includes a conductive layer 220a, the conductive layer 240a over the insulating layer 280, an oxide semiconductor layer 230a, an insulating layer 250a over the oxide semiconductor layer 230a, and a conductive layer 260a over the insulating layer 250a. The transistor 200Gb includes a conductive layer 220b, the conductive layer 240b over the insulating layer 280, an oxide semiconductor layer 230b, an insulating layer 250b over the oxide semiconductor layer 230b, and a conductive layer 260b over the insulating layer 250b.

In the transistor 200Ga, the oxide semiconductor layer 230a functions as a semiconductor layer, the conductive layer 260a functions as a gate electrode, the insulating layer 250a functions as a gate insulating layer, the conductive layer 220a functions as one of a source electrode and a drain electrode, and the conductive layer 240a functions as the other of the source electrode and the drain electrode. In the transistor 200Gb, the oxide semiconductor layer 230b functions as a semiconductor layer, the conductive layer 260b functions as a gate electrode, the insulating layer 250b functions as a gate insulating layer, the conductive layer 220b functions as one of a source electrode and a drain electrode, and the conductive layer 240b functions as the other of the source electrode and the drain electrode.

The semiconductor device illustrated in FIGS. 26A to 26C is different from the semiconductor device illustrated in FIGS. 25A to 25C in that the conductive layer 220, the oxide semiconductor layer 230, the insulating layer 250, and the conductive layer 260 are each divided in the groove portion 291 and the vicinity thereof.

In the YZ plane including the oxide semiconductor layers 230a and 230b, the two transistors (the transistors 200Ga and 200Gb) are provided in the groove portion 291, so that scaling down and high integration of the semiconductor device can be promoted.

In the example illustrated in FIGS. 26A to 26C, the insulating layer 250 is divided into the insulating layer 250a and the insulating layer 250b; however, the present invention is not limited thereto.

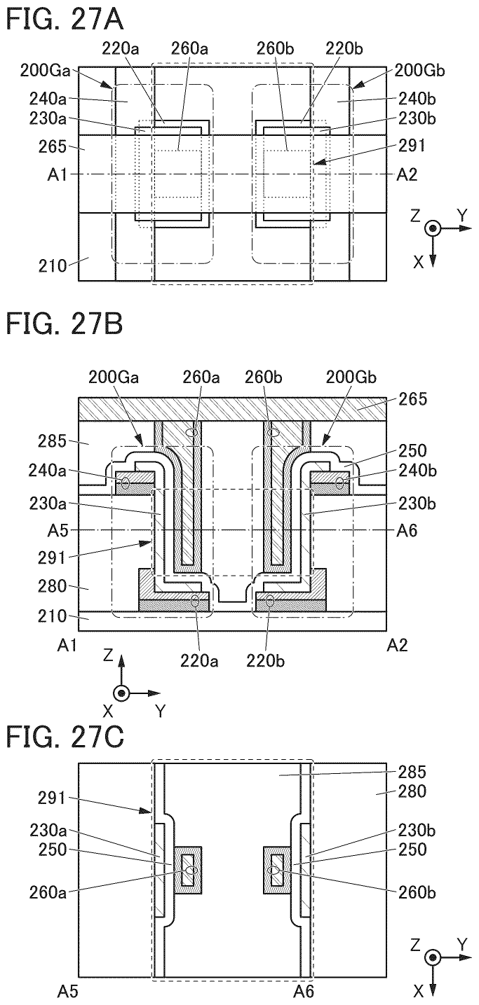

FIGS. 27A to 27C illustrate a modification example of the two transistors described with reference to FIGS. 26A to 26C. FIG. 27A is a plan view of the semiconductor device including the two transistors. FIG. 27B is a cross-sectional view taken along the dashed-dotted line A1-A2 in FIG. 27A. FIG. 27C is a cross-sectional view taken along the dashed-dotted line A5-A6 in FIG. 27A.

The semiconductor device illustrated in FIGS. 27A to 27C is different from the semiconductor device illustrated in FIGS. 26A to 26C in that the insulating layer 250 covers the oxide semiconductor layers 230a and 230b. When the insulating layer 250 covers the oxide semiconductor layers 230a and 230b, the side surface of the oxide semiconductor layer 230a on the groove portion 291 side and the side surface of the oxide semiconductor layer 230b on the groove portion 291 side can be covered. Thus, diffusion of hydrogen into the oxide semiconductor layers 230a and 230b can be inhibited. Accordingly, the transistor can have high reliability.

Each of the transistors 200E, 200F, 200Ga, and 200Gb can have a structure similar to that of at least one of the transistors 200A to 200D. Also in each of the transistors 200E, 200F, 200Ga, and 200Gb, the oxide layer 227 can be provided below the oxide semiconductor layer 230. The layer 228 can be provided between the oxide layer 227 and the oxide semiconductor layer 230.

### Structure Example 2 of Semiconductor Device

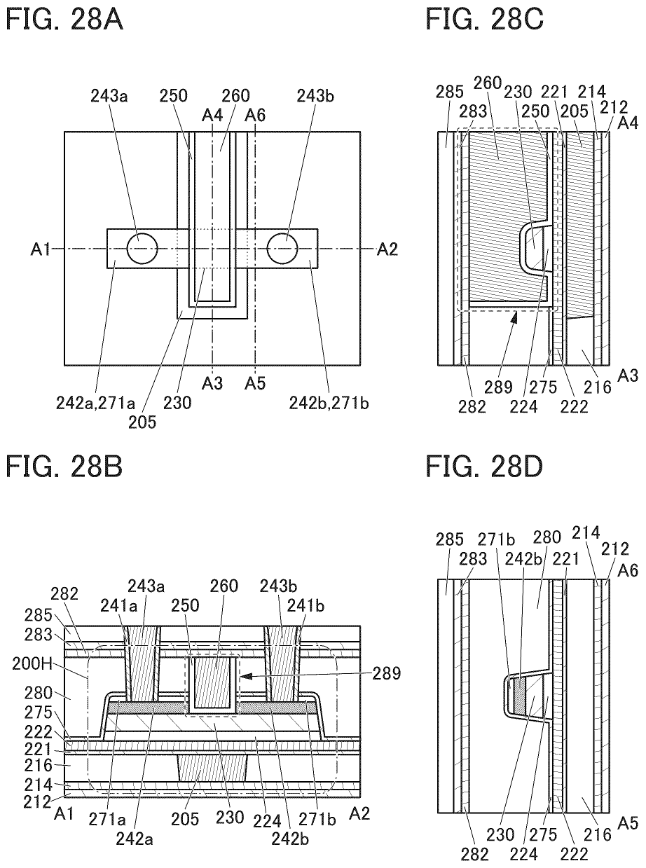

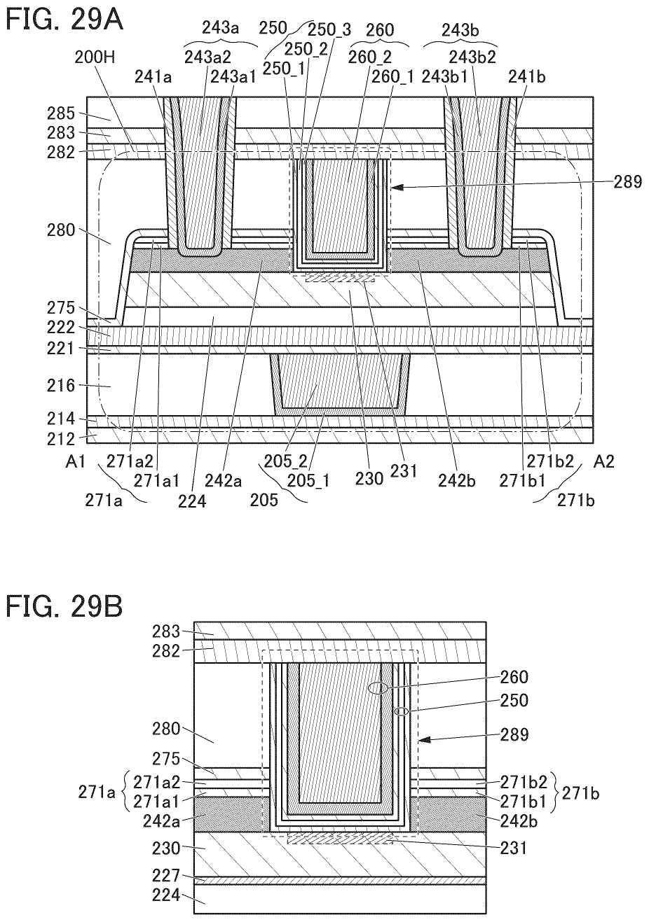

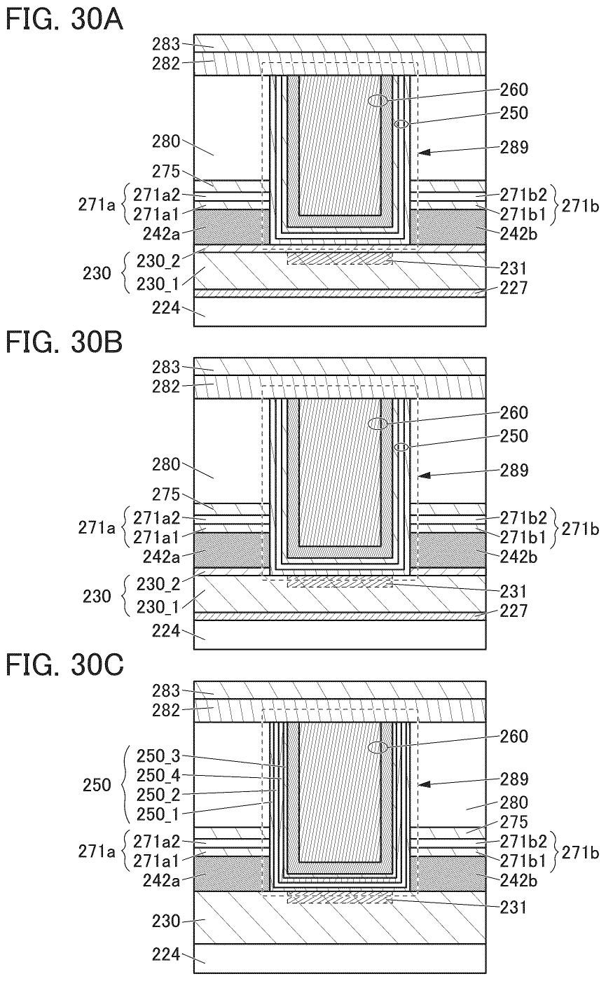

Other structure examples of the semiconductor device of one embodiment of the present invention will be described with reference to FIGS. 28A to 28D, FIGS. 29A and 29B, and FIGS. 30A to 30C. FIG. 28A is a plan view of a semiconductor device including a transistor 200H. FIG. 28B is a cross-sectional view taken along the dashed-dotted line A1-A2 in FIG. 28A, which corresponds to a cross-sectional view of the transistor 200H in the channel length direction. FIG. 28C is a cross-sectional view taken along the dashed-dotted line A3-A4 in FIG. 28A, which corresponds to a cross-sectional view of the transistor 200H in the channel width direction. FIG. 28D is a cross-sectional view taken along the dashed-dotted line A5-A6 in FIG. 28A. FIGS. 29A and 29B and FIGS. 30A to 30C are enlarged cross-sectional views of the transistor 200H in the channel length direction.

The transistor 200H includes a conductive layer 205, an insulating layer 221 over the conductive layer 205, an insulating layer 222 over the insulating layer 221, an insulating layer 224 over the insulating layer 222, the oxide semiconductor layer 230 over the insulating layer 224, a conductive layer 242a and a conductive layer 242b over the oxide semiconductor layer 230, an insulating layer 271a over the conductive layer 242a, an insulating layer 271b over the conductive layer 242b, the insulating layer 250 over the oxide semiconductor layer 230, and the conductive layer 260 over the insulating layer 250.

In the transistor 200H, the oxide semiconductor layer 230 functions as a channel formation region, the conductive layer 260 functions as a first gate electrode (also can be referred to as an upper gate electrode or a top gate electrode), and the insulating layer 250 functions as a first gate insulating layer. The conductive layer 205 functions as a second gate electrode (also can be referred to as a lower gate electrode or a bottom gate electrode), and the insulating layers 224, 222, and 221 each function as a second gate insulating layer. The conductive layer 242a functions as one of a source electrode and a drain electrode, and the conductive layer 242b functions as the other of the source electrode and the drain electrode.

The oxide semiconductor layer 230, the insulating layer 224, the insulating layer 250, and the conductive layer 260 included in the transistor 200H respectively correspond to the oxide semiconductor layer 30, the insulating layer 20, the insulating layer 50, and the conductive layer 60 described in Embodiment 1. Thus, for the structures, materials, and the like of the oxide semiconductor layer 230, the insulating layer 224, the insulating layer 250, and the conductive layer 260, the structures, materials, and the like of the oxide semiconductor layer 30, the insulating layer 20, the insulating layer 50, and the conductive layer 60 described in Embodiment 1 can be referred to.

Alternatively, the oxide semiconductor layer 230, the insulating layer 250, the insulating layer 224, and the conductive layer 205 included in the transistor 200H may respectively correspond to the oxide semiconductor layer 30, the insulating layer 20, the insulating layer 50, and the conductive layer 60 described in Embodiment 1. In that case, for the structures, materials, and the like of the oxide semiconductor layer 230, the insulating layer 250, the insulating layer 224, and the conductive layer 205, the structures, materials, and the like of the oxide semiconductor layer 30, the insulating layer 20, the insulating layer 50, and the conductive layer 60 described in Embodiment 1 can be referred to.

An insulating layer 275 is provided over the insulating layers 271a and 271b, and the insulating layer 280 is provided over the insulating layer 275. An opening portion 289 reaching the insulating layer 222 and the oxide semiconductor layer 230 is formed in the insulating layers 280 and 275, and the opening portion 289 overlaps with a region between the conductive layer 242a and the conductive layer 242b. In the plan view, the side end portion of the insulating layer 280 is aligned or substantially aligned with the side end portions of the conductive layers 242a and 242b in the opening portion 289. The insulating layer 250 and the conductive layer 260 are provided in the opening portion 289. An insulating layer 282 is provided in contact with the top surface of the insulating layer 280, the upper end portion of the insulating layer 250, and the top surface of the conductive layer 260. The insulating layer 283 is provided over the insulating layer 282. An insulating layer 216 is provided below the insulating layer 221, an insulating layer 214 is provided below the insulating layer 216 and the conductive layer 205, and an insulating layer 212 is provided below the insulating layer 214. The insulating layers 212, 214, 280, 282, 283, and 285 function as interlayer films.

An opening reaching the conductive layer 242a is formed in the insulating layers 285, 283, 282, 280, 275, and 271a, and the conductive layer 243a and an insulating layer 241a are provided in the opening. The insulating layer 241a is provided in contact with the sidewall of the opening, and the conductive layer 243a is located inward from the insulating layer 241a. An opening reaching the conductive layer 242b is formed in the insulating layers 285, 283, 282, 280, 275, and 271b, and the conductive layer 243b and an insulating layer 241b are provided in the opening. The insulating layer 241b is provided in contact with the sidewall of the opening, and the conductive layer 243b is located inward from the insulating layer 241b. The conductive layers 243a and 243b function as vias that connect a wiring or the like provided over the transistor 200H to the source or the drain of the transistor 200H.

As illustrated in FIG. 29B, the oxide semiconductor layer 230 includes the channel formation region 231. The oxide semiconductor layer 230 further includes the source region and the drain region. The source region and the drain region are n-type regions (low-resistance regions) having a higher carrier concentration than the channel formation region 231. The oxide semiconductor layer 230 may have a single-layer structure or a stacked-layer structure of two or more layers.

In the oxide semiconductor layer 230, the channel formation region 231 and the source and drain regions of the transistor 200H are formed. The channel formation region 231 is sandwiched between the source and drain regions. At least part of the channel formation region 231 overlaps with the conductive layer 260. The source region overlaps with the conductive layer 242a, and the drain region overlaps with the conductive layer 242b. Note that the source region and the drain region can be interchanged with each other.

When an insulating layer containing excess oxygen is provided in the vicinity of the oxide semiconductor layer and heat treatment is performed, oxygen can be supplied from the insulating layer to the oxide semiconductor layer to reduce oxygen vacancies and V_{O}H. However, supply of an excessive amount of oxygen to the source region or the drain region might cause a decrease in the on-state current or field-effect mobility of the transistor 200H. Furthermore, a variation in the amount of oxygen supplied to the source region or the drain region in the substrate plane leads to a variation in the characteristics of the semiconductor device including the transistor. An excessive amount of oxygen supplied from the insulating layer to the oxide semiconductor layer adversely affects the electrical characteristics and reliability of the transistor in some cases. Moreover, oxygen diffuses into a conductive layer such as a gate electrode, a source electrode, or a drain electrode to oxidize the conductive layer, which might impair the conductivity.

It is preferable that at least one of an insulating layer having a barrier property against hydrogen and an insulating layer having a function of capturing or fixing hydrogen be formed in the vicinity of the oxide semiconductor layer 230 to reduce V_{O}H in the channel formation region and its vicinity in the oxide semiconductor layer 230.

At least one of the insulating layers 212, 214, 221, 222, 275, 282, and 283 preferably functions as a barrier insulating layer against hydrogen. At least one of the insulating layers 212, 214, 221, 222, 275, 282, and 283 preferably functions as a barrier insulating layer against impurities. At least one of the insulating layers 212, 214, 221, 222, 275, 282, and 283 preferably functions as a barrier insulating layer against oxygen. Note that not all of the insulating layers 212, 214, 221, 222, 275, 282, and 283 need to be provided. When the barrier properties against hydrogen, impurities, oxygen, and the like are sufficient, any of the insulating layers 212, 214, 221, 222, 275, 282, and 283 can be formed selectively as appropriate. For example, the insulating layer 216 and the conductive layer 205 can be formed in contact with the top surface of the insulating layer 212, without providing the insulating layer 214.

The insulating layers 212, 221, 275, and 283 each preferably have a function of inhibiting diffusion of hydrogen. For example, silicon nitride, which has a higher hydrogen barrier property, is used for the insulating layers 212, 221, 275, and 283.

The insulating layers 214, 222, and 282 each preferably have a function of capturing or fixing hydrogen. For example, aluminum oxide is used for the insulating layers 214 and 282. For example, for the insulating layer 222 functioning as the second gate insulating layer, hafnium oxide, which is a high-k material, is preferably used.

When the insulating layer 212 having a function of inhibiting diffusion of hydrogen is provided below the transistor 200H as illustrated in FIG. 29A, diffusion of hydrogen from a layer below the transistor 200H can be inhibited. When the insulating layer 214 having a function of capturing or fixing hydrogen is provided, hydrogen contained in the insulating layer 216 or the like can be captured or fixed by the insulating layer 214. This can reduce the hydrogen concentration in the oxide semiconductor layer 230 and its vicinity.

When the insulating layer 221 having a function of inhibiting diffusion of hydrogen is provided below the oxide semiconductor layer 230, diffusion of hydrogen from below the oxide semiconductor layer 230 can be inhibited. When the insulating layer 222 having a function of capturing or fixing hydrogen is provided, hydrogen contained in the insulating layer 224 or the like can be captured or fixed by the insulating layer 222. This can reduce the hydrogen concentration in the oxide semiconductor layer 230 and its vicinity.

Providing the insulating layer 275 having a function of inhibiting diffusion of hydrogen to cover the oxide semiconductor layer 230, the conductive layer 242a, the conductive layer 242b, and the like can inhibit diffusion of hydrogen from the insulating layer 280 into the oxide semiconductor layer 230, the conductive layer 242a, the conductive layer 242b, and the like.

When the insulating layer 283 having a function of inhibiting diffusion of hydrogen is provided over the transistor 200H, diffusion of hydrogen from above the transistor 200H can be inhibited. When the insulating layer 282 having a function of capturing or fixing hydrogen is provided, hydrogen contained in the insulating layer 280 or the like can be captured or fixed by the insulating layer 282. This can reduce the hydrogen concentration in the oxide semiconductor layer 230 and its vicinity.

When the top and bottom of the transistor 200H are surrounded by barrier insulating layers against hydrogen in this manner, diffusion of hydrogen into the oxide semiconductor can be reduced and V_{O}H in the channel formation region can be reduced. Thus, the electrical characteristics and reliability of the transistor 200H can be improved.

The insulating layer 280 preferably contains excess oxygen. Supply of the oxygen to the oxide semiconductor layer 230 through the insulating layer 250 by heat treatment can reduce oxygen vacancies in the channel formation region.

The insulating layer 282 is preferably formed in an atmosphere containing an oxygen gas by a sputtering method. Thus, oxygen can be added to the insulating layer 280. The insulating layer 282 may have a single-layer structure or a stacked-layer structure of two or more layers.

As described above, heat treatment is performed on the insulating layer 280 containing excess oxygen, whereby an appropriate amount of oxygen can be supplied to the oxide semiconductor layer 230 through the insulating layer 250. Since the insulating layers 282 and 283 each having a barrier property against oxygen are placed over the insulating layer 280 in the heat treatment, oxygen contained in the insulating layer 280 can be prevented from excessively diffusing from the insulating layer 280. Since the insulating layer 275 having a barrier property against oxygen is formed between the insulating layer 280 and each of the oxide semiconductor layer 230 and the conductive layers 242a and 242b, oxygen contained in the insulating layer 280 can be prevented from excessively diffusing from the insulating layer 280. The heat treatment is performed in a state where the opening is formed in part of the insulating layers 280, 282, and 283, whereby part of oxygen contained in the insulating layer 280 can diffuse outwardly and the amount of oxygen supplied from the insulating layer 280 to the oxide semiconductor layer 230 can be adjusted.

As illustrated in FIG. 29B, the oxide layer 227 can be provided between the insulating layer 224 and the oxide semiconductor layer 230. The oxide layer 227 corresponds to the oxide layer 27 described in Embodiment 1. Thus, for the structure, material, and the like of the oxide layer 227, the structure, material, and the like of the oxide layer 27 described in Embodiment 1 can be referred to.

The oxide layer 227 is preferably formed by an ALD method. The oxide layer 227 formed by an ALD method can have excellent coverage.

The oxide layer 227 can also be formed by a sputtering method. When the oxide layer 227 is formed by a sputtering method, a layer containing a mixture of the components contained in the oxide layer 227 and the components contained in the conductive layer 220 is formed by damage due to the sputtering. The layer has a lower insulating property than the oxide layer 227; thus, an increase in the contact resistance between the conductive layer 220 and the oxide semiconductor layer 230 can be inhibited. The same applies to the contact resistance between the conductive layer 240 and the oxide semiconductor layer 230.

In the example illustrated in FIG. 29A, the oxide semiconductor layer 230 has a single-layer structure. Note that the oxide semiconductor layer 230 can have a stacked-layer structure of two or more layers. As illustrated in FIG. 30A, the oxide semiconductor layer 230 can have a two-layer structure of the oxide semiconductor layer 230_1 and the oxide semiconductor layer 230_2 over the oxide semiconductor layer 230_1. The oxide semiconductor layer 230_1 and the oxide semiconductor layer 230_2 respectively correspond to the oxide semiconductor layer 30a and the oxide semiconductor layer 30b described in Embodiment 1. Thus, for the structures, materials, and the like of the oxide semiconductor layer 230_1 and the oxide semiconductor layer 230_2, the structures, materials, and the like of the oxide semiconductor layer 30a and the oxide semiconductor layer 30b described in Embodiment 1 can be referred to.

In the example illustrated in FIG. 30A, the insulating layer 250 is in contact with the top surface of the oxide semiconductor layer 230_2; however, the present invention is not limited thereto. For example, as illustrated in FIG. 30B, the oxide semiconductor layer 230_2 in a region overlapping with the opening portion 289 can be removed so that the insulating layer 250 can be in contact with the side surface of the oxide semiconductor layer 230_2 and the top surface of the oxide semiconductor layer 230_1. With such a structure, the distance between the conductive layer 260 and the oxide semiconductor layer 230_1 can be shortened. Accordingly, an electric field from the gate electrode can be suitably applied to the oxide semiconductor layer 230_1. Preferably, the insulating layer 250 enables oxygen diffusion from the insulating layer 280 into the oxide semiconductor layer 230 and inhibition of oxidation of the conductive layers 242a, 242b, and 260.

The insulating layer 250 is formed in contact with the top surface of the insulating layer 222, the side surface of the insulating layer 224, the top and side surfaces of the oxide semiconductor layer 230, the side surface of the conductive layer 242a, the side surface of the conductive layer 242b, the side surface of the insulating layer 271a, the side surface of the insulating layer 271b, the side surface of the insulating layer 275, and the side surface of the insulating layer 280 in the opening portion 289.

Here, as illustrated in FIG. 29A, the insulating layer 250 preferably has a stacked-layer structure of the insulating layer 250_1 in contact with the oxide semiconductor layer 230, the insulating layer 250_2 over the insulating layer 250_1, and the insulating layer 250_3 over the insulating layer 250_2.

As illustrated in FIG. 30C, the insulating layer 250_4 may be provided over the insulating layer 250_2.

For the structures, materials, and the like of the insulating layers 250_1 to 250_4, the structures, materials, and the like of the insulating layers 250_1 to 250_4 described above in <Structure example 1 of semiconductor device> can be referred to.

For example, the insulating layer 250_1 including a region in contact with the side surface of the conductive layer 242a and a region in contact with the side surface of the conductive layer 242b has a function of capturing or fixing oxygen, so that oxidation of the side surfaces of the conductive layers 242a and 242b can be inhibited and accordingly formation of oxide films on the side surfaces can be inhibited. This can inhibit a reduction in on-state current or field-effect mobility of the transistor 200H. This structure can also inhibit oxygen in the insulating layer 250_2 from being absorbed into the conductive layers 242a and 242b. Thus, an appropriate amount of oxygen can be supplied from the insulating layer 250_2 to the oxide semiconductor layer 230, so that oxygen vacancies in the channel formation region in the oxide semiconductor layer 230 can be reduced.

When the insulating layer 250_1 is provided between the insulating layer 280 and the insulating layer 250_2 and between the insulating layer 250_2 and the oxide semiconductor layer 230, oxygen can be inhibited from being excessively supplied from the insulating layer 280 to the oxide semiconductor layer 230, and an appropriate amount of oxygen can be supplied to the oxide semiconductor layer 230. Thus, the amount of oxygen in the channel formation region and its vicinity in the oxide semiconductor layer 230 can be controlled to be an appropriate amount; hence, the transistor 200H can be prevented from having excessively normally-off characteristics and can have high reliability. In addition, excessive oxidation of the source and drain regions can be inhibited, and a reduction in on-state current or field-effect mobility of the transistor 200H can be inhibited.

With the above structure, the i-type or substantially i-type channel formation region and the n-type source and drain regions can be formed; thus, a semiconductor device having excellent electrical characteristics can be provided. The semiconductor device with the above structure can have excellent electrical characteristics even when being scaled down or highly integrated. Furthermore, scaling down of the transistor 200H can improve the high-frequency characteristics. Specifically, the cutoff frequency can be improved.

The thickness of each of the insulating layers 250_1 to 250_4 is preferably small for scaling down of the transistor 200H. The thickness of each of the insulating layers 250_1 to 250_4 is preferably greater than or equal to 0.1 nm and less than or equal to 20 nm, further preferably greater than or equal to 0.1 nm and less than or equal to 10 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each of the insulating layers 250_1 to 250_4 at least partly includes a region with the above thickness.

The conductive layer 205 is provided to overlap with the oxide semiconductor layer 230 and the conductive layer 260. For the conductive layer 205, any of conductive materials described later in [Conductive layer] can be used. Here, the conductive layer 205 is provided to fill an opening formed in the insulating layer 216. The conductive layer 205 is preferably provided to extend in the channel width direction as illustrated in FIGS. 28A and 28C. With such a structure, the conductive layer 205 functions as a wiring when a plurality of transistors are provided.

As illustrated in FIG. 29A, the conductive layer 205 preferably includes a conductive layer 205_1 and a conductive layer 205_2. The conductive layer 205_1 is provided in contact with the bottom surface and the sidewall of the opening. The conductive layer 205_2 is provided to fill a depression of the conductive layer 205_1 formed along the opening. Here, the top surface of the conductive layer 205 is level or substantially level with the top surface of the insulating layer 216.

The conductive layer 205_1 preferably contains a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 205_1 preferably contains a conductive material having a function of inhibiting diffusion of oxygen (e.g., at least one of an oxygen atom and an oxygen molecule).

When the conductive layer 205_1 is formed using a conductive material having a function of inhibiting diffusion of hydrogen, impurities such as hydrogen contained in the conductive layer 205_2 can be prevented from diffusing into the oxide semiconductor layer 230 through the insulating layer 216 and the like. When a conductive material having a function of inhibiting diffusion of oxygen is used for the conductive layer 205_1, a reduction in conductivity of the conductive layer 205_2 due to oxidation of the conductive layer 205_2 can be inhibited. Examples of the conductive material having a function of inhibiting diffusion of oxygen include titanium, titanium nitride, tantalum, tantalum nitride, ruthenium, and ruthenium oxide. The conductive layer 205_1 can have a single-layer structure or a stacked-layer structure of the above conductive material. For example, the conductive layer 205_1 preferably contains titanium nitride.

The conductive layer 205_2 is preferably formed using a conductor having high conductivity. For example, a conductive material containing tungsten, copper, or aluminum as its main component is preferably used for the conductive layer 205_2. For example, the conductive layer 205_2 preferably contains tungsten.

The conductive layer 205 can function as the second gate electrode. In that case, by changing a potential applied to the conductive layer 205 not in conjunction with but independently of a potential applied to the conductive layer 260, the threshold voltage (Vth) of the transistor 200H can be controlled. Specifically, when a negative potential is applied to the conductive layer 205, the Vth of the transistor 200H can be further increased and the off-state current can be reduced. Thus, drain current at the time when a potential applied to the conductive layer 260 is 0 V can be lower in the case where a negative potential is applied to the conductive layer 205 than in the case where the negative potential is not applied to the conductive layer 205.

Although FIG. 29A illustrates the stacked-layer structure of the conductive layers 205_1 and 205_2, the present invention is not limited to this structure. The conductive layer 205 may have a single-layer structure or a stacked-layer structure of three or more layers. For example, the conductive layer 205_1 may have a two-layer structure of a tantalum nitride film and a titanium nitride film over the tantalum nitride film, and the conductive layer 205_2 including a tungsten film may be provided over the conductive layer 205_1. With such a structure, impurities such as hydrogen and metal impurities such as copper contained in the layer below the transistor 200H can be inhibited from diffusing into the conductive layer 205.

The insulating layers 224, 221, and 222 function as the second gate insulating layer.

The insulating layer 224 in contact with the oxide semiconductor layer 230 can be formed using any of the insulating materials that can be used for the insulating layer 20 described in Embodiment 1. The insulating layer 224 preferably includes, for example, a silicon oxide film or a silicon oxynitride film. Thus, oxygen can be supplied from the insulating layer 224 to the oxide semiconductor layer 230, so that oxygen vacancies can be reduced. Note that the insulating layer 224 may have a stacked-layer structure of two or more layers. In that case, without limitation to a stacked-layer structure formed of the same material, a stacked-layer structure formed of different materials may be employed.

The above-described plasma treatment using a nitrogen-containing gas is preferably performed on the insulating layer 224. Thus, NO₂ can be added to the insulating layer 224. As described above, when NO₂ in the insulating layer 224 becomes negative fixed charge, the negative shift of the electrical characteristics of the OS transistor can be inhibited and the OS transistor can have normally-off characteristics. Accordingly, the semiconductor device having excellent electrical characteristics can be provided.

The insulating layer 224 is preferably processed into an island shape like the oxide semiconductor layer 230. Thus, in the case where a plurality of the transistors 200H are provided, the transistors 200H include the insulating layers 224 having substantially the same sizes. Accordingly, the amounts of oxygen supplied from the insulating layers 224 to the oxide semiconductor layers 230 are substantially the same in the transistors 200H. As a result, variations in electrical characteristics of the transistors 200H in the substrate plane can be reduced.

When the insulating layer 224 is provided to have an island shape, the level of at least part of the bottom surface of the conductive layer 260 can be lower than that of the bottom surface of the oxide semiconductor layer 230 (see FIG. 28C). Thus, the conductive layer 260 can be provided to face the top and side surfaces of the oxide semiconductor layer 230, so that an electric field of the conductive layer 260 can act on the top and side surfaces of the oxide semiconductor layer 230.

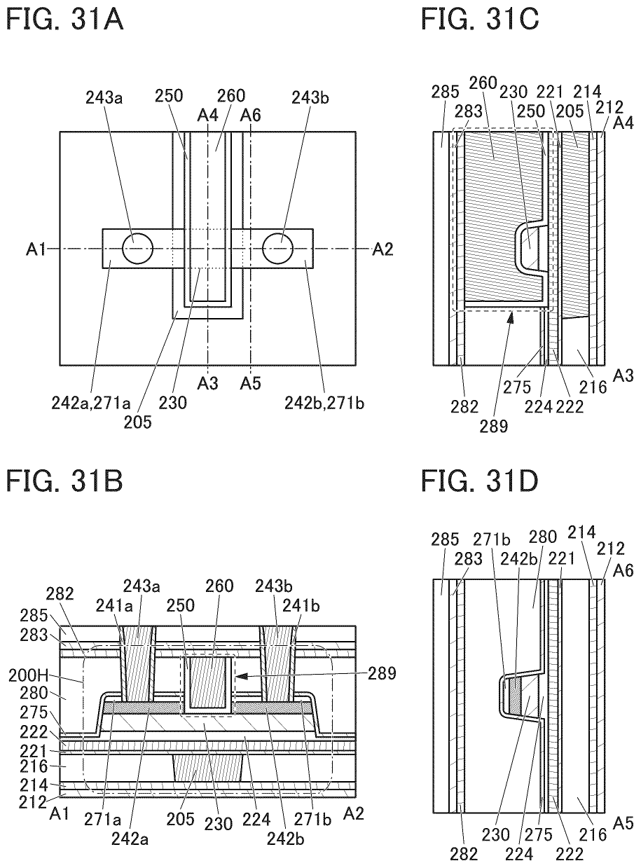

Note that the insulating layer 224 is not necessarily processed into an island shape. For example, as illustrated in FIGS. 31A to 31D, the insulating layer 224 may have a shape in which an opening is partly formed, instead of having an island shape. Here, FIGS. 31A to 31D correspond to FIGS. 28A to 28D, respectively, and are the same as FIGS. 28A to 28D except for the shape of the insulating layer 224.

The insulating layer 224 illustrated in FIGS. 31A to 31D has a smaller thickness in a region not overlapping with the oxide semiconductor layer 230 than in a region overlapping with the oxide semiconductor layer 230. An opening is formed in a region not overlapping with the oxide semiconductor layer 230 but overlapping with the insulating layer 250. In the case where a plurality of transistors are provided over one substrate, forming the insulating layer 224 in this manner results in formation of the oxide semiconductor layers 230 of the transistors over the same insulating layer 224. Thus, a variation in the amount of oxygen supplied from the insulating layer 224 to the oxide semiconductor layers 230 of the transistors can be reduced. Accordingly, variations in electrical characteristics of the transistors can be reduced.

In the insulating layer 224 illustrated in FIGS. 31A to 31D, the opening is formed in the region not overlapping with the oxide semiconductor layer 230 but overlapping with the insulating layer 250; however, a structure without the opening may be employed.

For the conductive layers 242a, 242b, and 260, any of the conductive materials described later in [Conductive layer] can be used. Specifically, a conductive material that is not easily oxidized or a conductive material having a function of inhibiting diffusion of oxygen is preferably used for the conductive layers 242a, 242b, and 260. Examples of the conductive material include a conductive material containing nitrogen and a conductive material containing oxygen. The use of such conductive materials can inhibit a reduction in the conductivity of the conductive layers 242a, 242b, and 260.

For each of the conductive layers 242a and 242b, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. For example, tantalum nitride can be used for the conductive layers 242a and 242b. For another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

The conductive layers 242a and 242b may each have a stacked-layer structure. In that case, the above-described conductive material is used for lower layers of the stacked-layer structures of the conductive layers 242a and 242b, and a conductive material having higher conductivity is used for upper layers of the stacked-layer structures of the conductive layers 242a and 242b. For example, tantalum nitride can be used for the lower layers and tungsten can be used for the upper layers.

The insulating layers 271a and 271b are inorganic insulating layers that function as an etching stopper at the time of processing the conductive layers 242a and 242b to protect the conductive layers 242a and 242b. Since the insulating layers 271a and 271b are respectively in contact with the conductive layers 242a and 242b, the insulating layers 271a and 271b are preferably inorganic insulators that are unlikely to oxidize the conductive layers 242a and 242b. Thus, the insulating layers 271a and 271b each preferably have a two-layer structure. Here, the lower layers of the insulating layers 271a and 271b are each preferably formed using a nitride insulator (e.g., silicon nitride) that can be used for the insulating layer 250_3 to inhibit oxidation of the conductive layers 242a and 242b. The upper layers of the insulating layers 271a and 271b are each preferably formed using an oxide insulator (e.g., silicon oxide) that can be used for the insulating layer 250_2 to function as an etching stopper.

An insulating layer to be the insulating layers 271a and 271b functions as a mask for a conductive layer to be the conductive layers 242a and 242b, and thus each of the conductive layers 242a and 242b does not have a curved surface between the side surface and the top surface as illustrated in FIG. 28D. Accordingly, the end portion at the intersection of the side surface and the top surface of each of the conductive layers 242a and 242b is angular. The cross-sectional area of each of the conductive layers 242a and 242b is larger in the case where the end portion at the intersection of the side surface and the top surface of each of the conductive layers 242a and 242b is angular than in the case where the end portion is rounded. Accordingly, the resistances of the conductive layers 242a and 242b are reduced, so that the on-state current of the transistor can be increased.

The conductive layer 260 is provided in the opening portion 289 to cover the top surface of the insulating layer 222, the side surface of the insulating layer 224, and the top and side surfaces of the oxide semiconductor layer 230 with the insulating layer 250 therebetween. The top surface of the conductive layer 260 is level or substantially level with the upper end portion of the insulating layer 250 and the top surface of the insulating layer 280.

Note that the sidewall of the opening portion 289 may be perpendicular or substantially perpendicular to the top surface of the insulating layer 222 or may have a tapered shape. The sidewall with a tapered shape can improve the coverage with the insulating layer 250 formed in the opening portion 289, so that the number of defects such as voids can be reduced.

The conductive layer 260 is preferably provided to extend in the channel width direction as illustrated in FIGS. 28A and 28C. With such a structure, the conductive layer 260 functions as a wiring when a plurality of transistors are provided.

As illustrated in FIG. 28C, a curved surface may be provided between the top and side surfaces of the oxide semiconductor layer 230 in the cross-sectional view of the transistor 200H in the channel width direction. That is, the end portion of the side surface and the end portion of the top surface may be curved.

As illustrated in FIG. 29A, the conductive layer 260 preferably has a two-layer structure. Here, the conductive layer 260 preferably includes the conductive layer 260_1 and the conductive layer 260_2 over the conductive layer 260_1. For example, the conductive layer 260_1 is preferably positioned to cover the bottom and side surfaces of the conductive layer 260_2. In that case, a conductive material that is not easily oxidized or a conductive material having a function of inhibiting diffusion of oxygen is preferably used for the conductive layer 260_1.

For the conductive layer 260_1, any of the conductive materials that can be used for the conductive layer 205_1 can be used. For example, when the conductive layer 260_1 has a function of inhibiting diffusion of oxygen, the conductivity of the conductive layer 260_2 can be inhibited from being lowered because of oxidation of the conductive layer 260_2 due to oxygen contained in the insulating layer 280 and the like.

For the conductive layer 260_2, any of the conductive materials that can be used for the conductive layer 205_2 can be used. The conductive layer 260_2 may have a stacked-layer structure, for example, a stacked-layer structure of a titanium film or a titanium nitride film and any of the conductive materials that can be used for the conductive layer 205_2.

The insulating layers 216, 280, and 285 each preferably have a lower dielectric constant than the insulating layer 222. In the case where a material with a low dielectric constant is used for an interlayer film, the parasitic capacitance generated between wirings can be reduced.

For example, the insulating layers 216, 280, and 285 can each be formed using any of materials with a low dielectric constant described later in [Insulating layer]. Silicon oxide and silicon oxynitride are particularly preferable because of their thermal stability. Materials such as silicon oxide, silicon oxynitride, and porous silicon oxide are preferably used, in which case a region containing excess oxygen can be easily formed.

The top surfaces of the insulating layers 216 and 280 may be planarized.

The concentration of impurities such as water and hydrogen in the insulating layer 280 is preferably reduced. For example, the insulating layer 280 preferably includes an oxide containing silicon, such as silicon oxide or silicon oxynitride.

For the conductive layers 243a and 243b, any of the conductive materials described later in [Conductive layer] can be used. The conductive layers 243a and 243b are preferably formed using a conductive material containing tungsten, copper, or aluminum as its main component, for example. The conductive layers 243a and 243b may each have a stacked-layer structure.

For example, as illustrated in FIG. 29A, the conductive layers 243a and 243b may each have a two-layer structure. The conductive layer 243a includes a conductive layer 243a1 formed along the opening and a conductive layer 243a2 located inward from the conductive layer 243al. The conductive layer 243b includes a conductive layer 243b1 formed along the opening and a conductive layer 243b2 located inward from the conductive layer 243b1.

The conductive layers 243a1 and 243b1 can each be formed to have a single-layer structure or a stacked-layer structure using any of the conductive materials that can be used for the conductive layer 205_1. Providing the conductive layers 243a1 and 243b1 can inhibit entry of impurities such as water and hydrogen into the oxide semiconductor layer 230 through the conductive layers 243a2 and 243b2. Note that the conductive layers 243a2 and 243b2 can be formed using any of the conductive materials that can be used for the conductive layers 243a and 243b.

As illustrated in FIG. 28B, the top surfaces of the conductive layers 243a and 243b are level or substantially level with the top surface of the insulating layer 285. As illustrated in FIG. 29A, the conductive layer 243a may be formed such that its lower portion is embedded in the conductive layer 242a. Similarly, the conductive layer 243b may be formed such that its lower portion is embedded in the conductive layer 242b.

A barrier insulating layer that can be used for the insulating layer 275 and the like is used as the insulating layers 241a and 241b. For example, silicon nitride is used for the insulating layers 241a and 241b. The insulating layers 241a and 241b are provided in contact with the insulating layers 285, 283, 282, 275, 271a, and 271b. Thus, impurities such as water and hydrogen contained in the insulating layer 280 or the like can be inhibited from entering the oxide semiconductor layer 230 through the conductive layers 243a and 243b. Silicon nitride is particularly preferable because of its high barrier property against hydrogen. Furthermore, oxygen contained in the insulating layer 280 can be prevented from being absorbed by the conductive layers 243a and 243b.

The insulating layers 241a and 241b may each have a stacked-layer structure. In that case, a combination of a barrier insulating layer against oxygen and a barrier insulating layer against hydrogen is preferably used for a first insulating layer in contact with the sidewall of the opening formed in the insulating layer 280 and the like and a second insulating layer located inward from the first insulating layer.

### Modification Example 1

In FIG. 28B and the like, the insulating layer 250 is in contact with the side surface of the insulating layer 280 in the opening portion 289; however, the present invention is not limited to this structure. For example, an insulating layer may be provided between the insulating layer 250 and the insulating layer 280 in the opening portion 289.

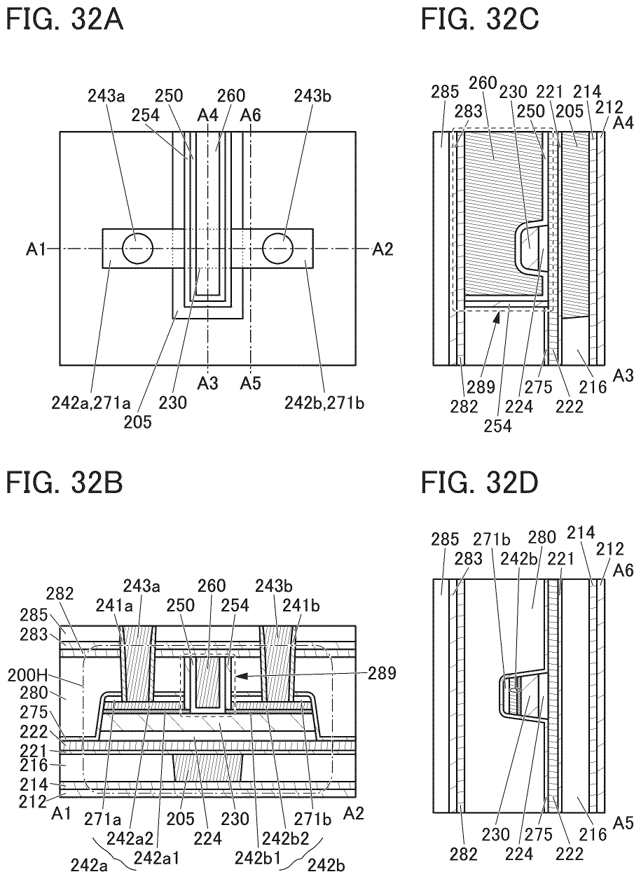

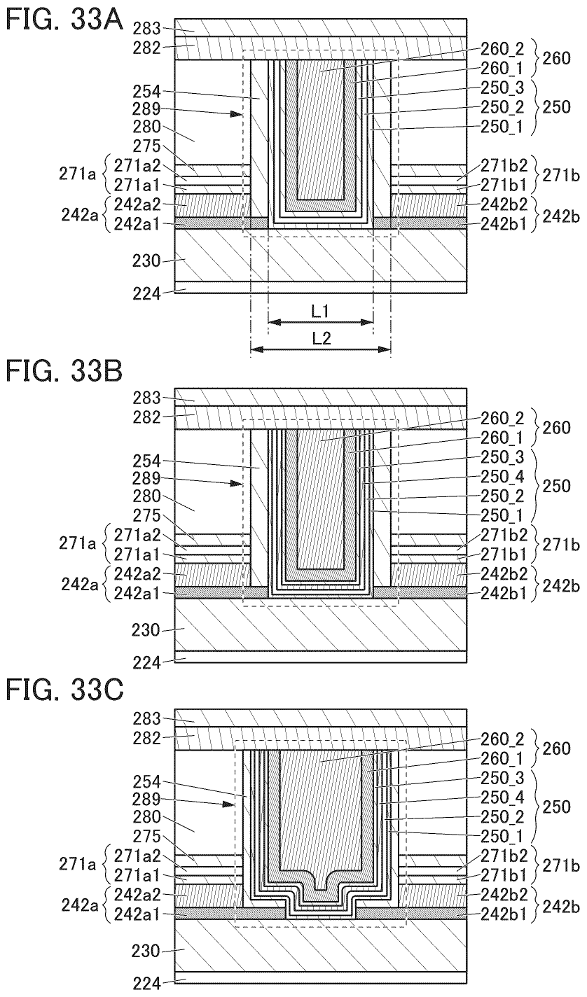

FIGS. 32A to 32D and FIGS. 33A to 33C illustrate a modification example of the semiconductor device described with reference to FIGS. 28A to 28D. FIGS. 32A to 32D are a plan view and cross-sectional views of the semiconductor device including the transistor 200H and correspond to the plan view and cross-sectional views in FIGS. 28A to 28D. FIGS. 33A to 33C are enlarged cross-sectional views of the transistor 200H in the channel length direction and correspond to the enlarged cross-sectional view in FIG. 29B.

The transistor 200H illustrated in FIGS. 32A to 32D is different from the transistor 200H illustrated in FIGS. 28A to 28D mainly in including an insulating layer 254. Differences from the above description are mainly described below. The above description is referred to for the same portions, and the description of the same portions is omitted in some cases.

In FIGS. 32A to 32D, the conductive layers 242a and 242b each have a two-layer structure. The conductive layer 242a has a stacked-layer structure of a conductive layer 242a1 and a conductive layer 242a2 over the conductive layer 242al. The conductive layer 242b has a stacked-layer structure of a conductive layer 242b1 and a conductive layer 242b2 over the conductive layer 242b1. The conductive layers 242a1 and 242b1 correspond to the lower layers of the conductive layers 242a and 242b, and the conductive layers 242a2 and 242b2 correspond to the upper layers of the conductive layers 242a and 242b.

As illustrated in FIGS. 32B and 32C, the insulating layer 254 is provided in the opening portion 289 and is in contact with the side surface of the insulating layer 280, the side surface of the conductive layer 242a2, the side surface of the conductive layer 242b2, the top surface of the conductive layer 242a1, the top surface of the conductive layer 242b1, and the top surface of the insulating layer 222 in the opening portion 289. In other words, the insulating layer 254 is formed in a sidewall shape to be in contact with the sidewall of the opening portion 289. Here, the sidewall of the opening portion 289 corresponds to, for example, the side surface of the insulating layer 280 and the like in the opening portion 289.

The insulating layer 254 preferably has a barrier property against oxygen. When the insulating layer 254 has a barrier property against oxygen, oxidation of the side surfaces of the conductive layers 242a and 242b can be inhibited and accordingly formation of oxide films on the side surfaces can be inhibited. It is thus possible to inhibit a reduction in the on-state current or field-effect mobility of the transistor 200H. As the insulating layer 254, a barrier insulating layer against oxygen can be used. For example, silicon nitride is used for the insulating layer 254.

The opening portion 289 overlaps with a region between the conductive layers 242a2 and 242b2. In the plan view, the side end portion of the insulating layer 280 is aligned or substantially aligned with the side end portions of the conductive layers 242a2 and 242b2 in the opening portion 289. Parts of the conductive layers 242a1 and 242b1 are formed to extend to the inside of the opening portion 289. In other words, part of the conductive layer 242a1 having a top surface on which the insulating layer 254 is formed (hereinafter, sometimes referred to as an extending portion of the conductive layer 242a1) is formed to extend beyond the conductive layer 242a2 toward the conductive layer 260. Similarly, part of the conductive layer 242b1 having a top surface on which the insulating layer 254 is formed (hereinafter, sometimes referred to as an extending portion of the conductive layer 242b1) is formed to extend beyond the conductive layer 242b2 toward the conductive layer 260.

Part of the top surface of the conductive layer 242a1 is in contact with the conductive layer 242a2, and part of the top surface of the conductive layer 242bl is in contact with the conductive layer 242b2. Accordingly, the insulating layer 254 is in contact with another part of the top surface of the conductive layer 242al, another part of the top surface of the conductive layer 242b1, the side surface of the conductive layer 242a2, and the side surface of the conductive layer 242b2 in the opening portion 289. The insulating layer 250 is in contact with the top surface of the oxide semiconductor layer 230, the side surface of the conductive layer 242al, the side surface of the conductive layer 242b1, and the side surface of the insulating layer 254.

By anisotropic etching, the insulating layer 254 is formed in a sidewall shape to be in contact with the sidewall of the opening portion 289. The insulating layer 254 is formed in contact with the side surfaces of the conductive layers 242a2 and 242b2, and thus has a function of protecting the conductive layers 242a2 and 242b2.

The insulating layer 254 functions as a mask at the time of dividing the conductive layer into the conductive layers 242a1 and 242b1. Thus, as illustrated in FIG. 33A, in the cross-sectional view of the transistor 200H, the side end portion of the insulating layer 254 is aligned or substantially aligned with the side end portions of the conductive layers 242a1 and 242b1.

Note that heat treatment in an oxygen-containing atmosphere is preferably performed after the division of the conductive layer into the conductive layers 242a1 and 242b1 but before the formation of the insulating layer 250. At this time, since the insulating layer 254 is formed in contact with the side surfaces of the conductive layers 242a2 and 242b2, excessive oxidation of the conductive layers 242a2 and 242b2 can be prevented. Even in the case where microwave plasma treatment is performed after the division of the conductive layer into the conductive layers 242a1 and 242b1, formation of oxide films on the side surfaces of the conductive layers 242a and 242b can be inhibited.

The insulating layer 254, the insulating layer 250, and the conductive layer 260 are provided to reflect the shape of the opening portion 289. Thus, the insulating layer 254 is provided to cover the sidewall of the opening portion 289, the insulating layer 250 is provided to cover the bottom portion of the opening portion 289 and the insulating layer 254, and the conductive layer 260 is provided to fill the depression of the insulating layer 250.

As described above, the insulating layer 250 may have a stacked-layer structure. For example, as illustrated in FIG. 33A, the insulating layer 250 may have a three-layer structure of the insulating layers 250_1 to 250_3. For another example, as illustrated in FIG. 33B, the insulating layer 250 may have a four-layer structure of the insulating layers 250_1 to 250_4.

The thickness of the insulating layer 254 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulating layer 254 has a thickness in the above range, excessive oxidation of the conductive layers 242a2 and 242b2 can be inhibited. Note that the insulating layer 254 at least partly has a region with the above thickness. The insulating layer 254 is provided in contact with the sidewall of the opening portion 289, and thus is preferably formed by, for example, an ALD method that provides excellent coverage. When the thickness of the insulating layer 254 is excessively large, the time for forming the insulating layer 254 by an ALD method is long, which decreases the productivity. For this reason, the thickness of the insulating layer 254 is preferably in the above range. Moreover, the insulating layer 254 preferably has a thickness that does not excessively inhibit diffusion of excess oxygen from the insulating layer 280 to the insulating layer 250_2 and diffusion of excess oxygen from the insulating layer 250_2 to the oxide semiconductor layer 230.

As illustrated in FIG. 33A, in the cross-sectional view of the transistor 200H in the channel length direction, a distance L1 between the conductive layers 242a1 and 242b1 is smaller than a distance L2 between the conductive layers 242a2 and 242b2. Here, the distance L1 refers to the shortest distance between the conductive layers 242a1 and 242b1, and the distance L2 refers to the shortest distance between the conductive layers 242a2 and 242b2. With such a structure, the distance between the source and the drain can be shortened, and the channel length can be accordingly shortened. This can improve the frequency characteristics of the transistor 200H. In this manner, scaling down of the semiconductor device enables the semiconductor device to have a higher operating speed.

In the structure illustrated in FIG. 33A, the difference between the distance L2 and the distance L1 is twice the thickness of the insulating layer 254. In other words, the distance L2 is equal or substantially equal to the sum of the distance L1 and the double of the thickness of the insulating layer 254. Here, the thickness of the insulating layer 254 refers to the width in the A1-A2 direction of at least part of the insulating layer 254.

The insulating layer 254 may have a stacked-layer structure of two or more layers. In that case, at least one of the stacked layers can be the above-described inorganic insulating layer that is not easily oxidized. For example, the inorganic insulating layer that is not easily oxidized is used as a first insulating layer of the insulating layer 254, and an insulating material (e.g., silicon oxide) that can be used for the insulating layer 250_2 is used for a second insulating layer over the first insulating layer of the insulating layer 254. The second insulating layer of the insulating layer 254 preferably has a lower dielectric constant than the first insulating layer of the insulating layer 254. When the insulating layer 254 has a two-layer structure to have a large thickness in the above manner, the distance between the conductive layer 260 and the conductive layer 242a or 242b can be increased and thus the parasitic capacitance can be reduced.

Although an example in which the insulating layer 254 is formed in a sidewall shape by anisotropic etching is described above, the present invention is not limited thereto. As illustrated in FIG. 33C, the insulating layer 254 can have an opening inside the opening portion 289. In that case, the opening of the insulating layer 254 can be formed by removing part of an insulating film to be the insulating layer 254 by a lithography method. The opening of the insulating layer 254 preferably overlaps with a region between the conductive layers 242a1 and 242b1.

As illustrated in FIG. 33C, extending portions are formed in a lower portion of the insulating layer 254 in the cross-sectional view. The extending portions of the insulating layer 254 overlap with the extending portions of the conductive layers 242a1 and 242b1.

### Modification Example 2

Although Modification example 1 describes the structure in which the insulating layer 254 is provided in contact with the sidewall of the opening portion 289, the present invention is not limited to this structure. For example, a structure in which the insulating layer 254 is not provided in the opening portion 289 may be employed.

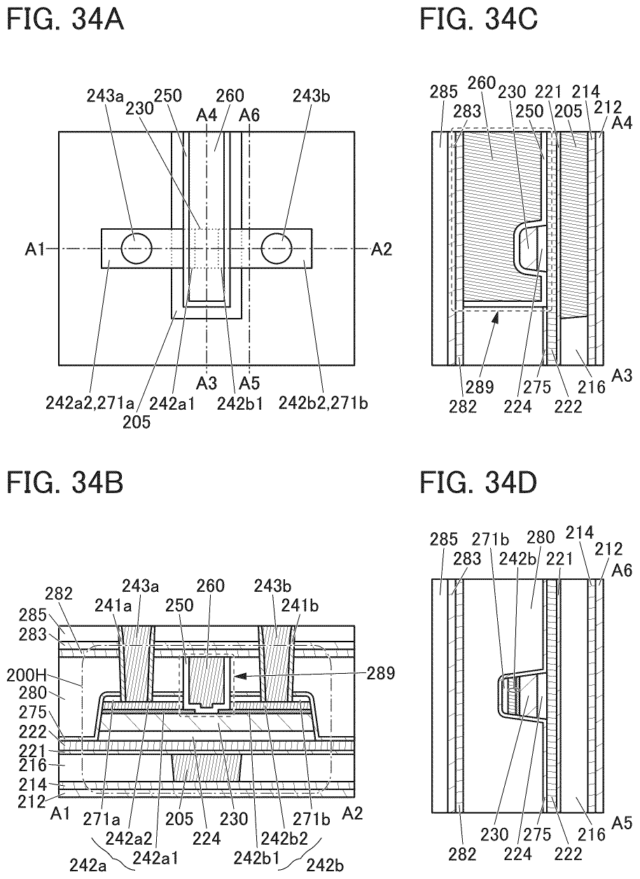

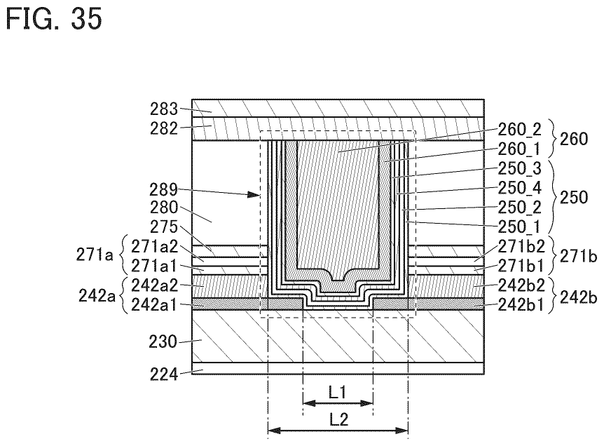

FIGS. 34A to 34D and FIG. 35 illustrate a modification example of the semiconductor device described in Modification example 1. FIGS. 34A to 34D are a plan view and cross-sectional views of the semiconductor device including the transistor 200H and correspond to the plan view and cross-sectional views in FIGS. 32A to 32D. FIG. 35 is an enlarged cross-sectional view of the transistor 200H in the channel length direction and corresponds to the enlarged cross-sectional view in FIG. 33C.

The transistor 200H illustrated in FIGS. 34A to 34D is different from the transistor 200H illustrated in FIGS. 32A to 32D mainly in not including the insulating layer 254. Differences from the above description are mainly described below. The above description is referred to for the same portions, and the description of the same portions is omitted in some cases.

As illustrated in FIG. 35, in the case where the insulating layer 254 is not provided, part of the insulating layer 250 is positioned to overlap with the extending portions of the conductive layers 242a1 and 242b1. In some cases, part of the conductive layer 260 is positioned to overlap with the extending portions of the conductive layers 242a1 and 242b1. Here, the extending portions of the conductive layers 242a1 and 242b1 are in contact with the insulating layer 250. The side surface of the insulating layer 250 is in contact with the side surfaces of the insulating layers 280, 275, 271a, and 271b and the side surfaces of the conductive layers 242a2 and 242b2.

The insulating layer 250 is formed to reflect the shape of the opening portion 289. Accordingly, the insulating layer 250 is formed to reflect the shapes of the conductive layers 242a1 and 242b1 that extend in the opening portion 289.

As illustrated in FIG. 35, in the cross-sectional view of the transistor 200H in the channel length direction, the distance L1 between the conductive layers 242a1 and 242b1 is smaller than the distance L2 between the conductive layers 242a2 and 242b2. With such a structure, the distance between the source and the drain can be shortened, and the channel length can be accordingly shortened. This can improve the frequency characteristics of the transistor 200H. In this manner, scaling down of the semiconductor device enables the semiconductor device to have a higher operating speed.

Furthermore, with the structure illustrated in FIG. 35, the width of the upper portion of the conductive layer 260 can be larger than the distance L1. This can reduce the wiring resistance of the conductive layer 260. Consequently, the power consumption of the semiconductor device can be reduced.

### <Materials for Semiconductor Device>

Materials that can be used for the semiconductor device of this embodiment will be described below. Note that the layers included in the semiconductor device of this embodiment may each have a single-layer structure or a stacked-layer structure.

### [Oxide Semiconductor Layer]

As described above, the oxide semiconductor layer 230 includes the channel formation region. The oxide semiconductor layer 230 further includes the source region and the drain region. The source region and the drain region are n-type regions (low-resistance regions) having a higher carrier concentration than the channel formation region. The oxide semiconductor layer 230 may have a stacked-layer structure of two or more layers.

Note that the carrier concentration in the channel formation region is preferably lower than 1×10¹⁹ cm⁻³, lower than 1×10¹⁸ cm⁻³, lower than 5×10¹⁷ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration in the channel formation region is not particularly limited and can be, for example, 1× 10-7 cm⁻³.

As has been described in the foregoing embodiment, the electrical characteristics of the OS transistor may vary easily and the reliability of the OS transistor may be decreased when Vo and impurities are present in the channel formation region in the oxide semiconductor. Accordingly, in order to obtain stable electrical characteristics of the OS transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen.

When an oxide semiconductor contains silicon or carbon, which is a Group 14 element, defect states are formed in the oxide semiconductor. Accordingly, the carbon concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to be normally on. Alternatively, when the oxide semiconductor contains nitrogen, a trap state is sometimes formed. This may make the electrical characteristics of the transistor unstable. Accordingly, the nitrogen concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus an oxygen vacancy is formed in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to be normally on. For this reason, hydrogen in the channel formation region in the oxide semiconductor is preferably reduced as much as possible. Specifically, the hydrogen concentration in the channel formation region in the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³. The lower limit of the hydrogen concentration in the channel formation region in the oxide semiconductor is not particularly limited and can be, for example, higher than or equal to 1×10¹⁶ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to be normally on. Thus, the concentration of an alkali metal or an alkaline earth metal in the channel formation region in the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

For the oxide semiconductor layer that can be used as the semiconductor layer of the transistor of one embodiment of the present invention, description in Embodiment 1 can be referred to.

### [Insulating Layer]

An inorganic insulating film is preferably used as each of the insulating layers included in the semiconductor device (e.g., the insulating layers 210, 212, 214, 221, 222, 224, 225, 241a, 241b, 250, 254, 275, 280, 281, 282, 283, 284, and 285). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With scaling down and high integration of a transistor, for example, a problem such as generation of leakage current may arise because of a thin gate insulating layer. When a high-k material is used for the gate insulating layer, the voltage at the time of operation of the transistor can be reduced while the physical thickness is maintained. Furthermore, the EOT of the gate insulating layer can be reduced. By contrast, when a material with a low dielectric constant is used for the insulating layer functioning as an interlayer film, the parasitic capacitance generated between wirings can be reduced. Thus, a material is preferably selected depending on the function of an insulating layer. Note that a material with a low dielectric constant is a material with high dielectric strength.

Examples of a high-k material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low dielectric constant include silicon oxide containing fluorine, silicon oxide containing carbon, and silicon oxide containing carbon and nitrogen. Another example is porous silicon oxide. Note that these silicon oxides can contain nitrogen.

A material that can have ferroelectricity may be used for the insulating layer included in the semiconductor device. Examples of the material that can have ferroelectricity include metal oxides such as hafnium oxide, zirconium oxide, and hafnium zirconium oxide. Examples of the material that can have ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, curopium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can have ferroelectricity also include perovskite-type oxynitrides such as SrTaO₂N and BaTaO₂N, and GaFeO₃ with a K-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, an insulating layer 130 to be described in Embodiment 4 can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

In this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer 130 needs to include a crystal. It is particularly preferable that the insulating layer include a crystal having an orthorhombic crystal structure, in which case ferroelectricity is exhibited. A crystal included in the insulating layer may have one or more of crystal structures selected from tetragonal, orthorhombic, monoclinic, and hexagonal crystal structures. Alternatively, the insulating layer may have an amorphous structure. In that case, the insulating layer may have a composite structure including an amorphous structure and a crystal structure.

A metal oxide containing one or both of hafnium and zirconium is also an insulating material having a function of capturing or fixing hydrogen. Thus, with the use of a metal oxide containing one or both of hafnium and zirconium for at least part of the gate insulating layer, hydrogen contained in the oxide semiconductor layer can be captured or fixed and the hydrogen concentration in the oxide semiconductor layer can be reduced. The transistor including the gate insulating layer can function as a ferroelectric field-effect transistor (FeFET).

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

A transistor including a metal oxide can have stable electrical characteristics when surrounded by an insulating layer having a function of inhibiting transmission of impurities and oxygen. The insulating layer having a function of inhibiting transmission of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting transmission of impurities and oxygen, a metal oxide such as aluminum oxide, magnesium oxide, germanium oxide, yttrium oxide, zirconium oxide, lanthanum oxide, neodymium oxide, hafnium oxide, or tantalum oxide, a nitride such as aluminum nitride or silicon nitride, or a nitride oxide such as silicon nitride oxide can be used.

Specific examples of the material for the insulating layer having a function of inhibiting transmission of oxygen and impurities such as water and hydrogen include metal oxides such as aluminum oxide, magnesium oxide, germanium oxide, yttrium oxide, zirconium oxide, lanthanum oxide, neodymium oxide, hafnium oxide, tantalum oxide, and an oxide containing aluminum and hafnium (hafnium aluminate). Other examples include nitrides such as aluminum nitride, aluminum titanium nitride, and silicon nitride. Other examples include a nitride oxide such as silicon nitride oxide. Examples of the material for the insulating layer having a function of inhibiting transmission of oxygen include gallium oxide.

An insulating layer that is in contact with an oxide semiconductor layer or provided in the vicinity of the oxide semiconductor layer, such as a gate insulating layer, preferably includes a region containing excess oxygen. For example, when an insulating layer including a region containing excess oxygen is in contact with an oxide semiconductor layer or positioned in the vicinity of the oxide semiconductor layer, oxygen vacancies in the oxide semiconductor layer can be reduced. For the insulating layer in which the region containing excess oxygen is easily formed, the description in Embodiment 1 can be referred to.

As the insulating layer that is in contact with the oxide semiconductor layer or provided in the vicinity of the oxide semiconductor layer, a barrier insulating layer against hydrogen is preferably used. When the insulating layer has a barrier property against hydrogen, diffusion of hydrogen into the oxide semiconductor layer can be inhibited. The barrier insulating layer against hydrogen can be rephrased as an insulating layer having a function of inhibiting diffusion of hydrogen.

Examples of an insulating material having a function of capturing or fixing hydrogen include metal oxides such as an oxide containing hafnium, an oxide containing magnesium, an oxide containing aluminum, an oxide containing aluminum and hafnium (hafnium aluminate), and hafnium silicate. Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. In addition, the thickness distribution of the film provided over the insulating layer can be uniform. Furthermore, inhibiting formation of a crystal grain boundary in the insulating layer can reduce leakage current due to the defect states in the crystal grain boundary. Thus, the insulating layer can function as an insulating film with a low leakage current.

Note that the insulating layer may partly include one or both of a crystal region and a crystal grain boundary.

Note that a function of capturing or fixing a target substance can also be referred to as a property that does not easily allow diffusion of a target substance. Thus, a function of capturing or fixing a target substance can be rephrased as a barrier property.

In this specification and the like, a barrier insulating layer refers to an insulating layer having a barrier property. In addition, the barrier property refers to a property that does not easily allow diffusion of a target substance (also referred to as a property that does not easily allow transmission of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

Examples of a material for the barrier insulating layer against hydrogen include aluminum oxide, magnesium oxide, hafnium oxide, zirconium oxide, an oxide containing aluminum and hafnium (hafnium aluminate), an oxide containing hafnium and zirconium (hafnium zirconium oxide), silicon nitride, and silicon nitride oxide.

The inorganic insulating layers given as examples of the insulating layer having a function of capturing or fixing hydrogen and the insulating layer having a function of inhibiting diffusion of hydrogen also have a barrier property against oxygen. Examples of a material for a barrier insulating layer against oxygen include an oxide containing one or both of aluminum and hafnium, magnesium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and hafnium silicate.

### [Conductive Layer]

For each of the conductive layers included in the semiconductor device (e.g., the conductive layers 205, 220, 240, 242a, 242b, 243a, 243b, 246, 255, 260, and 265), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. As an alloy containing any of the above metal elements as its component, a nitride of the alloy or an oxide of the alloy may be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, ITO, indium tin oxide containing titanium oxide, ITSO, In—Zn oxide, and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include a substrate which is an insulator substrate provided with a conductor or a semiconductor, a substrate which is a semiconductor substrate provided with a conductor or an insulator, and a substrate which is a conductor substrate provided with a semiconductor or an insulator. Alternatively, these substrates provided with elements may be used. Examples of the element provided over the substrate include a capacitor, a resistor, a switching element, a light-emitting element, and a memory element.

The above is the description of materials that can be used for the semiconductor device of this embodiment.

This embodiment can be combined with any of the other embodiments and examples as appropriate. In this specification, in the case where a plurality of structure examples are shown in one embodiment, the structure examples can be combined as appropriate.

### Embodiment 3

In this embodiment, an indium oxide film that can be used as an oxide semiconductor film of one embodiment of the present invention will be described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

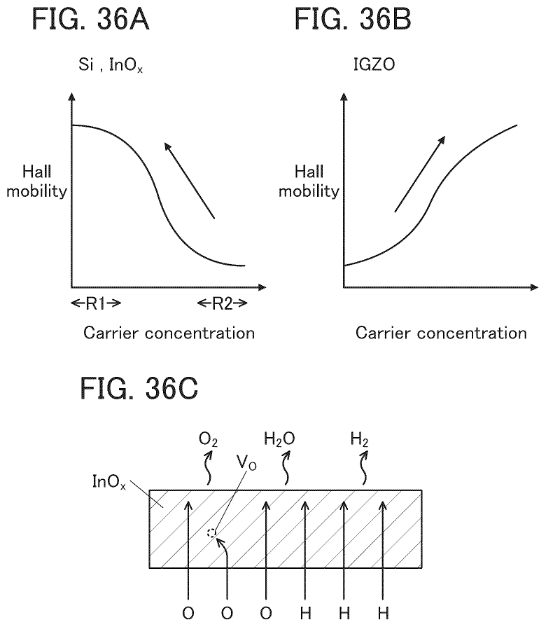

The dependence of the Hall mobility on the carrier concentration of indium oxide, silicon, and IGZO will be described. FIG. 36A is a schematic view showing the dependence of the Hall mobility on the carrier concentration of silicon (Si) and indium oxide (InO_{X}), and FIG. 36B is a schematic view showing the dependence of the Hall mobility on the carrier concentration of IGZO.

As indicated by an arrow in FIG. 36B, IGZO has a tendency in which the Hall mobility is higher as the carrier concentration is higher. By contrast, as indicated by an arrow in FIG. 36A, indium oxide has a tendency in which the Hall mobility is higher as the carrier concentration is lower (see Non-Patent Document 3). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 36A are based on the assumption of single crystal indium oxide; thus, the characteristics of non-single-crystal (e.g., polycrystal)indium oxide are sometimes different from those in FIG. 36A.

In FIG. 36A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range with a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range with a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element include titanium, zirconium, hafnium, tantalum, tungsten, molybdenum, tin, silicon, and boron. It is particularly preferable that an oxide of the element have conductivity or semiconductor properties. As a method for supplying the element that increases the carrier concentration, a method in which a film containing the element is formed to diffuse the element, an ion implantation method, an ion doping method, a plasma immersion ion implantation method, or plasma treatment can be employed. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 36A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

The expression “a semiconductor is of an i-type” can be replaced with the expression “the Fermi level (Ef) is equal to the intrinsic Fermi level (Ei) (Ef=Ei)”. As shown in FIG. 36B, the Hall mobility is lower as the carrier concentration is lower in IGZO. Accordingly, in the case where Ef eventually becomes equal to Ei, carriers disappear (i.e., the physical properties of IGZO become similar to those of an insulator) and a transistor containing IGZO cannot operate. By contrast, the Hall mobility is higher as the carrier concentration is lower in indium oxide as shown in FIG. 36A. In the case where Ef eventually becomes equal to Ei, the Hall mobility is the highest. That is, a transistor containing indium oxide can have high field-effect mobility when Ef is equal to Ei. Note that a transistor containing indium oxide has a low carrier concentration and thus tends to be normally off. Hence, a transistor containing indium oxide can have both normally-off characteristics and high field-effect mobility.

Normally off means a state where no current flows through a transistor when a potential is not applied to its gate or its gate-source voltage is 0 V. The normally-off characteristics can be evaluated using the threshold voltage (Vth) or shift value (Vsh) of a transistor. Note that Vth is calculated by a constant current method unless otherwise specified. Specifically, Vth is gate voltage (Vg) at which a value of drain current (Id)×channel length (L)/channel width (W) in the Id-Vg characteristics of a transistor is 1 nA (1×10⁻⁹ A). Vsh is gate voltage (Vg) at a point of intersection of a straight line of Id=1 pA (1×10⁻¹² A) and a tangent line of drain current (Id) on a logarithmic scale that has the highest gradient in the Id-Vg characteristics of the transistor, or gate voltage (Vg) at a point of intersection of a straight line of Id=1 pA and a straight line extrapolated from two points where the slope of Id on a logarithmic scale has the highest gradient in the Id-Vg characteristics of the transistor. For example, when at least one of Vth and Vsh is 0 or a positive value, the transistor can be regarded as being normally off.

In order that a semiconductor can be of an i-type, i.e., Ef can be equal to Ei, in a transistor containing indium oxide, the structure of a film in contact with an indium oxide film is important. For example, a transistor containing indium oxide can have a film structure in which a silicon oxide film, which is in contact with an indium oxide film, a hafnium oxide film, and a silicon nitride film are stacked. Such a film structure can achieve Ef=Ei, enabling a semiconductor device to have high reliability.

In the above film structure, a film containing oxygen, such as a silicon oxynitride film, a silicon nitride oxide film, an aluminum oxide film, or a gallium oxide film, can be used instead of the silicon oxide film. Also in the above film structure, a silicon nitride oxide film, a silicon oxynitride film, or the like can be used instead of the silicon nitride film. The hafnium oxide film that is closer to the indium oxide film than the silicon nitride film is functions as a hydrogen gettering site.

The above film structure can be regarded as a structure in which a film that is capable of supplying oxygen to the indium oxide film (e.g., the silicon oxide film), a film that is capable of gettering hydrogen (e.g., the hafnium oxide film), and a film that is capable of inhibiting entry of oxygen and hydrogen (e.g., the silicon nitride film) are stacked in this order from the indium oxide film side. With this structure, oxygen vacancies in the indium oxide film are filled with oxygen in the silicon oxide film. Moreover, hydrogen in the indium oxide film is captured in the hafnium oxide film by heat treatment or the like. Providing the silicon nitride film inhibits entry of oxygen and hydrogen from the outside. That is, the above film structure enables the indium oxide film to be closer to an i-type film. Thus, a transistor including the indium oxide film has high field-effect mobility and high reliability.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). At the crystal grain boundary, an impurity (typically, an insulating impurity, an insulating oxide, or the like) that hinders carrier flowing is likely to be segregated. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

In this specification and the like, a semiconductor layer where a crystal grain boundary is not observed in a channel formation region, a semiconductor layer where a channel formation region is included in one crystal grain, or a semiconductor layer where directions of crystal axes are the same in at least two regions in a channel formation region can be referred to as a single crystal film. A semiconductor layer where the direction of a crystal axis is continuously changed with another crystal axis or a crystal orientation as a rotation axis in one crystal grain in a channel formation region can also be referred to as a single crystal film.

Note that a channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can serve as a carrier scattering source and cause a reduction in field-effect mobility. Such impurities might inhibit crystal growth of the indium oxide film. Examples of the impurities for the indium oxide film include boron and silicon. The concentrations of these impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

An indium oxide film in this specification and the like has high film density. The theoretical film density of the indium oxide film is 7.18 g/cm³. The film density of the indium oxide film in this specification and the like ranges from 6.70 g/cm³ to 7.18 g/cm³, preferably from 6.90 g/cm³ to 7.18 g/cm³, further preferably from 7.00 g/cm³ to 7.18 g/cm³.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a TE image is pale (bright) when the film density is low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. As shown in FIG. 36C, oxygen (O) diffusing in an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes Vo, the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 36C, hydrogen diffuses in the indium oxide film. Hydrogen diffusing in the indium oxide film from the outside is transmitted through the indium oxide film and is released as a hydrogen molecule (H₂). When reacting with oxygen contained in the film, hydrogen is released as a water molecule. Note that oxygen and hydrogen described above diffuse in the indium oxide film by heat treatment. The temperature of the heat treatment is higher than or equal to 200° C. and lower than or equal to 700° C., preferably higher than or equal to 350° C. and lower than or equal to 650° C., further preferably higher than or equal to 400° C. and lower than or equal to 500° C.

As described in Embodiment 1, a transistor containing indium oxide with a small effective mass of electrons can have high on-state current or high field-effect mobility.

Table 3 shows the effective mass in each of single crystal indium oxide (here, In₂O₃) and single crystal silicon (Si). As shown in Table 3, indium oxide has features of a small effective mass of electrons and a large effective mass of holes. The effective mass of electrons of indium oxide is almost independent of its crystal orientation. Thus, a transistor containing indium oxide having crystallinity can have high field-effect mobility and high f characteristics. A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon as shown in Table 3, a transistor containing indium oxide can have higher field-effect mobility and lower off-state current than a Si transistor.

TABLE 3
Effective mass in In₂O₃

| Electron | | | |
|---|---|---|---|
| [100] orientation | [110] orientation | [111] orientation | Hole |
| 0.17 | 0.18 | 0.19 | 3.56 |

Effective mass in Si

| Electron | Hole |
|---|---|
| 0.26 | 0.17 |

At least part of this embodiment can be implemented as appropriate in combination with any of the other embodiments described in this specification.

### Embodiment 4

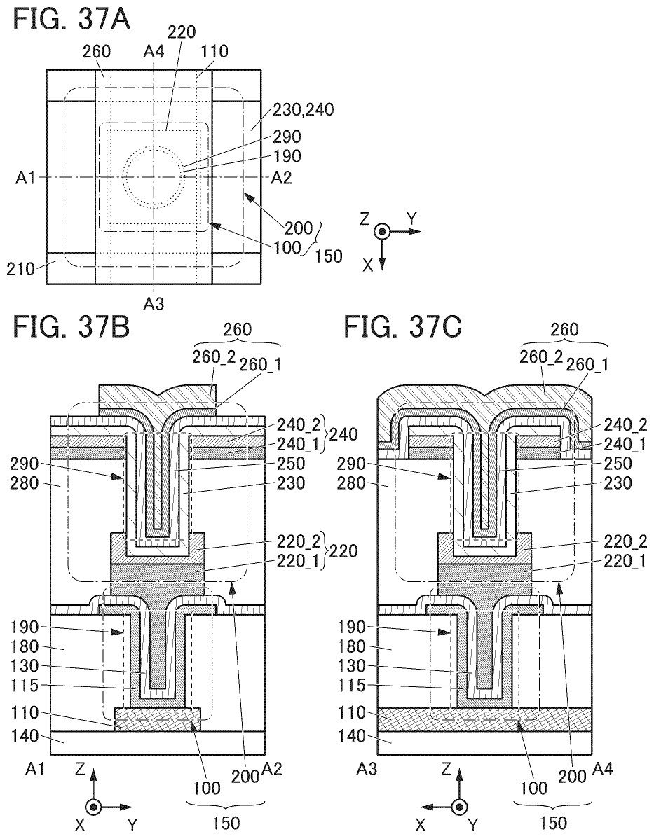

In this embodiment, memory devices of one embodiment of the present invention will be described with reference to FIGS. 37A to 37C, FIGS. 38A to 38C, FIGS. 39A to 39C, FIGS. 40A and 40B, FIGS. 41A and 41B, FIG. 42, and FIG. 43. The memory devices of one embodiment of the present invention each include a memory cell. The memory cell includes a transistor and a capacitor.

### Structure Example 1 of Memory Device

A structure of a memory device including a transistor and a capacitor is described with reference to FIGS. 37A to 37C. FIG. 37A is a plan view of a memory device including a transistor 200 and a capacitor 100. FIG. 37B is a cross-sectional view taken along the dashed-dotted line A1-A2 in FIG. 37A. FIG. 37C is a cross-sectional view taken along the dashed-dotted line A3-A4 in FIG. 37A.

The memory device illustrated in FIGS. 37A to 37C includes an insulating layer 140 over a substrate (not illustrated), a conductive layer 110 over the insulating layer 140, a memory cell 150 over the conductive layer 110, an insulating layer 180 over the conductive layer 110, and the insulating layer 280. The insulating layers 140 and 180 function as interlayer films. The conductive layer 110 functions as a wiring.

The memory cell 150 includes the capacitor 100 over the conductive layer 110 and the transistor 200 over the capacitor 100.

The capacitor 100 includes a conductive layer 115 over the conductive layer 110, the insulating layer 130 over the conductive layer 115, and the conductive layer 220_1 over the insulating layer 130. The conductive layer 220_1 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (MIM) capacitor. Note that the conductive layer 220_2 provided over the conductive layer 220_1 can be regarded as part of the upper electrode of the capacitor 100.

As illustrated in FIGS. 37B and 37C, an opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. The insulating layer 130 is placed to be positioned in the opening portion 190 at least partly. The conductive layer 220_1 is placed to be positioned in the opening portion 190 at least partly. The conductive layer 220_1 is preferably provided to fill the opening portion 190 as illustrated in FIGS. 37B and 37C. The films provided in the opening portion 190 are preferably formed by an ALD method. Thus, the coverage with the films can be improved. For example, the conductive layer 115, the insulating layer 130, and the conductive layer 220_1 are preferably formed by an ALD method.

The upper electrode and the lower electrode of the capacitor 100 face each other with the dielectric therebetween, along the side surface of the opening portion 190 as well as the bottom surface thereof; thus, the capacitance per unit area can be larger. Accordingly, the deeper the opening portion 190 is, the larger the capacitance of the capacitor 100 can be. Increasing the capacitance per unit area of the capacitor 100 in this manner allows stable reading operation of the memory device. This can also promote scaling down or high integration of the memory device.

FIGS. 37B and 37C illustrate an example in which the sidewall of the opening portion 190 is perpendicular to the top surface of the conductive layer 110 and the opening portion 190 is circular in the plan view. Such a structure enables scaling down or high integration of the memory device.

The conductive layer 115 and the insulating layer 130 are stacked along the sidewall of the opening portion 190 and the top surface of the conductive layer 110. The conductive layer 220_1 is provided over the insulating layer 130 to fill the opening portion 190. The capacitor 100 having such a structure may be referred to as a trench-type capacitor or a trench capacitor.

The insulating layer 280 is provided over the capacitor 100. The insulating layer 280 includes a portion positioned over the insulating layer 130 and a portion positioned over the conductive layer 220_2.

The transistor 200 includes the conductive layer 220 including the conductive layers 220_1 and 220_2, the conductive layer 240, the oxide semiconductor layer 230, the insulating layer 250, and the conductive layer 260.

The description in Embodiment 2 (for the transistor 200A illustrated in FIG. 5A) can be referred to for the transistor 200; thus, the detailed description thereof is omitted. The transistor included in the memory cell 150 is not limited to the transistor 200A, and any of the transistors described as examples in Embodiment 2 can be used. Alternatively, a transistor with a planar structure, a gate all around (GAA) structure, or a lateral gate all around (LGAA) structure can be used.

As illustrated in FIGS. 37A to 37C, the transistor 200 is provided to overlap with the capacitor 100. The opening portion 290 where parts of the components of the transistor 200 are provided includes a region overlapping with the opening portion 190 where parts of the components of the capacitor 100 are provided. In particular, since the conductive layer 220 has a function of one of the source electrode and the drain electrode of the transistor 200 and a function of the upper electrode of the capacitor 100, the transistor 200 and the capacitor 100 share part of the structure. With such a structure, the transistor 200 and the capacitor 100 can be provided without a significant increase in the occupation area in the plan view. Thus, the area occupied by the memory cell 150 can be reduced, so that the memory cells 150 can be arranged densely and the memory capacity of the memory device can be increased. In other words, the memory device can be highly integrated. FIGS. 37B and 37C illustrate an example in which the width of the opening portion 190 is smaller than the width of the opening portion 290. There is no particular limitation on the relationship between the width of the opening portion 190 and the width of the opening portion 290. In view of scaling down, the width of the opening portion 190 is preferably smaller than or equal to the width of the opening portion 290.

When the transistor 200 is provided above the capacitor 100, the transistor 200 is not affected by heat treatment in fabricating the capacitor 100. Thus, in the transistor 200, degradation of the electrical characteristics such as variation in threshold voltage and an increase in parasitic resistance, and an increase in variation in electrical characteristics due to the degradation of the electrical characteristics can be inhibited.

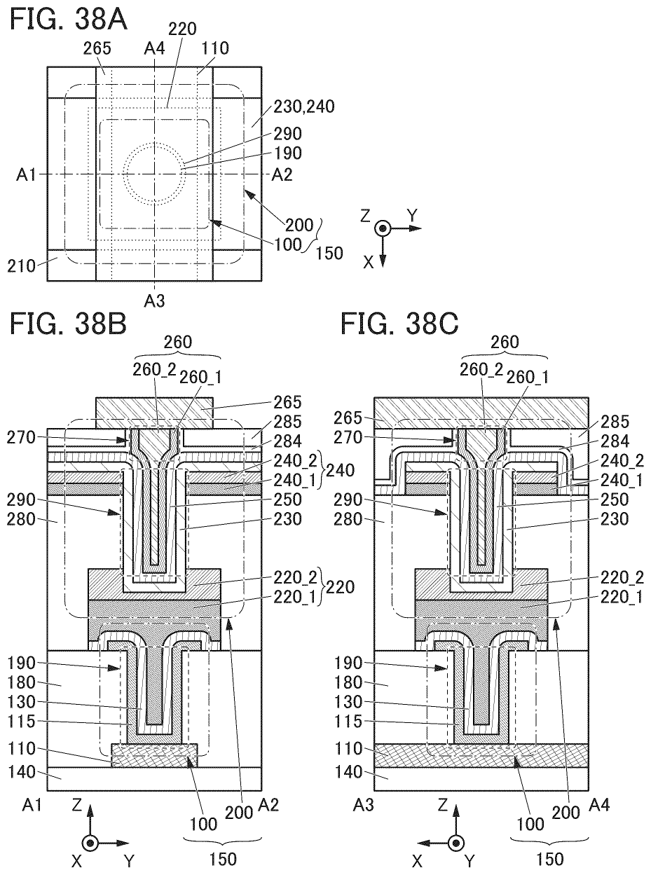

FIGS. 38A to 38C illustrate a memory device in which the transistor 200B described in Embodiment 2 is used as the transistor 200 included in the memory cell 150. FIG. 38A is a plan view of the memory device including the transistor 200 and the capacitor 100. FIG. 38B is a cross-sectional view taken along the dashed-dotted line A1-A2 in FIG. 38A. FIG. 38C is a cross-sectional view taken along the dashed-dotted line A3-A4 in FIG. 38A.

As illustrated in FIGS. 38B and 38C, the side end portion of the insulating layer 130 and the side end portion of the conductive layer 220 may be aligned or substantially aligned with each other. With such a structure, the insulating layer 130 and the conductive layer 220 can be formed using the same mask, so that the fabrication process of the memory device can be simplified.

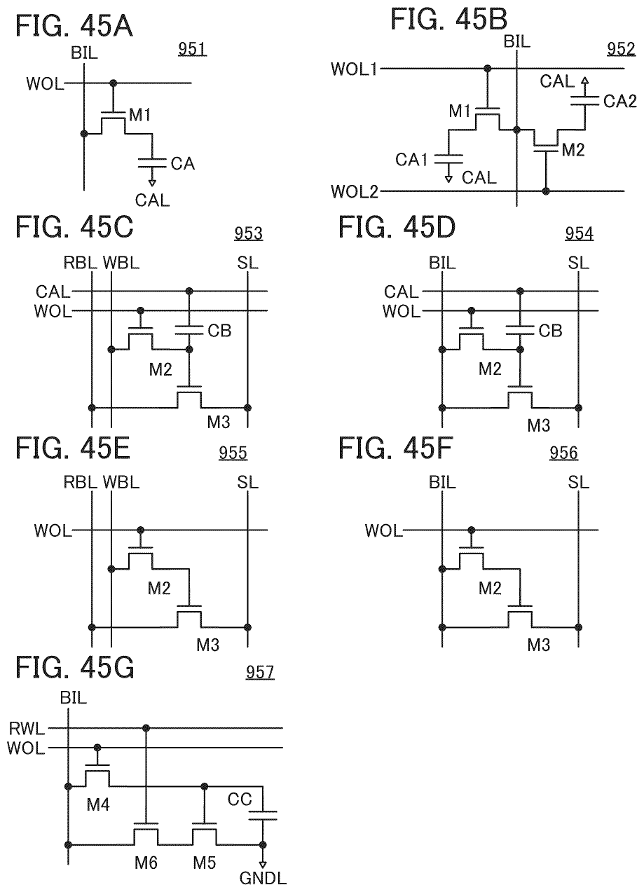

FIG. 45A is a circuit diagram of the memory device described in this embodiment. As illustrated in FIG. 45A, the structure illustrated in FIGS. 37A to 37C functions as a memory cell. A memory cell 951 includes a transistor M1 and a capacitor CA. Here, the transistor M1 corresponds to the transistor 200, and the capacitor CA corresponds to the capacitor 100. One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 260, and the wiring CAL corresponds to the conductive layer 110. As illustrated in FIGS. 37A to 37C, it is preferable that the conductive layer 260 be provided to extend in the X direction and the conductive layer 240 be provided to extend in the Y direction. With such a structure, the wiring BIL and the wiring WOL are provided to intersect with each other. The wiring CAL (the conductive layer 110) is provided parallel to the wiring WOL (the conductive layer 260) in FIG. 37A. Note that the present invention is not limited thereto. For example, the wiring CAL may be provided parallel to the wiring BIL (the conductive layer 240).

Note that the memory cell will be described in detail in a later embodiment.

### [Capacitor 100]

The capacitor 100 includes the conductive layer 115, the insulating layer 130, and the conductive layer 220_1. The conductive layer 110 is provided below the conductive layer 115. The conductive layer 115 includes a region in contact with the conductive layer 110.

The conductive layer 110 functions as the wiring CAL and can be provided in a belt-like shape, for example. Note that a belt-like shape refers to a shape including a region extending in a certain direction (e.g., the X direction, the Y direction, or the Z direction).

The conductive layer 110 can be formed as a single layer or stacked layers using any of the conductive materials described in [Conductive layer] in Embodiment 2. For example, a conductive material with high conductivity such as tungsten can be used for the conductive layer 110. With the use of a conductive material with high conductivity, the conductivity of the conductive layer 110 can be improved and the conductive layer 110 can function adequately as the wiring CAL.

For the conductive layer 115, it is preferable to use a single layer or stacked layers of a conductive material that is not easily oxidized, a conductive material having a function of inhibiting diffusion of oxygen, or the like. For example, titanium nitride, ITSO, or the like may be used. Alternatively, a structure in which titanium nitride is stacked over tungsten may be used, for example. Alternatively, a structure in which tungsten is stacked over first titanium nitride and second titanium nitride is stacked over the tungsten may be used, for example. With such a structure, the conductive layer 115 can be inhibited from being oxidized by the insulating layer 130 even when an oxide is used for the insulating layer 130. Such a structure can also inhibit oxidation of the conductive layer 115 by the insulating layer 180 even when an oxide is used for the insulating layer 180.

The insulating layer 130 is provided over the conductive layer 115. The insulating layer 130 can be provided to be in contact with the top and side surfaces of the conductive layer 115. That is, the insulating layer 130 preferably covers the side end portion of the conductive layer 115. This can prevent a short circuit between the conductive layer 115 and the conductive layer 220_1.

Alternatively, the side end portion of the insulating layer 130 and the side end portion of the conductive layer 115 may be aligned or substantially aligned with each other. With such a structure, the insulating layer 130 and the conductive layer 115 can be formed using the same mask, so that the fabrication process of the memory device can be simplified.

For the insulating layer 130, a material with a high dielectric constant (a high-k material) is preferably used. Using a high-k material for the insulating layer 130 allows the insulating layer 130 to be thick enough to inhibit leakage current and the capacitor 100 to have a sufficiently high capacitance.

The insulating layer 130 preferably has a stacked-layer structure including an insulating layer that contains a high-k material. A stacked-layer structure containing a high-k material and a material with higher dielectric strength than the high-k material is preferably used. For example, as the insulating layer 130, an insulating film in which zirconium oxide, aluminum oxide, and zirconium oxide are stacked in this order can be used. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Alternatively, a material that can have ferroelectricity may be used for the insulating layer 130. The description in Embodiment 2 can also be referred to for the details of the material that can have ferroelectricity.

A metal oxide containing one or both of hafnium and zirconium is preferable as the insulating layer 130 because the metal oxide can have ferroelectricity even when being a thin film of several nanometers. The thickness of the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). For example, the thickness is preferably greater than or equal to 8 nm and less than or equal to 12 nm. With the use of the ferroelectric layer that can have a small thickness, the capacitor 100 can be combined with a miniaturized semiconductor element such as a transistor to fabricate a semiconductor device.

A metal oxide containing one or both of hafnium and zirconium is preferable as the insulating layer 130 because the metal oxide can have ferroelectricity even with a minute area. For example, a ferroelectric layer can have ferroelectricity even with an area (occupation area) less than or equal to 100 μm², less than or equal to 10 μm², less than or equal to 1 μm², or less than or equal to 0.1 μm² in the plan view. Furthermore, even with an area less than or equal to 10000 nm² or less than or equal to 1000 nm², a ferroelectric layer can have ferroelectricity in some cases. With a small-area ferroelectric layer, the area occupied by the capacitor 100 can be reduced.

A ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is connected to one terminal of the ferroelectric capacitor. Thus, in the case of using a ferroelectric capacitor as the capacitor 100, the memory device described in this embodiment functions as a ferroelectric memory.

The conductive layer 220_1 is provided in contact with part of the top surface of the insulating layer 130. The side end portion of the conductive layer 220_1 is preferably positioned inward from the side end portion of the conductive layer 115 in both the X direction and the Y direction. In the structure in which the insulating layer 130 covers the side end portion of the conductive layer 115, the side end portion of the conductive layer 220_1 may be positioned outward from the side end portion of the conductive layer 115.

The insulating layer 180 functions as an interlayer film and thus preferably has a low dielectric constant. In the case where a material with a low dielectric constant is used for an interlayer film, parasitic capacitance generated between wirings can be reduced. As the insulating layer 180, an insulating layer containing a material with a low dielectric constant can be used as a single layer or stacked layers.

Although the insulating layer 180 has a single-layer structure in FIGS. 37B and 37C, the present invention is not limited thereto. The insulating layer 180 may have a stacked-layer structure of two layers or three or more layers.

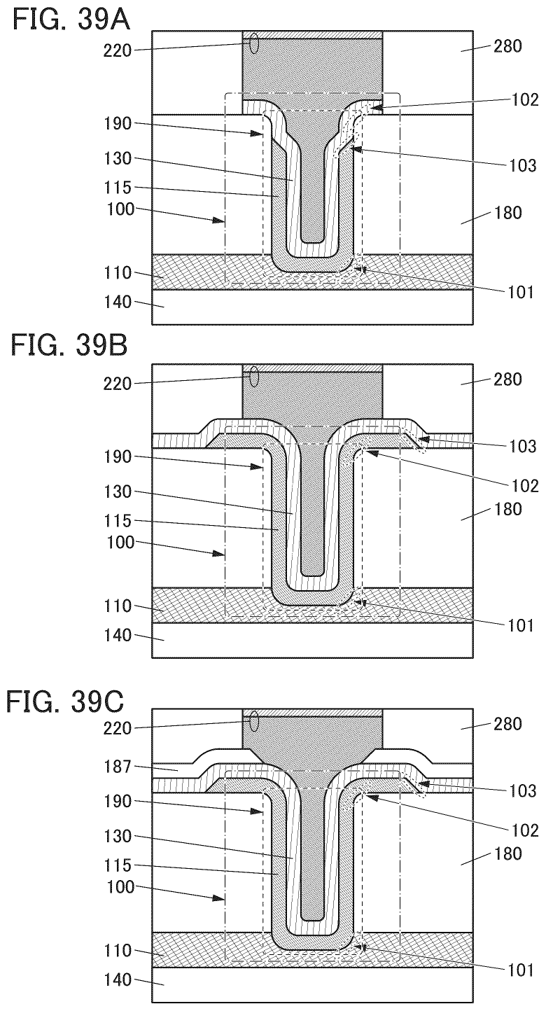

FIG. 39A illustrates an example in which the conductive layer 115 includes a region 101 with a curved corner in the depression of the conductive layer 110. Thus, electric field concentration on the insulating layer 130 in the vicinity of the region 101 can be inhibited as compared with the case where the region 101 has an angular portion (a right angle or an acute angle), for example. An end portion 103 of the conductive layer 115 is provided at a lower level than the top surface of the insulating layer 180 with respect to a reference surface. Accordingly, electric field concentration on the insulating layer 130 in the vicinity of the end portion 103 can be inhibited as compared with the case where the end portion 103 is positioned above the insulating layer 180. When electric field concentration on the insulating layer 130 is inhibited in this manner, the dielectric breakdown of the insulating layer 130 can be inhibited, so that a highly reliable memory device can be provided.

FIG. 39B illustrates an example in which the end portion 103 illustrated in FIG. 39A is positioned over the insulating layer 180. In the example illustrated in FIG. 39B, a region 102 from the top surface of the insulating layer 180 to the side surface of the opening portion 190 has a curved portion. In the example illustrated in FIG. 39B, the end portion 103 has a tapered shape. When the region 102 has a curved portion and the end portion 103 has a tapered shape, electric field concentration on the insulating layer 130 in the vicinity of the region 102 and in the vicinity of the end portion 103 can be inhibited even when the end portion 103 is positioned over the insulating layer 180. Accordingly, the dielectric breakdown of the insulating layer 130 is inhibited, so that a highly reliable memory device can be provided.

FIG. 39C illustrates an example in which an insulating layer 187 is provided over the insulating layer 130 illustrated in FIG. 39B, for example, over a region of the insulating layer 130 that overlaps with the insulating layer 180. Providing the insulating layer 187 can suitably inhibit electric field concentration on the insulating layer 130 in some cases.

### Structure Example 2 of Memory Device

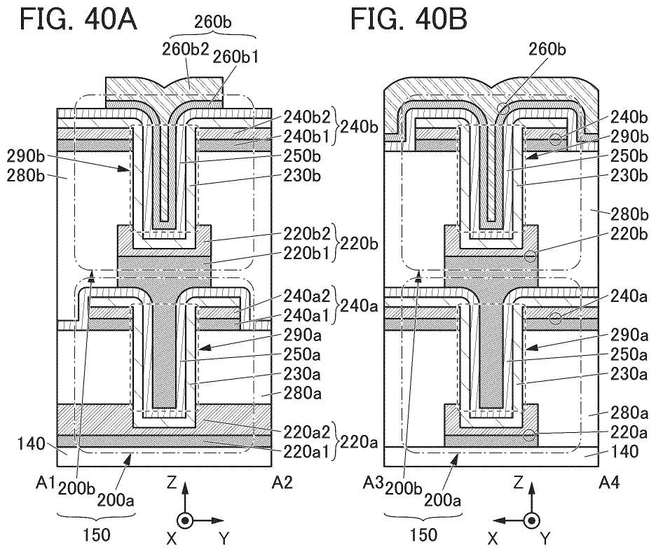

FIGS. 40A and 40B are cross-sectional views of a memory device including a transistor 200a and a transistor 200b.

The memory device illustrated in FIGS. 40A and 40B includes the insulating layer 140 over a substrate (not illustrated), the memory cell 150 over the insulating layer 140, an insulating layer 280a over the insulating layer 140, and an insulating layer 280b above the insulating layer 280a. The insulating layers 140, 280a, and 280b function as interlayer films.

The memory cell 150 includes the transistor 200a over the insulating layer 140 and the transistor 200b over the transistor 200a.

The description of the transistor 200 in Embodiment 2 (the transistor 200A illustrated in FIG. 5A) can be referred to for the transistors 200a and 200b; thus, the detailed description thereof is omitted. For example, the description with reference to FIG. 5A can be referred to for the structures of the conductive layer 220a, the oxide semiconductor layer 230a, and the like by replacing the conductive layer 220 with the conductive layer 220a and replacing the oxide semiconductor layer 230 with the oxide semiconductor layer 230a. For another example, the description with reference to FIG. 5A can be referred to for the structures of the conductive layer 220b, the oxide semiconductor layer 230b, and the like by replacing the conductive layer 220 with the conductive layer 220b and replacing the oxide semiconductor layer 230 with the oxide semiconductor layer 230b.

The insulating layers 280a and 280b can each have a structure similar to the structure that can be employed for the insulating layer 280.

The transistors included in the memory cell 150 are not limited to the combination of the transistors 200a and 200b, and one or more kinds of the transistors described in Embodiment 2 can be used.

In the memory cell 150 illustrated in FIGS. 40A and 40B, capacitance generated between the conductive layer 220b and the conductive layer 240a can be used; thus, data can be retained without formation of an additional capacitor.

The shortest distance from the top surface of the conductive layer 240a to the conductive layer 220b is preferably shorter than the shortest distance from the top surface of the conductive layer 240b to the gate wiring (the conductive layer 260b in FIG. 40A). Thus, the capacitance generated between the conductive layer 220b and the conductive layer 240a can be increased. In addition, the parasitic capacitance generated between the conductive layer 240b and the gate wiring can be reduced. The transistor 200b can have the structure of the transistor 200B described in Embodiment 2, for example.

As illustrated in FIGS. 40A and 40B, the transistor 200b is provided to overlap with the transistor 200a. An opening portion 290b where parts of the components of the transistor 200b are provided includes a region overlapping with an opening portion 290a where parts of the components of the transistor 200a are provided. In particular, since the conductive layer 220b has a function of one of the source electrode and the drain electrode of the transistor 200b and a function of the gate electrode of the transistor 200a, the transistor 200b and the transistor 200a share part of the structure. With such a structure, the transistor 200b and the transistor 200a can be provided without a significant increase in the occupation area in the plan view. Thus, the area occupied by the memory cell 150 can be reduced, so that the memory cells 150 can be arranged densely and the memory capacity of the memory device can be increased. In other words, the memory device can be highly integrated.

FIG. 45E is a circuit diagram of the memory device described in this embodiment. As illustrated in FIG. 45E, the structure illustrated in FIGS. 40A and 40B functions as a memory cell. A memory cell 955 includes a transistor M2 and a transistor M3. Here, the transistor M2 corresponds to the transistor 200b, and the transistor M3 corresponds to the transistor 200a.

One of a source and a drain of the transistor M2 is connected to a gate of the transistor M3. The other of the source and the drain of the transistor M2 is connected to a wiring WBL. A gate of the transistor M2 is connected to the wiring WOL. One of a source and a drain of the transistor M3 is connected to a wiring RBL. The other of the source and the drain of the transistor M3 is connected to a wiring SL.

Here, the wiring WBL corresponds to the conductive layer 240b, and the wiring WOL corresponds to the conductive layer 260b. As illustrated in FIGS. 40A and 40B, it is preferable that the conductive layer 260b be provided to extend in the X direction and the conductive layer 240b be provided to extend in the Y direction. With such a structure, the wiring WBL and the wiring WOL are provided to intersect with each other.

The transistor M2 may include a back gate. Similarly, the transistor M3 may include a back gate.

### Structure Example 3 of Memory Device

The memory cell 150 including the transistor 200 and the capacitor 100 described in this embodiment can be used as a memory cell of the memory device. The transistor 200 is a transistor whose channel is formed in a semiconductor layer containing an oxide semiconductor. Since the transistor 200 has a low off-state current, a memory device including the transistor 200 can retain stored data for a long time. In other words, such a memory device does not require refresh operation or has an extremely low frequency of refresh operation, leading to a sufficient reduction in power consumption. The transistor 200 has high frequency characteristics and thus enables the memory device to perform reading and writing at high speed.

The memory cells 150 can be arranged in a matrix three-dimensionally to form a memory cell array.

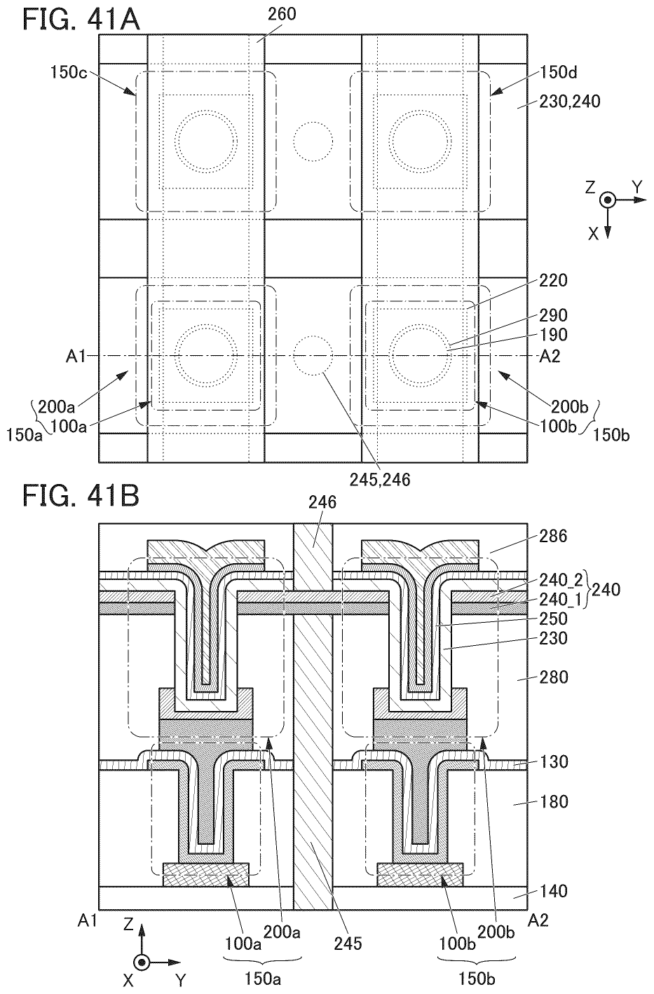

FIG. 41A is a plan view of a memory device. FIG. 41A illustrates an example in which 2×2 memory cells (memory cells 150a to 150d) are arranged in the X direction and the Y direction.

FIG. 41B is a cross-sectional view taken along the dashed-dotted line A1-A2 in FIG. 41A. In FIGS. 41A and 41B, two memory cells (the memory cells 150a and 150b in FIG. 41B) are connected to a common wiring (the conductive layer 246).

FIG. 45B is a circuit diagram corresponding to two memory cells. As illustrated in FIG. 45B, a memory device 952 includes two memory cells; one of the memory cells includes the transistor M1 and a capacitor CA1, and the other of the memory cells includes the transistor M2 and a capacitor CA2. In the case where FIG. 45B corresponds to FIG. 41B, for example, the transistor M1 corresponds to the transistor 200a, the capacitor CA1 corresponds to a capacitor 100a, the transistor M2 corresponds to the transistor 200b, and the capacitor CA2 corresponds to a capacitor 100b.

One of the source and the drain of the transistor M1 is connected to one of a pair of electrodes of the capacitor CA1. The other of the source and the drain of the transistor M1 is connected to the wiring BIL. The gate of the transistor M1 is connected to a wiring WOL1. The other of the pair of electrodes of the capacitor CA is connected to the wiring CAL. One of the source and the drain of the transistor M2 is connected to one of a pair of electrodes of the capacitor CA2. The other of the source and the drain of the transistor M2 is connected to the wiring BIL. The gate of the transistor M2 is connected to a wiring WOL2. The other of the pair of electrodes of the capacitor CA2 is connected to the wiring CAL.

Here, the wiring BIL corresponds to the conductive layer 240, the wiring WOL1 corresponds to the conductive layer 260, the wiring WOL2 corresponds to another conductive layer 260, and the wiring CAL corresponds to the conductive layer 110.

The memory cells 150a and 150b illustrated in FIGS. 41A and 41B each have a structure similar to that of the memory cell 150. The memory cell 150a includes the capacitor 100a and the transistor 200a, and the memory cell 150b includes the capacitor 100b and the transistor 200b. The memory cells 150c and 150d illustrated in FIG. 41A each have a structure similar to that of the memory cell 150. Thus, in the memory device illustrated in FIGS. 41A and 41B, components having the same functions as the components of the memory device illustrated in FIGS. 37A to 37C are denoted by the same reference numerals. The description of the memory cell 150 in <Structure example 1 of memory device> can be referred to for the details of the memory cells 150a to 150d.

As illustrated in FIGS. 41A and 41B, the conductive layer 260 functioning as the wiring WOL is provided in each of the memory cells 150a and 150b. As illustrated in FIG. 41A, one conductive layer 260 is shared by the memory cells 150a and 150c, and another conductive layer 260 is shared by the memory cells 150b and 150d. One conductive layer 240 functioning as part of the wiring BIL is shared by the memory cells 150a and 150b. That is, the conductive layer 240 is in contact with the oxide semiconductor layer 230 of the memory cell 150a and the oxide semiconductor layer 230 of the memory cell 150b. Another conductive layer 240 is shared by the memory cells 150c and 150d.

Here, the memory device illustrated in FIGS. 41A and 41B includes a conductive layer 245 and the conductive layer 246 functioning as plugs (also can be referred to as connection electrodes) connected to the memory cells 150a and 150b. The conductive layer 245 is placed in an opening portion formed in the insulating layers 140, 180, 130, and 280 and is in contact with the bottom surface of the conductive layer 240_1. The conductive layer 246 is placed in an opening portion formed in an insulating layer 286, the insulating layer 250, and the oxide semiconductor layer 230 and is in contact with the top surface of the conductive layer 240_2. Note that any of the conductive materials that can be used for the conductive layer 240 can be used for the conductive layers 245 and 246, for example.

The conductive layer 246 can be in contact with the top surface of the conductive layer 240_1. Alternatively, the conductive layer 246 can be in contact with the top surface of the oxide semiconductor layer 230. That is, the conductive layer 240_2 may have an opening portion in a position overlapping with the conductive layer 246. The oxide semiconductor layer 230 does not necessarily have an opening portion in a position overlapping with the conductive layer 246. As a connection portion between the memory cell and the plug, a layer having a low contact resistance with the conductive layer 246 among the layers included in the conductive layer 240 and the oxide semiconductor layer 230 is preferably in contact with the conductive layer 246.

Similarly, the conductive layer 245 can be in contact with the bottom surface of the conductive layer 240_2 or the bottom surface of the oxide semiconductor layer 230. That is, the conductive layer 240_1 may have an opening portion in a position overlapping with the conductive layer 246. Among the layers included in the conductive layer 240 and the oxide semiconductor layer 230, a layer having a low contact resistance with the conductive layer 245 is preferably in contact with the conductive layer 245.

Among the layers included in the conductive layer 240 and the oxide semiconductor layer 230, a layer with a low wiring resistance is preferably in contact with the conductive layers 245 and 246.

The conductive layers 245 and 246 each function as a plug or a wiring for connecting the memory cells 150a and 150b to a wiring, an electrode, a terminal, or a circuit element such as a switch, a transistor, a capacitor, an inductor, a resistor, or a diode. For example, the conductive layer 245 can be connected to a sense amplifier (not illustrated) provided below the memory device illustrated in FIG. 41B, and the conductive layer 246 can be connected to a similar memory device (not illustrated) provided above the memory device illustrated in FIG. 41B. In that case, the conductive layers 245 and 246 function as part of the wiring BIL. When the memory device or the like is provided above or below the memory device illustrated in FIG. 41B in this manner, the memory capacity per unit area can be increased.

The memory cells 150a and 150b have a line-symmetric structure with a perpendicular bisector of the dashed-dotted line A1-A2 as the symmetric axis. Thus, the transistors 200a and 200b are also placed symmetrically with the conductive layers 245 and 246 therebetween. The conductive layer 240 has a function of the other of the source electrode and the drain electrode of the transistor 200a and a function of the other of the source electrode and the drain electrode of the transistor 200b. The transistors 200a and 200b share the conductive layers 245 and 246 functioning as plugs. With the above connection structure between the two transistors and the plugs, a memory device that can be scaled down or highly integrated can be provided.

Note that the conductive layer 110 functioning as the wiring CAL may be provided in each of the memory cells 150a and 150b or may be provided in common to the memory cells 150a and 150b. However, as illustrated in FIG. 41B, the conductive layer 110 is provided to be apart from the conductive layer 245 so that the conductive layers 110 and 245 are not short-circuited.

The memory cell 150 illustrated in FIGS. 38A to 38C may be used as the memory cell illustrated in FIGS. 41A and 41B. When the side end portion of the insulating layer 130 and the side end portion of the conductive layer 220 are aligned with each other, the insulating layer 130 does not overlap with the conductive layer 245. This makes processing at the time of forming the opening portion in which the conductive layer 245 is provided relatively easy.

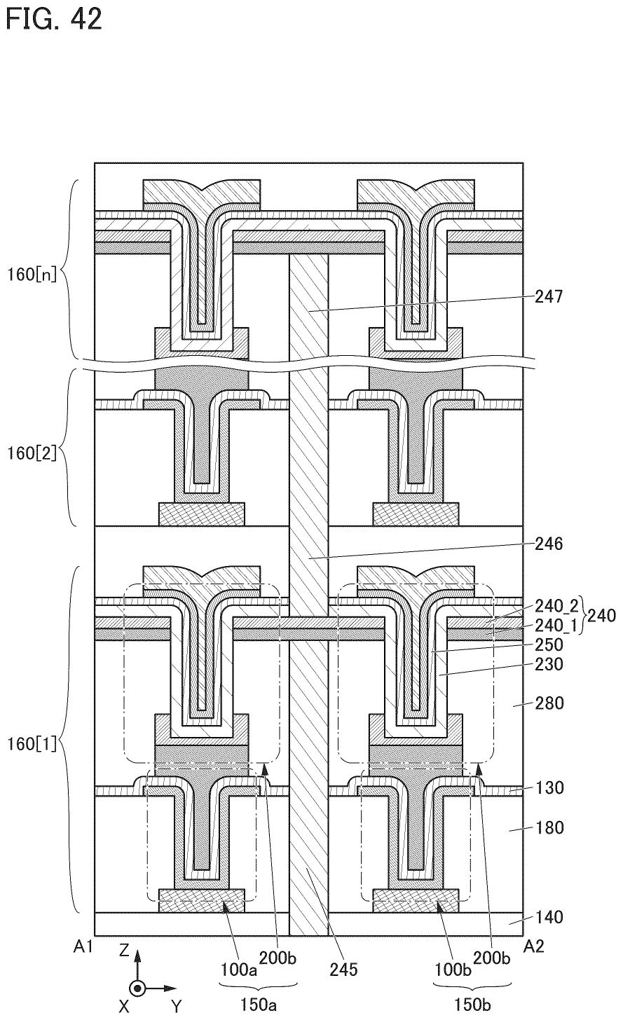

FIG. 42 illustrates an example in which n layers (n is an integer greater than or equal to 3) each including the four memory cells illustrated in FIG. 41A are stacked in the Z direction. FIG. 42 is a cross-sectional view taken along the dashed-dotted line A1-A2 in FIG. 41A.

A memory device illustrated in FIG. 42 includes n memory layers 160. Specifically, a memory layer 160[2] is provided over a memory layer 160[1], (n−2) memory layers are provided over the memory layer 160[2], and a memory layer 160[n] is provided as the uppermost layer. There is no particular limitation on the number of memory cells included in one memory layer 160, and two or more memory cells can be included. Through the conductive layer 245, the conductive layer 246, a conductive layer 247, and the like, memory cells included in the n memory layers 160 are connected to a sense amplifier (not illustrated) provided below the n memory layers 160.

FIG. 42 illustrates an example in which the conductive layer 245 is in contact with the bottom surface of the conductive layer 240 and the conductive layer 246 is in contact with the top surface of the conductive layer 240. As described above, a connection portion between the plug such as the conductive layer 245 or the conductive layer 246 and each memory cell can have any of a variety of modes and is not limited to the structure in FIG. 42.

When a plurality of memory cells are stacked as illustrated in FIG. 42, the cells can be provided in an integrated manner without increasing the area occupied by the memory cell array. That is, a 3D memory cell array can be formed.

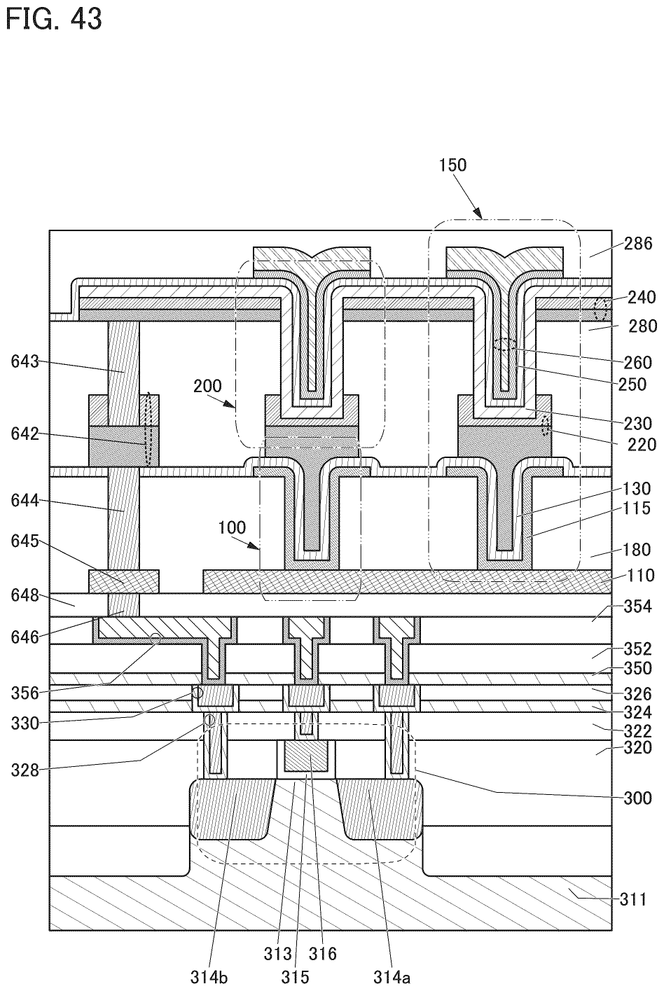

FIG. 43 illustrates a cross-sectional structure example of a memory device in which a layer including a memory cell is stacked over a layer including a driver circuit provided with a sense amplifier.

In FIG. 43, the memory cell 150 (the transistor 200 and the capacitor 100) is provided above a transistor 300.

The transistor 300 is one of the transistors included in the sense amplifier.

The description of the memory cell 150 in <Structure example 1 of memory device> can be referred to for the memory cell 150 illustrated in FIG. 43.

When the sense amplifier is provided to overlap with the memory cell 150 as illustrated in FIG. 43, the bit line can be shortened. Accordingly, the bit line capacitance can be reduced and the memory device can be driven at high speed.

The memory device illustrated in FIG. 43 can correspond to a semiconductor device 900 described in Embodiment 5. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is part of the substrate 311, and a low-resistance region 314a and a low-resistance region 314b functioning as a source region and a drain region. The transistor 300 may be either a p-channel transistor or an n-channel transistor. The substrate 311 preferably includes a silicon-based semiconductor, specifically, single crystal silicon.

As the substrate 311, a structure body in which a single crystal oxide semiconductor film (typically, indium oxide film) is provided over a stabilized zirconia substrate can also be used. As described in Embodiment 1 and the like, an indium oxide film formed over a stabilized zirconia substrate includes a single crystal. With the use of part of the indium oxide film as the semiconductor region 313, the field-effect mobility and reliability of the transistor 300 can be increased.

In the transistor 300 illustrated in FIG. 43, the semiconductor region 313 (part of the substrate 311) in which a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 43 is just an example and is not limited to having the structure illustrated therein; an appropriate transistor can be used in accordance with a circuit configuration or a driving method.

A wiring layer including an interlayer film, a wiring, a plug, and the like may be provided between components. A plurality of wiring layers can be provided in accordance with the design. Here, a plurality of conductive layers functioning as plugs or wirings are collectively denoted by the same reference numeral in some cases. In this specification and the like, a wiring and a plug connected to the wiring may be a single component. That is, part of a conductive layer functions as a wiring in some cases and part of a conductive layer functions as a plug in other cases.

For example, an insulating layer 320, an insulating layer 322, an insulating layer 324, and an insulating layer 326 are stacked over the transistor 300 in this order as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIG. 43, an insulating layer 350, an insulating layer 352, and an insulating layer 354 are stacked in this order. Furthermore, a conductive layer 356 is formed in the insulating layers 350, 352, and 354. The conductive layer 356 functions as a plug or a wiring.

As the insulating layer 352, the insulating layer 354, and the like functioning as interlayer films, the above-described insulating layer that can be used for the semiconductor device or the memory device can be used.

As the conductive layer functioning as a plug or a wiring, such as the conductive layer 328, the conductive layer 330, and the conductive layer 356, any of the conductive materials that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 200 is connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in the insulating layer 280. The conductive layers 642 and 220 can be formed using the same material in the same step. The conductive layer 644 is embedded in the insulating layers 180 and 130. The conductive layer 645 is embedded in the insulating layer 180. The conductive layers 645 and 110 can be formed using the same material in the same step. The conductive layer 646 is embedded in an insulating layer 648. The transistor 300 and the conductive layer 110 are insulated from each other by the insulating layer 648.

This embodiment can be combined with any of the other embodiments as appropriate. In this specification, in the case where a plurality of structure examples are shown in one embodiment, the structure examples can be combined as appropriate.

### Embodiment 5

In this embodiment, the semiconductor device 900 of one embodiment of the present invention will be described. The semiconductor device 900 can function as a memory device.

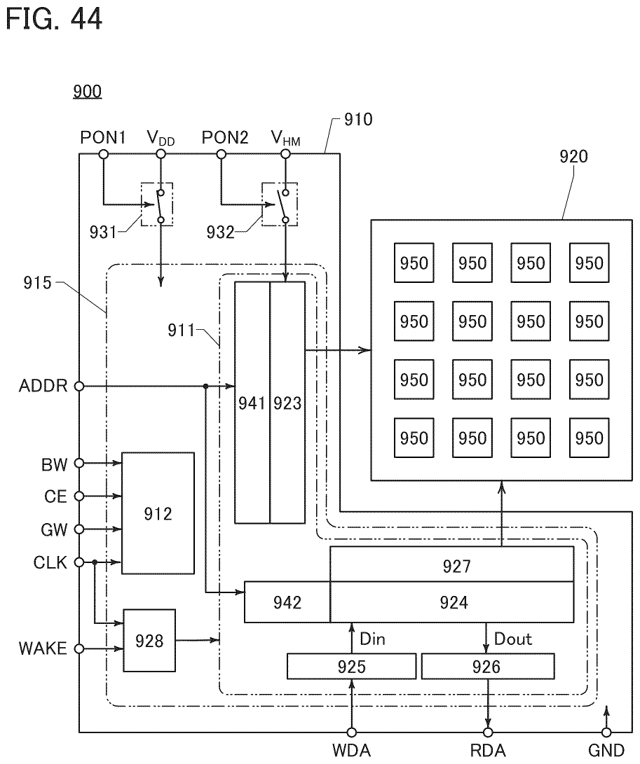

FIG. 44 is a block diagram illustrating a structure example of the semiconductor device 900. The semiconductor device 900 illustrated in FIG. 44 includes a driver circuit 910 and a memory array 920. The memory array 920 includes at least one memory cell 950. FIG. 44 illustrates an example in which the memory array 920 includes a plurality of memory cells 950 arranged in a matrix.

The memory device (e.g., the memory cell 150) described in Embodiment 4 can be used as the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is supplied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, a function of reading data from the memory cell 950, and a function of retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling supply of V_{DD} to the peripheral circuit 915. The PSW 932 has a function of controlling supply of V_{HM} to the row driver 923. Here, in the semiconductor device 900, a high power supply potential is V_{DD} and a low power supply potential is a ground potential (GND). In addition, V_{HM} is a high power supply potential used for setting a word line at a high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 44 but can be more than one. In that case, a power switch is provided for each power domain.

Structure examples of memory cells each of which can be used as the memory cell 950 are described with reference to FIGS. 45A to 45G.

### [DOSRAM]

FIG. 45A illustrates a circuit configuration example of a memory cell for a DRAM. In this specification and the like, a DRAM including an OS transistor is referred to as a dynamic oxide semiconductor random access memory (DOSRAM). The memory cell 951 includes the transistor M1 and the capacitor CA.

Note that the transistor M1 may include a front gate (sometimes simply referred to as a gate) and a back gate. Here, the back gate may be connected to a wiring supplied with a constant potential or a signal, and the front gate and the back gate may be connected to each other. A first terminal of the transistor M1 is connected to a first terminal of the capacitor CA. A second terminal of the transistor M1 is connected to the wiring BIL. A gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (sometimes referred to as a reference potential) is preferably applied to the wiring CAL.

Data writing and data reading are performed as follows: a high-level potential is applied to the wiring WOL to turn on the transistor M1 so that electrical continuity is established between the wiring BIL and the first terminal of the capacitor CA (current can flow therebetween).

The memory cell that can be used as the memory cell 950 is not limited to the memory cell 951, and the circuit configuration can be changed. For example, the memory cell 951 does not necessarily include the capacitor CA or the wiring CAL, and the first terminal of the transistor M1 may be in an electrically floating state.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cell 951.

As illustrated in FIG. 45B, one wiring BIL can be provided to be shared by two or more memory cells of DRAM.

### [NOSRAM]

FIG. 45C illustrates a circuit configuration example of a gain-cell memory cell including two transistors and one capacitor. A memory cell 953 includes the transistor M2, the transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. The gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed as follows: a high-level potential is applied to the wiring WOL to turn on the transistor M2 so that electrical continuity is established between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. Current flowing between the source and the drain of the transistor M3 and the potential of the first terminal of the transistor M3 are determined by the potential of the gate of the transistor M3 and the potential of the second terminal of the transistor M3. Accordingly, by reading the potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

For another example, one wiring BIL may be provided instead of the wiring WBL and the wiring RBL. A circuit configuration example of the memory cell is illustrated in FIG. 45D. In a memory cell 954, one wiring BIL is provided instead of the wiring WBL and the wiring RBL in the memory cell 953, and the second terminal of the transistor M2 and the first terminal of the transistor M3 are connected to the wiring BIL. That is, one wiring BIL operates as the write bit line and the read bit line in the memory cell 954.

The memory cell 955 illustrated in FIG. 45E is an example in which the capacitor CB and the wiring CAL in the memory cell 953 are omitted. A memory cell 956 illustrated in FIG. 45F is an example in which the capacitor CB and the wiring CAL in the memory cell 954 are omitted. Such configurations enable high integration of the memory cells.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953 to 956.

The memory cells 953 to 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When an OS transistor is used as the transistor M3, the memory cell can be configured with only n-channel transistors.

FIG. 45G illustrates a gain-cell memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed as follows: a high-level potential is applied to the wiring WOL to turn on the transistor M4 so that electrical continuity is established between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than an OS transistor depending on the crystal state of silicon used in a semiconductor layer, for example.

When OS transistors are used as the transistors M5 and M6, the memory cell can be configured with only n-channel transistors.

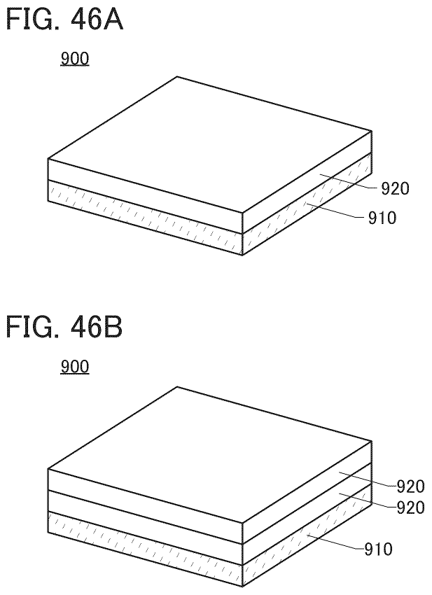

The driver circuit 910 and the memory array 920 included in the semiconductor device 900 may be provided on the same plane. Alternatively, as illustrated in FIG. 46A, the driver circuit 910 and the memory array 920 may be provided to overlap with each other. Providing the driver circuit 910 and the memory array 920 to overlap with each other can shorten a signal propagation distance. As illustrated in FIG. 46B, a plurality of memory arrays 920 may be stacked over the driver circuit 910.

Next, description is made on an example of an arithmetic processing device that can include the semiconductor device such as the memory device described above.

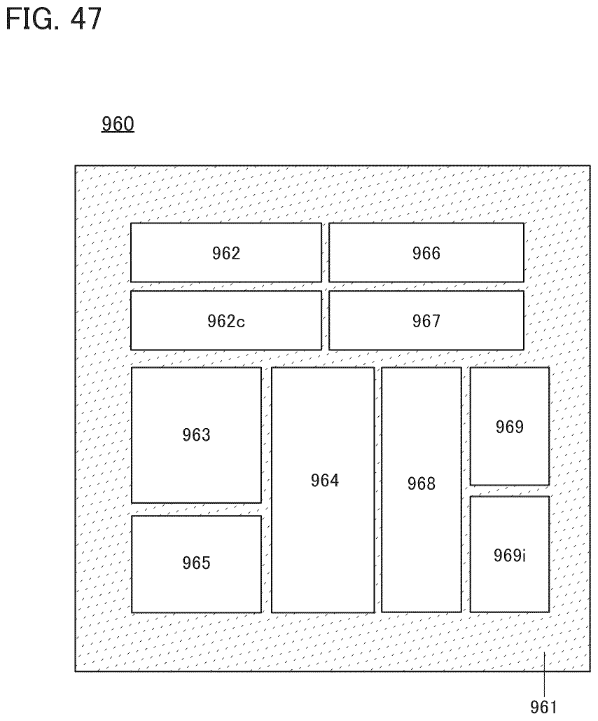

FIG. 47 is a block diagram of an arithmetic device 960. The arithmetic device 960 illustrated in FIG. 47 can be used as a CPU, for example. The arithmetic device 960 can also be used as a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 47 includes, over a substrate 961, an arithmetic logic unit (ALU) 962, an ALU controller 962c, an instruction decoder 963, an interrupt controller 964, a timing controller 965, a register 966, a register controller 967, a bus interface 968, a cache 969, and a cache interface 969i. A semiconductor substrate, an SOI substrate, a glass substrate, or the like is used as the substrate 961. The arithmetic device 960 may also include a rewritable ROM and a ROM interface. The cache 969 and the cache interface 969i may be provided in a separate chip.

The cache 969 is connected via the cache interface 969i to a main memory provided in another chip. The cache interface 969i has a function of supplying part of data retained in the main memory to the cache 969. The cache interface 969i also has a function of outputting part of data retained in the cache 969 to the ALU 962, the register 966, or the like through the bus interface 968.

As described later, the memory array 920 can be stacked over the arithmetic device 960. The memory array 920 can be used as a cache. Here, the cache interface 969i may have a function of supplying data retained in the memory array 920 to the cache 969. Moreover, in that case, the driver circuit 910 is preferably included in part of the cache interface 969i.

Note that it is also possible that the cache 969 is not provided and only the memory array 920 is used as a cache.

The arithmetic device 960 illustrated in FIG. 47 is just an example with a simplified structure, and the actual arithmetic device 960 has a variety of structures depending on the application. For example, what is called a multicore structure is preferably employed in which a plurality of cores each including the arithmetic device 960 in FIG. 47 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 968 is input to the instruction decoder 963 and decoded, and then input to the ALU controller 962c, the interrupt controller 964, the register controller 967, and the timing controller 965.

The ALU controller 962c, the interrupt controller 964, the register controller 967, and the timing controller 965 conduct various controls in accordance with the decoded instruction. Specifically, the ALU controller 962c generates signals for controlling the operation of the ALU 962. The interrupt controller 964 judges and processes an interrupt request from an external input/output device, a peripheral circuit, or the like on the basis of its priority, a mask state, or the like while the arithmetic device 960 is executing a program. The register controller 967 generates the address of the register 966, and reads/writes data from/to the register 966 in accordance with the state of the arithmetic device 960.

The timing controller 965 generates signals for controlling operation timings of the ALU 962, the ALU controller 962c, the instruction decoder 963, the interrupt controller 964, and the register controller 967. For example, the timing controller 965 includes an internal clock generator for generating an internal clock signal on the basis of a reference clock signal, and supplies the internal clock signal to the above circuits.

In the arithmetic device 960 illustrated in FIG. 47, the register controller 967 selects operation of retaining data in the register 966 in accordance with an instruction from the ALU 962. That is, the register controller 967 selects whether data is retained by a flip-flop or by a capacitor in a memory cell included in the register 966. When data retention by the flip-flop is selected, a power supply potential is supplied to the memory cell in the register 966. When data retention by the capacitor is selected, the data is rewritten into the capacitor, and supply of the power supply potential to the memory cell in the register 966 can be stopped.

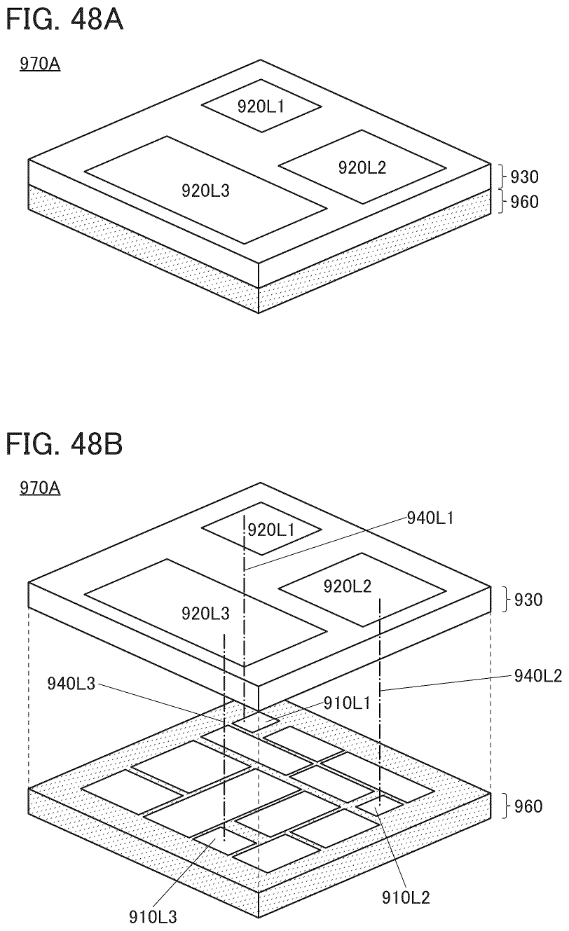

The memory array 920 and the arithmetic device 960 can be provided to overlap with each other. FIGS. 48A and 48B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 48B.

Providing the arithmetic device 960 and the layer 930 including the memory arrays to overlap with each other can shorten the connection distance therebetween. Accordingly, the communication speed therebetween can be increased. Moreover, a short connection distance leads to lower power consumption.

As a method for stacking the arithmetic device 960 and the layer 930 including the memory arrays, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 969 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 969 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 48B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 969i or the driver circuit 910L1 may be connected to the cache interface 969i. Similarly, each of the driver circuits 910L2 and 910L3 may function as part of the cache interface 969i or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

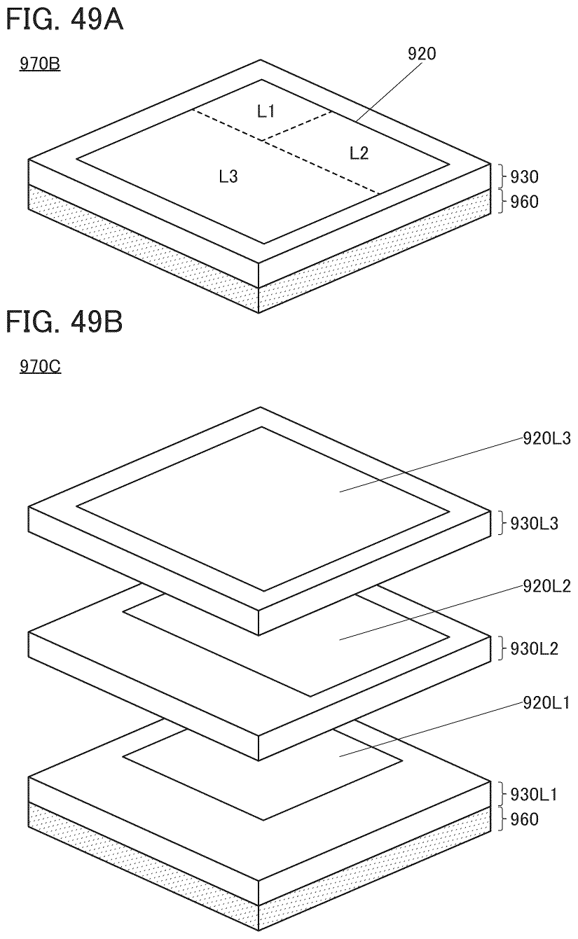

The layer 930 including one memory array 920 may be provided to overlap with the arithmetic device 960. FIG. 49A is a perspective view of a semiconductor device 970B.

In the semiconductor device 970B, one memory array 920 can be divided into a plurality of areas having different functions. FIG. 49A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 49B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate. In this specification, in the case where a plurality of structure examples are shown in one embodiment, the structure examples can be combined as appropriate.

### Embodiment 6

In this embodiment, a display device of one embodiment of the present invention will be described.

The semiconductor device of one embodiment of the present invention can be used for a display device or a module including the display device. Examples of the module including the display device include a module in which a connector such as a flexible printed circuit board (hereinafter, referred to as an FPC) or a tape carrier package (TCP) is attached to the display device and a module in which the display device is mounted with an integrated circuit (IC) by a chip on glass (COG) method, a chip on film (COF) method, or the like.

The display device in this embodiment may have a function of a touch panel. The display device can employ any of a variety of sensor elements that can sense proximity or touch of a sensing target such as a finger, for example.

Examples of a sensor type include a capacitive type, a resistive type, a surface acoustic wave type, an infrared type, an optical type, and a pressure-sensitive type.

Examples of a capacitive type include a surface capacitive type and a projected capacitive type. Examples of a projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. An in-cell touch panel has a structure in which an electrode included in a sensor element is provided on one or both of a substrate supporting a display element and a counter substrate.

### [Display Module]

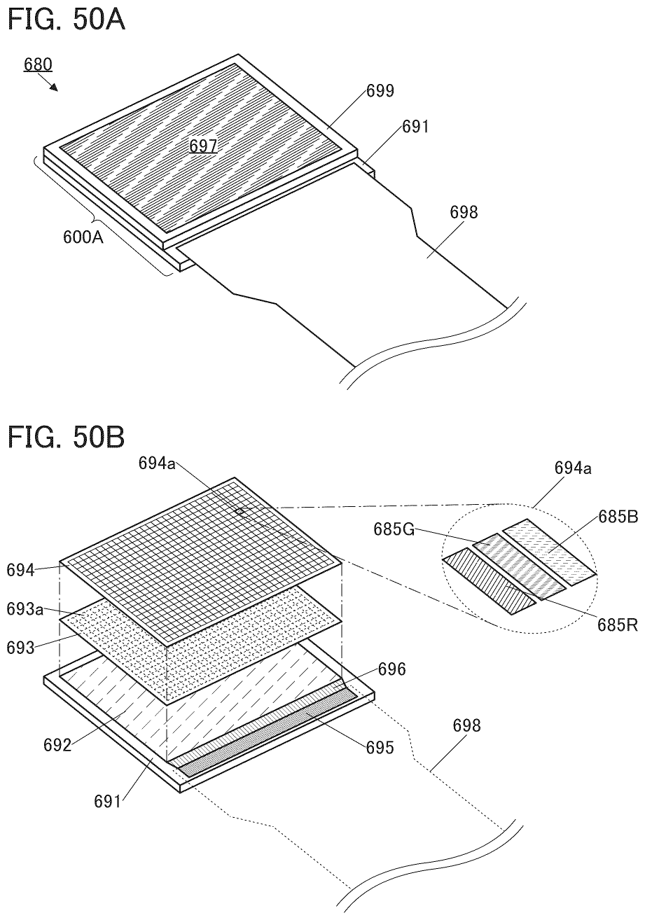

FIG. 50A is a perspective view of a display module 680. The display module 680 includes a display device 600A and an FPC 698. Note that the display device included in the display module 680 is not limited to the display device 600A and may be a display device 600B described later.

The display module 680 includes a substrate 691 and a substrate 699. The display module 680 includes a display portion 697. The display portion 697 is a region of the display module 680 where an image is displayed, and is a region where light emitted from pixels provided in a pixel portion 694 described later can be seen.

FIG. 50B is a perspective view schematically illustrating the structure on the substrate 691 side. Over the substrate 691, a circuit portion 692, a pixel circuit portion 693 over the circuit portion 692, and the pixel portion 694 over the pixel circuit portion 693 are stacked. In addition, a terminal portion 695 for connection to the FPC 698 is included in a portion over the substrate 691 that does not overlap with the pixel portion 694. The terminal portion 695 and the circuit portion 692 are connected to each other through a wiring portion 696 formed of a plurality of wirings.

The semiconductor device of one embodiment of the present invention can be used for one or both of the circuit portion 692 and the pixel circuit portion 693.

The pixel portion 694 includes a plurality of pixels 694a arranged periodically. An enlarged view of one pixel 694a is illustrated on the right side in FIG. 50B. FIG. 50B illustrates an example in which one pixel 694a includes a subpixel 685R emitting red light, a subpixel 685G emitting green light, and a subpixel 685B emitting blue light.

The subpixel includes a display element. Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

As the light-emitting element, for example, a self-luminous light-emitting element such as a light-emitting diode (LED), an organic LED (OLED), or a semiconductor laser can be used. Examples of the LED include a mini LED and a micro LED.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement. FIG. 50B illustrates an example in which stripe arrangement is employed as the pixel arrangement.

The pixel circuit portion 693 includes a plurality of pixel circuits 693a arranged periodically.

One pixel circuit 693a is a circuit that controls driving of a plurality of elements included in one pixel 694a. One pixel circuit 693a can be provided with three circuits each of which controls light emission of one light-emitting element. For example, the pixel circuit 693a can include at least one selection transistor, one current control transistor (driving transistor), and a capacitor for one light-emitting element. In that case, a gate signal is input to a gate of the selection transistor, and a source signal is input to a source of the selection transistor. With such a structure, an active-matrix display device is achieved.

The circuit portion 692 includes a circuit for driving the pixel circuits 693a in the pixel circuit portion 693. For example, one or both of a gate line driver circuit and a source line driver circuit are preferably included. The circuit portion 692 may also include at least one of an arithmetic circuit, a memory circuit, a power supply circuit, and the like.

The FPC 698 functions as a wiring for supplying a video signal, a power supply potential, or the like to the circuit portion 692 from the outside. An 1C may be mounted on the FPC 698.

The display module 680 can have a structure in which one or both of the pixel circuit portion 693 and the circuit portion 692 are stacked below the pixel portion 694; thus, the aperture ratio (the effective display area ratio) of the display portion 697 can be significantly high. Furthermore, the pixels 694a can be arranged extremely densely and thus the display portion 697 can have an extremely high resolution.

Such a display module 680 has an extremely high resolution, and thus is suitable for a device for virtual reality (VR) such as a head-mounted display (HMD) or a glasses-type device for augmented reality (AR). For example, even in the case of a structure in which the display portion of the display module 680 is seen through a lens, pixels of the extremely-high-resolution display portion 697 included in the display module 680 are prevented from being seen when the display portion is enlarged by the lens, so that display providing a high level of immersion can be performed. Without being limited thereto, the display module 680 is suitable for electronic devices including a relatively small display portion. For example, the display module 680 is suitable for a display portion of a wearable electronic device, such as a wrist watch.

### Structure Example 1 of Display Device

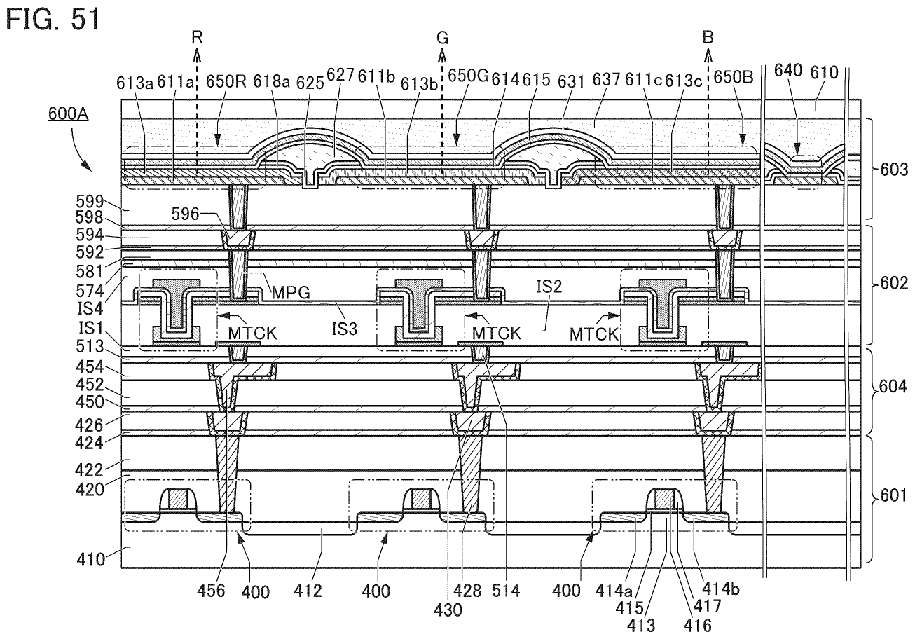

FIG. 51 is a cross-sectional view of the display device 600A. The display device 600A is an example of a display device having a metal maskless (MML) structure.

An island-shaped light-emitting layer of the light-emitting element included in the display device having the MML structure is formed in the following manner: a light-emitting layer is formed on the entire surface and then the light-emitting layer is processed by a lithography method. Accordingly, a high-resolution display device or a display device with a high aperture ratio, which has been difficult to achieve so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. For processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of devices.

A display device having the MML structure does not require a pseudo improvement in resolution by employing unique pixel arrangement such as PenTile arrangement, for example; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

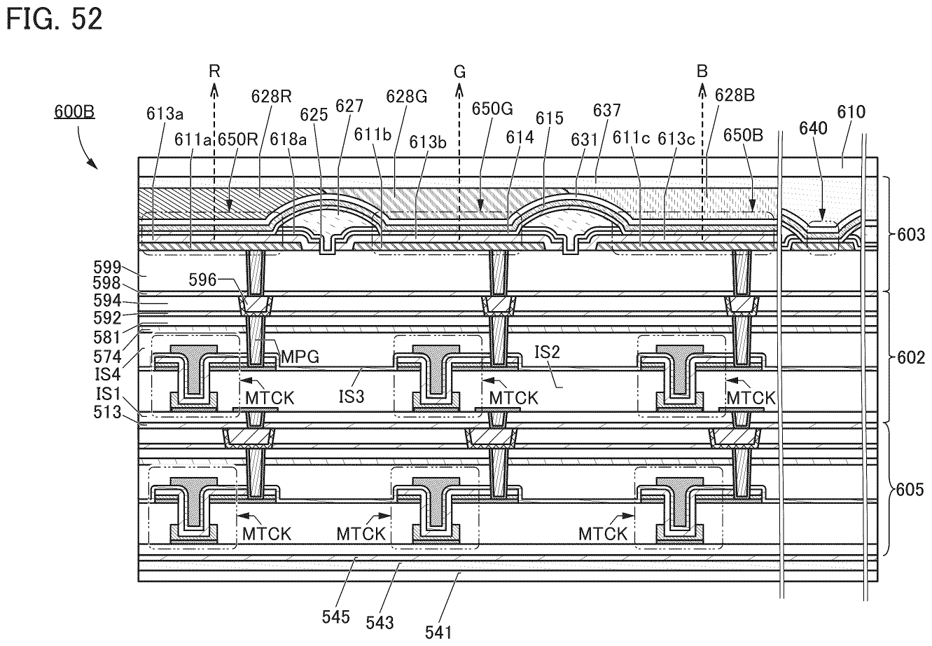

Providing a sacrificial layer over the light-emitting layer can reduce damage to the light-emitting layer in the fabrication process of the display device, resulting in an increase in reliability of the light-emitting element. Note that the sacrificial layer may remain in the completed display device or may be removed in the fabrication process. For example, a sacrificial layer 618a illustrated in FIG. 51 and FIG. 52 is part of the sacrificial layer provided over the light-emitting layer.

Employing a film formation step using an area mask and a processing step using a resist mask enables a light-emitting element to be fabricated by a relatively easy process.

FIG. 51 is a schematic cross-sectional view of the display device 600A that is a display device (a semiconductor device) of one embodiment of the present invention. The display device 600A is provided with a pixel circuit, a driver circuit, and the like over a substrate 410. In the display device 600A in FIG. 51, a wiring layer 604 is illustrated in addition to an element layer 601, an element layer 602, and an element layer 603. The wiring layer 604 is a layer provided with a wiring.

The pixel circuit of the display device is preferably provided in the element layer 602. The driver circuit (one or both of a gate driver and a source driver) of the display device is preferably provided in the element layer 601. One or more of a variety of circuits such as an arithmetic circuit and a memory circuit may be provided in the element layer 601.

For example, the element layer 601 includes the substrate 410 on which a transistor 400 is formed. The wiring layer 604 is provided above the transistor 400, and a wiring (a conductive layer 514 in FIG. 51) for connecting the transistor 400 to a conductive layer, a transistor, or the like provided in the element layer 602 is provided in the wiring layer 604. The element layers 602 and 603 are provided above the wiring layer 604, and the element layer 602 includes a transistor MTCK and the like, for example. The element layer 603 includes a light-emitting element (a light-emitting element 650R, a light-emitting element 650G, and a light-emitting element 650B in FIG. 51) and the like.

The transistor 400 is an example of a transistor included in the element layer 601. The transistor MTCK is an example of a transistor included in the element layer 602. The light-emitting element (the light-emitting elements 650R, 650G, and 650B) is an example of a light-emitting element included in the element layer 603.

As the substrate 410, a semiconductor substrate (e.g., a single crystal substrate formed of silicon or germanium) can be used, for example. Besides such a semiconductor substrate, any of the following can be used as the substrate 410: an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. As the substrate 410, a structure body in which a single crystal oxide semiconductor film (typically, indium oxide film) is provided over a stabilized zirconia substrate can also be used. In the description of this embodiment, the substrate 410 is a semiconductor substrate containing silicon as a material. Thus, a transistor included in the element layer 601 can be a Si transistor.

The transistor 400 includes an element isolation layer 412, a conductive layer 416, an insulating layer 415, an insulating layer 417, a semiconductor region 413 that is part of the substrate 410, a low-resistance region 414a, and a low-resistance region 414b. Although FIG. 51 illustrates the structure in which one of a source and a drain of the transistor 400 is connected to the conductive layer 514 provided in the element layer 602 through a conductive layer 428, a conductive layer 430, and a conductive layer 456, the connection structure of the display device of one embodiment of the present invention is not limited thereto.

The transistor 400 can have a fin-type structure when, for example, the top surface of the semiconductor region 413 and the side surface thereof in the channel width direction are covered with the conductive layer 416 functioning as a gate electrode with the insulating layer 415 functioning as a gate insulating layer therebetween. The effective channel width can be increased in the fin-type transistor 400, so that the on-state characteristics of the transistor 400 can be improved. In addition, contribution of the electric field of the gate electrode can be increased, so that the off-state characteristics of the transistor 400 can be improved. The transistor 400 may have a planar structure instead of a fin-type structure.

Note that the transistor 400 may be either a p-channel transistor or an n-channel transistor. Alternatively, a plurality of transistors 400 may be provided and both the p-channel transistor and the n-channel transistor may be used.

A region of the semiconductor region 413 where a channel is formed, a region in the vicinity thereof, and the low-resistance regions 414a and 414b functioning as source and drain regions preferably include a silicon-based semiconductor, specifically, single crystal silicon. Alternatively, the above-described regions may be formed using germanium, silicon germanium, gallium arsenide, aluminum gallium arsenide, or gallium nitride, for example. The transistor 400 may contain silicon whose effective mass is adjusted by applying stress to the crystal lattice and thereby changing the lattice spacing. Alternatively, the transistor 400 may be a high-electron-mobility transistor (HEMT) containing gallium arsenide and aluminum gallium arsenide, for example.

The conductive layer 416 can be formed using a semiconductor material such as silicon that contains an element imparting n-type conductivity (e.g., arsenic or phosphorus) or an element imparting p-type conductivity (e.g., boron or aluminum). For another example, the conductive layer 416 can be formed using a conductive material such as a metal material, an alloy material, or a metal oxide material.

Note that a material for a conductive layer determines the work function; thus, selecting the material for the conductive layer can adjust the threshold voltage of a transistor. Specifically, one or both of titanium nitride and tantalum nitride are preferably used for the conductive layer. Furthermore, in order to ensure the conductivity and embeddability of the conductive layer, one or both of tungsten and aluminum are preferably stacked over the conductive layer. In particular, tungsten is preferable in terms of heat resistance.

The element isolation layer 412 is provided to separate a plurality of transistors on the substrate 410 from each other. The element isolation layer can be formed by a local oxidation of silicon (LOCOS) method, a shallow trench isolation (STI) method, or a mesa isolation method. Over the transistor 400 illustrated in FIG. 51, an insulating layer 420 and an insulating layer 422 are stacked in this order from the substrate 410 side.

For the insulating layers 420 and 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may function as a planarization film for eliminating a level difference caused by the transistor 400 or the like covered with the insulating layers 420 and 422. For example, the top surface of the insulating layer 422 may be planarized by planarization treatment using a CMP method or the like to improve the planarity.

The conductive layer 428 connected to the transistor MTCK and the like provided above the insulating layer 422 is embedded in the insulating layers 420 and 422. Note that the conductive layer 428 has a function of a plug or a wiring.

In the display device 600A, the wiring layer 604 is provided over the transistor 400. The wiring layer 604 includes, for example, an insulating layer 424, an insulating layer 426, the conductive layer 430, an insulating layer 450, an insulating layer 452, an insulating layer 454, and the conductive layer 456.

Over the insulating layer 422 and the conductive layer 428, the insulating layers 424 and 426 are stacked in this order. An opening portion is formed in regions of the insulating layers 424 and 426 that overlap with the conductive layer 428. The conductive layer 430 is embedded in the opening portion.

The insulating layers 450, 452, and 454 are stacked in this order over the insulating layer 426 and the conductive layer 430. An opening portion is formed in regions of the insulating layers 450, 452, and 454 that overlap with the conductive layer 430. The conductive layer 456 is embedded in the opening portion.

The conductive layers 430 and 456 each have a function of a plug or a wiring that is connected to the transistor 400.

The insulating layers 424 and 450 are preferably formed using an insulating layer having a barrier property against at least one of hydrogen, oxygen, and water, like an insulating layer 574 described later, for example. The insulating layers 426, 452, and 454 are preferably formed using an insulating layer having a relatively low dielectric constant to reduce the parasitic capacitance generated between wirings, like an insulating layer 581 described later. The insulating layers 426, 452, and 454 each have functions of an interlayer insulating film and a planarization film.

The conductive layer 456 preferably includes a conductive layer having a barrier property against at least one of hydrogen, oxygen, and water.

As the conductive layer having a barrier property against hydrogen, tantalum nitride is preferably used, for example. By stacking tantalum nitride and tungsten, which has high conductivity, diffusion of hydrogen from the transistor 400 can be inhibited while the conductivity of a wiring is ensured. In that case, a tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. A conductive layer functioning as a plug or a wiring is embedded in the insulating layer IS1 and the insulating layer 513. Thus, the transistor 400 can be connected to the conductive layer 514 provided in the element layer 602. Alternatively, a source or a drain of the transistor MTCK and the source or the drain of the transistor 400 may be connected to each other.

The transistor MTCK is provided over the insulating layer IS1. An insulating layer IS4, the insulating layer 574, and the insulating layer 581 are stacked in this order over the transistor MTCK. A conductive layer MPG functioning as a plug or a wiring is embedded in an insulating layer IS3, the insulating layer IS4, the insulating layer 574, and the insulating layer 581. The conductive layer MPG is preferably in contact with the conductive layer 240 in an opening portion provided in the insulating layer 250 and the oxide semiconductor layer 230. The contact between the conductive layer MPG and the conductive layer 240 is preferable because the contact resistance therebetween can be reduced. Alternatively, the conductive layer MPG and the oxide semiconductor layer 230 may be in contact with each other and the conductive layer MPG and the conductive layer 240 may be connected to each other through the oxide semiconductor layer 230.

The insulating layer 574 preferably has a function of inhibiting transmission of impurities such as water and hydrogen (e.g., one or both of a hydrogen atom and a hydrogen molecule). The insulating layer 574 also preferably has a function of inhibiting transmission of oxygen (e.g., one or both of an oxygen atom and an oxygen molecule). For example, the insulating layer 574 preferably has a lower oxygen-transmitting property than the insulating layer IS2, the insulating layer IS3, and the insulating layer IS4. For the insulating layer having a function of inhibiting transmission of oxygen and impurities such as water and hydrogen, it is possible to use any of the materials that can be used for the insulating layer having a function of inhibiting transmission of oxygen and impurities described in Embodiment 2.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, oxygen contained in the insulating layer IS3 and the like can be inhibited from diffusing above the insulating layer 574.

The insulating layer 581 is preferably a film functioning as an interlayer film and having a lower dielectric constant than the insulating layer 574. When a material with a low dielectric constant is used for an interlayer film, the parasitic capacitance generated between wirings can be reduced. For example, the dielectric constant of the insulating layer 581 is preferably lower than 4, further preferably lower than 3. For example, the dielectric constant of the insulating layer 581 is preferably 0.7 times or less that of the insulating layer 574, further preferably 0.6 times or less that of the insulating layer 574. The concentration of impurities such as water and hydrogen in the insulating layer 581 is preferably reduced.

For example, silicon oxide and silicon oxynitride are thermally stable and thus are suitable for the insulating layer 581. Materials such as silicon oxide, silicon oxynitride, and porous silicon oxide are preferably used for the insulating layer 581, in which case a region containing excess oxygen can be easily formed. Moreover, the insulating layer 581 can be formed using a resin. The material that can be used for the insulating layer 581 may be an appropriate combination of the above-described materials.

An insulating layer 592 and an insulating layer 594 are stacked in this order over the insulating layers 574 and 581.

The insulating layer 592 is preferably formed using an insulating layer having a barrier property against at least one of hydrogen, oxygen, and water, like the insulating layer 574. Thus, diffusion of impurities such as water and hydrogen from the substrate 410 and the transistor MTCK into a region above the insulating layer 592 (e.g., a region where the light-emitting elements 650R, 650G, and 650B, and the like are provided) can be inhibited.

Like the insulating layer 581, the insulating layer 594 is preferably an interlayer film with a low dielectric constant. Thus, the insulating layer 594 can be formed using any of the materials that can be used for the insulating layer 581. When the insulating layer 594 is an interlayer film with a low dielectric constant, the parasitic capacitance generated between wirings can be reduced.

Note that the insulating layer 594 preferably has a lower dielectric constant than the insulating layer 592. For example, the dielectric constant of the insulating layer 594 is preferably lower than 4, further preferably lower than 3. For example, the dielectric constant of the insulating layer 594 is preferably 0.7 times or less that of the insulating layer 592, further preferably 0.6 times or less that of the insulating layer 592.

The conductive layer MPG functioning as a plug or a wiring is embedded in the insulating layer IS3, the insulating layer IS4, the insulating layer 574, and the insulating layer 581, and a conductive layer 596 functioning as a plug or a wiring is embedded in the insulating layer 592 and the insulating layer 594. In particular, the conductive layer MPG and the conductive layer 596 are connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, part of a conductive layer functions as a wiring in some cases and part of a conductive layer functions as a plug in other cases.

As a material for each of plugs and wirings (e.g., the conductive layers MPG, 428, 430, 456, 514, and 596), one or more conductive materials selected from a metal material, an alloy material, a metal nitride material, and a metal oxide material can be used in a single-layer structure or a stacked-layer structure. It is preferable to use a high-melting-point material that has both heat resistance and conductivity, such as tungsten or molybdenum, and it is particularly preferable to use tungsten. A low-resistance conductive material such as aluminum or copper is preferably used. The use of a low-resistance conductive material can reduce wiring resistance.

An insulating layer 598 and an insulating layer 599 are formed in this order over the insulating layer 594 and the conductive layer 596.

The insulating layer 598 is preferably formed using an insulating layer having a barrier property against at least one of hydrogen, oxygen, and water, like the insulating layer 574. The insulating layer 599 is preferably formed using an insulating layer having a relatively low dielectric constant to reduce the parasitic capacitance generated between wirings, like the insulating layer 581. The insulating layer 599 has functions of an interlayer insulating film and a planarization film.

The light-emitting elements and a connection portion 640 are formed over the insulating layer 599.

The connection portion 640 is referred to as a cathode contact portion in some cases, and is connected to cathodes of the light-emitting elements 650R, 650G, and 650B. In the connection portion 640 illustrated in FIG. 51, a conductive layer formed using the same material in the same step as a conductive layer 611a, a conductive layer 611b, and a conductive layer 611c is connected to a common electrode 615 described later. Although FIG. 51 illustrates an example in which the conductive layer is connected to the common electrode 615 through a common layer 614 described later, the conductive layer and the common electrode 615 may be in direct contact with each other.

Note that the connection portion 640 may be provided to surround four sides of the display portion in a plan view or may be provided in the display portion (e.g., between adjacent light-emitting elements) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layers 611a to 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

For the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include ITO, ITSO, In—Zn oxide, and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure.

Note that the layer 613a is formed to cover the top and side surfaces of the conductive layer 611a. Similarly, the layer 613b is formed to cover the top and side surfaces of the conductive layer 611b. Similarly, the layer 613c is formed to cover the top and side surfaces of the conductive layer 611c. Accordingly, regions provided with the conductive layers 611a, 611b, and 611c can be entirely used as the light-emitting regions of the light-emitting elements 650R, 650G, and 650B, thereby increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer contains one or more kinds of light-emitting substances. As the light-emitting substance, a substance emitting light of blue, violet, bluish violet, green, yellowish green, yellow, orange, red, or the like is used as appropriate. As the light-emitting substance, a substance emitting near-infrared light can also be used.

Examples of a light-emitting substance contained in the light-emitting element include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material).

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further contain one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. The tandem structure enables a light-emitting element to emit light at high luminance. Furthermore, the amount of current needed for obtaining a predetermined luminance can be smaller in the tandem structure than in the single structure; thus, the tandem structure enables higher reliability. The tandem structure can also be referred to as a stack structure.

When the light-emitting element has a microcavity structure, higher color purity can be achieved.

The layers 613a to 613c are each processed into an island shape by a photolithography method. At each of end portions of the layers 613a to 613c, an angle between the top surface and the side surface is approximately 90°. By contrast, an organic film formed using an FMM has a thickness that tends to gradually decrease with decreasing distance to an end portion, and has a top surface forming a slope in an area extending greater than or equal to 1 μm and less than or equal to 10 μm from the end portion, for example; thus, such an organic film has a shape whose top surface and side surface cannot be easily distinguished from each other.

The top and side surfaces of each of the layers 613a to 613c are clearly distinguished from each other. Accordingly, as for the layers 613a and 613b which are adjacent to each other, one of the side surfaces of the layer 613a and one of the side surfaces of the layer 613b face each other. The same applies to a combination of any two of the layers 613a to 613c.

The layers 613a to 613c each include at least a light-emitting layer. Preferably, the layer 613a, the layer 613b, and the layer 613c include a light-emitting layer emitting red (R) light, a light-emitting layer emitting green (G) light, and a light-emitting layer emitting blue (B) light, respectively, for example. Other than the above colors, cyan, magenta, yellow, or white can be employed as colors of light emitted from the light-emitting layers.

The layers 613a to 613c each preferably include a light-emitting layer and a carrier-transport layer (an electron-transport layer or a hole-transport layer) over the light-emitting layer. Since the surfaces of the layers 613a to 613c are exposed in the fabrication process of the display device in some cases, providing the carrier-transport layer over the light-emitting layer inhibits the light-emitting layer from being exposed on the outermost surface, so that damage to the light-emitting layer can be reduced. Thus, the reliability of the light-emitting element can be increased.

The common layer 614 includes, for example, an electron-injection layer or a hole-injection layer. Alternatively, the common layer 614 may be a stack of an electron-transport layer and an electron-injection layer, or may be a stack of a hole-transport layer and a hole-injection layer. The common layer 614 is shared by the light-emitting elements 650R, 650G, and 650B. Note that the common layer 614 is not necessarily provided, and the whole EL layer included in the light-emitting element may be provided in an island shape like the layers 613a to 613c.

The common electrode 615 is shared by the light-emitting elements 650R, 650G, and 650B. As illustrated in FIG. 51, the common electrode 615 shared by the plurality of light-emitting elements is connected to the conductive layer included in the connection portion 640.

An insulating layer 625 preferably has a function of a barrier insulating layer against at least one of water and oxygen. This can inhibit entry of impurities (typically, one or both of water and oxygen) that would diffuse into the light-emitting elements from the outside. With this structure, a highly reliable light-emitting element and a highly reliable display device can be provided.

As the insulating layer 625, the above-described barrier insulating layer against oxygen can be used, and aluminum oxide or silicon nitride is preferably used.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against at least one of water and oxygen can be increased. For example, the insulating layer 625 preferably has a sufficiently low hydrogen concentration or a sufficiently low carbon concentration, and further preferably has both a sufficiently low hydrogen concentration and a sufficiently low carbon concentration.

As an insulating layer 627, an insulating layer containing an organic material can be suitably used. As the organic material, a photosensitive resin is preferably used, and for example, a photosensitive resin composite containing an acrylic resin can be used. In this specification and the like, an acrylic resin refers not only to a polymethacrylic acid ester or a methacrylic resin, but also to all the acrylic polymer in a broad sense in some cases.

An organic material that can be used for the insulating layer 627 is not limited to the above. For example, for the insulating layer 627, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. A photoresist, which is a photosensitive resin, can be used for the insulating layer 627 in some cases. Examples of the photosensitive resin include positive-type materials and negative-type materials.

The insulating layer 627 may be formed using a material absorbing visible light. When the insulating layer 627 absorbs light emitted from the light-emitting element, light leakage (stray light) from the light-emitting element to an adjacent light-emitting element through the insulating layer 627 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

Note that the side surface of the insulating layer 627 preferably has a tapered shape. When the end portion of the side surface of the insulating layer 627 has a forward tapered shape (with an angle less than 90°, preferably less than or equal to 60°, further preferably less than or equal to) 45°, the common layer 614 and the common electrode 615 that are provided over the end portion of the side surface of the insulating layer 627 can be formed with good coverage without disconnection, local thinning, or the like. Consequently, the in-plane uniformity of the common layer 614 and the common electrode 615 can be increased, so that the display quality of the display device can be improved.

In a cross-sectional view of the display device, the top surface of the insulating layer 627 preferably has a convex shape. The convex top surface of the insulating layer 627 preferably has a shape that expands gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layers 613a and 613b). In that case, part of the insulating layer 627 is positioned between the end portion of the side surface of one of the two EL layers (e.g., the layer 613a) and the end portion of the side surface of the other of the two EL layers (e.g., the layer 613b).

It is preferable that one end portion of the insulating layer 627 overlap with the conductive layer 611a functioning as a pixel electrode and the other end portion of the insulating layer 627 overlap with the conductive layer 611b functioning as a pixel electrode. Such a structure enables the end portion of the insulating layer 627 to be formed over a flat or substantially flat region of the layer 613a (the layer 613b). This makes it relatively easy to process the insulating layer 627 to have a tapered shape as described above.

By providing the insulating layer 627 and the like in the above manner, a disconnected portion and a locally thinned portion can be prevented from being formed in the common layer 614 and the common electrode 615 from a flat or substantially flat region of the layer 613a to a flat or substantially flat region of the layer 613b. Thus, a connection defect due to a disconnected portion and an increase in electric resistance due to a locally thinned portion can be inhibited from occurring in the common layer 614 and the common electrode 615 between the light-emitting elements.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device in this embodiment includes a region where a distance between two adjacent island-shaped EL layers is less than or equal to 1 μm, preferably less than or equal to 0.5 μm (500 nm), further preferably less than or equal to 100 nm. Shortening the distance between the light-emitting elements in this manner enables a display device to have a high resolution and a high aperture ratio.

A protective layer 631 is provided over the light-emitting elements. The protective layer 631 functions as a passivation film for protecting the light-emitting elements. Providing the protective layer 631 that covers the light-emitting elements can inhibit entry of impurities such as water and oxygen into the light-emitting elements and increase the reliability of the light-emitting elements. The protective layer 631 preferably has a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as In—Ga oxide or IGZO may be used for the protective layer 631. Although the protective layer 631 includes an inorganic insulating film in this example, the present invention is not limited thereto. For example, the protective layer 631 may have a stacked-layer structure of an inorganic insulating film and an organic insulating film.

The protective layer 631 and a substrate 610 are bonded to each other with an adhesive layer 637. A solid sealing structure, a hollow sealing structure, or the like can be employed to seal the light-emitting elements. In FIG. 51, a solid sealing structure is employed, in which a space between the substrate 410 and the substrate 610 is filled with the adhesive layer 637. Alternatively, a hollow sealing structure may be employed, in which the space is filled with an inert gas (e.g., nitrogen or argon). In that case, the adhesive layer 637 may be provided not to overlap with the light-emitting elements. Alternatively, the space may be filled with a resin other than the frame-like adhesive layer 637.

As the adhesive layer 637, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a polyvinyl chloride (PVC) resin, a PVB resin, and an ethylene-vinyl acetate (EVA) resin. In particular, a material with low moisture permeability, such as an epoxy resin, is preferable. A two-component-mixture-type resin may be used. An adhesive sheet may be used.

The display device 600A is a top-emission display device. The aperture ratio of pixels in a top-emission structure can be higher than that of pixels in a bottom-emission structure because a transistor and the like can be provided to overlap with a light-emitting region of a light-emitting element in the top-emission structure. Light from the light-emitting elements is emitted to the substrate 610 side. For this reason, a material having a high visible-light-transmitting property is preferably used for the substrate 610. For example, a substrate having a high visible-light-transmitting property is preferably selected as the substrate 610 among substrates usable as the substrate 410. The pixel electrode contains a material reflecting visible light, and the counter electrode (the common electrode 615) contains a material transmitting visible light.

Note that the display device of one embodiment of the present invention may be not a top-emission display device but a bottom-emission display device where light from the light-emitting elements is emitted to the substrate 410 side. In that case, a substrate having a high visible-light-transmitting property is selected as the substrate 410.

### Structure Example 2 of Display Device

FIG. 52 is a cross-sectional view of the display device 600B.

The display device 600B can be a flexible display device when a flexible substrate is used as each of a substrate 541 and the substrate 610. The substrate 541 is bonded to an insulating layer 545 with an adhesive layer 543. The substrate 610 is bonded to the protective layer 631 with the adhesive layer 637.

The element layer 603 of the display device 600B is different from the element layer 603 of the display device 600A mainly in that the layers 613a to 613c have the same structure and a coloring layer 628R, a coloring layer 628G, and a coloring layer 628B are provided.

The layers 613a to 613c are formed using the same material in the same step. The layers 613a to 613c are isolated from each other. When the EL layer is provided in an island shape for each light-emitting element, leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 650R, 650G, and 650B illustrated in FIG. 52 emit white light, for example. White light emitted from the light-emitting elements 650R, 650G, and 650B passes through the coloring layers 628R, 628G, and 628B, whereby light of a desired color can be obtained.

In the case where the light-emitting elements configured to emit white light have a microcavity structure, light with a specific wavelength (e.g., red, green, or blue) is sometimes intensified and emitted.

Light emitted from the light-emitting element 650R is extracted as red light to the outside of the display device 600B through the coloring layer 628R. Similarly, light emitted from the light-emitting element 650G is extracted as green light to the outside of the display device 600B through the coloring layer 628G. Light emitted from the light-emitting element 650B is extracted as blue light to the outside of the display device 600B through the coloring layer 628B.

A light-emitting element emitting white light preferably has a tandem structure.

For another example, the light-emitting elements 650R, 650G, and 650B illustrated in FIG. 52 emit blue light. In that case, the layers 613a to 613c each include one or more light-emitting layers emitting blue light. In a subpixel emitting blue light, blue light emitted from the light-emitting element 650B can be extracted. In each of the subpixel emitting red light and the subpixel emitting green light, a color conversion layer is provided between the light-emitting element 650R and the coloring layer 628R and between the light-emitting element 650G and the coloring layer 628G, so that blue light emitted from the light-emitting element 650R or 650G is converted into light with a longer wavelength and red light or green light can be extracted. When light passing through the color conversion layer is extracted through the coloring layer, light other than light of a desired color can be absorbed by the coloring layer, and color purity of light emitted from a subpixel can be improved.

The coloring layer is a colored layer that selectively transmits light in a specific wavelength range and absorbs light in the other wavelength ranges. For example, a red color filter for transmitting light in the red wavelength range, a green color filter for transmitting light in the green wavelength range, a blue color filter for transmitting light in the blue wavelength range, or the like can be used. Each coloring layer can be formed using one or more of a metal material, a resin material, a pigment, and a dye.

The element layer 602 of the display device 600B has a structure similar to that of the element layer 602 of the display device 600A; thus, the detailed description thereof is omitted.

The display device 600B is different from the display device 600A in not including the element layer 601 but including an element layer 605. The element layer 605 has a structure similar to that of the element layer 602.

At least part of a transistor included in the element layer 605 is connected to a conductive layer or a transistor included in the element layer 602 through a plug, a wiring, and the like. Note that the wiring layer 604 may be provided between the element layer 602 and the element layer 605.

One or both of a pixel circuit and a driver circuit of the display device are preferably provided in the element layer 605.

Although FIG. 52 illustrates an example in which two element layers (the element layers 602 and 605) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and one or more layers between them be used for the pixel circuit or the driver circuit.

A Si transistor is typically formed on a single crystal Si wafer, and thus is difficult to have flexibility. Meanwhile, as illustrated in FIG. 52, in the case where the display device is formed using only OS transistors without using a Si transistor, the display device can have flexibility through a relatively simple manufacturing process.

This embodiment can be combined with any of the other embodiments as appropriate. In this specification, in the case where a plurality of structure examples are shown in one embodiment, the structure examples can be combined as appropriate.

### Embodiment 7

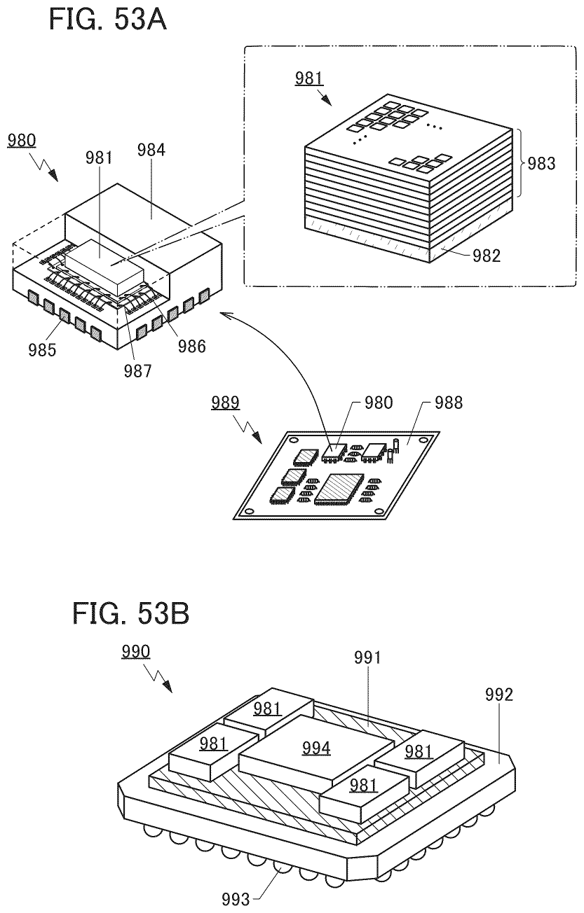

In this embodiment, application examples of the semiconductor device of one embodiment of the present invention will be described with reference to FIGS. 53A and 53B, FIGS. 54A to 54E, FIGS. 55A to 55F, FIGS. 56A to 56G, and FIGS. 57A to 57F.

The semiconductor device of one embodiment of the present invention can be used for an electronic component, a large computer, space equipment, a data center (also referred to as DC), and a variety of electronic devices, for example. With the use of the semiconductor device of one embodiment of the present invention, an electronic component, a large computer, space equipment, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop computers, a monitor of a computer and the like, digital signage, and a large game machine such as a pachinko machine.

In particular, the display device of one embodiment of the present invention can have a high resolution, and thus is suitable for an electronic device having a relatively small display portion. Examples of such an electronic device include watch-type and bracelet-type information terminal devices (wearable devices) and wearable devices that can be worn on the head, such as a VR device like a head-mounted display, a glasses-type AR device, and a mixed reality (MR) device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 53A is a perspective view of a substrate (a circuit board 989) provided with an electronic component 980. The electronic component 980 illustrated in FIG. 53A includes a semiconductor device 981 in a mold 984. FIG. 53A omits some components to show the inside of the electronic component 980. The electronic component 980 includes a land 985 outside the mold 984. The land 985 is electrically connected to an electrode pad 986, and the electrode pad 986 is electrically connected to the semiconductor device 981 through a wire 987. The electronic component 980 is mounted on a printed circuit board 988, for example. A plurality of such electronic components are combined and electrically connected to each other on the printed circuit board 988, which forms the circuit board 989.

The semiconductor device 981 includes a driver circuit layer 982 and a memory layer 983. The memory layer 983 has a structure in which a plurality of memory cell arrays are stacked. A stacked-layer structure of the driver circuit layer 982 and the memory layer 983 can be a monolithic stacked-layer structure. In the monolithic stacked-layer structure, layers can be connected to each other without using a through electrode technique such as a through silicon via (TSV) technique and a bonding technique such as Cu—Cu direct bonding. Monolithically stacking the driver circuit layer 982 and the memory layer 983 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 983 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. In the case where the memory layer 983 is formed with Si transistors, the monolithic stacked-layer structure is difficult to form as compared with the case where the memory layer 983 is formed with OS transistors. Thus, an OS transistor is superior to a Si transistor in the monolithic stacked-layer structure.

The semiconductor device 981 may be called a die. In this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 53B is a perspective view of an electronic component 990. The electronic component 990 is an example of a system in package (SiP) or a multi-chip module (MCM). In the electronic component 990, an interposer 991 is provided over a package substrate 992 (printed circuit board), and a semiconductor device 994 and a plurality of semiconductor devices 981 are provided over the interposer 991.

The electronic component 990 using the semiconductor device 981 as a high bandwidth memory (HBM) is illustrated as an example. The semiconductor device 994 can be used for an integrated circuit such as a CPU, a GPU, or a field programmable gate array (FPGA).

As the package substrate 992, a ceramic substrate, a plastic substrate, or a glass epoxy substrate can be used, for example. As the interposer 991, a silicon interposer or a resin interposer can be used, for example.

The interposer 991 includes a plurality of wirings and has a function of connecting a plurality of integrated circuits with different terminal pitches. The plurality of wirings are provided in a single layer or multiple layers. In addition, the interposer 991 has a function of connecting an integrated circuit provided on the interposer 991 to an electrode provided on the package substrate 992. Accordingly, the interposer is referred to as a “redistribution substrate” or an “intermediate substrate” in some cases. Furthermore, a through electrode is provided in the interposer 991 and the through electrode is used to connect an integrated circuit and the package substrate 992 in some cases. Moreover, in the case of using a silicon interposer, a TSV can also be used as the through electrode.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is unlikely to occur. Furthermore, a surface of a silicon interposer has high planarity; thus, poor connection between the silicon interposer and an integrated circuit provided on the silicon interposer is unlikely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer, a TSV, and the like, a space for a width of the terminal pitch and the like is needed. Accordingly, in the case where the size of the electronic component 990 is to be reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

A heat sink (a radiator plate) may be provided to overlap with the electronic component 990. In the case of providing a heat sink, the heights of integrated circuits provided on the interposer 991 are preferably equal to each other. For example, in the electronic component 990 described in this embodiment, the heights of the semiconductor devices 981 and the semiconductor device 994 are preferably equal to each other.

To mount the electronic component 990 on another substrate, an electrode 993 may be provided on a bottom portion of the package substrate 992. FIG. 53B illustrates an example in which the electrode 993 is formed of a solder ball. Solder balls are provided in a matrix on the bottom portion of the package substrate 992, so that ball grid array (BGA) mounting can be achieved. Alternatively, the electrode 993 may be formed of a conductive pin. When conductive pins are provided in a matrix on the bottom portion of the package substrate 992, pin grid array (PGA) mounting can be achieved.

The electronic component 990 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

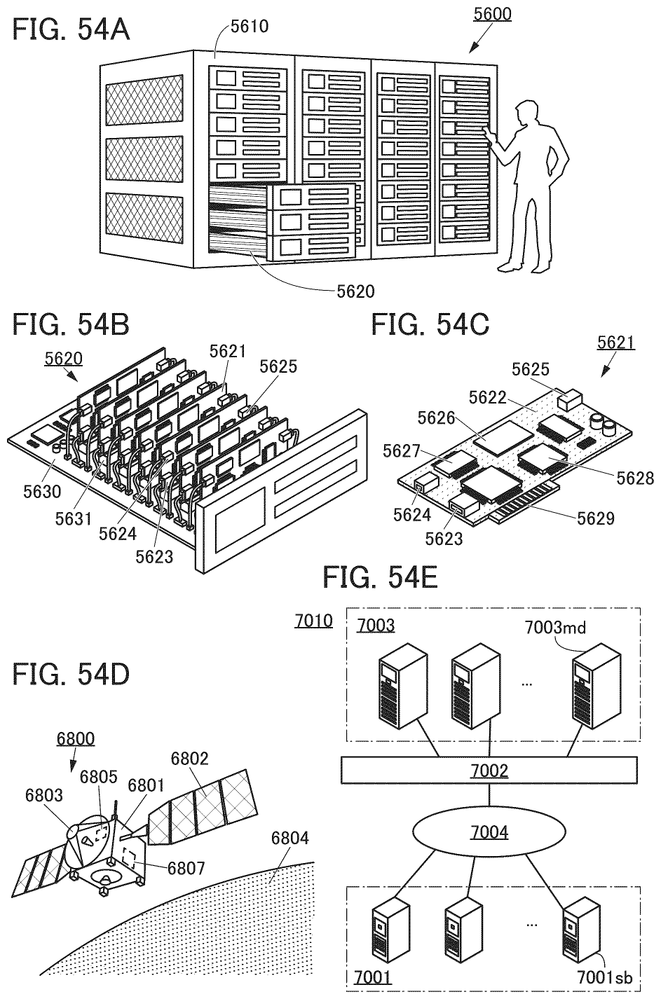

FIG. 54A is a perspective view of a large computer 5600. In the large computer 5600 illustrated in FIG. 54A, a plurality of rack mount computers 5620 are stored in a rack 5610. Note that the large computer 5600 may be referred to as a supercomputer.

The computer 5620 can have a structure illustrated in a perspective view of FIG. 54B, for example. In FIG. 54B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 54C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 54C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can each serve as, for example, an interface for performing power supply, signal input, or the like to the PC card 5621. For another example, they can each serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 990 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the electronic component 990 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention is suitable as space equipment.

The semiconductor device of one embodiment of the present invention includes an OS transistor. A change in electrical characteristics due to radiation irradiation is smaller in an OS transistor than in a Si transistor. That is, the OS transistor is highly resistant to radiation, and thus has high reliability and is suitable in an environment where radiation can enter. For example, the OS transistor is suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification can include one or more of thermosphere, mesosphere, and stratosphere.

FIG. 54D illustrates an artificial satellite 6800 as an example of space equipment. The artificial satellite 6800 includes a body 6801, a solar panel 6802, an antenna 6803, a secondary battery 6805, and a control device 6807. In FIG. 54D, a planet 6804 in outer space is illustrated as an example.

Although not illustrated in FIG. 54D, a battery management system (also referred to as BMS) or a battery control circuit may be provided in the secondary battery 6805. The OS transistor is preferably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention is suitable for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention is suitable for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable electric power for data retention, cooling equipment for data retention, or the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 54E illustrates a storage system that can be used in a data center. A storage system 7010 illustrated in FIG. 54E includes a plurality of servers 7001sb as a host 7001. The storage system 7010 includes a plurality of memory devices 7003md as a storage 7003. In the illustrated example, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

### [Electronic Device]

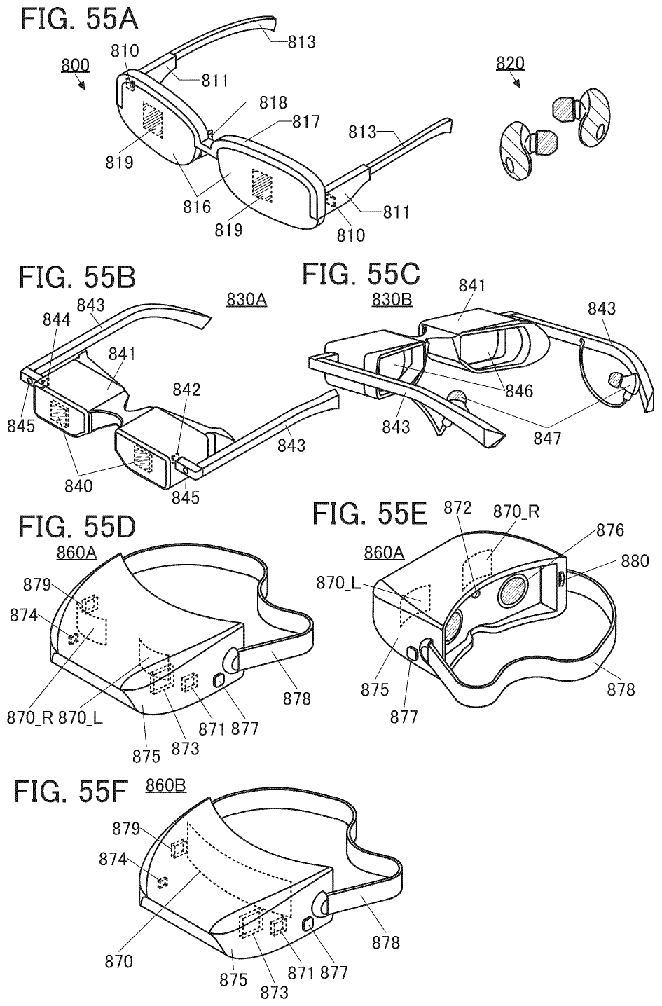

Examples of wearable devices that can be worn on a head will be described with reference to FIGS. 55A to 55F. These wearable devices have at least one of a function of displaying AR contents, a function of displaying VR contents, a function of displaying substitutional reality (SR) contents, and a function of displaying MR contents. The electronic device having a function of displaying contents of at least one of AR, VR, SR, MR, and the like enables the user to feel a higher level of immersion.

An electronic device 800 illustrated in FIG. 55A includes a pair of display panels 810, a pair of housings 811, a communication portion (not illustrated), a pair of wearing portions 813, a control portion (not illustrated), an image capturing portion (not illustrated), a pair of optical members 816, a frame 817, and a pair of nose pads 818.

The display device of one embodiment of the present invention can be used for the display panels 810. Thus, the electronic device is capable of performing ultrahigh-resolution display. The semiconductor device of one embodiment of the present invention can be used for the control portion (not illustrated). In that case, the power consumption of the electronic device can be reduced.

The electronic device 800 can project images displayed on the display panels 810 onto display regions 819 of the optical members 816. Since the optical members 816 have a light-transmitting property, the user can see images displayed on the display regions, which are superimposed on transmission images seen through the optical members 816. Accordingly, the electronic device 800 is capable of AR display.

In the electronic device 800, a camera capable of capturing images of the front side may be provided as the image capturing portion. When the electronic device 800 is provided with an acceleration sensor such as a gyroscope sensor, the orientation of the user's head can be sensed and an image corresponding to the orientation can be displayed on the display regions 819.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 800 is provided with a battery so that charging can be performed wirelessly and/or by wire.

A touch sensor module may be provided in the housing 811. The touch sensor module has a function of detecting a touch on the outer surface of the housing 811. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 811, the range of the operation can be increased.

An electronic device 830A illustrated in FIG. 55B and an electronic device 830B illustrated in FIG. 55C each include a pair of display portions 840, a housing 841, a communication portion 842, a pair of wearing portions 843, a control portion 844, a pair of image capturing portions 845, and a pair of lenses 846.

The display device of one embodiment of the present invention can be used for the display portions 840. Thus, the electronic devices are capable of performing ultrahigh-resolution display. Such electronic devices provide a high level of immersion to the user. The semiconductor device of one embodiment of the present invention can be used for the control portion 844. In that case, the power consumption of the electronic devices can be reduced.

The display portions 840 are positioned inside the housing 841 so as to be seen through the lenses 846. When the pair of display portions 840 display different images, three-dimensional display using parallax can be performed.

The electronic devices 830A and 830B can be regarded as electronic devices for VR. The user wearing the electronic device 830A or the electronic device 830B can see images displayed on the display portions 840 through the lenses 846.

The electronic devices 830A and 830B preferably include a mechanism for adjusting the lateral positions of the lenses 846 and the display portions 840 so that the lenses 846 and the display portions 840 are positioned optimally in accordance with the positions of the user's eyes. Moreover, the electronic devices 830A and 830B preferably include a mechanism for adjusting focus by changing the distance between the lenses 846 and the display portions 840.

The electronic device 830A or the electronic device 830B can be mounted on the user's head with the wearing portions 843. FIG. 55B and the like illustrate examples in which the wearing portion 843 has a shape like a temple of glasses; however, one embodiment of the present invention is not limited thereto. The wearing portion 843 may have any shape with which the user can wear the electronic device, such as a shape of a helmet or a band.

The image capturing portion 845 has a function of obtaining information on the external environment. Data obtained by the image capturing portion 845 can be output to the display portion 840. An image sensor can be used for the image capturing portion 845. Moreover, a plurality of cameras may be provided so as to cover a plurality of fields of view, such as a telescope field of view and a wide field of view.

Although an example in which the image capturing portions 845 are provided is illustrated here, a range sensor (hereinafter, also referred to as a sensing portion) capable of measuring a distance between the user and an object just needs to be provided. That is, the image capturing portion 845 is one embodiment of the sensing portion. As the sensing portion, an image sensor or a range image sensor such as a light detection and ranging (LiDAR) sensor can be used, for example. By using images obtained by the camera and images obtained by the range image sensor, more pieces of information can be obtained and a gesture operation with higher accuracy is possible.

The electronic device 830A may include a vibration mechanism that functions as bone-conduction earphones. For example, at least one of the display portion 840, the housing 841, and the wearing portion 843 can include the vibration mechanism. Thus, without additionally requiring an audio device such as headphones, earphones, or a speaker, the user can enjoy videos and sound only by wearing the electronic device 830A.

The electronic devices 830A and 830B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 820. The earphones 820 include a communication portion (not illustrated) and have a wireless communication function. The earphones 820 can receive information (e.g., audio data) from the electronic device with the wireless communication function. For example, the electronic device 800 in FIG. 55A has a function of transmitting information to the earphones 820 with the wireless communication function.

The electronic device may include earphone portions. The electronic device 830B in FIG. 55C includes earphone portions 847. For example, the earphone portion 847 can be connected to the control portion 844 by wire. Part of a wiring that connects the earphone portion 847 and the control portion 844 may be positioned inside the housing 841 or the wearing portion 843. Alternatively, the earphone portions 847 and the wearing portions 843 may include magnets. This is preferable because the earphone portions 847 can be fixed to the wearing portions 843 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 55D and 55E are perspective views of a goggles-type electronic device 860A for VR. FIGS. 55D and 55E illustrate an example in which a housing 875 includes a pair of curved display devices 870 (a display device 870_R and a display device 870_L). The electronic device 860A includes a motion detection portion 871, an eye-gaze detection portion 872, an arithmetic portion 873, a communication portion 874, lenses 876, an operation button 877, a wearing tool 878, a sensor 879, a dial 880, and the like.

When the two display devices 870 are provided, the user's eyes can see the respective display devices. This allows a high-definition video to be displayed even when three-dimensional display using parallax or the like is performed. In addition, the display device 870 is curved around an arc with an approximate center at the user's eye. This keeps a certain distance between the user's eye and the display surface of the display device 870, enabling the user to see a more natural video. Even when having what is called viewing angle dependence where the luminance or chromaticity of light changes depending on a viewing angle, the display device 870 can have a structure in which the user's eye is positioned in the normal direction of the display surface of the display device 870; accordingly, the influence of the viewing angle dependence particularly in the horizontal direction can be practically ignored, enabling display of a more realistic video.

As illustrated in FIG. 55E, the lenses 876 are positioned between the display devices 870 and the user's eyes. FIG. 55E illustrates an example in which the dial 880 for changing the positions of the lenses for visibility adjustment is provided. In the case where the electronic device 860A has an autofocus function, the dial 880 for visibility adjustment is not necessarily provided.

FIG. 55F illustrates a goggles-type electronic device 860B including one display device 870. Such a structure can reduce the number of components.

The display device 870 can display an image for the right eye and an image for the left eye side by side on a right region and a left region, respectively. Thus, a three-dimensional video using binocular parallax can be displayed. Note that the display device 870 may display two different images side by side using parallax, or may display two same images side by side without using parallax.

One image which can be seen with both eyes may be displayed on the entire display device 870. Thus, a panorama video can be displayed from end to end of the field of view, which can provide a higher sense of reality.

The display device of one embodiment of the present invention can be used as the display device 870. Since the display device of one embodiment of the present invention has an extremely high resolution, even when an image is magnified using the lenses 876, the pixels are not perceived by the user and thus a more realistic video can be displayed.

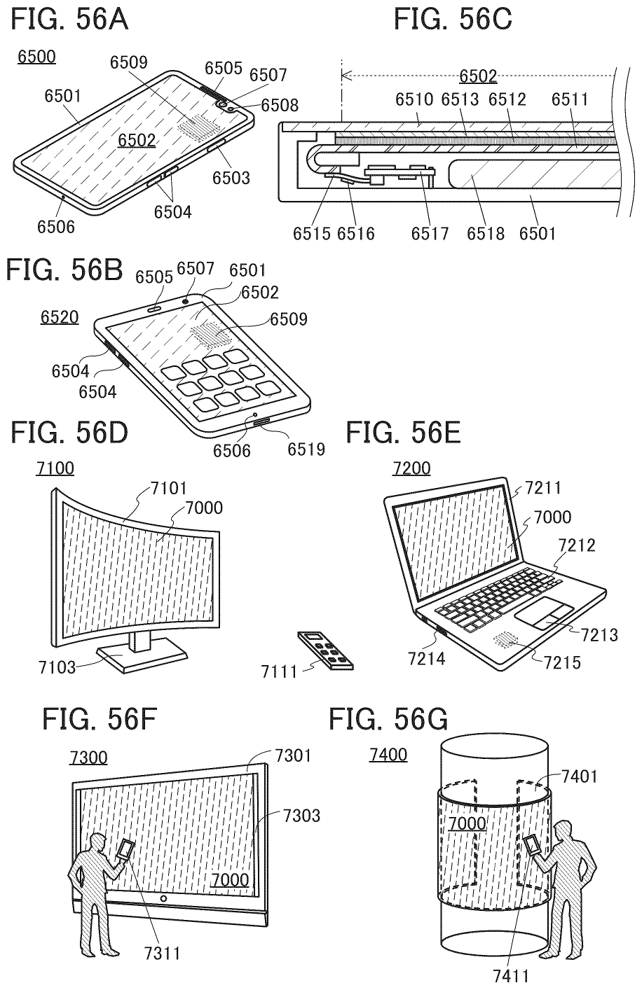

An electronic device 6500 in FIG. 56A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 in FIG. 56B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. The control device 6509 includes, for example, one or more selected from a CPU, a GPU, and a memory device. The semiconductor device of one embodiment of the present invention can be used for one or both of the display portion 6502 and the control device 6509.

FIG. 56C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An 1C 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. An electronic device with a narrow bezel can be obtained when part of the display panel 6511 is folded back such that the portion connected to the FPC 6515 is provided on the back side of a pixel portion.

FIG. 56D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

The television device 7100 illustrated in FIG. 56D can be operated with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 56E illustrates an example of a laptop computer. A laptop computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIGS. 56F and 56G illustrate examples of digital signage.

Digital signage 7300 illustrated in FIG. 56F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 56G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIGS. 56F and 56G.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 56F and 56G, it is preferable that the digital signage 7300 or the digital signage 7400 be capable of working with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device and the display device of one embodiment of the present invention can be used around a driver's seat in a car, which is a vehicle.

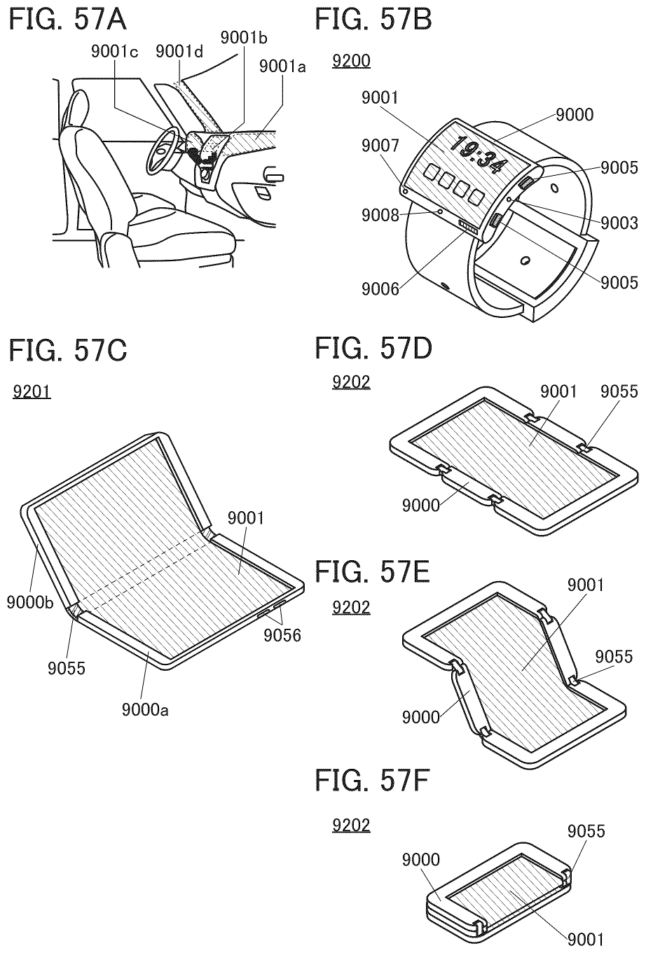

FIG. 57A illustrates the vicinity of a windshield inside a car. FIG. 57A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panels, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying a video taken by an imaging unit provided for the car body. That is, displaying an image taken by the imaging unit provided on the outside of the car body leads to elimination of blind areas and enhancement of safety. Moreover, displaying a video to compensate for the area that a driver cannot see makes it possible for the driver to confirm safety more easily and comfortably. The display panel 9001d can also be used as a lighting device.

FIG. 57B is a perspective view of a watch-type portable information terminal 9200. The portable information terminal 9200 can be used as a Smartwatch (registered trademark), for example. The display surface of a display portion 9001 is curved, and display can be performed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 57B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays), a microphone 9008, and the like.

FIG. 57C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housings 9000a and 9000b) joined together with the hinge 9055.

FIGS. 57D to 57F are perspective views illustrating a foldable portable information terminal 9202. FIG. 57D is a perspective view of an opened state of the portable information terminal 9202, FIG. 57F is a perspective view of a folded state thereof, and FIG. 57E is a perspective view of a state in the middle of change from one of FIG. 57D and FIG. 57F to the other. In this manner, the portable information terminal 9202 can be folded in three.

The display portion 9001 of the portable information terminal 9202 is supported by three housings 9000 joined together with the hinges 9055.

In FIGS. 57C to 57F, the display device of one embodiment of the present invention can be used for the display portion 9001. The display portion 9001 can be folded with a radius of curvature greater than or equal to 0.1 mm and less than or equal to 150 mm, for example.

The portable information terminals 9201 and 9202 are highly portable when folded. When the portable information terminals 9201 and 9202 are opened, a seamless large display region is highly browsable.

The use of the semiconductor device of one embodiment of the present invention for one or more selected from an electronic component, a large computer, space equipment, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate. In this specification, in the case where a plurality of structure examples are shown in one embodiment, the structure examples can be combined as appropriate.

### Example 1

In this example, the impurity concentration, crystallinity, and oxygen-transmitting property of an indium oxide film were evaluated. Specifically, five samples (Samples 2A to 2E) each including an indium oxide film were fabricated and subjected to SIMS analysis, and TEM images of the samples were taken. In addition, 10 samples (Samples 5A to 5J) each including an indium oxide film were fabricated and subjected to SIMS analysis to evaluate the oxygen-transmitting properties of the indium oxide films.

A method for fabricating Samples 2A to 2E will be described.

First, a silicon substrate was prepared for each of Samples 2A to 2E. Next, a 100-nm-thick silicon oxide film was formed on the silicon substrate by thermal oxidation treatment.

Then, an indium oxide film was formed over the silicon oxide film by an ALD method.

In the formation of the indium oxide film, triethylindium (TEI) was used as a precursor. Note that TEI with an aluminum content of 820 ppm was used for Sample 2A, and TEI with an aluminum content lower than 0.1 ppm was used for Samples 2B to 2E.

In the formation of the indium oxide film, ozone (O₃) and oxygen (O₂) were used as oxidizers. The time of introducing the oxidizers in one cycle was 30 seconds for Samples 2A and 2D, 9 seconds for Sample 2B, 15 seconds for Sample 2C, and 60 seconds for Sample 2E. Note that the time of introducing the oxidizers in one cycle is simply referred to as the oxidation time in some cases.

The indium oxide film with a target thickness of 40 nm was formed in Sample 2A, and the indium oxide film with a target thickness of 20 nm was formed in each of Samples 2B to 2E.

Through the above steps, Samples 2A to 2E were fabricated.

### [Evaluation of Hydrogen Concentration and Carbon Concentration]

Samples 2A to 2E were subjected to SIMS analysis. The analysis direction of the SIMS analysis is a direction from the surface of the sample toward the substrate. Through the SIMS analysis, the depth profiles of the hydrogen concentration and the carbon concentration were obtained. The SIMS analysis was performed with a PHI-ADEPT1010 quadrupole SIMS instrument produced by ULVAC-PHI, Inc. using a cesium primary ion (Cs⁺) as a primary ion species. Hereinafter, the depth profile of the hydrogen concentration is sometimes referred to as an H profile, and the depth profile of the carbon concentration is sometimes referred to as a C profile.

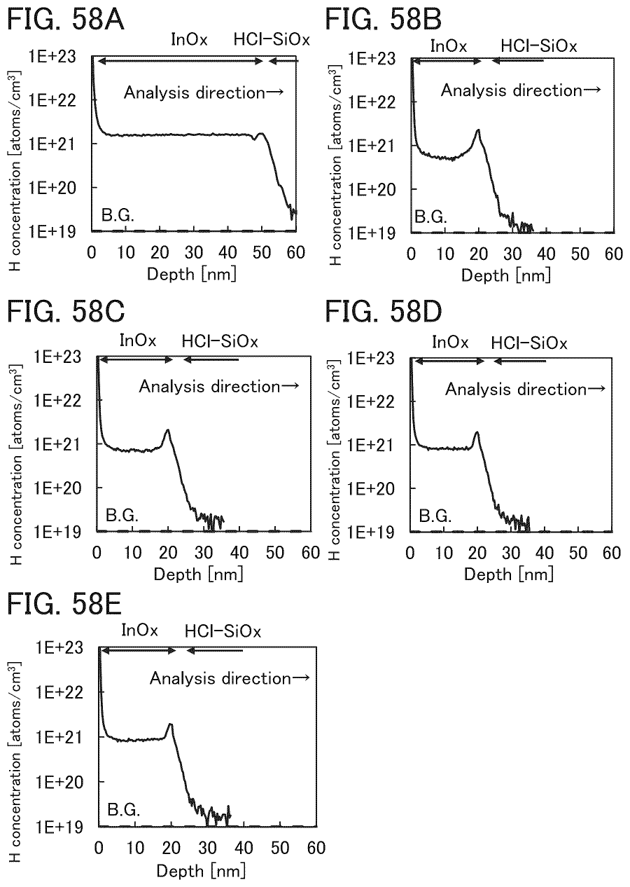

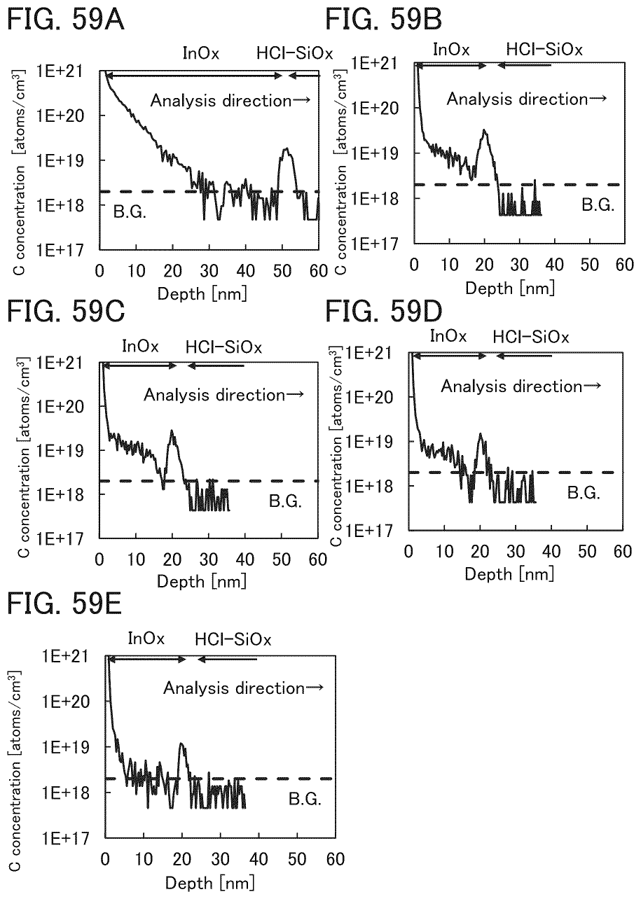

FIGS. 58A to 58E show the H profiles of Samples 2A to 2E. In each of FIGS. 58A to 58E, the horizontal axis represents the depth [nm] from the surface of the sample. The leftmost position at a depth of 0 nm corresponds to the surface of the sample (the surface of the indium oxide film). The vertical axis represents the H concentration [atoms/cm³]. The background level (B.G.) of hydrogen in the SIMS analysis was 1.0×10¹⁹ atoms/cm³. FIG. 58A, FIG. 58B, FIG. 58C, FIG. 58D, and FIG. 58E show the H profiles of Sample 2A, Sample 2B, Sample 2C, Sample 2D, and Sample 2E, respectively. In FIGS. 58A to 58E, HCl-SiOx represents the silicon oxide film and InO_{X} represents the indium oxide film. The same applies to FIGS. 59A to 59E, FIGS. 60A to 60E, and FIGS. 61A to 61E.

FIGS. 59A to 59E show the C profiles of Samples 2A to 2E. In each of FIGS. 59A to 59E, the horizontal axis represents the depth [nm] from the surface of the sample. The leftmost position at a depth of 0 nm corresponds to the surface of the sample (the surface of the indium oxide film). The vertical axis represents the C concentration [atoms/cm³]. The background level (B.G.) of carbon in the SIMS analysis was 2.0×10¹⁸ atoms/cm³. FIG. 59A, FIG. 59B, FIG. 59C, FIG. 59D, and FIG. 59E show the C profiles of Sample 2A, Sample 2B, Sample 2C, Sample 2D, and Sample 2E, respectively.

As shown in FIGS. 58A to 58E, a longer oxidation time results in a higher hydrogen concentration in the indium oxide film. According to FIGS. 59A to 59E, a longer oxidation time results in a lower carbon concentration in the indium oxide film.

### [Evaluation of Aluminum Concentration and Gallium Concentration]

Samples 2A to 2E were subjected to SIMS analysis. The analysis direction of the SIMS analysis is a direction from the surface of the sample toward the substrate. Through the SIMS analysis, the depth profiles of the aluminum (Al) concentration and the gallium (Ga) concentration were obtained. The SIMS analysis was performed with an IMS-7f-Auto magnetic field SIMS instrument produced by CAMECA SAS using O₂⁺ as a primary ion species. Hereinafter, the depth profile of the Al concentration is sometimes referred to as an Al profile, and the depth profile of the Ga concentration is sometimes referred to as a Ga profile.

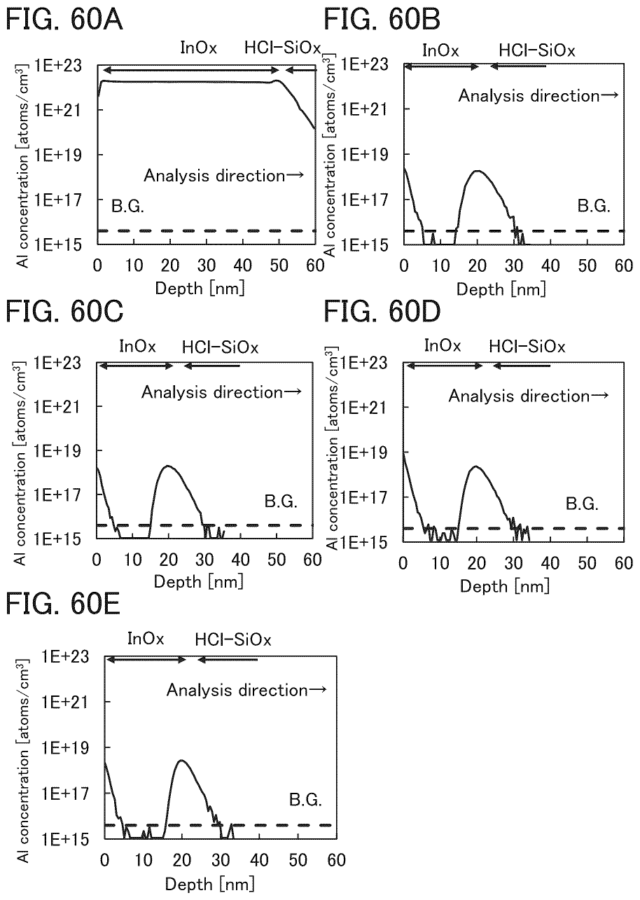

FIGS. 60A to 60E show the Al profiles of Samples 2A to 2E. In each of FIGS. 60A to 60E, the horizontal axis represents the depth [nm] from the surface of the sample. The leftmost position at a depth of 0 nm corresponds to the surface of the sample (the surface of the indium oxide film). The vertical axis represents the Al concentration [atoms/cm³]. The background level (B.G.) of Al in the SIMS analysis was 3.0×10¹⁵ atoms/cm³. FIG. 60A, FIG. 60B, FIG. 60C, FIG. 60D, and FIG. 60E show the Al profiles of Sample 2A, Sample 2B, Sample 2C, Sample 2D, and Sample 2E, respectively.

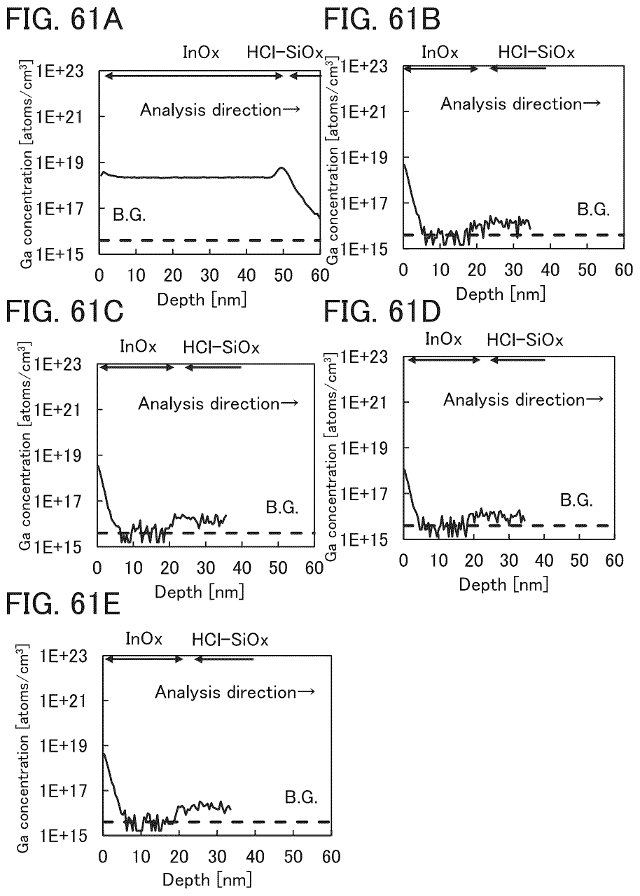

FIGS. 61A to 61E show the Ga profiles of Samples 2A to 2E. In each of FIGS. 61A to 61E, the horizontal axis represents the depth [nm] from the surface of the sample. The leftmost position at a depth of 0 nm corresponds to the surface of the sample (the surface of the indium oxide film). The vertical axis represents the Ga concentration [atoms/cm³]. The background level (B.G.) of Ga in the SIMS analysis was 4.0×10¹⁵ atoms/cm³. FIG. 61A, FIG. 61B, FIG. 61C, FIG. 61D, and FIG. 61E show the Ga profiles of Sample 2A, Sample 2B, Sample 2C, Sample 2D, and Sample 2E, respectively.

According to FIGS. 60B to 60E and FIGS. 61B to 61E, the Al concentration and the Ga concentration in the indium oxide film formed using the precursor having a low Al content are each lower than or equal to the background level. In other words, with the use of the precursor having a low Al content, the Al concentration in the indium oxide film can be lower than or equal to 3.0×10¹⁵ atoms/cm³ and the Ga concentration in the indium oxide film can be lower than or equal to 4.0×10¹⁵ atoms/cm³.

The concentrations of the elements were calculated from the depth profiles of the concentrations of the elements shown in FIGS. 58A to 58E, FIGS. 59A to 59E, FIGS. 60A to 60E, and FIGS. 61A to 61E. Table 4 shows the results. In Table 4, the unit of the concentrations of the elements is converted from [atoms/cm³] into [ppm]. The unit is converted on the assumption that the density of In₂O₃ is 7.787×10²² atoms/cm³.

TABLE 4

| | Al content | Oxidation | H concentration | C concentration | Al concentration | Ga concentration |
|---|---|---|---|---|---|---|
| Sample | (ppm) | time (s) | (ppm) | (ppm) | (ppm) | (ppm) |
| 2A | 820 | 30 | 20400 | (≤30) | 227000 | 30 |
| 2B | <0.1 | 9 | 6500 | 110 | (≤0.02) | (≤0.05) |
| 2C | <0.1 | 15 | 9000 | 140 | (≤0.02) | (≤0.05) |
| 2D | <0.1 | 30 | 10400 | 70 | (≤0.02) | (≤0.05) |
| 2E | <0.1 | 60 | 10900 | (≤30) | (≤0.02) | (≤0.05) |

### [Crystallinity]

Cross-sectional TEM images and plan-view TEM images of Samples 2A to 2E were taken. In order to take the TEM images, the fabricated samples were thinned by ion milling. The TEM images were observed with a spherical aberration corrector function.

The TEM images were taken with an atomic resolution analytical electron microscope JEM-ARM200F produced by JEOL Ltd. at an acceleration voltage of 200 kV.

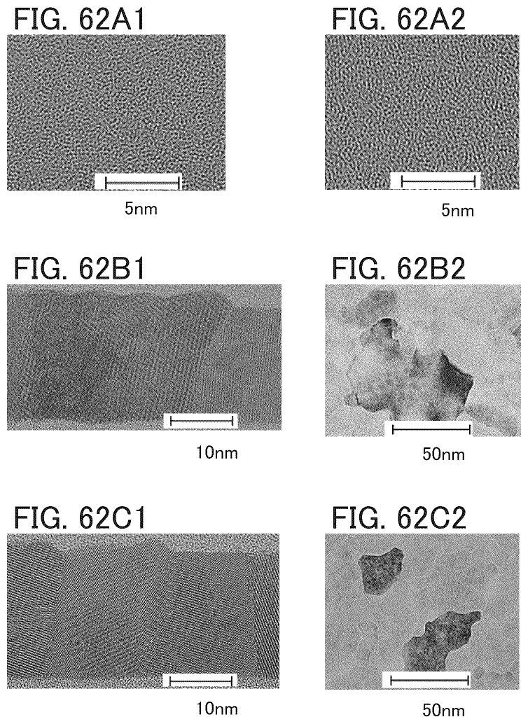

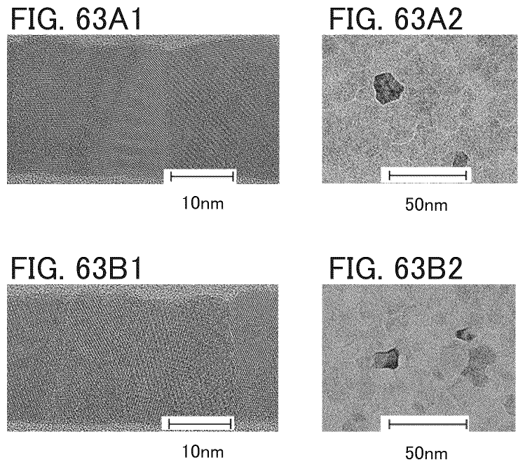

FIGS. 62A1 and 62A2 show the cross-sectional TEM image and the plan-view TEM image of Sample 2A. FIGS. 62B1 and 62B2 show the cross-sectional TEM image and the plan-view TEM image of Sample 2B. FIGS. 62C1 and 62C2 show the cross-sectional TEM image and the plan-view TEM image of Sample 2C. FIGS. 63A1 and 63A2 show the cross-sectional TEM image and the plan-view TEM image of Sample 2D. FIGS. 63B1 and 63B2 show the cross-sectional TEM image and the plan-view TEM image of Sample 2E. The total magnification of the plan-view TEM image of Sample 2A is 4000000 times, and FIG. 62A2 shows a region (also referred to as a field of view) of approximately 10 nm×13 nm cut out from the 45-nm-square plan-view TEM image. The total magnification of each of the plan-view TEM images of Samples 2B to 2E is 500000 times, and FIGS. 62B2 and 62C2 and FIGS. 63A2 and 63B2 each show a region of approximately 100 nm×125 nm cut out from the 360-nm-square plan-view TEM image.

According to FIGS. 62A1 and 62A2, the indium oxide film in Sample 2A has low crystallinity. In FIGS. 62B1, 62B2, 62C1, and 62C2 and FIGS. 63A1, 63A2, 63B1, and 63B2, polycrystallization is observed in the indium oxide films in Samples 2B to 2E. Thus, with the use of the precursor having a low Al content, the crystallinity of the indium oxide film can be increased.

According to FIGS. 62B1, 62B2, 62C1, and 62C2 and FIGS. 63A1, 63A2, 63B1, and 63B2, the average diameter of the 10 crystal grains is 37 nm in Sample 2B, 28 nm in Sample 2C, 14 nm in Sample 2D, and 13 nm in Sample 2E. Thus, as the oxidation time is longer, the average diameter of the crystal grains tends to be smaller. In other words, as the oxidation time is longer, the crystal grains tend to be smaller.

Next, the extension length of a grain boundary (sometimes referred to as the grain boundary length) was calculated on the basis of the observation results of the plan-view TEM images. Specifically, portions where the lattice fringes are disconnected in the plan-view TEM image are regarded as grain boundary regions, and lines are drawn on the portions. Then, the center lines of the grain boundary regions on which the lines are drawn are approximated by polygonal lines, and the total length of the polygonal lines is regarded as the extension length of the grain boundary. That is, as the extension length of the grain boundary is longer, the number of grain boundary components is larger. Note that the extension length of the grain boundary may be calculated for every field of view and the average value of the extension lengths may be used.

The grain boundary lengths calculated from the plan-view TEM images shown in FIG. 62B2, FIG. 62C2, FIG. 63A2, and FIG. 63B2 are 518 nm, 850 nm, 1170 nm, and 1380 nm, respectively. Note that the grain boundary lengths described here are each an average value of the grain boundary lengths in two fields of view of 90 nm square extracted from the plan-view TEM image at a total magnification of 2000000 times.

Table 5 shows the calculated extension lengths of the grain boundaries and the concentrations of the elements calculated from the depth profiles of the concentrations of the elements shown in FIGS. 58B to 58E and FIGS. 59B to 59E.

TABLE 5

| | | Average extension | H concen- | C concen- |
|---|---|---|---|---|
| | Oxidation | length of grain | tration | tration |
| Sample | time (s) | boundary | (atoms/cm³) | (atoms/cm³) |
| 2B | 9 | 518 nm | 5.5 × 10²⁰ | 8.5 × 10¹⁸ |
| 2C | 15 | 850 nm | 7.2 × 10²⁰ | 1.0 × 10¹⁹ |
| 2D | 30 | 1170 nm | 8.2 × 10²⁰ | 5.2 × 10¹⁸ |
| 2E | 60 | 1380 nm | 8.5 × 10²⁰ | (2.0 × 10¹⁸) |

### [Oxygen-Transmitting Property]

In order to evaluate the oxygen-transmitting property of the indium oxide film, the 10 samples (Samples 5A to 5J) were fabricated.

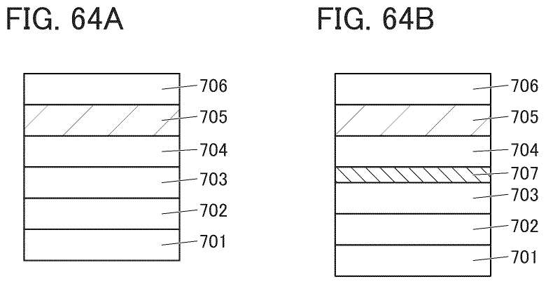

FIGS. 64A and 64B illustrate structures of stacked films included in the samples.

The stacked films included in each of Samples 5A and 5B include a layer 701, a layer 702 over the layer 701, a layer 703 over the layer 702, a layer 704 over the layer 703, a layer 705 over the layer 704, and a layer 706 over the layer 705 as illustrated in FIG. 64A.

The stacked films included in each of Samples 5C to 5J include the layer 701, the layer 702 over the layer 701, the layer 703 over the layer 702, a layer 707 over the layer 703, the layer 704 over the layer 707, the layer 705 over the layer 704, and the layer 706 over the layer 705 as illustrated in FIG. 64B. Note that the film used as the layer 707 corresponds to the indium oxide film.

A silicon substrate was prepared as the layer 701. A 100-nm-thick silicon oxide film was formed by thermal oxidation treatment as the layer 702. A 100-nm-thick silicon oxynitride film was formed by a PECVD method as the layer 703.

As the layer 707 in each of Samples 5C to 5J, an indium oxide film with a target thickness of 10 nm was formed by an ALD method. The indium oxide film in each of Samples 5C and 5D was formed under the same conditions as the indium oxide film included in Sample 2B. The indium oxide film in each of Samples 5E and 5F was formed under the same conditions as the indium oxide film included in Sample 2C. The indium oxide film in each of Samples 5G and 5H was formed under the same conditions as the indium oxide film included in Sample 2D. The indium oxide film in each of Samples 5I and 5J was formed under the same conditions as the indium oxide film included in Sample 2E.

A 50-nm-thick silicon oxynitride film was formed by a PECVD method as the layer 704. A 50-nm-thick silicon oxide film containing ¹⁸O was formed by a sputtering method as the layer 705. The silicon oxide film was formed using a silicon oxide target and an ¹⁸O₂ gas as a film formation gas. A 20-nm-thick silicon nitride film was formed by a sputtering method as the layer 706.

Then, Samples 5B, 5D, 5F, 5H, and 5J were subjected to heat treatment at 400° C. for 8 hours in a nitrogen atmosphere. Samples 5A, 5C, 5E, 5G, and 5I were not subjected to the heat treatment.

Through the above steps, Samples 5A to 5J were fabricated.

By comparing the concentration distributions of oxygen (¹⁸O) in Samples 5A to 5J, the oxygen-transmitting property of the oxide film used as the layer 707 (the amount of oxygen transmitted through the layer 707 by thermal diffusion or the degree at which the layer 707 inhibits thermal diffusion of oxygen) can be evaluated.

Samples 5A to 5J were subjected to SIMS analysis. The analysis direction of the SIMS analysis is a direction from the layer 701 toward the layer 706. Through the SIMS analysis, the depth profile of the oxygen (¹⁸O) concentration was obtained. The SIMS analysis was performed with a PHI-ADEPT1010 quadrupole SIMS instrument produced by ULVAC-PHI, Inc. Hereinafter, the depth profile of the oxygen (¹⁸O) concentration is sometimes referred to as an ¹⁸O profile.

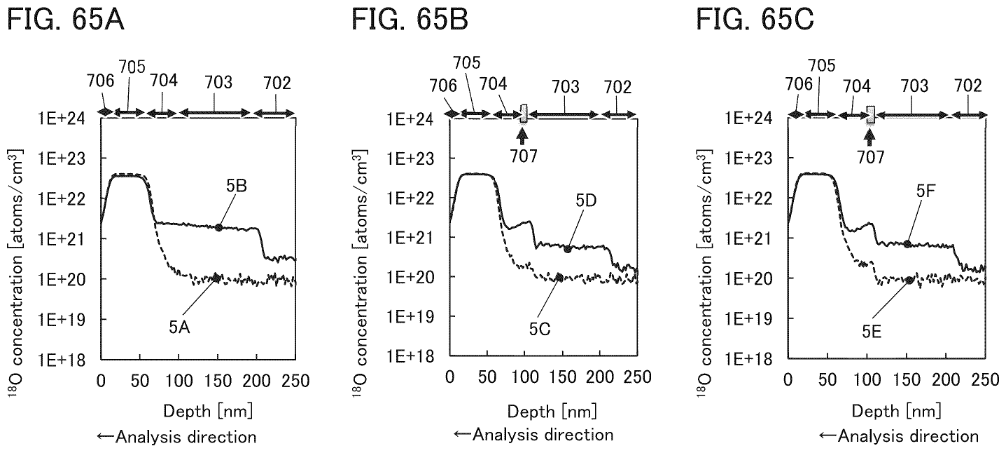

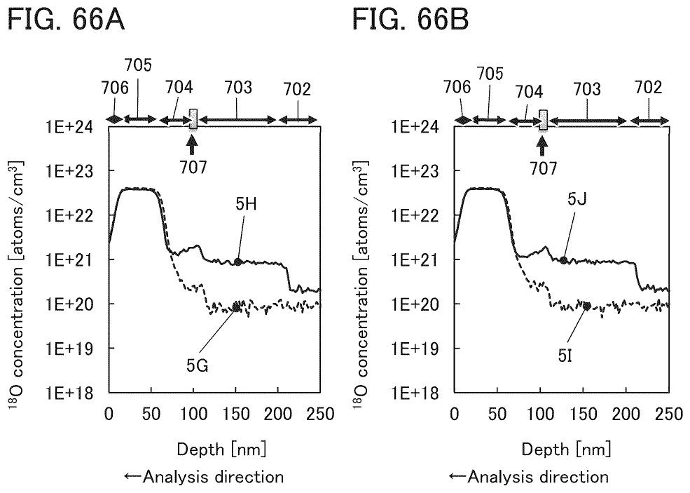

FIGS. 65A to 65C and FIGS. 66A and 66B show the ¹⁸O profiles of Samples 5A to 5J. In each of FIGS. 65A to 65C and FIGS. 66A and 66B, the horizontal axis represents the depth [nm] from the surface of the sample. The leftmost position at a depth of 0 nm corresponds to the surface of the sample (the surface of the layer 706). The vertical axis represents the ¹⁸O concentration [atoms/cm³]. The dashed line and the solid line in FIG. 65A respectively represent the ¹⁸O profile of Sample 5A and the ¹⁸O profile of Sample 5B. The dashed line and the solid line in FIG. 65B respectively represent the ¹⁸O profile of Sample 5C and the ¹⁸O profile of Sample 5D. The dashed line and the solid line in FIG. 65C respectively represent the ¹⁸O profile of Sample 5E and the ¹⁸O profile of Sample 5F. The dashed line and the solid line in FIG. 66A respectively represent the ¹⁸O profile of Sample 5G and the ¹⁸O profile of Sample 5H. The dashed line and the solid line in FIG. 66B respectively represent the ¹⁸O profile of Sample 5I and the ¹⁸O profile of Sample 5J.

According to the ¹⁸O profiles of Samples 5A to 5J, the layer 705 includes a region where the concentration if oxygen (¹⁸O) measured by SIMS is higher than or equal to 1××10²² atoms/cm³. The layer 703 before the heat treatment (the layer 703 in each of Samples 5A, 5C, 5E, 5G, and 5I) includes a region where the concentration of oxygen (¹⁸O) measured by SIMS is lower than 1×10²⁰ atoms/cm³. This reveals that oxygen (¹⁸O) contained in the layer 705 does not diffuse into the layer 703 before the heat treatment.

It is found from FIGS. 65A to 65C and FIGS. 66A and 66B that oxygen (¹⁸O) contained in the layer 705 diffuses into the layer 703 in each of Samples 5B, 5D, 5F, 5H, and 5J subjected to the heat treatment. This indicates that oxygen (¹⁸O) contained in the layer 705 is transmitted through the indium oxide film by thermal diffusion.

The ¹⁸O concentration in the vicinity of the center of the layer 703 (at a depth of approximately 150 nm in the ¹⁸O profile) is 6.0×10²⁰ atoms/cm³ in Sample 5D (see FIG. 65B), 7.0×10²⁰ atoms/cm³ in Sample 5F (see FIG. 65C), 7.8×10²⁰ atoms/cm³ in Sample 5H (see FIG. 66A), and 9.2×10²⁰ atoms/cm³ in Sample 5J (see FIG. 66B). That is, in the case where the layer 707 (the indium oxide film) is provided between the layer 705 and the layer 703, it is confirmed that oxygen in a range higher than or equal to 2×10²⁰ atoms/cm³, specifically higher than or equal to 5×10²⁰ atoms/cm³, contained in the layer 705 diffuses into the layer 703 through the layer 707 by the heat treatment at a heating temperature of 400° C. for a treatment time of 8 hours.

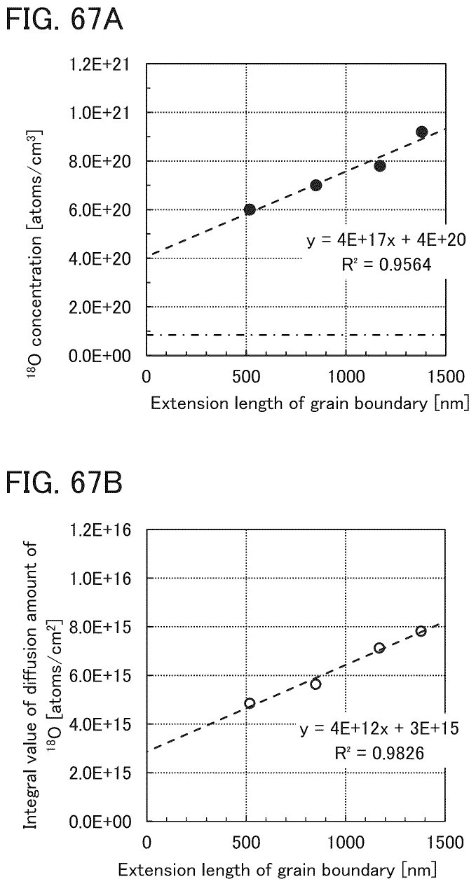

FIG. 67A shows a graph in which the extension length of the grain boundary is plotted on the horizontal axis and the ¹⁸O concentration in the vicinity of the center of the layer 703 is plotted on the vertical axis. The dashed line in FIG. 67A represents a regression line with respect to the plot, the formula of the regression line is y=4×10¹⁷x+4×10²⁰, and the value of the determination coefficient R² is 0.9564. The dashed-dotted line in FIG. 67A represents the concentration of ¹⁸O existing in the layer 703 since before the heat treatment.

According to the formula of the regression line, it is indicated that the indium oxide film in which the extension length of the grain boundary is 0 nm has a property of transmitting oxygen in a range higher than or equal to 2×10²⁰ atoms/cm³ or higher than or equal to 3×10²⁰ atoms/cm³ in the heat treatment at a heating temperature of 400° C. for a treatment time of 8 hours. It is also indicated that the indium oxide film in which the extension length of the grain boundary is 1000 nm has a property of transmitting oxygen in a range lower than or equal to 1×10²¹ atoms/cm³ or lower than or equal to 8×10²⁰ atoms/cm³ in the heat treatment at a heating temperature of 400° C. for a treatment time of 8 hours.

FIG. 67A shows that as the extension length of the grain boundary is longer, the ¹⁸O concentration in the vicinity of the center of the layer 703 tends to be higher. In other words, it is revealed that the indium oxide film having more grain boundaries per unit volume transmits a larger amount of oxygen. This indicates that oxygen diffuses through the crystal grain boundary in the indium oxide film. It is also indicated that the grain boundary diffusion of oxygen occurs in the indium oxide film.

The intercept of the regression line is 4×10²⁰ atoms/cm³, which is higher than the concentration of ¹⁸O existing in the layer 703 since before the heat treatment. In the case where the indium oxide film in which the extension length of the grain boundary is 0 nm is regarded as a single crystal indium oxide film, it is indicated that oxygen diffuses in a crystal grain (bulk) even in the single crystal indium oxide film. For example, it is indicated that oxygen in a range higher than or equal to 2×10²⁰ atoms/cm³ or higher than or equal to 3×10²⁰ atoms/cm³ diffuses in the crystal grain included in the indium oxide film by the heat treatment at a heating temperature of 400° C. for a treatment time of 8 hours.

The above results demonstrate that the indium oxide film has a property of transmitting oxygen. It is also demonstrated that not only the grain boundary diffusion of oxygen but also the diffusion of oxygen in the crystal grain (bulk) occurs in the indium oxide film.

Transmission of oxygen through the indium oxide film was evaluated by integrating the amount per unit area of ¹⁸O diffusing into the layer 703. The value obtained by subtracting the amount per unit area of ¹⁸O in the layer 703 in the sample not subjected to the heat treatment from the amount per unit area of ¹⁸O in the layer 703 in the sample subjected to the heat treatment was regarded as the integral value of the diffusion amount of ¹⁸O.

FIG. 67B shows a graph in which the extension length of the grain boundary is plotted on the horizontal axis and the integral value of the diffusion amount of ¹⁸O into the layer 703 is plotted on the vertical axis. The dashed line in FIG. 67B represents a regression line with respect to the plot, the formula of the regression line is y=4×10¹²x+3×10¹⁵, and the value of the determination coefficient R² is 0.9826.

According to the formula of the regression line, it is indicated that the indium oxide film in which the extension length of the grain boundary is 0 nm has a property of transmitting oxygen in a range greater than or equal to 1×10¹⁵ atoms/cm² or greater than or equal to 2×10¹⁵ atoms/cm² in the heat treatment at a heating temperature of 400° C. for a treatment time of 8 hours. It is also indicated that the indium oxide film in which the extension length of the grain boundary is 1000 nm has a property of transmitting oxygen in a range less than or equal to 1×10¹⁶ atoms/cm² or less than or equal to 8×10¹⁵ atoms/cm² in the heat treatment at a heating temperature of 400° C. for a treatment time of 8 hours.

### [Hydrogen-Transmitting Property]

In order to evaluate the hydrogen-transmitting property of the indium oxide film, 10 samples (Samples 7A to 7J) were fabricated.

FIGS. 64A and 64B illustrate structures of stacked films included in the samples.

The stacked films included in each of Samples 7A and 7B include the layer 701, the layer 702 over the layer 701, the layer 703 over the layer 702, the layer 704 over the layer 703, the layer 705 over the layer 704, and the layer 706 over the layer 705 as illustrated in FIG. 64A.

The stacked films included in each of Samples 7C to 7J include the layer 701, the layer 702 over the layer 701, the layer 703 over the layer 702, the layer 707 over the layer 703, the layer 704 over the layer 707, the layer 705 over the layer 704, and the layer 706 over the layer 705 as illustrated in FIG. 64B. Note that the film used as the layer 707 corresponds to the indium oxide film.

A silicon substrate was prepared as the layer 701. A 100-nm-thick silicon oxide film was formed by thermal oxidation treatment as the layer 702. A 100-nm-thick silicon oxynitride film was formed by a PECVD method as the layer 703.

As the layer 707 in each of Samples 7C to 7J, an indium oxide film with a target thickness of 10 nm was formed by an ALD method. The indium oxide film in each of Samples 7C and 7D was formed under the same conditions as the indium oxide film included in Sample 2B. The indium oxide film in each of Samples 7E and 7F was formed under the same conditions as the indium oxide film included in Sample 2C. The indium oxide film in each of Samples 7G and 7H was formed under the same conditions as the indium oxide film included in Sample 2D. The indium oxide film in each of Samples 7I and 7J was formed under the same conditions as the indium oxide film included in Sample 2E.

A 50-nm-thick silicon oxynitride film was formed by a PECVD method as the layer 704. A 50-nm-thick silicon oxynitride film containing deuterium was formed by a PECVD method as the layer 705. The silicon oxynitride film was formed using a 5% deuterium (D₂) gas diluted with Ar, an SiH₄ gas, and an N₂O gas as film formation gases. A 20-nm-thick silicon nitride film was formed by a sputtering method as the layer 706.

Then, Samples 7B, 7D, 7F, 7H, and 7J were subjected to heat treatment at 200° C. for 8 hours in a nitrogen atmosphere. Samples 7A, 7C, 7E, 7G, and 7I were not subjected to the heat treatment.

Through the above steps, Samples 7A to 7J were fabricated.

By comparing the concentration distributions of deuterium (D (²H)) in Samples 7A to 7J, the hydrogen-transmitting property of the oxide film used as the layer 707 (the amount of hydrogen transmitted through the layer 707 by thermal diffusion or the degree at which the layer 707 inhibits thermal diffusion of hydrogen) can be evaluated.

Samples 7A to 7J were subjected to SIMS analysis. The analysis direction of the SIMS analysis is a direction from the layer 701 toward the layer 706. Through the SIMS analysis, the depth profile of the deuterium (D (²H)) concentration was obtained. The SIMS analysis was performed with a PHI-ADEPT1010 quadrupole SIMS instrument produced by ULVAC-PHI, Inc. Hereinafter, the depth profile of the deuterium (D (²H)) concentration is sometimes referred to as a D concentration profile or a D profile.

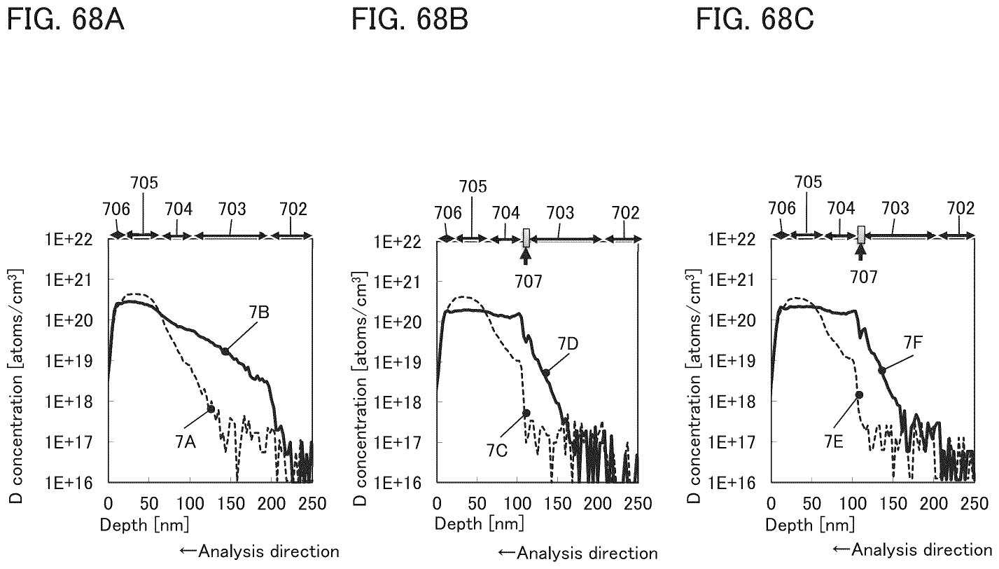

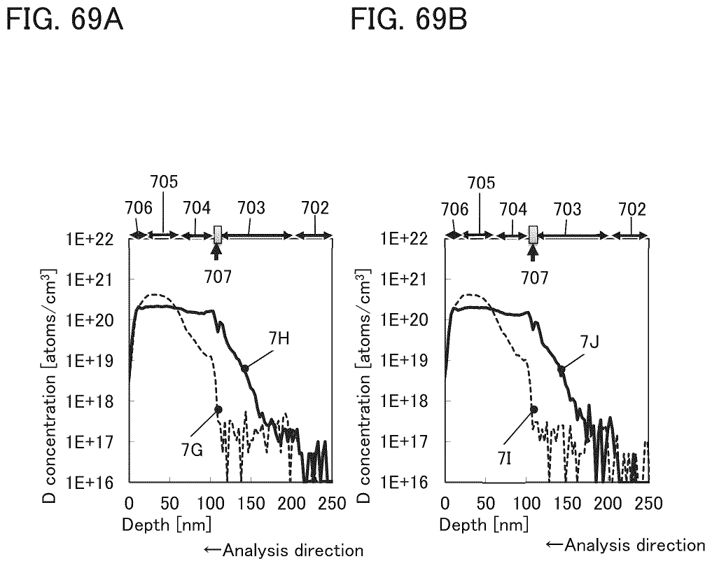

FIGS. 68A to 68C and FIGS. 69A and 69B show the D profiles of Samples 7A to 7J. In each of FIGS. 68A to 68C and FIGS. 69A and 69B, the horizontal axis represents the depth [nm] from the surface of the sample. The leftmost position at a depth of 0 nm corresponds to the surface of the sample (the surface of the layer 706). The vertical axis represents the D concentration [atoms/cm³]. The dashed line and the solid line in FIG. 68A respectively represent the D profile of Sample 7A and the D profile of Sample 7B. The dashed line and the solid line in FIG. 68B respectively represent the D profile of Sample 7C and the D profile of Sample 7D. The dashed line and the solid line in FIG. 68C respectively represent the D profile of Sample 7E and the D profile of Sample 7F. The dashed line and the solid line in FIG. 69A respectively represent the D profile of Sample 7G and the D profile of Sample 7H. The dashed line and the solid line in FIG. 69B respectively represent the D profile of Sample 7I and the D profile of Sample 7J. The background level of D in the SIMS analysis was 1.6×10¹⁶ atoms/cm³.

According to the D profiles of Samples 7A to 7J, the layer 705 includes a region where the concentration of deuterium measured by SIMS is higher than or equal to 1×10²⁰ atoms/cm³. The layer 703 before the heat treatment (the layer 703 in each of Samples 7A, 7C, 7E, 7G, and 7I) includes a region where the concentration of deuterium measured by SIMS is lower than 1×10¹⁸ atoms/cm³. This reveals that deuterium contained in the layer 705 does not diffuse into the layer 703 before the heat treatment.

It is found from FIGS. 68A to 68C and FIGS. 69A and 69B that deuterium contained in the layer 705 diffuses into the layer 703 in each of Samples 7B, 7D, 7F, 7H, and 7J subjected to the heat treatment. This indicates that deuterium contained in the layer 705 is transmitted through the indium oxide film by thermal diffusion.

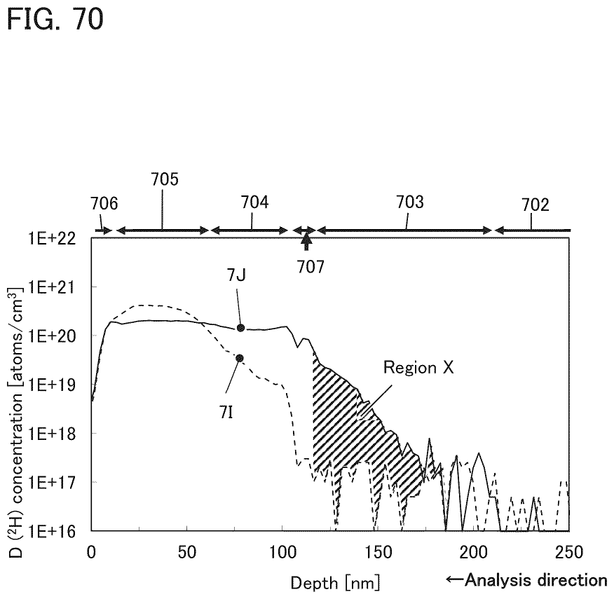

The D concentration profile of deuterium diffusing into the layer 703 through the layer 707 by the heat treatment at a heating temperature of 200° C. for a treatment time of 8 hours has distribution in the layer 703. Thus, transmission of deuterium through the indium oxide film was evaluated by integrating the amount per unit area of deuterium diffusing into the layer 703. FIG. 70 is a conceptual diagram showing a method for calculating the integral value. Specifically, the value (a region X in FIG. 70) obtained by subtracting the amount per unit area of deuterium in the layer 703 not subjected to the heat treatment from the amount per unit area of deuterium in the layer 703 subjected to the heat treatment at a heating temperature of 200° C. for a treatment time of 8 hours was regarded as the integral value of the diffusion amount of deuterium.

The integral value of the diffusion amount of deuterium into the layer 703 is 4.19×10¹³ atoms/cm² in Sample 7D, 5.23×10¹³ atoms/cm² in Sample 7F, 6.93×10¹³ atoms/cm² in Sample 7H, and 7.86×10¹³ atoms/cm² in Sample 7J. That is, in the case where the layer 707 (the indium oxide film) is provided between the layer 705 and the layer 703, it is confirmed that the integral value of the diffusion amount of deuterium, which is contained in the layer 705, into the layer 703 through the layer 707 by the heat treatment at a heating temperature of 200° C. for a treatment time of 8 hours is greater than or equal to 2×10¹³ atoms/cm², specifically greater than or equal to 4×10¹³ atoms/cm².

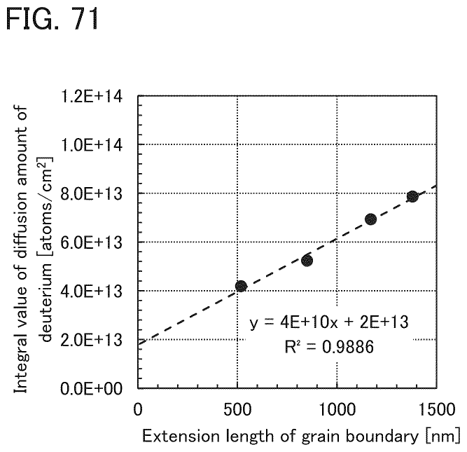

FIG. 71 shows a graph in which the extension length of the grain boundary is plotted on the horizontal axis and the integral value of the diffusion amount of deuterium into the layer 703 is plotted on the vertical axis. The dashed line in FIG. 7I represents a regression line with respect to the plot, the formula of the regression line is y=4×10¹⁰x+2×10¹³, and the value of the determination coefficient R² is 0.9886.

According to the formula of the regression line, it is indicated that the indium oxide film in which the extension length of the grain boundary is 0 nm has a property of transmitting deuterium by the heat treatment at a heating temperature of 200° C. for a treatment time of 8 hours such that the integral value of the diffusion amount of deuterium into the layer 703 is greater than or equal to 5×10¹² atoms/cm² or greater than or equal to 1×10¹³ atoms/cm². It is also indicated that the indium oxide film in which the extension length of the grain boundary is 1000 nm has a property of transmitting deuterium by the heat treatment at a heating temperature of 200° C. for a treatment time of 8 hours such that the integral value of the diffusion amount of deuterium into the layer 703 is less than or equal to 1×10¹⁴ atoms/cm² or less than or equal to 8×10¹³ atoms/cm².

FIG. 71 shows that as the extension length of the grain boundary is longer, the integral value of the diffusion amount of deuterium into the layer 703 tends to be larger. In other words, it is revealed that the indium oxide film having more grain boundaries per unit volume transmits a larger amount of deuterium. This indicates that hydrogen diffuses through the crystal grain boundary in the indium oxide film. It is also indicated that the grain boundary diffusion of hydrogen occurs in the indium oxide film.

The intercept of the regression line is 2×10¹³ atoms/cm². In the case where the indium oxide film in which the extension length of the grain boundary is 0 nm is regarded as a single crystal indium oxide film, it is indicated that deuterium diffuses in a crystal grain (bulk) even in the single crystal indium oxide film. For example, it is indicated that deuterium in a range greater than or equal to 5×10¹² atoms/cm² or greater than or equal to 1×10¹³ atoms/cm² diffuses in the crystal grain included in the indium oxide film by the heat treatment at a heating temperature of 200° C. for a treatment time of 8 hours.

In this example, the hydrogen-transmitting property of the indium oxide film was evaluated using deuterium because the indium oxide film formed in this example contains hydrogen. Since deuterium is an isotope of hydrogen, a deuterium-transmitting property is presumably equivalent to a hydrogen-transmitting property. Accordingly, the deuterium-transmitting property, the diffusion of deuterium, and the integral value of the diffusion amount of deuterium can be rephrased respectively as a hydrogen-transmitting property, diffusion of hydrogen, and an integral value of the diffusion amount of hydrogen.

The above results demonstrate that the indium oxide film has a property of transmitting hydrogen. It is also demonstrated that not only the grain boundary diffusion of hydrogen but also the diffusion of hydrogen in the crystal grain (bulk) occurs in the indium oxide film.

The structure, configuration, method, or the like described in this example can be used in an appropriate combination with any of the structures, configurations, methods, and the like described in the other embodiments and the like.

### Example 2

In this example, the amount of oxygen released from an indium oxide film was evaluated.

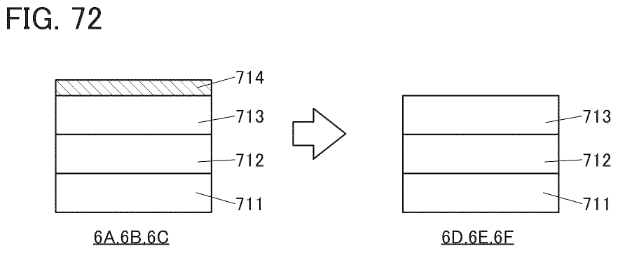

In this example, Samples 6A to 6F were fabricated. FIG. 72 shows cross-sectional views illustrating structures and fabrication methods of Samples 6A to 6F.

### <Sample Fabrication>

First, a glass substrate was prepared as a substrate 711. Next, an approximately 100-nm-thick silicon nitride film was formed as an insulating film 712 over the substrate 711, and an approximately 100-nm-thick silicon oxynitride film was formed as an insulating film 713. The insulating film 712 and the insulating film 713 were formed by a PECVD method, and the substrate temperature at the time of the formation was 350° C.

Then, an approximately 50-nm-thick film was formed as an oxide semiconductor film 714 over the insulating film 713. Here, a material of the oxide semiconductor film 714 was different between the samples. The oxide semiconductor film 714 in each of Samples 6A and 6D was formed by a sputtering method using an indium oxide sputtering target, the substrate temperature at the time of the formation was 250° C., and an oxygen gas was used as a film formation gas. The oxide semiconductor film 714 in each of Samples 6B and 6E was formed by a sputtering method using an In—Sn—Zn oxide sputtering target with an atomic ratio of metal elements of In:Sn:Zn=40:1:10 (4:0.1:1), the substrate temperature at the time of the formation was 200° C., and an oxygen gas was used as a film formation gas. The oxide semiconductor film 714 in each of Samples 6C and 6F was formed by a sputtering method using an IGZO sputtering target with an atomic ratio of metal elements of In:Ga:Zn=1:1:1, the substrate was not heated at the time of the formation, and an oxygen gas was used as a film formation gas.

Next, the oxide semiconductor film 714 in each of Samples 6D to 6F was removed (see FIG. 72). The oxide semiconductor film 714 was removed by a wet etching method. Thus, the insulating film 713 in each of Samples 6D to 6F was exposed. The oxide semiconductor film 714 in each of Samples 6A to 6C was not removed (see FIG. 72).

Through the above steps, Samples 6A to 6F were fabricated.

### <TDS Analysis>

A gas released from each of the samples was evaluated by thermal desorption spectroscopy (TDS). In the TDS measurement, the substrate temperature was increased from approximately 50° C. to approximately 500° C. at a substrate temperature rising rate of approximately 15° C./min.

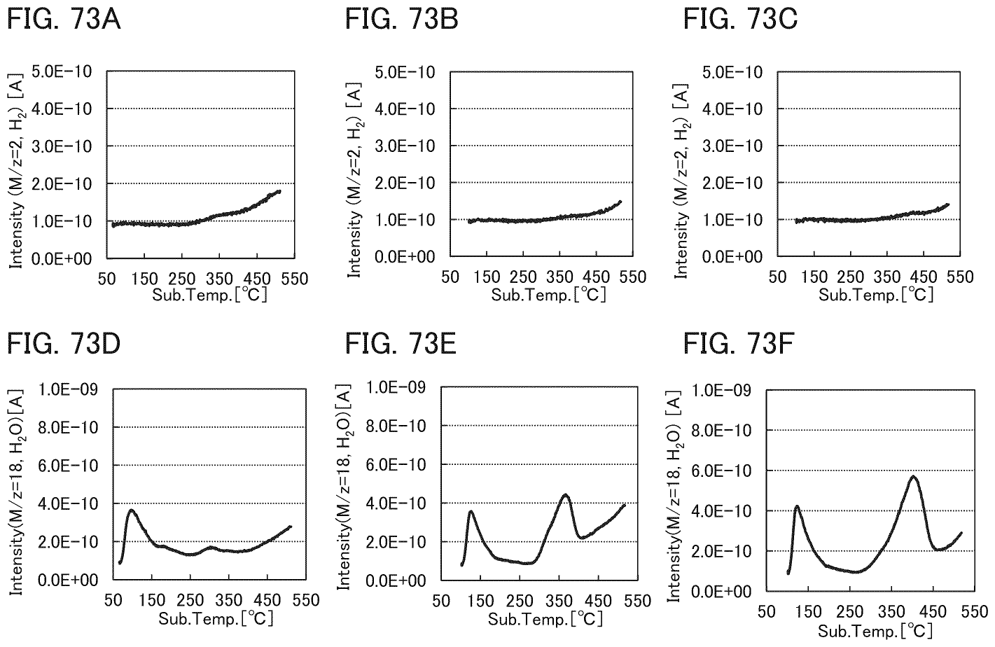

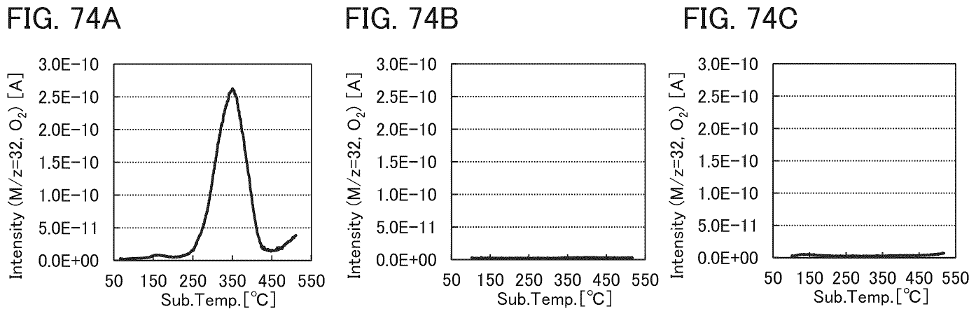

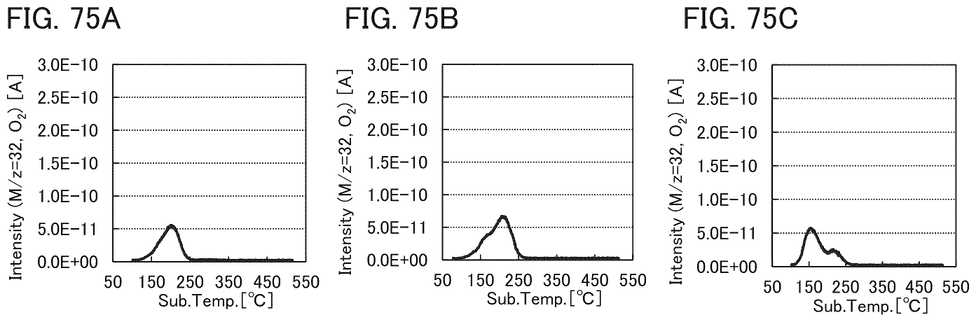

FIGS. 73A to 73F and FIGS. 74A to 74C show the TDS analysis results of Samples 6A to 6C. FIGS. 75A to 75C show the TDS analysis results of Samples 6D to 6F. FIGS. 73A to 73C show the TDS analysis results of hydrogen (H₂, M/z=2), FIGS. 73D to 73F show the TDS analysis results of water (H₂O, M/z=18), and FIGS. 74A to 74C and FIGS. 75A to 75C show the TDS analysis results of oxygen (¹⁶O₂, M/z=32). In each of the graphs showing the TDS analysis results, the horizontal axis represents the substrate temperature (Sub. Temp.) and the vertical axis represents the detection intensity (Intensity).

FIGS. 73A and 73D and FIG. 74A show the data of Sample 6A, FIGS. 73B and 73E and FIG. 74B show the data of Sample 6B, and FIGS. 73C and 73F and FIG. 74C show the data of Sample 6C. FIG. 75A shows the data of Sample 6D, FIG. 75B shows the data of Sample 6E, and FIG. 75C shows the data of Sample 6F.

FIGS. 73A to 73C reveal that the amount of H₂ released from Sample 6A is larger than the amounts of H₂ released from Samples 6B and 6C. FIGS. 73D to 73F show that the amount of H₂O released from Sample 6A is smaller than the amounts of H₂O released from Samples 6B and 6C. It is presumed that hydrogen is bonded to oxygen in the oxide semiconductor film 714 to be released as H₂O. Accordingly, it is indicated that hydrogen is transmitted through the oxide semiconductor film 714 more easily in Sample 6A than in Samples 6B and 6C.

According to FIGS. 74A to 74C, the amount of O₂ released from Sample 6A is much larger than the amounts of O₂ released from Samples 6B and 6C. Specifically, the released amount of oxygen in the entire measured temperature range is 4.30×10¹⁵ cm⁻² in Sample 6A, 4.50×10¹³ cm⁻² in Sample 6B, and 9.30×10¹³ cm⁻² in Sample 6C.

FIGS. 75A to 75C reveal that the amounts of O₂ released from Samples 6D to 6F are each approximately 1×10¹⁵ cm⁻². Specifically, the released amount of oxygen in the entire measured temperature range is 7.10×10¹⁴ cm⁻² in Sample 6D, 1.00×10¹⁵ cm⁻² in Sample 6E, and 7.30×10¹⁴ cm⁻² in Sample 6F. Accordingly, it is found that a certain amount of oxygen is supplied to the insulating film 713 at the time of forming the oxide semiconductor film 714.

A difference between the amount of O₂ released from Sample 6A and the amount of O₂ released from Sample 6D is approximately 3×10¹⁵ cm⁻². This indicates that oxygen in the indium oxide film is easily released as O₂. That is, the indium oxide film is found to have a high oxygen-transmitting property. It is also found that oxygen in the indium oxide film easily diffuses. Thus, even in the case where a defect such as an oxygen vacancy or VOH is formed in the indium oxide film, oxygen in the indium oxide film can diffuse to repair the defect immediately, so that the reliability can be increased.

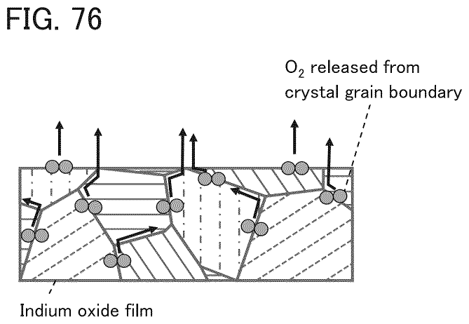

Inspection of the TDS analysis results of oxygen (1602, M/z=32) in Sample 6A (see FIG. 74A) indicates that surface reaction release is a bottleneck in release of O₂ from the indium oxide film. The indium oxide film included in Sample 6A is found to be a polycrystal film as a result of STEM observation. The above results demonstrate that, as shown in FIG. 76, excess oxygen in the indium oxide film exists mainly in the crystal grain boundary in the form of an oxygen molecule (O₂), and is released as the oxygen molecule to the outside from the crystal grain boundary by cutting the surface adsorption bond.

The structure, configuration, method, or the like described in this example can be used in an appropriate combination with any of the structures, configurations, methods, and the like described in the other embodiments and the like.

This application is based on Japanese Patent Application Serial No. 2024-045180 filed with Japan Patent Office on Mar. 21, 2024, Japanese Patent Application Serial No. 2024-045186 filed with Japan Patent Office on Mar. 21, 2024, Japanese Patent Application Serial No. 2024-084366 filed with Japan Patent Office on May 23, 2024, and Japanese Patent Application Serial No. 2024-229970 filed with Japan Patent Office on Dec. 26, 2024, the entire contents of which are hereby incorporated by reference.

What is claimed is:

1. An oxide semiconductor film comprising:
indium;
oxygen; and
a crystal grain,
wherein a gallium concentration and a zinc concentration in the oxide semiconductor film are each lower than or equal to 0.1 atomic %,
wherein an extension length of a grain boundary in the oxide semiconductor film is greater than or equal to 0 nm and less than or equal to 10000 nm,
wherein the extension length of the grain boundary is calculated using a field of view of 90 nm square extracted from a transmission electron microscope image of the oxide semiconductor film, and
wherein the oxide semiconductor film has a property of transmitting oxygen in a range higher than or equal to 2×10²⁰ atoms/cm³ and lower than or equal to 1×10²¹ atoms/cm³ in heat treatment at a heating temperature of 400° C. for a treatment time of 8 hours.

2. An oxide semiconductor film having a property of transmitting oxygen, comprising:
indium;
oxygen; and
a crystal grain,
wherein a gallium concentration and a zinc concentration in the oxide semiconductor film are each lower than or equal to 0.1 atomic %,
wherein an extension length of a grain boundary in the oxide semiconductor film is greater than or equal to 0 nm and less than or equal to 10000 nm,
wherein the extension length of the grain boundary is calculated using a field of view of 90 nm square extracted from a transmission electron microscope image of the oxide semiconductor film,
wherein, when the oxide semiconductor film is between a first film and a second film, oxygen in a range higher than or equal to 2×10²⁰ atoms/cm³ in the first film diffuses into the second film through the oxide semiconductor film by heat treatment at a heating temperature of 400° C. for a treatment time of 8 hours,
wherein the first film comprises a region where an oxygen concentration measured by secondary ion mass spectrometry is higher than or equal to 1×10²² atoms/cm³, and
wherein the second film before the heat treatment comprises a region where an oxygen concentration measured by secondary ion mass spectrometry is lower than 1×10²⁰ atoms/cm³.

3. An oxide semiconductor film comprising:
indium;
oxygen; and
a crystal grain,
wherein a gallium concentration and a zinc concentration in the oxide semiconductor film are each lower than or equal to 0.1 atomic %,
wherein an extension length of a grain boundary in the oxide semiconductor film is greater than or equal to 0 nm and less than or equal to 10000 nm,
wherein the extension length of the grain boundary is calculated using a field of view of 90 nm square extracted from a transmission electron microscope image of the oxide semiconductor film, and
wherein the oxide semiconductor film has a property such that an integral value of a diffusion amount of deuterium is greater than or equal to 5×10¹² atoms/cm² and less than or equal to 1×10¹⁴ atoms/cm² in heat treatment at a heating temperature of 200° C. for a treatment time of 8 hours.

4. The oxide semiconductor film according to claim 1, wherein the extension length of the grain boundary in the oxide semiconductor film is greater than or equal to 0 nm and less than or equal to 1000 nm.

5. The oxide semiconductor film according to claim 1, wherein a carbon concentration and an aluminum concentration in the oxide semiconductor film are each lower than 100 ppm.

6. A semiconductor device comprising:
an oxide semiconductor layer comprising the oxide semiconductor film according to claim 1;
a conductive layer; and
an insulating layer comprising a portion positioned between the oxide semiconductor layer and the conductive layer.

7. The semiconductor device according to claim 6, further comprising an oxide layer overlapping with the insulating layer with the oxide semiconductor layer therebetween,
wherein the oxide layer comprises a cubic crystal grain.

8. The semiconductor device according to claim 7, wherein a lattice mismatch degree of the crystal grain in the oxide semiconductor film with respect to the crystal grain in the oxide layer is higher than or equal to −10% and lower than or equal to 10%.

9. The semiconductor device according to claim 7, wherein the oxide layer comprises yttrium, zirconium, and oxygen.

10. The semiconductor device according to claim 6, further comprising an oxide layer overlapping with the insulating layer with the oxide semiconductor layer therebetween,
wherein the oxide layer comprises a hexagonal crystal grain or a trigonal crystal grain.

11. The semiconductor device according to claim 10, wherein a c-axis of the crystal grain in the oxide layer is perpendicular or substantially perpendicular to a surface or a formation surface of the oxide layer.

12. The semiconductor device according to claim 10, wherein the oxide layer comprises indium, gallium, zinc, and oxygen.

13. The semiconductor device according to claim 12, further comprising a layer between the oxide layer and the oxide semiconductor layer,
wherein the layer comprises aluminum and oxygen.

14. The semiconductor device according to claim 6,
wherein the oxide semiconductor layer comprises an In—Ga—Zn oxide film over the oxide semiconductor film, and
wherein the oxide semiconductor film has a higher property of transmitting one or both of an oxygen atom and a hydrogen atom than the In—Ga—Zn oxide film.

15. The oxide semiconductor film according to claim 2, wherein the extension length of the grain boundary in the oxide semiconductor film is greater than or equal to 0 nm and less than or equal to 1000 nm.

16. The oxide semiconductor film according to claim 2, wherein a carbon concentration and an aluminum concentration in the oxide semiconductor film are each lower than 100 ppm.

17. A semiconductor device comprising:
an oxide semiconductor layer comprising the oxide semiconductor film according to claim 2;
a conductive layer; and
an insulating layer comprising a portion positioned between the oxide semiconductor layer and the conductive layer.

18. The oxide semiconductor film according to claim 3, wherein the extension length of the grain boundary in the oxide semiconductor film is greater than or equal to 0 nm and less than or equal to 1000 nm.

19. The oxide semiconductor film according to claim 3, wherein a carbon concentration and an aluminum concentration in the oxide semiconductor film are each lower than 100 ppm.

20. A semiconductor device comprising:
an oxide semiconductor layer comprising the oxide semiconductor film according to claim 3;
a conductive layer; and
an insulating layer comprising a portion positioned between the oxide semiconductor layer and the conductive layer.
